(19) United States
(12) Patent Application Publication
(10) Pub. No.: US 2026/0090293 A1
(43) Pub. Date: Mar. 26, 2026

(54) SEMICONDUCTOR STACKS AND PROCESSES THEREOF

(71) Applicant: Lam Research Corporation, Fremont, CA (US)

(72) Inventors: Easwar Srinivasan, Portland, OR (US); Bhadri N. Varadarajan, Beaverton, OR (US); Karl Frederick Leeser, West Linn, OR (US); Dennis M. Hausmann, Lake Oswego, OR (US); Bart J. van Schravendijk, Palo Alto, CA (US); Aaron Durbin, Portland, OR (US); Ramesh Chandrasekharan, Lake Oswego, OR (US); Yukinori Sakiyama, West Linn, OR (US)

(21) Appl. No.: 19/114,262

(22) PCT Filed: Sep. 19, 2023
(86) PCT No.: PCT/US2023/033175

§ 371 Date: Mar. 21, 2025

Related U.S. Application Data
(60) Provisional application No. 63/376,560, filed on Sep. 21, 2022.

(51) Int. Cl. H10P 14/20; C23C 16/02; C23C 16/44; C23C 16/455; C23C 16/52; C30B 25/10; C30B 25/16; C30B 25/18; C30B 29/68; H01J 37/32; H10P 14/24; H10P 70/00

(52) U.S. Cl. CPC H10P 14/3411; C23C 16/0227; C23C 16/4401; C23C 16/45536; C23C 16/45544; C23C 16/52; C30B 25/105; C30B 25/165; C30B 25/186; C30B 29/68; H01J 37/32449; H10P 14/24; H10P 70/12; H01J 2237/3321

(57) ABSTRACT

The present disclosure relates to vertical stacks including heterolayers, as well as processes and methods of their manufacture. Also described herein are apparatuses and systems for preparing and making such stacks.

### INCORPORATION BY REFERENCE

An Application Data Sheet is filed concurrently with this specification as part of this application. Each application to which this application claims benefit or priority as identified in the concurrently filed Application Data Sheet is incorporated by reference herein in its entirety and for all purposes.

### FIELD

The present disclosure relates to vertical stacks including heterolayers, as well as processes and methods of their manufacture.

### BACKGROUND

Controlled deposition of heterolayers remains a challenge. In particular, if high temperature processes are employed, interdiffusion of atoms between such layers can result.

The background description provided herein is for the purpose of generally presenting the context of the present technology. Work of the presently named inventors, to the extent it is described in this background section, as well as aspects of the description that may not otherwise qualify as prior art at the time of filing, are neither expressly nor impliedly admitted as prior art against the present technology.

### SUMMARY

The present disclosure relates to vertical stacks including heterolayers. In some instances, the stacks include heteroepitaxial layers. Such heterolayers or heteroepitaxial layers can, in some instances, include alternating first layers and second layers; alternating first semiconductor layers and second semiconductor layers; alternating semiconductor layers and sacrificial layers; alternating silicon-containing layers (Si layers) and silicon- and germanium-containing layers (SiGe layers); or the like.

Currently, the industry standard relies on thermal-based chemical vapor deposition (CVD) to obtain epitaxial layers. For a vertical stack including numerous heteroepitaxial layers, use of high temperature (e.g., greater than about 600° C., 650° C., 700° C., 800° C., 900° C., or more) can increase the deposition rate but at the risk of leading to interdiffusion of atoms between the heterolayers. Furthermore, use of such a high temperature can reduce the height of the stack that can be grown due to increased lattice defect formation under such conditions. While use of lower temperatures can reduce interdiffusion and reduce lattice defect formation, growth rates of the epitaxial layers can be so low that the process is no longer economical. Thus, in one instance, the plasma-based epitaxy methods herein can provide sufficient growth rates for deposited heterolayers, while reducing interdiffusion. Furthermore, if low temperature, plasma-based epitaxy is employed, then a higher limit for critical thickness (he) can allow for thicker stacks and thicker epitaxial layers, as more fully described herein.

In a first aspect, the present disclosure encompasses a method for forming heterolayers on a substrate. In particular embodiments, the method includes: (a) forming a first layer (e.g., a first semiconductor layer) by flowing a first precursor into the reaction chamber and toward the substrate in the presence of an energetic species; and (b) forming a second layer (e.g., a second semiconductor layer) by flowing a second precursor and an optional third precursor into the reaction chamber and toward the substrate in the presence of an energetic species.

In some embodiments, the method further includes: (c) repeating operation (a) and operation (b) until a predetermined number of layers have been deposited on the substrate. In particular embodiments, the predetermined number of layers are deposited at a temperature of less than about 650° C. or less than about 600° C.

In some embodiments, the method further includes (e.g., prior to operation (a)): providing a substrate in a reaction chamber (e.g., an epitaxy chamber), wherein the substrate is at least one of optionally precleaned or optionally pretreated.

In some embodiments, the substrate is precleaned, thereby providing a precleaned surface. In other embodiments, the substrate is pretreated, thereby providing a pretreated surface.

In yet other embodiments, the substrate is precleaned and pretreated, thereby providing a precleaned and pretreated surface.

In some embodiments, the energetic species includes at least one of radicals, metastables, ions, neutrals, plasma, photons, radiation, excited molecules, excited atoms, or others described herein, as well as plasma-generated forms of radicals, metastables, ions, neutrals, excited molecules, or excited atoms.

In some embodiments, the energetic species (e.g., at least one of radicals, metastables, or other energetic species described herein) reacts with the first precursor to deposit the first layer on the substrate. In other embodiments, the energetic species (e.g., at least one of radicals, metastables, or other energetic species described herein) reacts with the second precursor to deposit the second layer on the substrate. In yet other embodiments, the energetic species reacts with the second precursor and with the third precursor to deposit the second layer on the substrate. A particular type of energetic species may be used alone, or two (or more) different types may be used together. For example and without limitation, radicals may be used alone, metastables may be used alone, or both radicals and metastables may be used together.

In some embodiments, the second layer includes a sacrificial layer.

In other embodiments, the method further includes (e.g., before operation (a) or (b)): (a″′) depositing a buffer layer between the substrate and the first layer or between the substrate and the second layer.

In some embodiments, operations (a) and (b) occur subsequent to an initial layer (e.g., an initial semiconductor layer) being deposited on the substrate. The initial layer can include a layer (e.g., an epitaxial layer) composed of any semiconductor material described herein. In other embodiments, operations (a) and (b) occur subsequent to a buffer layer being deposited on the substrate.

In some embodiments, the first precursor and the second precursor are different. In further embodiments, operation (b) includes the third precursor, in which the first precursor and the third precursor are the same. Alternatively, the first precursor and the third precursor can be different.

In some embodiments, operation (a) is performed before operation (b). In other embodiments, operation (b) is performed before operation (a).

In some embodiments, the method further includes (e.g., before or during operation (a) or operation (b)): filtering the energetic species (e.g., at least one of the radicals or the metastables) prior to flowing the energetic species (e.g., the radicals or the metastables) to the reaction chamber from the remote plasma source.

In some embodiments, the energetic species (e.g., at least one of the radicals or the metastables) is generated in a remote plasma source positioned upstream of a reaction chamber. In other embodiments, operation (a) includes: generating the energetic species (e.g., at least one of the radicals or the metastables) in the remote plasma source and the flowing in operation (a) includes introducing the first precursor downstream from the remote plasma source. In yet other embodiments, operation (b) includes: generating the energetic species (e.g., at least one of the radicals or the metastables) in the remote plasma source and the flowing in operation (b) includes introducing at least one of the second precursor or the optional third precursor downstream from the remote plasma source.

In some embodiments, the energetic species (e.g., at least one of the radicals or metastables) is generated in situ in a portion of the reaction chamber.

In some embodiments, the energetic species (e.g., at least one of the radicals or metastables) is generated by way of plasma. Non-limiting examples of plasma include capacitively coupled plasma (CCP), inductively coupled plasma (ICP), transformer coupled plasma (TCP), electron cyclotron resonance (ECR) plasma, surface wave plasma (SWP, e.g., plasma generated using a radial line slot antenna (RLSA)), microwave plasma (MWP), plasma generated using ultraviolet (UV) radiation, low energy plasma (LEP), low temperature plasma (LTP), and the like.

In some embodiments, the energetic species (e.g., at least one of the radicals or the metastables) is generated using a source gas that includes a hydrogen-containing gas or a deuterium-containing gas. In particular embodiments, the hydrogen-containing gas or the deuterium-containing gas is mixed with a carrier gas including an inert gas (e.g., at least one of argon, helium, or the like, as well as combinations thereof).

In some embodiments, the method further includes (e.g., before or during operation (a), as well as before or during operation (b)): heating the substrate using a radiative heat source. In some embodiments, the substrate is heated from a frontside of the substrate. In other embodiments, the substrate is heated (e.g., on a frontside) using a pedestal on which the substrate resides. In yet other embodiments, the substrate is heated from a backside of the substrate.

In some embodiments, the first layer includes a silicon-containing layer (Si-containing layer), and the second layer includes a silicon- and germanium-containing layer (SiGe-containing layer). In other embodiments, the first layer includes a silicon- and germanium-containing layer (SiGe-containing layer), and the second layer includes a silicon-containing layer (Si-containing layer). In particular embodiments, a concentration of germanium (Ge) within the layer is within a range of about 10 atomic % (at. %) to 50 at. %. In yet other embodiments, the concentration of Ge within the layer forms a concentration gradient (e.g., having a concentration gradient that extends within the layer, in which the gradient has a change in concentration from about 10 at. % to 50 at. %, 15 at. % to 50 at. %, 20 at. % to 50 at. %, 10 at. % to 20 at. %, 10 at. % to 30 at. %, and 10 at. % to 40 at. %, as well as ranges therebetween).

In some embodiments, the method further includes: providing an interfacial layer between the first layer and the second layer. Such an operation can be provided after operation (a), between operation (a) and operation (b), or after operation (b). In some embodiments, the interfacial layer is an epitaxial layer. One or more interfacial layers may be presented between the first and second layers. The concentration of one or more atoms (e.g., Si, Ge, Group IV atoms, or other atoms described herein) may be the same or different within each interfacial layers. The concentration of atom(s) can be within any useful range, such as from about 10 at. % to 50 at. %. In one instance, the concentration of a particular atom is different within two or more different interfacial layers. In another instance, the concentration of a first atom in a first interfacial layer is the same as the concentration of a second atom in a second interfacial layer, in which the first and second atoms are different. In yet another instance, the concentration of a first atom in a first interfacial layer is different from the concentration of a second atom in a second interfacial layer, in which the first and second atoms are different. In yet other embodiments, the concentration of the first atom or the second atom within the layer forms a concentration gradient (e.g., having a concentration gradient that extends from about 10 at. % to 50 at. %, 15 at. % to 50 at. %, 20 at. % to 50 at. %, 10 at. % to 20 at. %, 10 at. % to 30 at. %, and 10 at. % to 40 at. %, as well as ranges therebetween).

In some embodiments, the method further includes: exposing the substrate to a plasma between operations (a) and (b). Without wishing to be limited by mechanism, such an exposing operation can be performed on a surface of the first layer or on a surface of the second layer to provide a prepared surface. In some implementations, this may provide a smoothened surface for depositing the next layer.

In some embodiments, the method further includes at least one of (e.g., before operation (a)): (a′) precleaning the substrate to provide a precleaned surface of the substrate; or (a″) pretreating the surface of the substrate to provide a pretreated surface of the substrate. In some embodiments, the method includes performing operation (a′) only, performing operation (a″) only, or performing both operations (a′) and (a″). In some embodiments, the precleaned surface includes an oxide-free surface. In other embodiments, the pretreated surface includes a hydrophobic surface or a passivated surface. Further details regarding precleaning operations and pretreating operations are described herein (e.g., as described in paragraphs [0278] to [0405], or elsewhere herein).

In some embodiments, operation (a′) includes delivering a halogen-containing reagent (e.g., any described herein, including halogen-containing compounds, liquids, solutions, or gases), a halogen-containing vapor (e.g., a fluorine-containing vapor) or a halogen-containing plasma (e.g., a fluorine-containing plasma). In other embodiments, operation (a′) includes removing an oxide from a surface of the substrate.

In some embodiments, operation (a″) includes delivering a hydrogen-containing reagent (e.g., any described herein, including hydrogen-containing compounds, liquids, solutions, or gases), a deuterium-containing reagent (e.g., any described herein, including deuterium-containing compounds, liquids, solutions, or gases), a hydrogen-containing plasma, or a deuterium-containing plasma. In other embodiments, operation (a″) includes forming a hydrogenated surface or a deuterated surface on the substrate. In yet other embodiments, operation (a″) is performed within the reactor chamber.

In some embodiments, the method further includes (e.g., before operation (a) or after operation (c)) at least one of: (c′) performing a reactor clean of the reaction chamber either after removing the substrate from the reaction chamber or before providing the substrate to the reaction chamber by removing contaminants from an environment or a surface within the reaction chamber; or (c″) performing a reactor treat of the reaction chamber by passivating the environment or the surface within the reaction chamber.

In some embodiments, the method further includes (e.g., prior to operation (a)): cleaning or treating the reaction chamber. Further details regarding reactor cleaning operations and reactor treating operations are described herein (e.g., as described in paragraphs [0478] to [0492], or elsewhere herein).

In some embodiments, at least one of operation (a) or operation (b) includes generating a plasma including at least one of the radicals or the metastables. In other embodiments, the generating and the flowing in at least one of operation (a) or operation (b) are performed in any order or simultaneously. In yet other embodiments, the plasma is generated in a remote plasma source positioned upstream of the reaction chamber. Further details regarding plasma-based deposition operations are described herein (e.g., as described in paragraphs [0406] to [0437], or elsewhere herein).

In some embodiments, the plasma is generated using a source gas that includes a hydrogen-containing gas or a deuterium-containing gas. In some embodiments, the hydrogen-containing gas or the deuterium-containing gas is mixed with a carrier gas including an inert gas (e.g., any described herein).

In some embodiments, the first layer has a thickness of about 5 nanometers (nm) to 60 nm. In other embodiments, the second layer has a thickness of about 5 nm to 25 nm. In yet other embodiments, each of the at least one of the first layer or the second layer has, independently, a thickness of about 3 nm to 60 nm, as well as ranges therebetween (e.g., from about 3 nm to 50 nm, 3 nm to 40 nm, 3 nm to 30 nm, 3 nm to 25 nm, 3 nm to 20 nm, 4 nm to 60 nm, 4 nm to 50 nm, 4 nm to 40 nm, 4 nm to 30 nm, 4 nm to 25 nm, 4 nm to 20 nm, 5 nm to 60 nm, 5 nm to 50 nm, 5 nm to 40 nm, 5 nm to 30 nm, 5 nm to 25 nm, 5 nm to 20 nm, 6 nm to 60 nm, 6 nm to 50 nm, 6 nm to 40 nm, 6 nm to 30 nm, 6 nm to 25 nm, 6 nm to 20 nm, 7 nm to 60 nm, 7 nm to 50 nm, 7 nm to 40 nm, 7 nm to 30 nm, 7 nm to 25 nm, 7 nm to 20 nm, 8 nm to 60 nm, 8 nm to 50 nm, 8 nm to 40 nm, 8 nm to 30 nm, 8 nm to 25 nm, 8 nm to 20 nm, 9 nm to 60 nm, 9 nm to 50 nm, 9 nm to 40 nm, 9 nm to 30 nm, 9 nm to 25 nm, 9 nm to 20 nm, 10 nm to 60 nm, 10 nm to 50 nm, 10 nm to 40 nm, 10 nm to 30 nm, 10 nm to 25 nm, or 10 nm to 20 nm).

In a second aspect, the present disclosure encompasses an apparatus to form heterolayers on a substrate. In some embodiments, the apparatus includes: a reaction chamber; a substrate support positioned in the reaction chamber and configured to support a substrate; a plasma source; and one or more controllers configured with instructions for performing any method or any operation(s) described herein.

In some embodiments, the one or more controllers are configured with instructions for performing the following operations: (a) causing formation of a first layer (e.g., a first semiconductor layer) by flowing a first precursor into the reaction chamber and toward the substrate in the presence of a plasma-generated energetic species; (b) causing formation of a second layer (e.g., a second semiconductor layer) by flowing a second precursor and an optional third precursor into the reaction chamber and toward the substrate in the presence of a plasma-generated reactive species; and (c) causing repetition of (a) and (b) until a predetermined number of layers have been deposited on the substrate. In particular embodiments, the first layer has a differing etch behavior than the second layer.

In some embodiments, the plasma-generated energetic species includes one or more plasma-generated radicals, plasma-generated metastables, or plasma-generated ions.

In some embodiments, operation (a) to cause formation of the first layer includes reacting the plasma-generated energetic species with the first precursor to deposit the first layer on the substrate. In other embodiments, operation (b) to cause formation of a second layer includes reacting the plasma-generated energetic species with the second precursor and the optional third precursor to deposit the second layer on the substrate.

In some embodiments, the one or more controllers are configured with instructions for performing the following operation (e.g., before operation (a)): (a′) causing to provide the substrate in the reaction chamber.

In some embodiments, the one or more controllers are configured with instructions for performing the following operation: generating a plasma in operation (a) or operation (b) (e.g., optionally in a remote plasma source), wherein the plasma includes at least one of plasma-generated radicals or plasma-generated metastables. Non-limiting examples of plasma-generated radicals and plasma-generated metastables include at least one of hydrogen-containing radicals, deuterium-containing radicals, helium-containing metastables, or argon-containing metastables, as well as combinations thereof. In other embodiments, the generating and the flowing in operations (a) and (b) are performed in any order or simultaneously.

In some embodiments, the plasma source of the apparatus is an in situ plasma source positioned in the reaction chamber. In other embodiments, the plasma source is a remote plasma source positioned upstream from the reaction chamber. In further embodiments, the remote plasma source is fluidly coupled to the reaction chamber via one or more gas outlets.

In some embodiments, the one or more controllers are configured with instructions for performing the following operation: generating a plasma in operation (a) or operation (b), wherein the generating includes generating the plasma in the remote plasma source. In further embodiments, the flowing in operation (a) includes introducing the first precursor downstream from the remote plasma source. In other embodiments, the flowing in operation (b) includes introducing at least one of the second precursor or the optional third precursor downstream from the remote plasma source.

In some embodiments, the apparatus further includes at least one of a water trap or one or more water pumps. In particular embodiments, the water trap or the water pump is located in a process chamber (e.g., a reaction chamber, an epitaxy chamber, or others described herein) or a module (e.g., a transfer module, a processing module, or others described herein). In other embodiments, the water trap or the water pump is located at a gas outlet of the one or more gas outlets. In any embodiment herein, the water trap or the water pump is configured to reduce at least one of moisture or an oxygen level. In some embodiments, the water trap or the water pump is configured to maintain an oxygen level within the reaction chamber of less than about 500 ppb. Non-limiting examples of water pumps include a cryopump, a turbopump, a drag pump, a getter pump, a roughing pump, as well as others described herein.

In some embodiments, the one or more gas outlets or gas inlets include stainless steel.

In some embodiments, the apparatus further includes a purifier at a gas inlet fluidly coupled to a processing chamber (e.g., a reaction chamber, an epitaxy chamber, or others described herein) or a module (e.g., a transfer module, a processing module, or others described herein). In particular embodiments, the purifier is configured to reduce at least one of moisture or an oxygen level.

In some embodiments, the apparatus further includes a gas line, which in turn includes one or more heaters to enable bake-out. In particular embodiments, the one or more heaters (e.g., heating elements) are associated with one or more valves upstream of the reaction chamber.

In some embodiments, the apparatus further includes one or more heaters (e.g., heating elements) to enable heating of a processing chamber (e.g., a reaction chamber, an epitaxy chamber, or others described herein), a module (e.g., a transfer module, a processing module, or others described herein), or a component within the processing chamber or the module (e.g., the component can be any described herein, such as a showerhead). In particular embodiments, the one or more heaters are configured to reduce at least one or moisture or an oxygen level.

In some embodiments, the apparatus further includes one or more coolers (e.g., cooling elements) to enable cooling of a processing chamber (e.g., a reaction chamber, an epitaxy chamber, or others described herein), a module (e.g., a transfer module, a processing module, or others described herein), or a component within the processing chamber or the module (e.g., the component can be any described herein, such as a showerhead).

In some embodiments, the apparatus further includes an ion filter positioned between the plasma source (e.g., a remote plasma source) and the reaction chamber. In other embodiments, the ion filter is integrated into a showerhead positioned in the reaction chamber. In yet other embodiments, the ion filter is located downstream of the plasma source.

In some embodiments, the plasma source of the apparatus includes a capacitively coupled plasma (CCP) source, an inductively coupled plasma (ICP) source, a transformer coupled plasma (TCP) source, an electron cyclotron resonance (ECR) plasma source, a surface wave plasma (SWP) source, a microwave plasma (MWP) source, a radial line slot antenna (RLSA), a low energy plasma (LEP) source, or a low temperature plasma (LTP) source.

In some embodiments, the CCP source includes a first power source operatively coupled to a first plate of the CCP source and further includes a second power source operatively coupled to a second plate of the CCP source. In particular embodiments, the plasma frequency is within a range of about 400 kHz to 1000 kHz or about 700 MHz to 2.5 GHz.

In some embodiments, the SWP source (e.g., RLSA) includes a microwave generator. In particular embodiments, the microwave generator is configured to generate signals within a frequency range of about 700 MHz to 1 GHz. In other embodiments, the microwave generator provides a microwave having a frequency of about 1 to 100 GHz, such as from about 2.45 GHz, 8.35 GHz, 5.8 GHz, 1.98 GHz, or the like. In yet other embodiments, the SWP source (e.g., RLSA) includes a plurality of sources arranged in an array, wherein the plurality of sources are configured to spread plasma in a uniform manner.

In some embodiments, the apparatus further includes a radiative heat source configured to heat a front side of the substrate. In particular embodiments, the radiative heat source is an infrared (IR) lamp. In some embodiments, the radiative heat source is configured to provide radiation having a wavelength from about 400 nm to 1000 nm or from 500 nm to 1000 nm. In other embodiments, the apparatus further includes a heating element configured to heat a back side of the substrate. In particular embodiments, the heating element (e.g., a light emitting diode (LED)) is integrated into the substrate support that is positioned in the reaction chamber and is configured to support a substrate (e.g., a pedestal or a chuck). In any embodiment therein, the radiative heat source or the heating element is composed of materials that are transparent to the spectrum provided by the source or element and that are resistant to reactor clean or reactor treat operations described herein.

In some embodiments, the reaction chamber includes quartz.

In some embodiments, the reaction chamber, the plasma source, or a component disposed within the reaction chamber includes a coating (e.g., a ceramic, a metal, an oxide, a silicate, as well as others described herein). In other embodiments, the component disposed within the reaction chamber is a showerhead.

In some embodiments, the reaction chamber is an epitaxy chamber.

In some embodiments, the apparatus is a multi-station process chamber.

In some embodiments, the substrate support includes a heated pedestal. In particular embodiments, the substrate support includes a pedestal that is at a temperature within a range of about 250° C. to 650° C. In other embodiments, the substrate support includes a pedestal that is configured to provide the substrate at a temperature within a range of about 250° C. to 650° C.

In some embodiments, the one or more controllers are configured with instructions for performing the following operation: causing formation of a first layer in operation (a) at a first temperature and causing formation of a second layer in operation (b) at a second temperature. In particular embodiments, the first temperature is different than the second temperature.

In some embodiments, a pressure inside the reaction chamber during formation of the first layer or formation of the second layer is less than about 0.5 Torr. In particular embodiments, the pressure is from about 0.1 Torr to 3 Torr. In yet other embodiments, the pressure during formation is about 0.001 Torr to 1000 Torr (e.g., from about 0.001 Torr to 700 Torr, 0.001 Torr to 200 Torr, 0.001 Torr to 100 Torr, 0.001 Torr to 60 Torr, 0.001 Torr to 20 Torr, 0.001 Torr to 10 Torr, 0.001 Torr to 5 Torr, 0.001 Torr to 1 Torr, 0.01 Torr to 1000 Torr, 0.01 Torr to 700 Torr, 0.01 Torr to 200 Torr, 0.01 Torr to 100 Torr, 0.01 Torr to 60 Torr, 0.01 Torr to 20 Torr, 0.01 Torr to 10 Torr, 0.01 Torr to 5 Torr, 0.01 Torr to 1 Torr, 0.1 Torr to 1000 Torr, 0.1 Torr to 700 Torr, 0.1 Torr to 200 Torr, 0.1 Torr to 100 Torr, 0.1 Torr to 60 Torr, 0.1 Torr to 20 Torr, 0.1 Torr to 10 Torr, 0.1 Torr to 5 Torr, 0.1 Torr to 1 Torr, 1 Torr to 1000 Torr, 1 Torr to 700 Torr, 1 Torr to 200 Torr, 1 Torr to 100 Torr, 1 Torr to 60 Torr, 1 Torr to 20 Torr, 1 Torr to 10 Torr, 1 Torr to 5 Torr, and the like).

In a third aspect, the present disclosure encompasses a method for epitaxially depositing a film. In some embodiments, the method includes: precleaning a surface of a substrate, thereby providing a precleaned surface; pretreating the surface of the substrate, thereby providing a pretreated surface; epitaxially depositing a layer (e.g., a semiconductor layer) in the presence of plasma on a precleaned and pretreated surface and within an epitaxy chamber; removing the substrate from the epitaxy chamber; and performing a reactor clean of the epitaxy chamber.

In some embodiments, precleaning can include removing an oxide. In other embodiments, precleaning includes delivering a halogen-containing reagent (e.g., any described herein, including halogen-containing compounds, liquids, solutions, or gases), a halogen-containing vapor (e.g., a fluorine-containing vapor), or a halogen-containing plasma (e.g., a fluorine-containing plasma).

In some embodiments, pretreating can include providing a hydrophobic surface or a passivated surface. In other embodiments, pretreating includes delivering a hydrogen-containing reagent (e.g., any described herein, including hydrogen-containing compounds, liquids, solutions, or gases), a deuterium-containing reagent (e.g., any described herein, including deuterium-containing compounds, liquids, solutions, or gases), a hydrogen-containing plasma, or a deuterium-containing plasma. In particular embodiments, pretreating is configured to provide a surface including Si—H bonds (e.g., as in a hydrogenated surface) or Si—D bonds (e.g., as in a deuterated surface). In other embodiments, pretreating is configured to provide a surface including both Si—H bonds and Si—D bonds.

In some embodiments, epitaxially depositing can include depositing at least one of a first layer or a second layer in the presence of plasma on a precleaned and pretreated surface and within the epitaxy chamber. In particular embodiments, the pretreating operation and the epitaxially depositing operation are performed within the epitaxy chamber. In other embodiments, epitaxially depositing includes remote plasma. In yet other embodiments, epitaxially depositing includes in situ plasma.

In some embodiments, removing is performed under a vacuum.

In some embodiments, performing the reactor clean is performed before providing the substrate to the epitaxy chamber or after removing the substrate from the epitaxy chamber. In particular embodiments, performing the reactor clean includes delivering a halogen-containing reagent (e.g., any described herein, including halogen-containing compounds, liquids, solutions, or gases), a halogen-containing vapor (e.g., a fluorine-containing vapor or a chlorine-containing vapor), a halogen-containing plasma (e.g., a fluorine-containing plasma or a chlorine-containing plasma), a hydrogen-containing reagent (e.g., any described herein, including hydrogen-containing compounds, liquids, solutions, or gases), a deuterium-containing reagent (e.g., any described herein, including deuterium-containing compounds, liquids, solutions, or gases), a hydrogen-containing plasma, or a deuterium-containing plasma to the epitaxy chamber.

In some embodiments, the method further includes (e.g., before epitaxially depositing): depositing a buffer layer between the substrate and the first layer or between the substrate and the second layer.

In some embodiments, each of the precleaning, the pretreating, the epitaxially depositing, and the performing the reactor clean is, independently, performed at a temperature of less than about 900° C., 800° C., 750° C., 700° C., 650° C., 600° C., 550° C., or 500° C.; or at a temperature of about 400° C. to 900° C. or at a temperature of about 400° C. to 700° C.

In some embodiments, each of the precleaning, the pretreating, the epitaxially depositing, and the performing the reactor clean is, independently, performed in the presence of plasma.

In some embodiments, the precleaning is performed in a preclean chamber, and the epitaxy chamber and the preclean chamber are provided in a vacuum platform.

In some embodiments, the method further includes (e.g., before the epitaxially depositing): transferring the substrate from the preclean chamber to the epitaxy chamber under vacuum. Such transferring can occur in any useful manner, e.g., by use of a transfer module configured to access both the preclean chamber and the epitaxy chamber.

In some embodiments, epitaxially depositing provides a plurality of alternating first layers and second layers. In some embodiments, the plurality of layers includes more than 2, 3, 4, 5, 6, 7, 8, 9, 10, 11, 12, 13, 14, 15, or more pairs, in which each pair includes a single first layer and a single second layer. In other embodiments, the plurality of layers includes more than 1, 2, 3, 4, 5, or more quartets, in which each quartet includes two first layers and two second layers.

In some embodiments, the method further includes (e.g., after the epitaxially depositing): further pretreating a surface of at least one of the first layer or the second layer, thereby providing a pretreated surface. In other embodiments, the pretreated surface includes a passivated surface or a hydrophobic surface, as described herein.

In some embodiments, the method further includes (e.g., after or during the epitaxially depositing): further preparing a surface of at least one of the first layer or the second layer, thereby providing a prepared surface. In other embodiments, the prepared surface includes a smoothened surface, as described herein.

In some embodiments, the method further includes (e.g., after the performing the reactor clean): performing a reactor treat by passivating an environment or a surface within the epitaxy chamber. In other embodiments, the passivated environment or the passivated surface has a reduced level of a halogen, as compared to an environment or a surface present within the epitaxy chamber prior to performing the reactor treat. In some embodiments, the passivating includes delivering a hydrogen-containing reagent, a deuterium-containing reagent, a hydrogen-containing plasma, or a deuterium-containing plasma to the epitaxy chamber.

In a fourth aspect, the present disclosure encompasses a method for forming a stack. In some embodiments, the method includes: precleaning a substrate to provide a precleaned surface; pretreating the precleaned surface of the substrate to provide a precleaned, pretreated surface; epitaxially depositing a layer (e.g., a semiconductor layer) in the presence of plasma on the precleaned, pretreated surface of the substrate and within an epitaxy chamber; removing the substrate from the epitaxy chamber; and performing a reactor clean of the epitaxy chamber.

In some embodiments, the layer includes a plurality of alternating first layers and second layers (e.g., a plurality of alternating first semiconductor layers and second semiconductor layers). In particular embodiments, the plurality of alternating first layers and second layers includes more than 2, 3, 4, 5, 6, 7, 8, 9, 10, 11, 12, 13, 14, 15, or more pairs, in which each pair includes a single first layer and a single second layer.

In some embodiments, precleaning includes exposing the surface of the substrate with a halogen-containing reagent (e.g., any described herein, including halogen-containing compounds, liquids, solutions, or gases), a halogen-containing vapor (e.g., a fluorine-containing vapor), or a halogen-containing plasma (e.g., a fluorine-containing plasma).

In some embodiments, pretreating includes exposing the surface of the substrate with a hydrogen-containing reagent (e.g., any described herein, including hydrogen-containing compounds, liquids, solutions, or gases), a deuterium-containing reagent (e.g., any described herein, including deuterium-containing compounds, liquids, solutions, or gases), a hydrogen-containing plasma or a deuterium-containing plasma.

In some embodiments, epitaxially depositing includes remote plasma.

In some embodiments, performing the reactor clean is performed at least one of before providing the substrate within the epitaxy chamber or after the removing the substrate from the epitaxy chamber. In particular embodiments, performing the reactor clean includes a halogen-containing reagent (e.g., any described herein, including halogen-containing compounds, liquids, solutions, or gases), a halogen-containing vapor, or a halogen-containing plasma.

In some embodiments, the method includes (e.g., after the epitaxially depositing): depositing a hardmask on a surface of the plurality of alternating first layers and second layers. In particular embodiments, the hardmask is not an epitaxial layer or is not deposited in an epitaxial manner.

In some embodiments, the method includes (e.g., before the epitaxially depositing): depositing a buffer layer between the substrate and the plurality of alternating first layers and second layers. In particular embodiments, the buffer layer is an epitaxial layer or is deposited in an epitaxial manner.

In some embodiments, each of the precleaning, the pretreating, the epitaxially depositing, and the performing the reactor clean is, independently, performed at a temperature of less than about 900° C., 800° C., 750° C., 700° C., 650° C., 600° C., 550° C., or 500° C.

In some embodiments, each of the precleaning, the pretreating, the epitaxially depositing, and the performing the reactor clean is, independently, performed in the presence of plasma.

In a fifth aspect, the present disclosure encompasses a system or an apparatus including: at least one preclean chamber; at least one epitaxy chamber; a plasma source; at least one outlet for coupling to a vacuum; one or more process gas inlets coupled to one or more sources; and one or more controllers for controlling operations, wherein the one or more controllers include machine-readable instructions for performing one or more cycles of operations (e.g., any described herein) or for performing one or more methods (e.g., any described herein).

In some embodiments, the preclean chamber or the epitaxy chamber includes a substrate support configured to support a substrate. In some embodiments, the substrate support is a pedestal or a chuck. In further embodiments, the system or apparatus includes a transfer module configured to transfer a substrate from the preclean chamber to the epitaxy chamber (e.g., under vacuum).

In some embodiments, the one or more process gas inlets are coupled to one or more fluorine-containing reactant sources. In other embodiments, the one or more process gas inlets are coupled to one or more hydrogen-containing reactant sources or deuterium-containing reactant sources. In other embodiments, the one or more process gas inlets are coupled to one or more first precursor sources. In other embodiments, the one or more process gas inlets are coupled to one or more second precursor sources. In yet other embodiments, the one or more process gas inlets are coupled to one or more third precursor sources. In other embodiments, the one or more process gas inlets are coupled to one or more halogen-containing reactant sources.

In some embodiments, the one or more controllers include machine-readable instructions for performing one or more cycles of: causing introduction of the one or more fluorine-containing reactants to the preclean chamber; causing transfer of the substrate from the preclean chamber to the epitaxy chamber under vacuum (e.g., by way of a transfer module); causing introduction of the one or more hydrogen-containing reactants or deuterium-containing reactants to the epitaxy chamber; causing introduction of at least one of the one or more first precursors, second precursors, or optional third precursors in cycles to the epitaxy chamber; causing transfer of the substrate out of the epitaxy chamber; and causing introduction of the one or more halogen-containing reactants to the epitaxy chamber.

In some embodiments, the one or more controllers further include machine-readable instructions for: causing generation of plasma in the plasma source. In other embodiments, the one or more controllers further include machine-readable instructions for: causing generation of plasma in the plasma source while introduction of the one or more fluorine-containing reactants to the preclean chamber. In yet other embodiments, the one or more controllers further include machine-readable instructions for: causing generation of plasma in the plasma source while introduction of the one or more hydrogen-containing reactants, deuterium-containing reactants, first precursors, second precursors, optional third precursors, or halogen-containing reactants to the epitaxy chamber.

In some embodiments, the one or more process gas inlets are coupled to the plasma source. In further embodiments, the one or more process gas inlets coupled to the plasma source are also coupled to at least one of the one or more fluorine-containing reactant sources, hydrogen-containing reactant sources, or deuterium-containing reactant sources.

In some embodiments, the one or more process gas inlets are coupled to the at least one epitaxy chamber. In further embodiments, the one or more process gas inlets coupled to the at least one epitaxy chamber are also coupled to at least one of one or more first precursor sources, second precursor sources, optional third precursor sources, or halogen-containing reactant sources.

In a sixth aspect, the present disclosure encompasses a system or an apparatus including: at least one preclean chamber; at least one pretreat chamber; at least one epitaxy chamber; a plasma source; at least one outlet for coupling to a vacuum; one or more process gas inlets; and one or more controllers for controlling operations, wherein the one or more controllers include machine-readable instructions for performing one or more cycles of operations (e.g., any described herein) or for performing one or more methods (e.g., any described herein).

In some embodiments, the preclean chamber or the pretreat chamber or the epitaxy chamber includes a substrate support configured to support a substrate. In some embodiments, the substrate support is a pedestal or a chuck. In further embodiments, the system or apparatus includes a transfer module configured to transfer a substrate from the pretreat chamber to the preclean chamber (e.g., under vacuum) or a transfer module configured to transfer a substrate from the preclean chamber to the epitaxy chamber (e.g., under vacuum).

In some embodiments, the one or more process gas inlets are coupled to one or more fluorine-containing reactant sources. In other embodiments, the one or more process gas inlets are coupled to one or more hydrogen-containing reactant sources or deuterium-containing reactant sources. In other embodiments, the one or more process gas inlets are coupled to one or more first precursor sources. In other embodiments, the one or more process gas inlets are coupled to one or more second precursor sources. In other embodiments, the one or more process gas inlets are coupled to one or more optional third precursor sources. In some embodiments, the one or more process gas inlets are coupled to one or more halogen-containing reactant sources.

In some embodiments, the one or more controllers include machine-readable instructions for performing one or more cycles of: causing introduction of the one or more fluorine-containing reactants to the preclean chamber; causing transfer of the substrate from the preclean chamber to the pretreat chamber under vacuum (e.g., by way of a transfer module); causing introduction of the one or more hydrogen-containing reactants or deuterium-containing reactants to the pretreat chamber; causing transfer of the substrate from the pretreat chamber to the epitaxy chamber under vacuum (e.g., by way of a transfer module); causing introduction of the at least one of one or more first precursors, second precursors, or optional third precursors in cycles to the epitaxy chamber; causing transfer of the substrate out of the epitaxy chamber (e.g., by way of a transfer module); and causing introduction of the one or more halogen-containing reactants to the epitaxy chamber.

In some embodiments, the one or more controllers include machine-readable instructions for performing one or more cycles of: causing generation of plasma in the plasma source. In other embodiments, the one or more controllers include machine-readable instructions for: causing generation of plasma in the plasma source while introduction of the one or more fluorine-containing reactants to the preclean chamber. In other embodiments, the one or more controllers include machine-readable instructions for: causing generation of plasma in the plasma source while introduction of the one or more hydrogen-containing reactants or deuterium-containing reactants to the pretreat chamber. In other embodiments, the one or more controllers include machine-readable instructions for: causing generation of plasma in the plasma source while introduction of at least one of the one or more first precursors, second precursors, or optional third precursors to the epitaxy chamber. In yet other embodiments, the one or more controllers include machine-readable instructions for: causing generation of plasma in the plasma source while introduction of the one or more halogen-containing reactants to the epitaxy chamber.

In some embodiments, the one or more process gas inlets are coupled to the plasma source. In other embodiments, the one or more process gas inlets coupled to the plasma source are also coupled to at least one of one or more fluorine-containing reactant sources, hydrogen-containing reactant sources, or deuterium-containing reactant sources.

In some embodiments, the one or more process gas inlets are coupled to the at least one epitaxy chamber. In other embodiments, the one or more process gas inlets coupled to the at least one epitaxy chamber are also coupled to at least one of one or more first precursor sources, second precursor sources, optional third precursor sources, or halogen-containing reactant sources.

In any embodiment herein, the energetic species include at least one of radicals, plasma-generated radicals, metastables, plasma-generated metastables, ions, plasma-generated ions, neutrals, plasma-generated neutrals, plasma, photons, radiation, excited molecules, excited atoms, or others described herein.

In any embodiment herein, the radicals include plasma-generated radicals. In some embodiments, the radicals or the plasma-generated radicals include at least one of hydrogen-containing radicals, deuterium-containing radicals, nitrogen-containing radicals, or the like.

In any embodiment herein, the metastables includes plasma-generated metastables. In some embodiments, the metastables or the plasma-generated metastables include at least one of helium-containing metastables, argon-containing metastables, or the like.

In any embodiment herein, the energetic species (e.g., at least one of the radicals or metastables) is generated by way of plasma. Non-limiting examples of plasma include capacitively coupled plasma (CCP), inductively coupled plasma (ICP), transformer coupled plasma (TCP), electron cyclotron resonance (ECR) plasma, surface wave plasma (SWP), plasma generated using a SWP (e.g., a radial line slot antenna (RLSA)), microwave plasma (MWP), plasma generated using ultraviolet (UV) radiation, low energy plasma (LEP), low temperature plasma (LTP), and the like. Non-limiting examples of sources of plasma include a beam source, a line source, or a pixelated source.

In any embodiment herein, the plasma is generated using a source gas. In some embodiments, the source gas includes at least one of a hydrogen-containing gas, a deuterium-containing gas, a nitrogen-containing gas, or an inert gas, such as a helium-containing gas, an argon-containing gas, or another inert gas. Other non-limiting sources gases are described herein, and mixtures of any of the source gases may be employed.

In any embodiment herein, at least the first layer includes a semiconductor layer (e.g., a first semiconductor layer). In other embodiments, at least the second layer includes a semiconductor layer (e.g., a second semiconductor layer). In yet other embodiments, the first layer includes a first semiconductor layer, and the second layer includes a second semiconductor layer.

In any embodiment herein, the first layer (e.g., the first semiconductor layer) has a differing etch behavior than the second layer (e.g., the second semiconductor layer). In some embodiments, a ratio of an etch rate of the first layer to an etch rate of the second layer is more than about 2:1, 5:1, 10:1, 25:1, 20:1, or 100:1. In other embodiments, a ratio of an etch rate of the second layer to an etch rate of the first layer is more than about 2:1, 5:1, 10:1, 25:1, 20:1, or 100:1.

In any embodiment herein, the temperature is different during deposition of the first layer than during deposition of the second layer.

In any embodiment herein, the layer (e.g., the first semiconductor layer or the second semiconductor layer) includes a sacrificial layer.

In any embodiment herein, a deposition rate associated with depositing at least one of the first layer or the second layer is at least about 3 nanometers per minute (nm/min). In other embodiments, a deposition rate associated with depositing at least one of the first layer or the second layer is at least about 30 nm/min.

In any embodiment herein, the energetic species (e.g., at least one of the radicals or the metastables) is generated in a remote plasma source positioned upstream of a reaction chamber (e.g., an epitaxy chamber).

In any embodiment herein, the energetic species (e.g., at least one of the radicals or metastables) is generated in situ in a portion of the reaction chamber.

In any embodiment herein, the first precursor includes a silicon-containing precursor (Si precursors). Examples include silicon hydride, a silicon hydrohalide, or a silicon halide. Non-limiting examples of precursors include silane (SiH₄), disilane (Si₂H₆), trisilane (Si₃H₈), cyclotrisilane (Si₃H₆), tetrasilane (Si₄H₁₀), cyclotetrasilane (Si₄H₈), pentasilane (S₁₅H₁₂), cyclopentasilane (S₁₅H₁₀), hexasilane (Si₆H₁₄), cyclohexasilane (Si₆H₁₂), heptasilane (Si₇H₁₆), cycloheptasilane (Si₇H₁₄), octasilane (S₁₅H₁₈), monochlorosilane (MCS, SiH₃Cl), dichlorosilane (DCS, SiH₂Cl₂), trichlorosilane (TCS, SiHCl₃), 1,2-dichlorodisilane (Si₂H₄Cl₂), 1,2,3-trichlorosilane (Si₃H₅Cl₃), silicon tetrachloride (STC, SiCl₄), hexachlorodisilane (HCDS, Si₂Cl₆), octachlorotrisilane (OCTS, Si₃Cl₈), and germylsilane (H₃Ge—SiH₃), as well as any described herein. Any of such precursors can include one or more hydrogen atoms that is substituted with deuterium.

In any embodiment herein, the second precursor includes a germanium-containing precursor (Ge precursor) or a silicon- and germanium-containing precursor (SiGe precursor).

Examples include a germanium hydride, a germanium hydrohalide, a germanium halide, or a silicon-germanium-hydride precursor. Non-limiting examples of precursors include germane (GeH₄), digermane (Ge₂H₆), trigermane (G₃H₈), tetragermane (Ge₄H₁₀), pentagermane (Ge₅H₁₂), dichlorogermane (GeH₂Cl₂), trichlorogermane (GeHCl₃), germanium tetrachloride (GeCl₄), and hexachlorodigermane (Ge₂Cl₆), as well as any described herein. Any of such precursors can include one or more hydrogen atoms that is substituted with deuterium.

In any embodiment herein, the third precursor includes a Si precursor. Examples include a silicon hydride, a silicon hydrohalide, or a silicon halide. Non-limiting examples of precursors include silane (SiH₄), disilane (Si₂H₆), trisilane (Si₃H₈), cyclotrisilane (Si₃H₆), tetrasilane (Si₄H₁₀), cyclotetrasilane (Si₄H₈), pentasilane (Si₅H₁₂), cyclopentasilane (Si₅H₁₀), hexasilane (Si₆H₁₄), cyclohexasilane (Si₆H₁₂), heptasilane (Si₇H₁₆), cycloheptasilane (Si₇H₁₄), octasilane (S₁₅H₁₈), monochlorosilane (MCS, SiH₃Cl), dichlorosilane (DCS, SiH₂Cl₂), trichlorosilane (TCS, SiHCl₃), 1,2-dichlorodisilane (Si₂H₄Cl₂), 1,2,3-trichlorosilane (Si₃H₅Cl₃), silicon tetrachloride (STC, SiCl₄), hexachlorodisilane (HCDS, Si₂Cl₆), octachlorotrisilane (OCTS, Si₃Cl₈), and germylsilane (H₃Ge—SiH₃), as well as any described herein. Any of such precursors can include one or more hydrogen atoms that is substituted with deuterium.

In any embodiment herein, the first layer includes a silicon-containing layer (Si layer), and the second layer includes a silicon- and germanium-containing layer (SiGe layer). In other embodiments, the first layer includes a silicon- and germanium-containing layer (SiGe layer), and the second layer includes a silicon-containing layer (Si layer). In particular embodiments, a concentration of germanium within a layer (e.g., within at least one of the first or the second layers) is from about 10 at. % to 50 at. %, as well as other ranges described herein.

In any embodiment herein, the predetermined number of layers is at least 4, 5, 6, 7, 8, 9, 10, 11, 12, 13, 14, 15, 16, 17, 18, 19, 20, 21, 22, 23, 24, 25, 26, 27, 28, 29, 30, or more layers.

In any embodiment herein, the predetermined number of layers includes a plurality of first layer (e.g., first semiconductor layers) within a stack. In some embodiments, a thickness of at least one first layer may or may not be the same as a thickness of another first layer within the stack.

In any embodiment herein, the predetermined number of layers includes a plurality of second layers (e.g., second semiconductor layers) within a stack. In some embodiments, a thickness of at least one second layer may or may not be the same as a thickness of another second layer within the stack.

In any embodiment herein, the predetermined number of layers includes a plurality of alternating first layers and second layers (e.g., alternating first semiconductor layers and second semiconductor layers) within a stack. In some embodiments, a thickness of at least one first layer may or may not be the same as a thickness of another first layer within the stack. In other embodiments, a thickness of at least one second layer may or may not be the same as a thickness of another second layer within the stack.

In any embodiment herein, the heterolayers form a strained semiconductor structure. In particular embodiments, at least one of the heterolayer, first layer, or second layer is an epitaxial layer. In other embodiments, each heterolayer, first layer, and second layer is an epitaxial layer.

In any embodiment herein, the layer has a thickness of about 5 nm to 60 nm. In other embodiment, the layer (e.g., a first semiconductor layer or a second semiconductor layer, such as any described herein) has a thickness of about 5 nm to 60 nm, 5 nm to 50 nm, 5 nm to 25 nm, 5 nm to 20 nm, 5 nm to 10 nm, 10 nm to 60 nm, 10 nm to 50 nm, 10 nm to 25 nm, or 10 nm to 20 nm.

In any embodiment herein, the substrate has at least one of a precleaned surface, a pretreated, or a precleaned and pretreated surface.

In any embodiment herein, the reaction chamber includes an epitaxy chamber.

In any embodiment herein, the reaction chamber is at least one of cleaned or treated.

In any embodiment herein, a surface of the apparatus or system (e.g., a surface of a reaction chamber, an epitaxy chamber, an energy source, a window of an energy source, a pedestal, a chuck, or a portion of any of these) includes a coating. In particular embodiments, the coating is configured to be resistant to damage or etching by reactor clean or reactor treat operations described herein.

In any embodiment herein, at least one of the precleaning, the pretreating, the epitaxially depositing, and the performing the reactor clean is, independently, performed at a temperature of less than about 900° C., 800° C., 750° C., 700° C., 650° C., 600° C., 550° C., or 500° C.; or at a temperature of about 400° C. to 900° C. or at a temperature of about 400° C. to 700° C.

In any embodiment herein, each of the precleaning, the pretreating, the epitaxially depositing, and the performing the reactor clean is, independently, performed at a temperature of less than about 900° C., 800° C., 750° C., 700° C., 650° C., 600° C., 550° C., or 500° C.; or at a temperature of about 400° C. to 900° C. or at a temperature of about 400° C. to 700° C.

In any embodiment herein, the method includes epitaxially depositing one or more layers (e.g., semiconductor layers). In some embodiments, epitaxially depositing includes providing a plurality of alternating first layers and second layers. In particular embodiments, the plurality of layers includes more than 2, 3, 4, 5, 6, 7, 8, 9, 10, 11, 12, 13, 14, 15, or more pairs, in which each pair includes a single first layer and a single second layer. In other embodiments, the plurality of layers includes more than 1, 2, 3, 4, 5, or more quartets, in which each quartet includes two first layers and two second layers. In yet other embodiments, the plurality of layers include more than 4, 5, 6, 7, 8, 9, 10, 11, 12, 13, 14, 15, 16, 17, 18, 19, 20, 21, 22, 23, 24, 25, 26, 27, 28, 29, 30, or more individual layers, in which each individual layer can be a first layer or a second layer.

In any embodiment herein, the method includes atomic layer deposition (ALD), plasma-enhanced ALD (PEALD), chemical vapor deposition (CVD), plasma-enhanced CVD (PECVD), or remote plasma CVD (RPCVD). In particular embodiments, the method includes an operation (e.g., at least one of operation (a) or operation (b)), in which the operation includes ALD, PEALD, CVD, PECVD, or RPCVD. In other embodiments, the operation (e.g., at least one of operation (a) or operation (b)) is repeated in cycles. For instance, taking operation (a) of flowing a first precursor into a reaction chamber, flow of the first precursor nay be introduced into the chamber for an n number of cycles with optional purge cycles disposed therebetween.

In any embodiment therein, the method, apparatus, or system further includes a showerhead. In some instances, the showerhead is disposed within the reaction chamber. In other instances, the showerhead includes a coating (e.g., any described herein). In some embodiments, the showerhead is configured to be cooled. In yet other embodiments, the showerhead comprises a plurality of apertures arranged in a non-uniform pattern (e.g., a pattern that includes an increased number of apertures as a function of radius).

In any embodiment herein, the method further includes (e.g., after depositing): pretreating a surface of at least one of the first layer or the second layer.

In any embodiment herein, the method further includes (e.g., after performing the reactor clean): performing a reactor treat by passivating an environment or a surface within the epitaxy chamber. In some embodiments, passivating includes delivering hydrogen-containing plasma to the epitaxy chamber. Additional embodiments are described herein.

### BRIEF DESCRIPTION OF THE DRAWINGS

FIG. 1A-E provides a schematic of (A) a non-limiting stack 100, (B) non-limiting pairs 106 of layers, (C) non-limiting quartets 107 of layers, (D) another non-limiting stack 150, and (E) yet another non-limiting stack 151.

FIG. 2A-I provides (A-G) a flowchart of a non-limiting method 200A-200G, respectively, (H) a schematic of a non-limiting system 250, and (I) a schematic of another non-limiting system 290.

FIG. 3A-E provides (A) a flowchart of a non-limiting method 300, (B) a flowchart of another non-limiting method 350, (C) a process timing diagram of a non-limiting method 360, (D) a process timing diagram of another non-limiting method 390, and (E) a flowchart of another non-limiting method 3000.

FIG. 4A-C provides (A) a flowchart of a non-limiting method 400, (B) a flowchart of another non-limiting method 450, and (C) a process timing diagram of a non-limiting method 460.

FIG. 5 is a schematic diagram of an example process station 500 for performing disclosed embodiments.

FIG. 6 is a schematic diagram of an example process tool 600 for performing disclosed embodiments.

FIG. 7A-B shows a schematic illustration of example apparatuses 700a,700b including a capacitively coupled plasma (CCP) reactor.

FIG. 8A-B shows a schematic illustration of example multi-station processing tools 800a,800b for carrying out disclosed embodiments.

FIG. 9 is a schematic diagram of another example process station 900 for performing disclosed embodiments.

FIG. 10 is a schematic diagram of another example process tool 1000 for performing disclosed embodiments.

FIG. 11 is a schematic diagram of another example process station 1100 for performing disclosed embodiments.

FIG. 12 is a schematic diagram of an example plasma processing apparatus 1200 with a remote plasma source according to some implementations.

FIG. 13 is a schematic diagram of another example process station 1300 for performing disclosed embodiments.

FIG. 14 is a schematic diagram of an example plasma processing apparatus 1400 with a remote plasma source according to some implementations.

### DETAILED DESCRIPTION

Reference is made herein in detail to specific embodiments of the disclosure. Examples of the specific embodiments are illustrated in the accompanying drawings. While the disclosure will be described in conjunction with these specific embodiments, it will be understood that it is not intended to limit the disclosure to such specific embodiments. On the contrary, it is intended to cover alternatives, modifications, and equivalents as may be included within the spirit and scope of the disclosure. In the following description, numerous specific details are set forth in order to provide a thorough understanding of the present disclosure. The present disclosure may be practiced without some or all of these specific details. In other instances, well known process operations have not been described in detail so as to not unnecessarily obscure the present disclosure.

The implementations disclosed below describe deposition of a material on a substrate such as a wafer, substrate, or other work piece. The work piece may be of various shapes, sizes, and materials. In this application, the terms “semiconductor wafer,” “wafer,” “substrate,” “wafer substrate,” and “partially fabricated integrated circuit” are used interchangeably. The substrate can have any useful property, such as a diameter of more than about 150 mm, 200 mm, 300 mm, 450 mm, or larger.

This disclosure relates generally to the field of vertical stacks, as well as methods of making such stacks and apparatuses to implement such methods. For instance, the vertical stack can include heterolayers. Heterolayers may be defined as those present in a vertical stack, in which a first layer is disposed under a second layer. In one example, the first layer and the second layer are composed of differing materials. Such a heterolayer may be epitaxial or not. As used herein, a “heterolayer” refers to an overlying layer formed of a material that is different than the material of an underlying layer. For instance, a difference can include the presence or absence of at least one different atom, bond, or other chemical or material characteristic in the overlying layer, as compared to the underlying layer. Another difference can include differing amounts of at least one different atom, bond, or other chemical or material characteristic in the overlying layer, as compared to the underlying layer.

In one embodiment, the first layer includes or consists of silicon (Si), and the second layer includes a non-silicon atom or includes a combination of Si with a non-Si atom. In another embodiment, the first layer includes a non-silicon atom or includes a combination of Si with a non-Si atom, and the second layer includes or consists of Si. Non-limiting examples of non-Si atoms include germanium (Ge), oxygen (O), nitrogen (N), carbon (C), phosphorous (P), boron (B), as well as combinations thereof. In particular embodiments, the stack includes a plurality of alternating first layers and second layers.

In some non-limiting embodiments, the vertical stack includes a plurality of alternating first layers and second layers (e.g., first semiconductor layers and second semiconductor layers).

In particular embodiments, the vertical stack includes an n1 number of first semiconductor layers and an n2 number of second semiconductor layers, in which n1+n2>4 (e.g., having more than 4, 5, 6, 7, 8, 9, 10, 11, 12, 13, 14, 15, 16, 17, 18, 19, 20, 21, 22, 23, 24, 25, 26, 27, 28, 29, 30, or more layers). In some embodiments, the vertical stack includes more than 2, 3, 4, 5, 6, 7, 8, 9, 10, 11, 12, 13, 14, 15, or more pairs of layers (e.g., in which a pair includes a single first semiconductor layer and a single second semiconductor layer, and such pairs are further described herein). In other embodiments, the vertical stack includes more than 1, 2, 3, 4, 5, or more quartets of layers (e.g., in which a quartet includes a first semiconductor layer, a second semiconductor layer, another first semiconductor layer, and another second semiconductor layer; and such quartets are further described herein).

In particular embodiments of any stack herein, each layer is typically an epitaxial, crystalline layer having any useful thickness, e.g., such as a thickness of about 5 nm to 30 nm for each of the first or second semiconductor layers. Within a stack, each first semiconductor layer can have the same thickness or differing thicknesses. Similarly, each second semiconductor layer can have the same thickness or differing thicknesses. In other embodiments, at least one of the first or second semiconductor layer is a non-epitaxial layer. In yet other embodiments, at least one of the first or second semiconductor layer is a crystalline layer, a semi-crystalline layer, a polycrystalline layer, or an amorphous layer.

In some embodiments, the vertical stack includes a first semiconductor layer and a second semiconductor layer, in which the first and second semiconductor layers are different. As used herein, a “semiconductor layer” refers to a layer formed from a material employed in semiconductor processing. Non-limiting materials can include any described herein, including those having Group III atoms, Group IV atoms, Group V atoms, as well as combinations thereof (e.g., IV-IV materials, such as those having a first Group IV atom and a second Group IV atom that is different than the first Group IV atom). Yet other materials can include Group I (e.g., copper (Cu), silver (Ag), or gold (Au)), Group II (e.g., zinc (Zn), cadmium (Cd), or mercury (Hg)), Group III (e.g., boron (B), aluminum (Al), gallium (Ga), indium (In), or thallium (Tl)), Group IV (e.g., carbon (C), silicon (Si), germanium (Ge), tin (Sn), or lead (Pb)), Group V (e.g., nitrogen (N), phosphorus (P), arsenic (As), antimony (Sb), or bismuth (Bi)), Group VI (e.g., oxygen (O), sulfur (S), selenium (Se), or tellurium (Te)), and Group VII atoms (e.g., fluorine (F), chlorine (Cl), bromine (Br), or iodine (I)), as well as combinations thereof (e.g., 1-III-VI materials having at least one Group I atom, at least one Group III atom, and at least group VI atom; II-VI materials having at least one Group II atom and at least one Group VI atom; II-V materials having at least one Group II atom and at least one Group V atom; I-VII materials having at least one Group I atom and at least one Group VII atom; III-V materials having at least one Group III atom and at least one Group V atom; IV-VI materials having at least one Group IV atom and at least one Group VI atom; V-VI materials having at least one Group V atom and at least one Group VI atom; oxides, nitrides, carbides, oxynitrides, oxycarbides, carbonitrides, and the like).

In some embodiments, the layers of a stack contain alloys and elements from only Group IV of the periodic table. In some cases, one or more layers of the stack include primarily one or more Group IV elements with a small amount (e.g., about 1 at. % or less) of one or more Group III or Group V elements as dopants. In other cases, one or more layers of the stack include primarily one or more Group IV elements with a small amount (e.g., about 1 at. % or less) of one or more Group III and Group V elements as dopants.

In particular embodiments, the first semiconductor layer has a differing etch behavior than the second semiconductor layer. In some embodiments, the first semiconductor layer is selectively etched, as compared to the second semiconductor layer. In other embodiments, the second semiconductor layer is selectively etched, as compared to the first semiconductor layer. In particular embodiments, the ratio of the etch rate of the first semiconductor layer to the etch rate of second semiconductor layer is more than about 2:1, 5:1, 10:1, 25:1, 20:1, or 100:1. In other embodiments, the ratio of the etch rate of the second semiconductor layer to the etch rate of first semiconductor layer is more than about 2:1, 5:1, 10:1, 25:1, 20:1, or 100:1. Additional details regarding etch differences are described herein.

In some embodiments, the vertical stack includes a plurality of epitaxial layers. As used herein, an “epitaxial layer” refers to a layer formed by epitaxy, as described herein. In some embodiments, each of the first and second semiconductor layers includes an epitaxial layer having any useful thickness or range of thicknesses. In other embodiments, the first semiconductor layer includes an epitaxial layer; and the second semiconductor layer includes an epitaxial layer or a non-epitaxial layer. In some embodiments, at least one of the first or the second semiconductor layer includes a crystalline layer, a semi-crystalline layer, or a polycrystalline layer.

In some embodiments, the vertical stack includes a semiconductor layer (e.g., as a first semiconductor layer) and a sacrificial layer (e.g., as a second semiconductor layer). As used herein, a “sacrificial layer” is a layer that can be removed or etched with semiconductor processing. In one embodiment, the sacrificial layer can be removed with a selective etch. Such a sacrificial layer can be formed from any material described herein, such as a semiconductor material.

In particular embodiments, the semiconductor layer can serve as a channel layer for a transistor in a memory array. As used herein, a “channel layer” is a layer configured to transport charge carriers, electrons, or holes. In proximity to a channel, an insulating layer may be employed (e.g., as described herein, such as in paragraph [0160]).

In some embodiments, the vertical stack includes a plurality of alternating semiconductor layers and sacrificial layers. In some embodiments, the semiconductor layer includes an epitaxial layer having any useful thickness or range of thicknesses. In one instance, the vertical stack can include a plurality of semiconductor layers, and the thickness of each semiconductor layer within the stack can be the same or different. In some embodiments, the sacrificial layer includes an epitaxial layer or a non-epitaxial layer. In some embodiments, the sacrificial layer includes a crystalline layer, a semi-crystalline layer, or a polycrystalline layer.

In some embodiments, the vertical stack includes alternating semiconductor layers that are epitaxially grown. In other embodiments, after additional processing, one of these layers can become a channel, while the other layer can be sacrificial. During subsequent processing, the sacrificial layer can be removed and replaced with an insulating layer to isolate the channels. Examples of materials for a channel or a channel layer can include silicon-containing material (e.g., such as in an Si layer or an SiGe layer). Any of the channel materials can further include one or more dopants, such as phosphorous (P), boron (B), carbon (C), tin (Sn), arsenic (As), and the like. Examples of material for an insulating layer include an insulator material or a dielectric material, such as silicon nitride, silicon oxide, silicon oxynitride, silicon carbide, silicon oxycarbide, silicon carbonitride, oxynitrides, oxycarbides, carbonitrides, or a doped form thereof (e.g., silicon carbide doped with at least one of oxygen or nitrogen).

In particular embodiments, the vertical stack includes alternating layers of a silicon-containing layer (a Si layer) and a silicon- and germanium-containing layer (a SiGe layer). In some non-limiting embodiments, the vertical stack includes a plurality of alternating Si layers and SiGe layers (e.g., more than 4 layers, more than 2 pairs of layers, or more than 1 quartet of layers). In particular embodiments, each layer is typically an epitaxial, crystalline layer having any useful thickness, e.g., such as a thickness of about 5-20 nm for each Si layer or each SiGe layer. Within a stack, each Si layer can have the same thickness or differing thicknesses. Similarly, each SiGe layer can have the same thickness or differing thicknesses. In other embodiments, at least one of the Si layer or the SiGe layer is a non-epitaxial layer. In yet other embodiments, the Si layer or the SiGe layer is a crystalline layer, a semi-crystalline layer, a polycrystalline layer, or an amorphous layer.

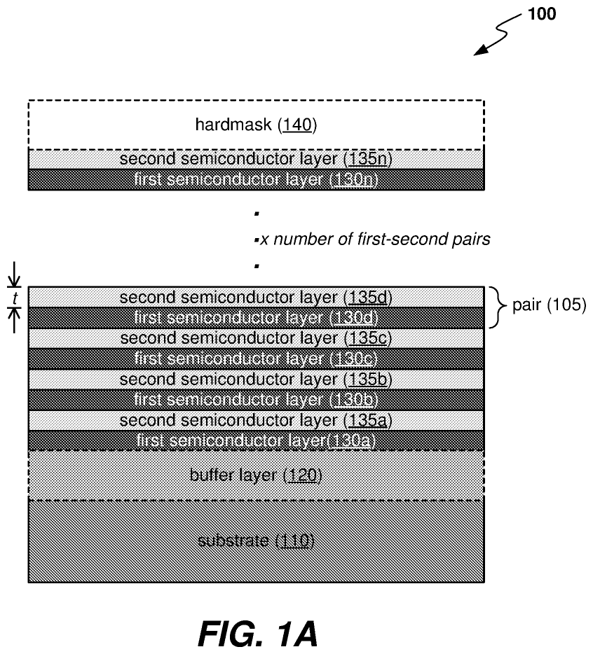

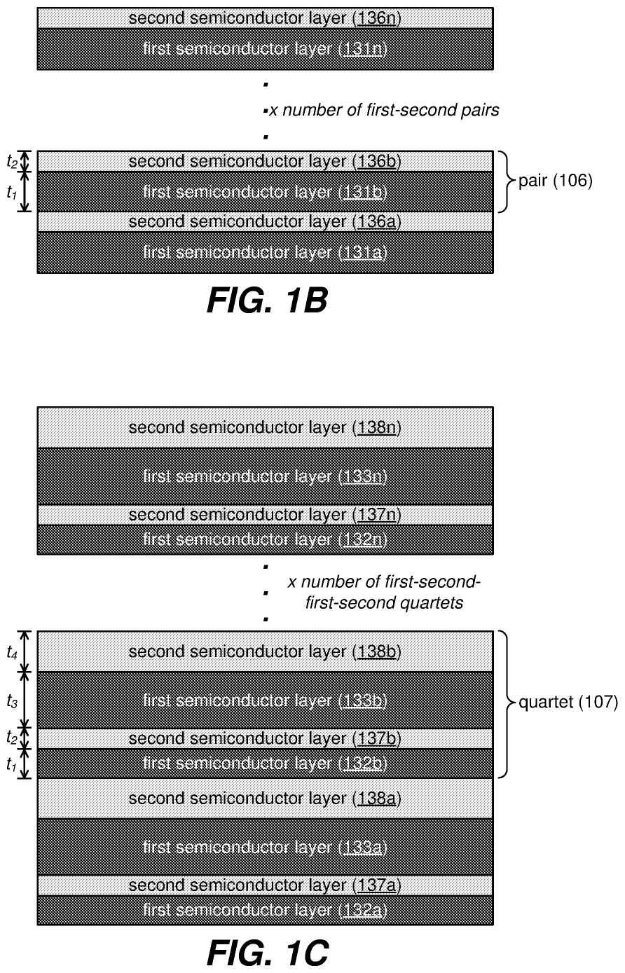

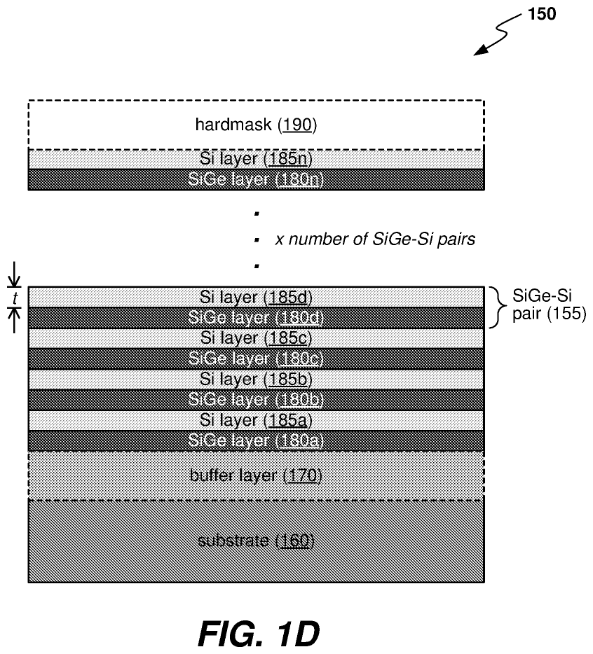

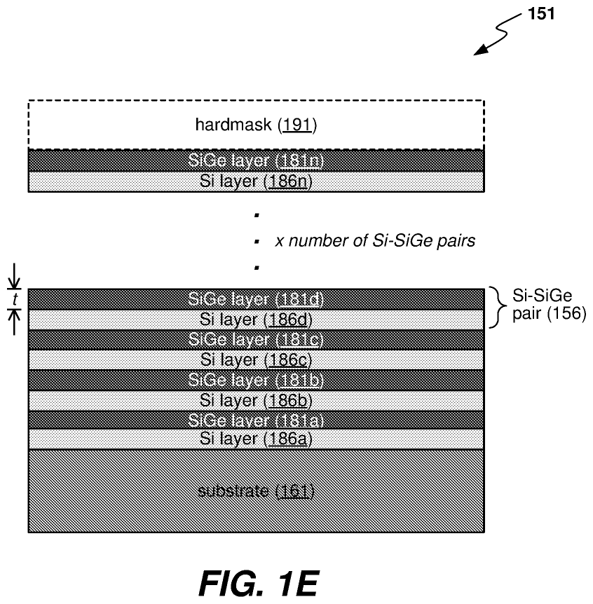

FIG. 1A shows a non-limiting stack 100 disposed on an optional buffer layer 120, which in turn is disposed on a top surface of a substrate 110. In particular embodiments, the buffer layer is an epitaxial layer or is deposited in an epitaxial manner. In other embodiments, the buffer layer is absent.

The stack can include alternating layers of first layers and second layers. Here, the stack 100 includes an n1 number of first semiconductor layers 130a-n and an n2 number of second semiconductor layers 135a-n, in which n1 and n2 are integers. In some embodiments, n1=n2. In other embodiments, n1<n2, or n1>n2. Each layer can have a thickness t, in which each t for each of the first semiconductor layers 130a-n and the second semiconductor layers 135a-n can be the same or different. The stack can be characterized as having a pair 105 of first and second semiconductor layers, in which the stack has an x number of first-second semiconductor pairs.

Each of x, n1, and n2 is, independently, selected from 1 to 100 (e.g., from 2 to 100, 3 to 100, 4 to 100, 5 to 100, 6 to 100, 7 to 100, 8 to 100, 9 to 100, 10 to 100, 1 to 50, 2 to 50, 3 to 50, 4 to 50, 5 to 50, 6 to 50, 7 to 50, 8 to 50, 9 to 50, 10 to 50, and the like).

In particular embodiments, x=n1=n2. For example, a stack can have 10 pairs (x=10), in which each pair includes a single first layer and a single second layer; and, thus, providing 10 first layers (n1=10) and 10 second layers (n2=10) within the stack. In other embodiments, x<n1, n2, such as when a stack has 10 pairs (x=10); but the stack further has an additional first layer before the first pair (in proximity to the substrate or in proximity to the bottom of the stack) or an additional first layer after the first pair (in proximity to the hardmask or in proximity to the top of the stack). Thus, in some instances, a portion of the stack can be composed of repeating layers (e.g., provided as repeating pairs), and another portion of the stack can include non-repeating layers.

Optionally, the stack can have a hardmask 140 or a metal layer disposed thereon. In particular embodiments, the hardmask is not an epitaxial layer or is not deposited in an epitaxial manner.

As seen in FIG. 1B, the stack can include an n1 number of first semiconductor layers 131a-n and an n2 number of second semiconductor layers 136a-n, in which n1 and n2 are integers.

In some embodiments, n1=n2. In other embodiments, n1<n2, or n1>n2. Each layer can have a thickness, which may or may not be the same within the stack. As seen in FIG. 1B, the stack can include a first semiconductor layer 131b having a thickness t₁, and a second semiconductor layer 136b having a thickness t₂. In some embodiments, t₁<t₂, or t₁>t₂. In other embodiments, t₁=t₂. Even within the stack, each t₁ associated with each of the first semiconductor layers 131a-n can be different or the same. Similarly, each t₂ associated with each of the second semiconductor layers 136a-n can be different or the same.

As seen in FIG. 1B, the stack can be characterized as having a pair 106 of first and second semiconductor layers, in which the stack has an x number of first-second semiconductor pairs, an n1 number of first semiconductor layers 131a-n, and an n2 number of second semiconductor layers 136a-n. Each of x, n1, and n2 is, independently, selected from 1 to 100 (e.g., from 2 to 100, 3 to 100, 4 to 100, 5 to 100, 6 to 100, 7 to 100, 8 to 100, 9 to 100, 10 to 100, 1 to 50, 2 to 50, 3 to 50, 4 to 50, 5 to 50, 6 to 50, 7 to 50, 8 to 50, 9 to 50, 10 to 50, and the like). In some embodiments, the stack includes more than 2, 3, 4, 5, 6, 7, 8, 9, 10, 11, 12, 13, 14, 15, 20, 25, 30, 35, 40, 45, 50, or more pairs. In other embodiments, a portion of the stack can be composed of repeating pairs, and another portion of the stack can include non-repeating layers.

In addition to pairs, the stack can include triplets, quartets, or any other useful y number of repeating groups of layers (e.g., in which y is 2, 3, 4, 5, 6, or more). Where a pair will have y=2 layers (a single first semiconductor layer and a single second semiconductor layer), a quartet can have y=4 layers (a first semiconductor layer, then a second semiconductor layer, another first semiconductor layer, and finally another second semiconductor layer).

As seen in FIG. 1C, the stack can be characterized as having a quartet 107 of first and second semiconductor layers, in which the stack has an x number of first-second-first-second semiconductor quartets, an n1a number of first semiconductor layers 132a-n, an n1b number of further first semiconductor layers 133a-n, an n2a number of second semiconductor layers 137a-n, and an n2b number of further second semiconductor layers 138a-n. Each of x, n1a, nib, n2a, and n2b is, independently, selected from 1 to 100 (e.g., from 2 to 100, 3 to 100, 4 to 100, 5 to 100, 6 to 100, 7 to 100, 8 to 100, 9 to 100, 10 to 100, 1 to 50, 2 to 50, 3 to 50, 4 to 50, 5 to 50, 6 to 50, 7 to 50, 8 to 50, 9 to 50, 10 to 50, and the like). In some embodiments, the stack includes more than 1, 2, 3, 4, 5, 10, 15, 20, 25, 30, 35, 40, 45, 50, or more quartets. In other embodiments, a portion of the stack can be composed of repeating quartets, and another portion of the stack can include non-repeating layers.

The quartet can include a first semiconductor layer 132b having a thickness t₁, a second semiconductor layer 137b having a thickness t₂, another first semiconductor layer 133b having a thickness t₃, and another second semiconductor layer 138b having a thickness t₄. In some embodiments, t₁≤t₂, t₁≥t₂, t₁≤t₃, t₁≥t₃, t₁≤t₄, t₁≥t₄, t₂≤t₃, t₂≥t₃, t₂≤t₄, t₂≥t₄, t₃<t₄, or t₃≥t₄. In other embodiments, t₁≤t₃, t₁≥t₃, t₂≤t₄, and t₂≥t₄. In yet other embodiments, t₁=t₂=t₃=t₄. Even within the stack, each t₁ or t₃ associated with each of the first semiconductor layers 132a-n/133a-n, respectively, can be different or the same. Similarly, each t₂ or t₄ associated with each of the second semiconductor layers 137a-n/138a-n, respectively, can be different or the same. The quartet 107 can be repeated to form a stack. In particular embodiments, the thicknesses may or may not be the same within the top or the bottom of the stack (e.g., to account for varying etch rates or deposition rates, which can depend on whether the layer is towards the top of the stack or towards the bottom of the stack).

In some embodiments, the stack can include silicon-containing layers (Si layers) and silicon- and germanium-containing layers (SiGe layers). FIG. 1D shows a non-limiting stack 150 disposed on an optional buffer layer 170, which in turn is disposed on a top surface of a substrate 160. In particular embodiments, the buffer layer is an epitaxial layer or is deposited in an epitaxial manner.

Here, the stack 150 includes an n1 number of SiGe layers 180a-n and an n2 number of Si layers 185a-n, in which n1 and n2 are integers. In some embodiments, n1=n2. In other embodiments, n1<n2 or n1>n2. Each layer can have a thickness t, in which each t for each of the SiGe layers 180a-n and the Si layers 185a-n can be the same or different. The stack can be characterized as having a pair 155 of SiGe—Si layers, in which the stack has an x number of SiGe—Si pairs. Each of x, n1, and n2 is, independently, selected from 1 to 100 (e.g., from 2 to 100, 3 to 100, 4 to 100, 5 to 100, 6 to 100, 7 to 100, 8 to 100, 9 to 100, 10 to 100, 1 to 50, 2 to 50, 3 to 50, 4 to 50, 5 to 50, 6 to 50, 7 to 50, 8 to 50, 9 to 50, 10 to 50, and the like).

Optionally, the stack can have a hardmask 190 or a metal layer disposed thereon. In particular embodiments, the hardmask is not an epitaxial layer or is not deposited in an epitaxial manner. Non-limiting materials for a hardmask (e.g., an ashable hardmask) or a metal layer include silicon (e.g., silicon oxide, silicon nitride, silicon oxynitride, silicon oxycarbide, silicon carbide, etc.), carbon (e.g., amorphous carbon or amorphous carbon-hydrogen), nitrogen, oxygen, aluminum (Al), a nitride (e.g., titanium nitride (TiN), tantalum nitride (TaN), or tungsten nitride (WN)), a metal (e.g., cobalt (Co), nickel (Ni), ruthenium (Ru), tin (Sn), indium (In), palladium (Pd), germanium (Ge), titanium (Ti), tungsten (W), chromium (Cr), copper (Cu), tantalum (Ta), and combinations thereof), a metal oxide (e.g., an oxide of any metal described herein, including titanium oxide, titanium silicon oxide, tungsten oxide, or tantalum oxide), as well as any other described herein. Any of these materials can be provided as a layer in proximity to the hardmask, such as a seeding layer, an anti-reflective coating layer, a liner layer, an adhesion layer, and the like.

In some embodiments, the order of layers within the pair or quartet can be modified. FIG. 1E shows a non-limiting stack 151 having heterolayers disposed on a top surface of a substrate 161. Here, the stack 151 includes a Si layer 186a dispose directly on a top surface of the substrate 161. In addition, the stack 151 includes an n1 number of Si layers 186a-n and an n2 number of SiGe layers 181a-n, in which n1 and n2 are integers. In some embodiments, n1=n2. In other embodiments, n1<n2 or n1>n2. Each layer can have a thickness t, in which each t for each of the Si layers 186a-n and the SiGe layers 181a-n can be the same or different. The stack can be characterized as having a pair 156 of Si—SiGe layers, in which the stack has an x number of Si—SiGe pairs. Each of x, n1, and n2 is, independently, selected from 1 to 100 (e.g., from 2 to 100, 3 to 100, 4 to 100, 5 to 100, 6 to 100, 7 to 100, 8 to 100, 9 to 100, 10 to 100, 1 to 50, 2 to 50, 3 to 50, 4 to 50, 5 to 50, 6 to 50, 7 to 50, 8 to 50, 9 to 50, 10 to 50, and the like). Optionally, the stack can have a hardmask 191 or a metal layer disposed thereon. In particular embodiments, the hardmask is not an epitaxial layer or is not deposited in an epitaxial manner.

Heterolayers can be provided within a stack in any useful manner. In one instance, heterolayers are deposited to minimize defects within the layer. In some embodiments, stacks can be prepared to minimize interdiffusion of atoms between the heterolayers. Other characteristics of stacks and layers, as well as methods thereof, are described herein.

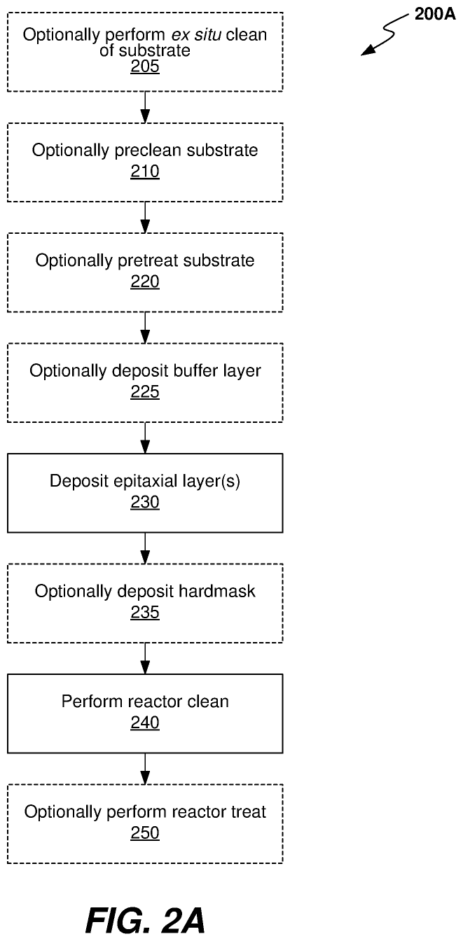

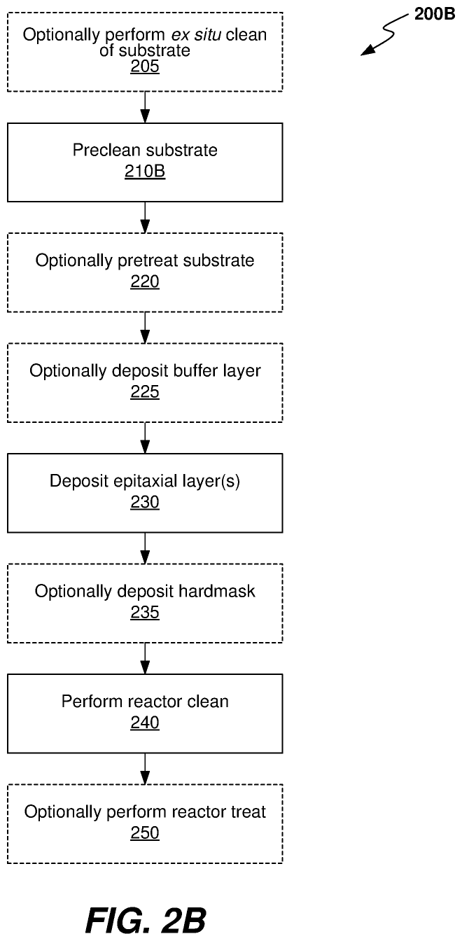

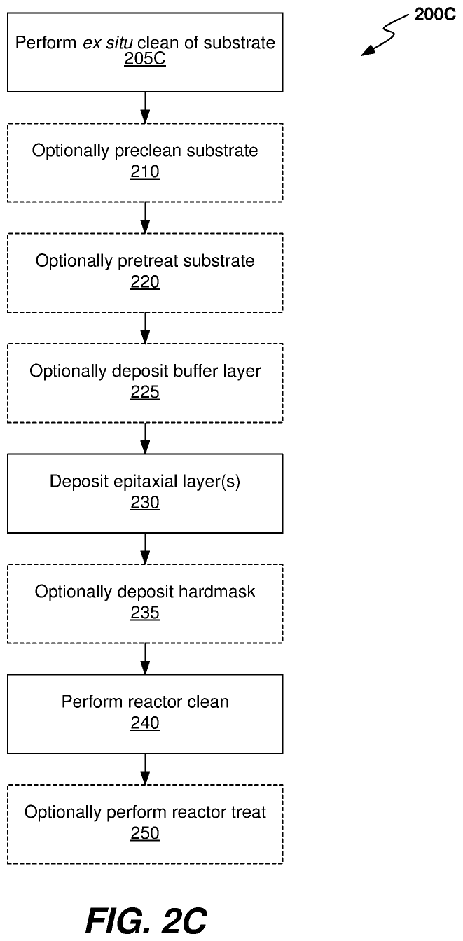

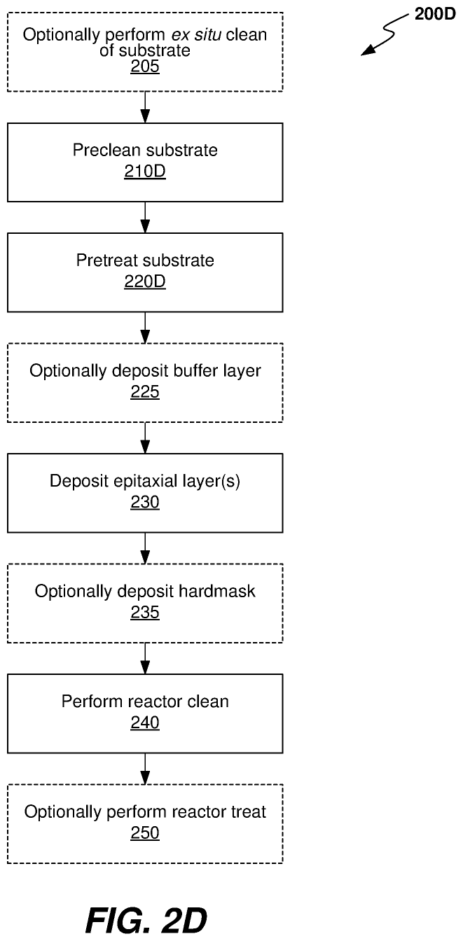

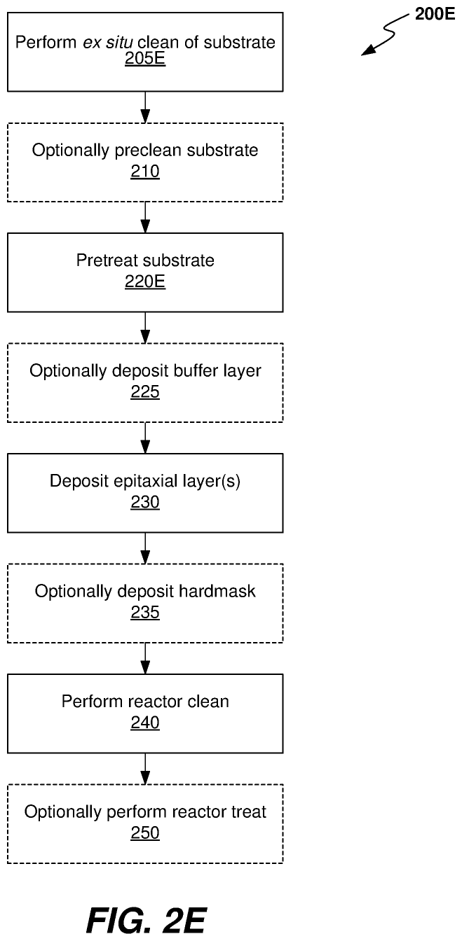

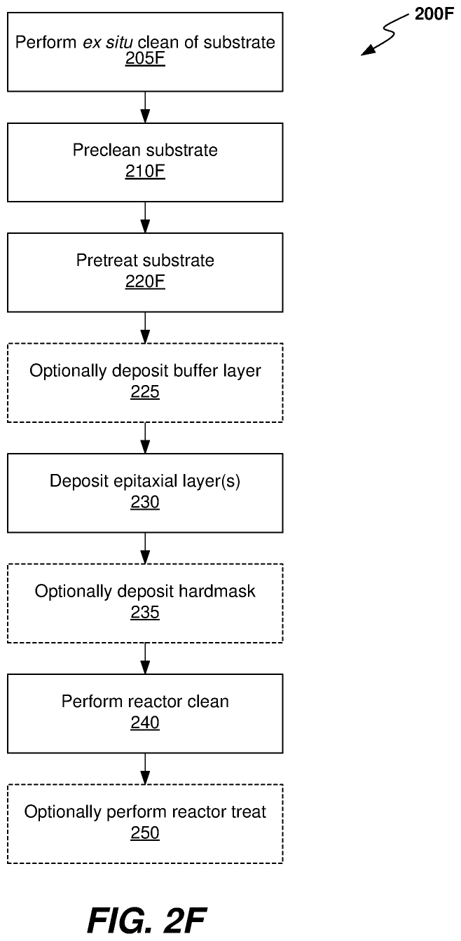

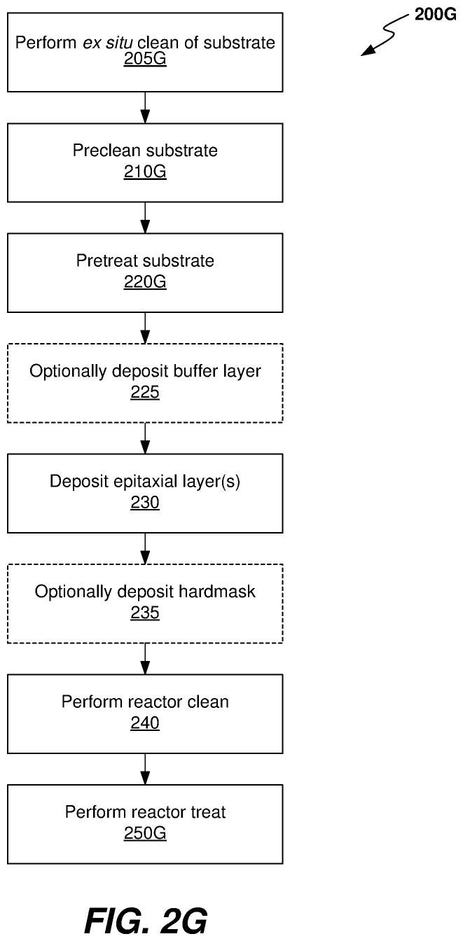

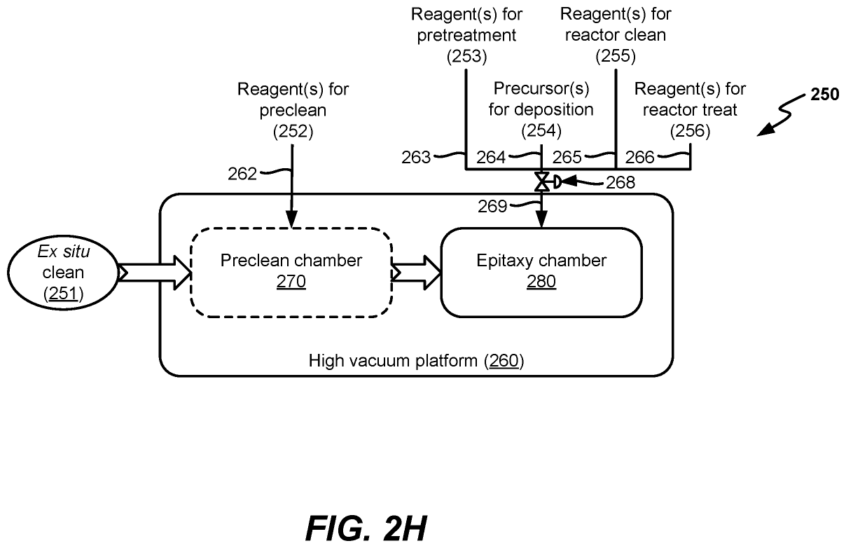

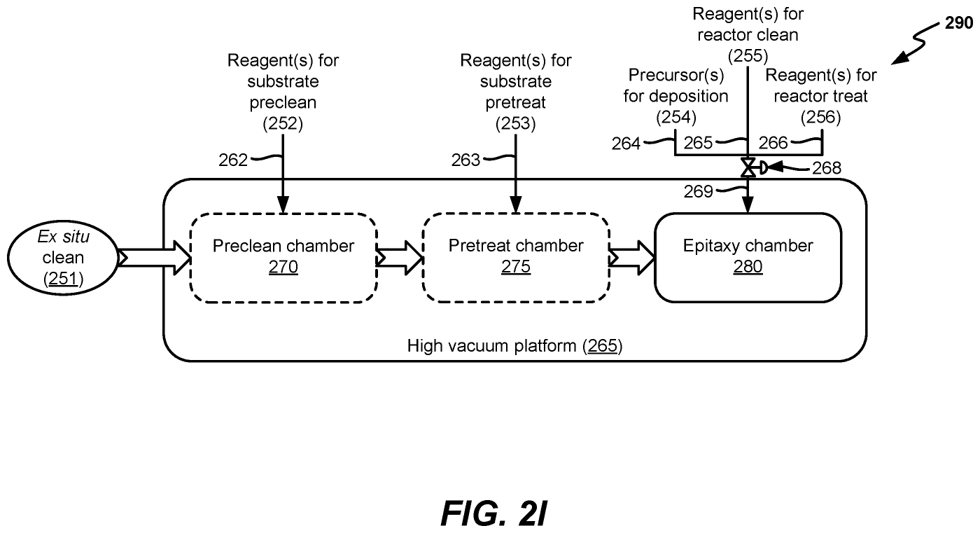

FIG. 2A provides a non-limiting schematic for providing a stack, forming heterolayers within a stack, or depositing a film. In one embodiment, the method can include various operations. As can be seen, one non-limiting method 200 includes various optional and required operations. FIG. 2B-2G shows methods in which select operations are performed in different combinations.

As seen in FIG. 2A, the method 200A can include an optional operation 205 for performing ex situ cleaning of the substrate. Such an ex situ clean operation 205 can include a wet process or a dry process, such as any described herein with reference to a preclean operation 210 or a reactor clean operation 240. In one embodiment, the ex situ clean operation 205 can remove metals or other contaminants from a surface of the substrate.

The method can further include optional operation 210 of precleaning a surface of the substrate and an optional operation 220 of pretreating the surface of the substrate. Such optional operations (e.g., at least one of operations 210 or 220) can be configured to provide a pristine surface upon which epitaxial layers can be deposited. In certain embodiments, operation 210 of precleaning is configured to remove native oxide on a surface of the substrate, and operation 220 is configured to provide a pristine surface prior to epitaxial deposition.

As used herein, in some embodiments, the term “preclean” or “precleaning” refers to a process to clean a surface of the substrate. In particular non-limiting embodiments, such precleaning can provide an oxide-free surface disposed on the substrate. In other non-limiting embodiments, such precleaning can be configured to remove native oxide disposed on a surface of the substrate.

As used herein, in some embodiments, the term “pretreat,” “pretreating,” or “pretreatment” refers to a process to treat a surface of the substrate. In particular non-limiting embodiments, such pretreating can remove contaminants (e.g., oxygen, carbon, fluorine, and the like) disposed on a surface of the substrate, in which such contaminants can be present on the surface after precleaning but before deposition. In other non-limiting embodiments, such pretreating can provide a passivated surface disposed on the substrate. In yet other non-limiting embodiments, such pretreating can provide a hydrophobic surface disposed on the substrate. As used herein, a “hydrophobic surface” refers to a surface that repels water or water vapor. In one embodiment, the hydrophobic surface is characterized as having at least one of Si—H, Si—D, and Si—F bonds. In another embodiment, the hydrophobic surface is characterized as having substantially all or at least 90% of the surface as presenting at least one of Si—H, Si—D, or Si—F bonds. In another embodiment, the hydrophobic surface is characterized as having at least 95% of the surface as presenting at least one of Si—H, Si—D, or Si—F bonds. In another embodiment, a hydrophobic surface is characterized as having a static water contact angle θ that is more than about 90° for a liquid (water) that is provided at the test surface, in which θ is measured between the surface-liquid interface and the liquid-vapor interface.

In some embodiments, operation 210 can be configured to preclean a surface of the substrate to remove an oxide. Non-limiting preclean operations are described herein. In one embodiment, operation 210 can include delivering a halogen-containing reagent, a fluorine-containing vapor, or a fluorine-containing plasma into a reaction chamber housing the substrate. Without wishing to be limited by mechanism, fluorine atoms can react with oxygen atoms provided as silicon oxide on the surface of the substrate, thereby generating a fluorine-containing byproduct. Such byproducts can then be pyrolyzed, sublimated, evaporated, or otherwise removed from the surface. Operation 210 can include a dry process, a wet process, or a combination of dry and wet processes; and non-limiting examples of such processes are further described herein. Such an operation 210 can be conducted in the absence or presence of plasma.

In some embodiments, operation 220 can be configured to pretreat a surface of the substrate to provide a pretreated surface (e.g., a hydrophobic surface). Non-limiting pretreat operations are described herein. In one embodiment, operation 220 can include delivering a hydrogen-containing reagent, a deuterium-containing reagent, a hydrogen gas, a deuterium gas, a hydrogen-containing plasma, or a deuterium-containing plasma into a reaction chamber housing the substrate. In particular embodiments, the reaction chamber housing the substrate is the epitaxy chamber. In this way, a pretreated surface can be used without further moving the substrate for epitaxial deposition. Operation 220 can include a dry process in the absence or presence of plasma. Non-limiting examples of pretreat processes are further described herein.

Turning again to FIG. 2A, the method 200A can further include forming heterolayers on the substrate by way of operation 230 of depositing one or more epitaxial layers. Such layers can include one or more first semiconductor layers and one or more second semiconductor layers. In one embodiment, the layers can include semiconductor layers, sacrificial layers, or both. In another embodiment, the layers include alternating semiconductor layer and sacrificial layers. In some embodiments, operation 230 includes deposition on a substrate having a precleaned surface (e.g., an oxide-free surface, which can be obtained after performing operation 210); a pretreated surface (e.g., a hydrophobic surface or a passivated surface obtained after performing operation 220); and a precleaned, pretreated surface (e.g., a pristine surface, which can be obtained after performing operations 210 and 220).

Operation 230 can include any processes useful for forming at least a first semiconductor layer or a second semiconductor layer. Such processes can provide the first semiconductor layer, such as by flowing a first precursor into a reaction chamber (e.g., an epitaxy chamber) and toward the substrate, as well as by generating an energetic species (e.g., a plasma including radicals, metastables, and the like) that can react with the first precursor to deposit the semiconductor layer on the substrate. Examples of first precursors including any described herein, such as those including a Group IV atom (e.g., a C-containing precursor, a Si-containing precursor, a Ge-containing precursor, or a Sn-containing precursor, such as any described herein), a Group III atom (e.g., a B-containing precursor, an Al-containing precursor, a Ga-containing precursor, an In-containing precursor, or a T1-containing precursor, such as any described herein), or a Group V atom (e.g., an N-containing precursor, a P-containing precursor, an As-containing precursor, a Sb-containing precursor, or a Bi-containing precursor, such as any described herein), as well as combinations thereof.

Further processes can include providing a second semiconductor layer, such as by flowing a second precursor into a reaction chamber (e.g., an epitaxy chamber) and toward the substrate, as well as by generating an energetic species (e.g., a plasma including radicals, metastables, and the like) that can react with the second precursor to deposit the second layer on top of the first layer. Examples of a second precursor include any described herein, such as those including a Group IV atom (e.g., a C-containing precursor, a Si-containing precursor, a Ge-containing precursor, or a Sn-containing precursor, such as any described herein), a Group III atom (e.g., a B-containing precursor, an Al-containing precursor, a Ga-containing precursor, an In-containing precursor, or a T1-containing precursor, such as any described herein), or a Group V atom, as well as combinations thereof, in which the second precursor is different than the first precursor.

Any energetic species can be employed during deposition. As used herein, an “energetic species” can include any species that is reactive with one or more components provided during a deposition process. Such components can include a precursor, a deposited layer, and the like. Non-limiting examples of energetic species include radicals, metastables, ions, neutral species, plasma, photons, radiation, excited molecules, excited atoms, a reactive species, or others described herein. In one non-limiting embodiment, the metastable has an energy of about 0.01-1 eV. In another non-limiting embodiment, the ion has an energy of about 100-1000 eV. In yet another non-limiting embodiment, the energetic species has an energy of about 0.01-1000 eV. Any description herein related to radicals and metastables may, in some non-limiting instances, encompass any energetic species described herein.

Delivery of first and second precursors can be repeated until a predetermined number of first and second layers have been deposited on the substrate. Non-limiting examples of deposition processes are described herein.

Optionally, for depositing the first or second semiconductor layers, two or more precursors can be delivered into reaction chamber. For example, taking the example of a silicon-and germanium-containing layer (SiGe-containing layer), a single precursor can be used that provides both Si atoms and Ge atoms (e.g., germylsilane or H₃Ge—SiH₃). Alternatively, two precursors can be delivered to the substrate, in which a first precursor can include an Si atom (e.g., as in a silicon hydride, silicon hydrohalide, or silicon halide precursor), and a second precursor can include a Ge atom (e.g., as in a germanium hydride, germanium hydrohalide, or germanium halide precursor). Additional precursors are described herein. As also described herein, precursors can be delivered in combination with one or more carrier gases, inert gases, and the like.

The method can include optional operations that can be conducted before or after depositing heterolayers. As seen in FIG. 2A, in one embodiment, the method includes an optional operation 225 of depositing a buffer layer on a surface of the substrate prior to deposition of one or more epitaxial layers. In some embodiments, the buffer layer is deposited epitaxially. In other embodiments, the buffer layer is not deposited epitaxially. The buffer layer may be deposited within the epitaxy chamber or within another chamber that is different than the epitaxy chamber.

In another embodiment, the method includes an optional operation 235 of depositing a hardmask or a metal layer on a surface of a deposited epitaxial layer (e.g., an epitaxial first semiconductor layer, an epitaxial second semiconductor layer, or an epitaxial sacrificial layer). In particular embodiments, operation 235 is not performed in an epitaxial manner.

Upon depositing a desired number of heterolayers, the stack can be removed from the reactor chamber. As further seen in FIG. 2A, the method 200A can further include operation 240 for performing a reactor clean. Operation 240 can be performed at any time after operation 230 or before operation 230. In this way, the reactor chamber can be clean prior to deposition of first and second semiconductor layers. In one embodiment, operation 240 includes removing contaminants from an environment or a surface within the reaction chamber. In one instance, performing the reactor clean includes delivering halogen-containing vapor, halogen-containing plasma, fluorine-containing vapor, fluorine-containing plasma, chlorine-containing vapor, or chlorine-containing plasma to the reaction chamber. Non-limiting examples of reactor clean processes are described herein.

Further operations can be conducted to ensure an effective environment for epitaxial deposition. In one instance, after performing operation 240 for cleaning the reactor, an optional operation 250 for performing a reactor treat can be conducted. In some embodiments, operation 250 includes passivating the environment or the surface within the reaction chamber. In one instance, passivation can include gettering or capturing halogen atoms or other contaminants that may be introduced during any operations herein (e.g., preclean operations 210/210B/210D/210F/210G, pretreat operations 220/220D/220E/220F/220G, deposition operations 230, or reactor clean operations 240 in FIG. 2A-G). Non-limiting examples of reactor treat processes are described herein.

Any combination of optional operations can be performed. As seen in FIG. 2B, the method 200B can further require operation 210B of precleaning a surface of the substrate, thereby providing a precleaned surface. In one non-limiting instance, operation 210B includes removing an oxide from the surface of the substrate. Such a preclean operation 210B can be performed with or without performing operation 205 for ex situ clean of the substrate. For instance, if preclean operation 210B serves the same purpose as ex situ operation 205, then ex situ operation 205 may not be performed. In another instance, if preclean operation 210B provides the same surface as when ex situ operation 205 is performed, then ex situ operation 205 may not be performed.

As seen in FIG. 2C, the method 200C can further require operation 205C of performing an ex situ cleaning a surface of the substrate, thereby removing various contaminants from the surface of the substrate. Such an ex situ clean operation 205C can be performed with or without performing operation 210 for in situ precleaning of the substrate. For instance, if ex situ clean operation 205C serves the same purpose as in situ operation 210, then in situ operation 210 may not be performed. In another instance, if ex situ clean operation 205C provides the same surface as when in situ operation 210 is performed, then in situ operation 210 may not be performed.

After ex situ cleaning or in situ precleaning, a pretreat operation may be performed. As seen in FIG. 2D, the method 200D can further require operation 210D of precleaning a surface of the substrate, thereby providing a precleaned surface (e.g., thereby removing an oxide from the surface of the substrate to provide an oxide-free surface); and then followed by operation 220D of pretreating the surface of the substrate, thereby providing a pretreated surface (e.g., a hydrophobic surface or a passivated surface).

As seen in FIG. 2E, the method 200E can further require operation 205E of ex situ cleaning a surface of the substrate, thereby removing contaminants from the surface of the substrate; and then followed by operation 220E of pretreating the surface of the substrate, thereby providing a pretreated surface (e.g., a hydrophobic surface or a passivated surface).

In yet other instances, both ex situ cleaning and in situ precleaning are performed. As seen in FIG. 2F, the method 200F can further require operation 205F of ex situ cleaning a surface of the substrate, thereby removing contaminants from the surface of the substrate; followed by operation 210F of precleaning a surface of the substrate, thereby providing a precleaned surface of the substrate; and then followed by operation 220F of pretreating the surface of the substrate, thereby providing a pretreated surface of the substrate.

After performing various clean, preclean, and pretreat operations for the substrate, the process can include operations to clean and treat the reactor. As seen in FIG. 2G, the method 200G can include operation 205G of ex situ cleaning a surface of the substrate, thereby removing contaminants from the surface of the substrate; followed by operation 210G of precleaning a surface of the substrate, thereby providing a precleaned surface; and then followed by operation 220G of pretreating the surface of the substrate, thereby providing a pretreated surface. A deposition operation 230 can be performed with an optional operation 225 to provide a buffer layer (before operation 230) and an optional operation 235 to deposit a hardmask (after operation 230).

In particular embodiments, the hardmask is not an epitaxial layer, or operation 235 is not performed in an epitaxial manner

Further operations can be conducted to treat the reactor chamber after deposition or to ensure an effective environment for subsequent epitaxial deposition. In one instance, as seen in FIG. 2G, the method 200G can further include operation 240 for cleaning the reactor chamber, thereby removing contaminants from any environment within the chamber; and followed by operation 250G for performing a reactor treat, thereby passivating the environment within the reaction chamber. In one instance, passivation can include gettering or capturing halogen atoms or other contaminants that may be introduced during any operations herein (e.g., preclean operations 210/210B/210D/210F/210G, pretreat operations 220/220D/220E/220F/220G, deposition operations 230, or reactor clean operations 240 in FIG. 2A-G). Non-limiting examples of reactor treat processes are described herein.

FIG. 2H provides a non-limiting schematic for a system 250, which can be configured to conduct any methods or operations described herein. As can be seen, a non-limiting high vacuum platform 260 can be configured to optionally include a preclean chamber 270 and to include an epitaxy chamber 280. An ex situ clean operation 251 can be conducted outside of the platform to clean the substrate. Such a substrate can be delivered to the preclean chamber 270, if present, or delivered directly to the epitaxy chamber 280.

As can be seen, the preclean chamber 270 can be configured to perform a preclean operation, such as by having one or more inlets (e.g., process gas inlets 262, if the reagents are in vapor form) coupled to reagents 252 for performing a preclean operation. Non-limiting reagents of precleaning the substrate can include, e.g., one or more fluorine-containing reactants or other reagents described herein. As used herein, the terms “reactant” and “reagent” are used interchangeably. After being precleaned, the substrate can then be transferred to the epitaxy chamber 280. To maintain the surface of the substrate, such a transfer can be conducted under vacuum.

Within the epitaxy chamber, a pretreat operation can be conducted to provide a passivated surface for the substrate. For instance, the epitaxy chamber 280 can be configured to have one or more inlets (e.g., process gas inlets 263, which in turn is fluidly coupled to gas inlet 269) coupled to reagents 253 for performing a pretreat operation. Non-limiting reagents of pretreating the substrate can include, e.g., hydrogen gas, hydrogen-containing plasma, or other reagents described herein.

After being pretreated, the substrate is retained within the epitaxy chamber 280. One or more precursors can be delivered to the substrate in the presence of plasma, which in turn can provide radicals or metastables that react with the precursor to deposit the semiconductor layer or the sacrificial layer on the substrate. For instance, the epitaxy chamber 280 can be configured to have one or more inlets (e.g., process gas inlets 264, which in turn is fluidly coupled to gas inlet 269) coupled to reagents 254 for performing a deposition operation. Non-limiting reagents of deposition can include, e.g., any precursor (e.g., Si-, Ge-, or Si- and Ge-containing precursors) or other reagents described herein.

The buffer layer may be deposited within the epitaxy chamber 280 or within another chamber that is different than the epitaxy chamber. For instance, the buffer layer may be deposited in another chamber that is provided within the high vacuum platform 260 or in another chamber that is located outside of the platform.

To provide plasma, the epitaxy chamber 280 or one or more inlets coupled to the epitaxy chamber 280 can, in turn, be coupled to a plasma source (e.g., a remote plasma source). As used herein, a “remote plasma source” refers to plasma generation which occurs remote from the substrate, as further described herein. In some non-limiting instances, a remote plasma source is located outside of the epitaxy chamber 280 but fluidically connected to the epitaxy chamber (e.g., by way of one or more gas inlets). In other non-limiting instances, a remote plasma source is located upstream of the epitaxy chamber in which the substrate is residing. As used herein, the terms “upstream” and “downstream” relate to relative positional terms, in which upstream refers to a position that is located before a given point and downstream refers to a position that is located after a given point.

After deposition, the substrate and the resultant film can be removed from the epitaxy chamber 280. Further operations can include cleaning and treating the epitaxy chamber. As can be seen in FIG. 2H, the epitaxy chamber 280 can be configured to have one or more inlets (e.g., process gas inlets 265, 266, which in turn are fluidly coupled to gas inlet 269) coupled to reagents 255 for performing a reactor clean operation or coupled to reagents 256 for performing a reactor treat operation. Non-limiting reagents of cleaning and treating the reactor can include, e.g., hydrogen gas, hydrogen-containing plasma, halogen-containing gas, halogen-containing plasma, silane gas, germane gas, or other reagents described herein. Any inlets herein (e.g., gas inlets 262-266, 269) can be connected directly or indirectly to the chamber (e.g., chambers 270, 280), and such inlets can include one or more valves (e.g., valve 268) to control the introduction of process gases (e.g., reagents 252-256) into a chamber (e.g., chambers 270, 280).

In particular embodiments, the preclean operation and pretreat operation for the substrate are performed in separate chambers. FIG. 21 provides a non-limiting schematic for a system 290. As can be seen, a non-limiting high vacuum platform 265 can be configured to optionally include a preclean chamber 270, optionally include a pretreat chamber 275, and to include an epitaxy chamber 280.

As can be seen, the preclean chamber 270 can be configured to perform a preclean operation, such as by having one or more inlets (e.g., process gas inlets 262, if the reagents are in vapor form) coupled to reagents 252 for performing a preclean operation. After being precleaned, the substrate can then be transferred to the pretreat chamber 275, which can be configured to have one or more inlets (e.g., process gas inlets 263) coupled to reagents 253 for performing a pretreat operation. To maintain the surface of the substrate, such a transfer from the preclean chamber 270 to the pretreat chamber 275 can be conducted under vacuum.

Next, the precleaned and pretreated substrate can be transferred from the pretreat chamber 275 to the epitaxy chamber 280, which can be conducted under vacuum. The epitaxy chamber 280 can be configured to have one or more inlets (e.g., process gas inlets 264, 265, 266, which in turn are fluidly coupled to gas inlet 269) coupled to reagents 254 for performing a deposition operation or coupled to reagents 255 for performing a reactor clean operation or coupled to reagents 256 for performing a reactor treat operation. By having an integrated platform, transfers between chambers can be conducted under vacuum. Any inlets herein (e.g., gas inlets 262-266, 269) can be connected directly or indirectly to the chamber (e.g., chambers 270, 275, 280), and such inlets can include one or more valves (e.g., valve 268) to control the introduction of process gases (e.g., reagents 252-256) into a chamber (e.g., chambers 270, 275, 280).

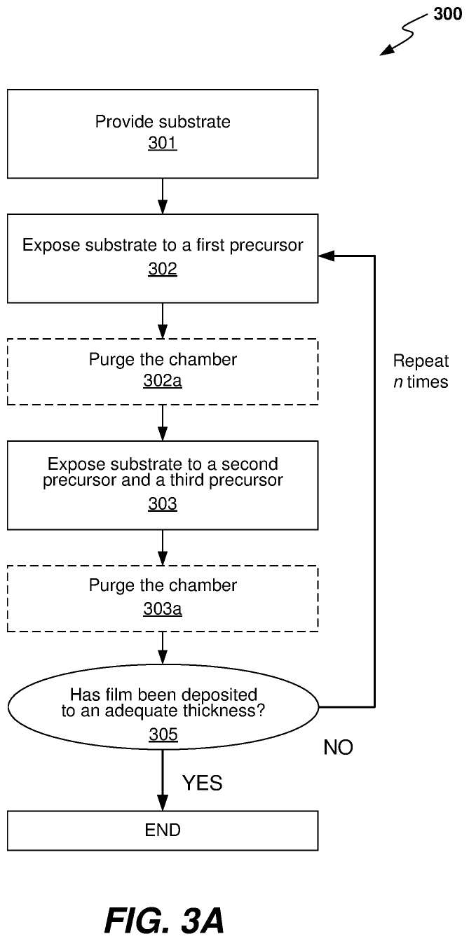

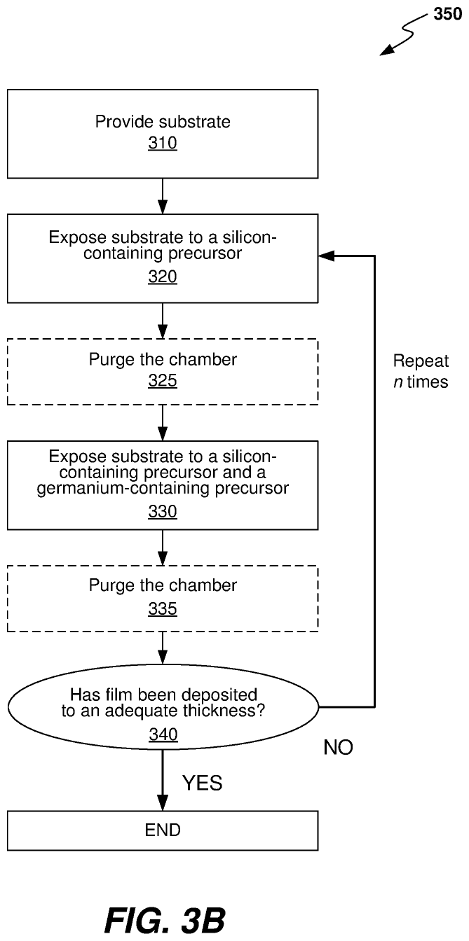

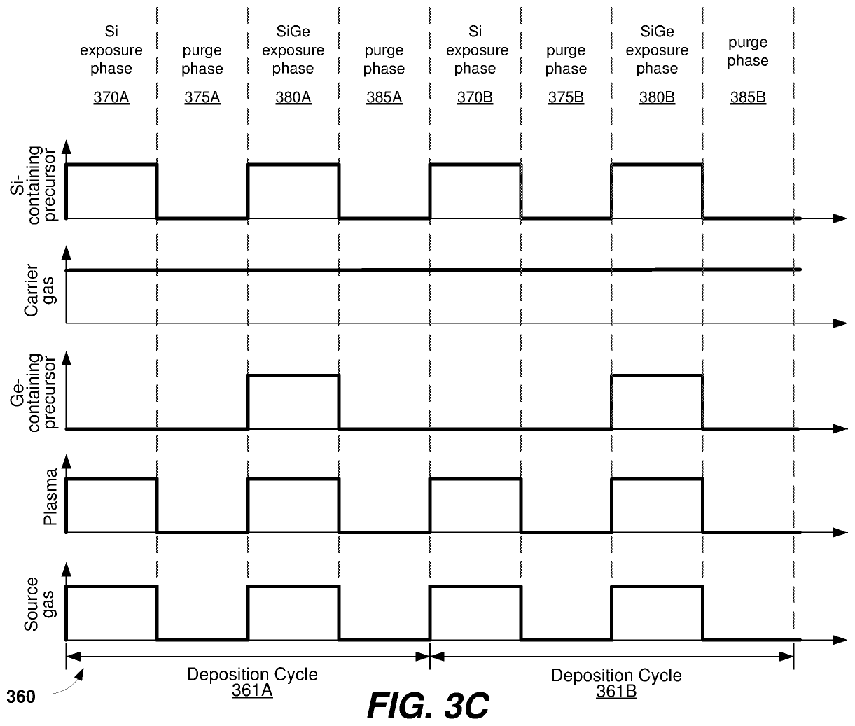

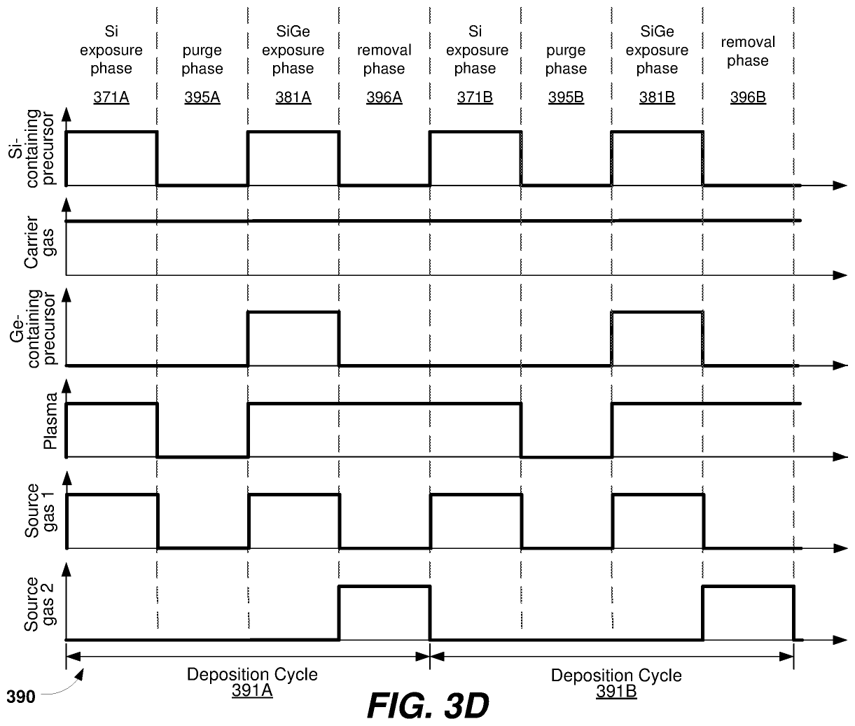

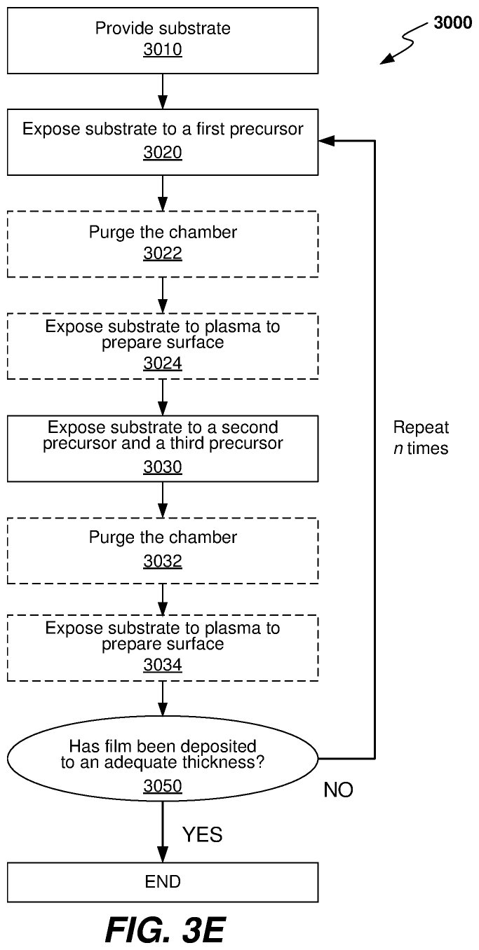

FIG. 3A provides a non-limiting schematic for providing a stack. In one embodiment, the method 300 includes various operations. At operation 301, a substrate is provided, for example, in a process chamber of a reactor. In some implementations, the reactor may be a reactor configured for performing plasma-based deposition operations. At operation 302, the substrate is exposed to a first precursor. It should be noted that, during the time the substrate is exposed to the first precursor, the substrate may additionally be exposed to radicals or metastables (e.g., any described herein) or other reaction-promoting stimulus, which interact with the precursor to deposit a layer (e.g., a semiconductor layer or a sacrificial layer) on the substrate. As used herein, a “reaction-promoting stimulus” is any type of chemical, energetic, or other stimulus that can interact with a precursor to deposit a material on a surface. In some implementations, the radicals, metastables, and the like may be generated using a plasma (e.g., a remote plasma or in situ plasma within the process chamber), a hot wire filament, or other sources (e.g., any described herein). In some embodiments, the precursor may be flowed to the substrate without activation in a remote plasma source.

As a result of operation 302, a first semiconductor layer (e.g., an epitaxial semiconductor layer) is deposited on the substrate. Optionally, at operation 302a, the process chamber is purged. At operation 303, the substrate is exposed to a second precursor and a third precursor. Typically, the second precursor in operation 303 is different than the first precursor employed in operation 302, thereby providing different layers (or heterolayers) having differing composition. However, the third precursor used in operation 303 may be the same or may be different than the first precursor used in operation 302.

Similar to what is described above with respect to operation 302, during the time the substrate is exposed to the second precursor and the third precursor in operation 303, the substrate may additionally be exposed to radicals, metastables, and the like (e.g., hydrogen-containing radicals, e.g., a hydrogen radical (H*); nitrogen-containing radicals, e.g., a nitrogen radical (N*); argon-containing metastables, e.g., an argon metastable (Ar*); helium-containing metastables, e.g., a helium metastable (He*), or the like) that interact with the precursors to deposit a second semiconductor layer on the substrate. In some embodiments, the radicals, metastables, and the like may be selected such that they do not interact with silicon. For example, in one embodiment, a reactive plasma may contain substantially no components that react with silicon. In one example, a reactive plasma may contain only hydrogen (e.g., H* or H₂), deuterium (e.g., D* or D₂), hydrogen deuteride (HD), an inert gas (e.g., He, Ar, He*, Ar*, etc.), or any combination thereof. In another example, a reactive plasma does not contain a nitrogen-containing species, a halogen-containing species, or an oxygen-containing species. The radicals or metastables may be generated using a plasma (e.g., a remote plasma or an in situ plasma), or any other suitable technique (e.g., a hot wire filament, as described above). In some embodiments, the second precursor and the third precursor are flowed to the substrate without activation in a remote plasma source. As a result of operation 303, a second semiconductor layer (e.g., an epitaxial semiconductor layer) is deposited on the substrate. Optionally, at operation 303a, the chamber is purged. Additionally or alternatively to purging the chamber, in some embodiments, a plasma may be generated, for example, of hydrogen. This may eliminate sources of other elements (e.g., Ge) remaining in the chamber such that another layer (e.g., an Si-containing layer) is not contaminated by remaining elements. In some implementations, this may prepare a sharp interface between layers.

At operation 305, a determination of whether a film of adequate thickness has been deposited is made. The determination may be made based on whether a total thickness of layer exceeds a predetermined threshold, whether more than a predetermined number of alternating first and second semiconductor layers have been deposited, or any suitable combination thereof. If, at operation 305, it is determined that film has not been deposited to adequate thickness (“no” at 305), the process can loop back to operation 302 and expose the substrate to the first precursor. In some implementations, blocks 302-305 are repeated n times. Conversely, if, at operation 305, it is determined that the film has been deposited to adequate thickness (“yes” at 305), the process ends.

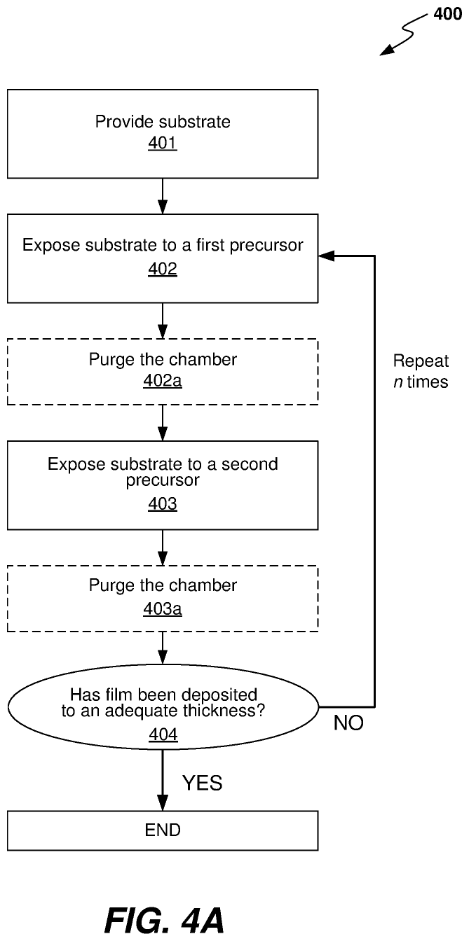

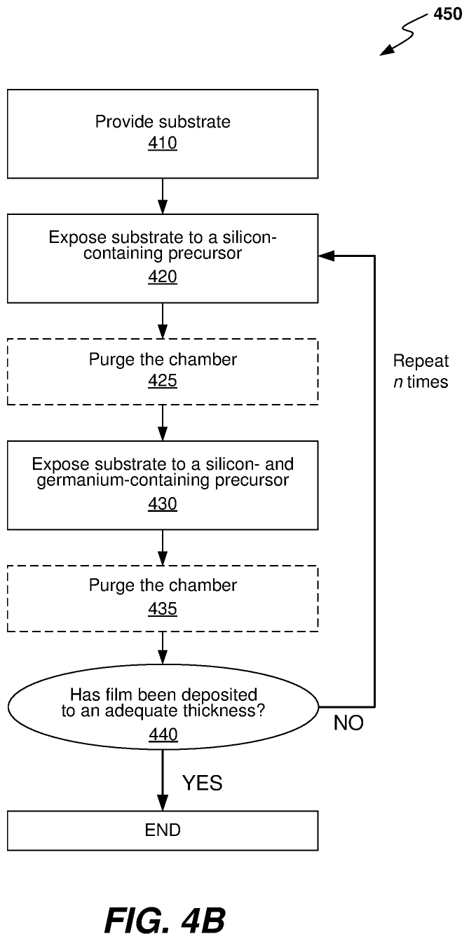

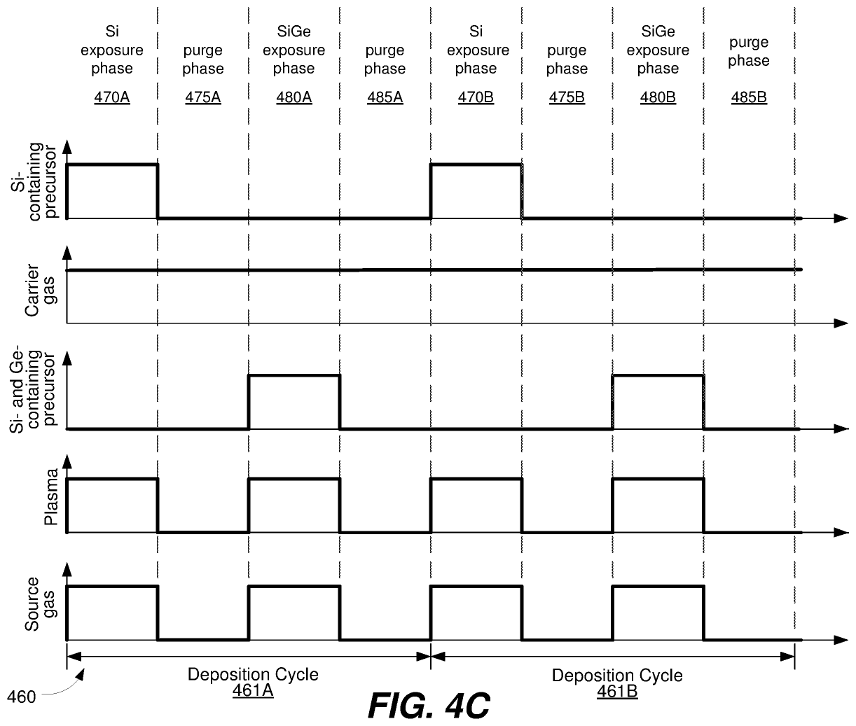

In particular embodiments, the method can provide rapid switching between operations. For instance, the apparatus or system to implement the method can be configured to rapidly switch between various operations during deposition. Taking the non-limiting method 300 in FIG. 3A, the method can provide rapid switching between phases or operations within a deposition cycle, such as rapid switching between an exposure operation 302, a purge operation 302a, a further exposure operation 303, and further purge operation 303a, as well as in subsequent repeat cycles for an n number of times. Rapid switching may occur between any operations described herein, such as between various operations 320/325/330/335 in FIG. 3B, between various operations described as phases 370A/375A/380A/385A in a first deposition cycle 361A and as phases 370B/375B/380B/385B in a second deposition cycle 361B in FIG. 3C, between various operations described as phases 371A/395A/381A/396A in a first deposition cycle 391A and as phases 371B/395B/381B/396B in a second deposition cycle 391B in FIG. 3D, between various operations 3020/3022/3024/3030/3032/3034 in FIG. 3E, between various operations 402/402a/403/403a in FIG. 4A, between various operations 420/425/430/435 in FIG. 4B, and between various operations described as phases 470A/475A/480A/485A in a first deposition cycle 461A and as phases 470B/475B/480B/485B in a second deposition cycle 461B in FIG. 4C. Methods, systems, and apparatuses that can be implemented to facilitate rapid switching are described herein (e.g., such as in paragraphs [0525]-[0526] herein).

The process can be implemented using particular precursors. In the example shown in FIG. 3B, a silicon-containing precursor is utilized to deposit an Si layer, and a silicon-containing precursor and a germanium-containing precursor are utilized to deposit an SiGe layer. At 310, a substrate is provided, for example, in a process chamber of a reactor. In some implementations, the reactor may be a reactor configured for performing plasma-based deposition operations. At 320, the substrate is exposed to a silicon-containing precursor. It should be noted that, during the time the substrate is exposed to the silicon-containing precursor, the substrate may additionally be exposed to radicals (e.g., hydrogen-containing radicals, nitrogen-containing radicals, or the like), metastables (e.g., argon-containing metastables, helium-containing metastables, or the like), or other reaction-promoting stimulus, which interact with the precursor to deposit an Si layer on the substrate. It should be noted that, in some embodiments, a reactive plasma may contain substantially no components that react with silicon. In one example, a reactive plasma may contain only hydrogen (e.g., H* or H₂), deuterium (e.g., D* or D₂), hydrogen deuteride (HD), an inert gas (e.g., He, Ar, He*, Ar*, etc.), or any combination thereof. In another example, a reactive plasma does not contain a nitrogen-containing species, a halogen-containing species, or an oxygen-containing species. In some implementations, the radicals, metastables, and the like may be generated using a plasma, which may be a remote plasma (e.g., upstream of the process chamber in which the substrate is residing) or in situ within the process chamber in which the substrate is residing. In other implementations, the radicals, metastables, and the like may be generated using other techniques. For example, in some implementations, the radicals, metastables, and the like may be generated using a hot wire filament (e.g., a tungsten filament) in which the high temperature of the filament is used to generate radicals, metastables, and the like from a gas (e.g., a hydrogen containing gas) flowed around the filament. In some embodiments, the silicon-containing precursor may be flowed to the substrate without activation in a remote plasma source. As a result of 320, an Si layer (e.g., an epitaxial Si layer) is deposited on the substrate. Optionally, at 325, the process chamber is purged. Additionally or alternatively to purging the chamber, in some embodiments, a plasma may be generated for example, of hydrogen. This may eliminate sources of other elements (e.g., Ge) remaining in the chamber such that the Si layer is not contaminated by remaining elements. In some implementations, this may prepare a sharp interface between layers.

At 330, the substrate is exposed to a silicon-containing precursor and a germanium-containing precursor. The silicon-containing precursor utilized at 330 may be the same or may be different than the silicon-containing precursor utilized at 320. Similar to what is described above with respect to block 320, during the time the substrate is exposed to the silicon-containing precursor and the germanium-containing precursor, the substrate may additionally be exposed to radicals (e.g., hydrogen-containing radicals, nitrogen-containing radicals, or the like) or metastables (e.g., argon-containing metastables, helium-containing metastables, or the like), which interact with the precursors to deposit a SiGe layer on the substrate. It should be noted that, in some embodiments, a reactive plasma may contain substantially no components that react with silicon or with germanium or with both silicon and germanium. In one example, a reactive plasma may contain only hydrogen (e.g., H* or H₂), deuterium (e.g., D* or D₂), hydrogen deuteride (HD), an inert gas (e.g., He, Ar, He*, Ar*, etc.), or any combination thereof. In another example, a reactive plasma does not contain a nitrogen-containing species, a halogen-containing species, or an oxygen-containing species. The radicals, metastables, and the like may be generated using a plasma (e.g., a remote plasma or an in situ plasma), or any other suitable technique (e.g., a hot wire filament, as described above). In some embodiments, the silicon-containing precursor and the germanium-containing precursor are flowed to the substrate without activation in a remote plasma source. As a result of 330, a SiGe layer (e.g., an epitaxial SiGe layer) is deposited on the substrate. Optionally, at 335, the chamber is purged. Additionally or alternatively to purging the chamber, in some embodiments, a plasma may be generated, for example, of hydrogen. This may prepare a sharp interface between layers.

At 340, a determination of whether a film of adequate thickness has been deposited is made. The determination may be made based on whether a total thickness of layer exceeds a predetermined threshold, whether more than a predetermined number of alternating Si and SiGe layers have been deposited, or any suitable combination thereof. If, at 340, it is determined that film has not been deposited to adequate thickness (“no” at 340), the process can loop back to 320 and expose the substrate to the silicon-containing precursor. In some implementations, blocks 320-340 are repeated n times. Conversely, if, at 340, it is determined that the film has been deposited to adequate thickness (“yes” at 340), the process ends.

FIG. 3C provides a non-limiting process timing diagram 360 for depositing alternating Si and SiGe layers utilizing plasma. During a first deposition cycle 361A, an Si exposure phase 370A includes exposing a substrate to a silicon-containing precursor. The silicon-containing precursor may be provided in connection with a carrier gas. During Si exposure phase 370A, plasma is ignited using a source gas. During Si exposure phase 370A, an Si layer is deposited on the substrate. During a purge phase 375A, the flow of silicon-containing precursor to the process chamber is stopped. Additionally, the plasma is deactivated, and flow of source gas to generate the plasma is also stopped. The carrier gas may continue flowing to the process chamber. During a SiGe exposure phase 380A, the substrate is exposed to a silicon-containing precursor and a germanium-containing precursor. During SiGe exposure phase 380A, the plasma is ignited using the source gas. During SiGe exposure phase 380A, a SiGe layer is deposited, e.g., on top of the Si layer.

First deposition cycle 361A ends with a purge phase 385A where the plasma is on. It should be noted that, in some implementations, there may not be breaks between steps. In some such implementations, the silicon-containing precursor and the germanium-containing precursor may either be flowed into the chamber (e.g., “on”) or diverted (e.g., “off”). A second deposition cycle 361B is then performed, which includes a second Si exposure phase 370B, a subsequent purge phase 375B, a second SiGe exposure phase 380B, and a subsequent purge phase 385B. After second deposition cycle 361B, two sets of alternating layers of Si and SiGe have been deposited.

FIG. 3D provides a non-limiting process timing diagram 390 for depositing alternating Si and SiGe layers utilizing plasma. Here, instead of purging the chamber, a plasma is generated to eliminate sources of other non-Si elements (e.g., Ge) remaining in the chamber to ensure that the Si layer is not contaminated by remaining elements. For instance, during a first deposition cycle 391A, an Si exposure phase 371A includes exposing a substrate to a silicon-containing precursor. The silicon-containing precursor may be provided in connection with a carrier gas. During Si exposure phase 371A, plasma is ignited using a first source gas (source gas 1). During Si exposure phase 371A, an Si layer is deposited on the substrate. During a purge phase 395A, the flow of silicon-containing precursor to the process chamber is stopped. Additionally, the plasma is deactivated, and flow of first source gas to generate the plasma is also stopped. The carrier gas may optionally continue flowing to the process chamber.

During SiGe exposure phase 381A, the substrate is exposed to a silicon-containing precursor and a germanium-containing precursor. During SiGe exposure phase 381A, the plasma is ignited using the first source gas, and then a SiGe layer is deposited, e.g., on top of the Si layer. It should be noted that, in some implementations, there may not be breaks between steps. In some such implementations, the silicon-containing precursor and the germanium-containing precursor may either be flowed into the chamber (e.g., “on”) or diverted (e.g., “off”).

The first deposition cycle 391A ends with a removal phase 396A, which employs plasma (instead of or in addition to a purge phase) to remove any source of the second element (such as Ge) remaining in the chamber. For instance, removal phase 396A can be configured to eliminate any source of Ge within the chamber, so that it does not contaminate the pure Si layer. During removal phase 396A, the plasma is activated, and flow of a second source gas (source gas 2) is initiated to generate the plasma. Of course, if the first and second source gas is the same (e.g., source gas 1=source gas 2=H₂), then only one source gas can be used throughout the first deposition cycle 391A.

A second deposition cycle 391B is then performed, which includes a second Si exposure phase 371B, a second purge phase 395B, a second SiGe exposure phase 381B, and a second removal phase 396B. After second deposition cycle 391B, two sets of alternating layers of Si and SiGe have been deposited.

Between or within a deposition cycle, other operations may be performed. In one instance, the substrate can be exposed to a plasma (e.g., any described herein), thereby providing a prepared surface between the first and second semiconductor layers.

Such a prepared surface can be provided during deposition. In the example shown in FIG. 3E, a first precursor is utilized to deposit a first semiconductor layer, and a second precursor and an optional third precursor are utilized to deposit a second semiconductor layer. At 3010, a substrate is provided, for example, in a process chamber of a reactor. In some implementations, the reactor may be configured for performing plasma-based deposition operations. At 3020, the substrate is exposed to a first precursor. It should be noted that, during the time the substrate is exposed to the first precursor, the substrate may additionally be exposed to radicals (e.g., hydrogen-containing radicals, nitrogen-containing radicals, or the like), metastables (e.g., argon-containing metastables, helium-containing metastables, or the like), or other reaction-promoting stimulus, which interact with the precursor to deposit a first semiconductor layer on the substrate. It should be noted that, in some embodiments, a reactive plasma may contain substantially no components that react with silicon or with germanium or with both silicon and germanium. In one example, a reactive plasma may contain only hydrogen (e.g., H* or H₂), deuterium (e.g., D* or D₂), hydrogen deuteride (HD), an inert gas (e.g., He, Ar, He*, Ar*, etc.), or any combination thereof. In another example, a reactive plasma does not contain a nitrogen-containing species, a halogen-containing species, or an oxygen-containing species. In some implementations, the radicals, metastables, and the like may be generated using a plasma, which may be a remote plasma (e.g., upstream of the process chamber in which the substrate is residing) or in situ within the process chamber in which the substrate is residing. In other implementations, the radicals, metastables, and the like may be generated using other techniques (e.g., any described herein, such as a hot wire filament). In some embodiments, the first precursor may be flowed to the substrate without activation in a remote plasma source. As a result of 3020, a first semiconductor layer (e.g., an epitaxial semiconductor layer) is deposited on the substrate.

Optionally, at 3022, the process chamber is purged. Additionally or alternatively to purging the chamber, in some embodiments, a plasma may be generated, as seen in optional operation 3024. Purging or generating a plasma may eliminate sources of other elements (e.g., Ge) remaining in the chamber, such that the next layer to be deposited (e.g., the second semiconductor layer) is not contaminated by remaining elements. In some implementations, this may prepare a sharp interface between the first and second semiconductor layers.

In optional operation 3024, a plasma is generated to provide a prepared surface of the deposited first semiconductor layer. In one embodiment, the plasma may be generated for example, of hydrogen, argon, helium, or other radicals, metastables, or ions described herein. In some implementations, this may provide a smoothened surface for depositing the next layer (e.g., depositing a second semiconductor layer).

At 3030, the substrate is exposed to a second precursor and an optional third precursor. The second precursor utilized at 3030 may be the same or may be different than the first precursor utilized at 3020. Similar to what is described above with respect to block 3020, during the time the substrate is exposed to the second precursor and the optional third precursor, the substrate may additionally be exposed to radicals (e.g., hydrogen-containing radicals, nitrogen-containing radicals, or the like) or metastables (e.g., argon-containing metastables, helium-containing metastables, or the like), which interact with the precursors to deposit a second semiconductor layer on the substrate. In some embodiments, the radicals, metastables, and the like may be selected to be those that do not interact with atoms that are deposited within the first or second semiconductor layers. For example, in some embodiments, a reactive plasma may contain substantially no components that react with silicon or with germanium or with both silicon and germanium. In one example, a reactive plasma may contain only hydrogen (e.g., H* or H₂), deuterium (e.g., D* or D₂), hydrogen deuteride (HD), an inert gas (e.g., He, Ar, He*, Ar*, etc.), or any combination thereof. In another example, a reactive plasma does not contain a nitrogen-containing species, a halogen-containing species, or an oxygen-containing species. The radicals, metastables, and the like may be generated using a plasma (e.g., a remote plasma or an in situ plasma), or any other suitable technique (e.g., a hot wire filament, as described above). In some embodiments, the second precursor and the optional third precursor are flowed to the substrate without activation in a remote plasma source. As a result of 3030, a second semiconductor layer (e.g., an epitaxial semiconductor layer) is deposited on the substrate.

Optionally, at 3032, the chamber is purged. Additionally or alternatively to purging the chamber, in some embodiments, a plasma may be generated, for example, of hydrogen. This may eliminate sources of other elements (e.g., Ge) remaining in the chamber, such that the next layer to be deposited (e.g., a further first semiconductor layer) is not contaminated by remaining elements. In some implementations, this may prepare a sharp interface between the first and second semiconductor layers.

Optionally, at 3034, a plasma is generated to provide a prepared surface of the deposited second semiconductor layer. In one embodiment, the plasma may be generated for example, of hydrogen, argon, helium, or other radicals, metastables, or ions described herein. In some implementations, this may provide a smoothened surface for depositing the next layer (e.g., depositing a further first semiconductor layer).

At 3050, a determination of whether a film of adequate thickness has been deposited is made. The determination may be made based on whether a total thickness of layer exceeds a predetermined threshold, whether more than a predetermined number of alternating first and second semiconductor layers have been deposited, or any suitable combination thereof. If, at 3050, it is determined that film has not been deposited to adequate thickness (“no” at 3050), the process can loop back to 3020 and expose the substrate to a first precursor. In some implementations, blocks 3020-3050 are repeated n times. Conversely, if, at 3050, it is determined that the film has been deposited to adequate thickness (“yes” at 3050), the process ends.

FIG. 4A-C provides a non-limiting method in which a single precursor is used to deposit the first semiconductor layer and a single, different precursor is used to deposit the second semiconductor layer. In the example shown in FIG. 4A, the method 400 includes use of a first precursor to deposit a first semiconductor layer and a second precursor to deposit a second semiconductor layer. At 401, a substrate is provided, for example, in a process chamber of a reactor (e.g., optionally configured for performing plasma-based deposition operations). At 402, the substrate is exposed to a first precursor. It should be noted that, during the time the substrate is exposed to the first precursor, the substrate may additionally be exposed to energetic species (e.g., radicals, metastables, and the like), which interact with the precursor to deposit a semiconductor layer on the substrate. In some implementations, the energetic species (e.g., radicals, metastables, and the like) may be generated using a plasma or using other techniques (e.g., any described herein). As a result of 402, a first semiconductor layer (e.g., an epitaxial semiconductor layer) is deposited on the substrate. Optionally, at 402a, the process chamber is purged.

At 403, the substrate is exposed to a second precursor that is different than the first precursor. Similar to what is described above with respect to operation 402, during the time the substrate is exposed to the second precursor, the substrate may additionally be exposed to radicals, metastables, and the like, which interact with the precursors to deposit a second semiconductor layer on the substrate (e.g., and on a top surface of the first semiconductor substrate). The radicals, metastables, and the like may be generated using a plasma (e.g., a remote plasma or an in situ plasma), or any other suitable technique (e.g., a hot wire filament, as described above). As a result of 403, a second semiconductor layer (e.g., an epitaxial second layer) is deposited on the substrate. Optionally, at 403a, the chamber is purged.

At 404, a determination of whether a film of adequate thickness has been deposited is made. The determination may be made based on whether a total thickness of layer exceeds a predetermined threshold, whether more than a predetermined number of alternating first and second semiconductor layers have been deposited, or any suitable combination thereof. If, at 404, it is determined that film has not been deposited to adequate thickness (“no” at 404), the process can loop back to 402 and expose the substrate to the first precursor. In some implementations, blocks 402-404 are repeated n times. Conversely, if, at 404, it is determined that the film has been deposited to adequate thickness (“yes” at 404), the process ends.

FIG. 4B provides a non-limiting schematic for providing a stack having alternating Si and SiGe layers. In the example shown in FIG. 4B, a single precursor including both a silicon atom and a germanium atom (a silicon and germanium-containing precursor) is utilized to deposit a SiGe layer, unlike what is shown in and described above in connection with FIG. 3B describing use of two separate precursors (a silicon-containing precursor with a germanium-containing precursor). At 410, a substrate is provided, for example, in a process chamber of a reactor. In some implementations, the reactor may be a reactor configured for performing plasma-based deposition operations.

At 420, the substrate is exposed to a silicon-containing precursor. It should be noted that, during the time the substrate is exposed to the silicon-containing precursor, the substrate may additionally be exposed to energetic species (e.g., any described herein), radicals (e.g., hydrogen-containing radicals, nitrogen-containing radicals, or the like) or metastables (e.g., argon-containing metastables, helium-containing metastables, or the like), which interact with the precursor to deposit an Si layer on the substrate. In some implementations, the energetic species, radicals, metastables, or the like may be generated using a plasma, which may be a remote plasma (e.g., upstream of the process chamber in which the substrate is residing) or in situ within the process chamber in which the substrate is residing. It should be noted that, in some embodiments, a reactive plasma may contain substantially no components that react with silicon or with germanium or with both silicon and germanium. In one example, a reactive plasma may contain only hydrogen (e.g., H* or H₂), deuterium (e.g., D* or D₂), hydrogen deuteride (HD), an inert gas (e.g., He, Ar, He*, Ar*, etc.), or any combination thereof. In another example, a reactive plasma does not contain nitrogen-containing species, halogen-containing species, or oxygen-containing species. In other implementations, the energetic species, radicals, metastables, or the like may be generated using other techniques. For example, in some implementations, the energetic species, radicals, metastables, or the like may be generated using a hot wire filament (e.g., a tungsten filament) in which the high temperature of the filament is used to generate radicals, metastables, and the like from a gas (e.g., a hydrogen containing gas) flowed around the filament. As a result of 420, an Si layer (e.g., an epitaxial Si layer) is deposited on the substrate.

Optionally, at 425, the process chamber is purged.

At 430, the substrate is exposed to a silicon and germanium-containing precursor. Similar to what is described above with respect to block 420, during the time the substrate is exposed to the silicon- and germanium-containing precursor, the substrate may additionally be exposed to radicals (e.g., hydrogen-containing radicals, nitrogen-containing radicals, or the like) or metastables (e.g., argon-containing metastables, helium-containing metastables, or the like), which interact with the precursors to deposit a SiGe layer on the substrate. The radicals, metastables, and the like may be generated using a plasma (e.g., a remote plasma or an in situ plasma), or any other suitable technique (e.g., a hot wire filament, as described above). It should be noted that, in some embodiments, a reactive plasma may contain substantially no components that react with silicon or with germanium or with silicon and germanium. In one example, a reactive plasma may contain only hydrogen (e.g., H* or H₂), deuterium (e.g., D* or D₂), hydrogen deuteride (HD), an inert gas (e.g., He, Ar, He*, Ar*, etc.), or any combination thereof. In another example, a reactive plasma does not contain a nitrogen-containing species, a halogen-containing species, or an oxygen-containing species. As a result of 430, a SiGe layer (e.g., an epitaxial SiGe layer) is deposited on the substrate.

Optionally, at 435, the chamber is purged.

At 440, a determination of whether a film of adequate thickness has been deposited is made. The determination may be made based on whether a total thickness of layer exceeds a predetermined threshold, whether more than a predetermined number of alternating Si and SiGe layers have been deposited, or any suitable combination thereof. If, at 440, it is determined that film has not been deposited to adequate thickness (“no” at 440), the process can loop back to 420 and expose the substrate to the silicon-containing precursor. In some implementations, blocks 420-440 are repeated n times. Conversely, if, at 440, it is determined that the film has been deposited to adequate thickness (“yes” at 440), the process ends.

FIG. 4C provides a non-limiting process timing diagram 460 that corresponds to the method shown in FIG. 4B. During a first deposition cycle 461A, an Si exposure phase 470A includes exposing a substrate to a silicon-containing precursor. The silicon-containing precursor may be provided in connection with a carrier gas. During Si exposure phase 470A, plasma is activated using a source gas. During Si exposure phase 470A, an Si layer is deposited on the substrate. During a purge phase 475A, the flow of silicon-containing precursor to the process chamber is stopped. Additionally, the plasma is deactivated, and flow of source gas to generate the plasma is also stopped. The carrier gas may continue flowing to the process chamber. During a SiGe exposure phase 480A, the substrate is exposed to a silicon and germanium-containing precursor. During SiGe exposure phase 480A, the plasma is activated using the source gas. During SiGe exposure phase 480A, a SiGe layer is deposited, e.g., on top of the Si layer. First deposition cycle 461A ends with a purge phase 485A. A second deposition cycle 461B is then performed, which includes a second Si exposure phase 470B, a subsequent purge phase 475B, a second SiGe exposure phase 480B, and a subsequent purge phase 485B. After second deposition cycle 461B, two sets of alternating layers of Si and SiGe have been deposited.

### Growth of Epitaxial Layers

The structures herein (e.g., a film, stack, and the like) can include one or more layers, which can have any useful characteristic. For instance, a vertical stack herein can include at least one Si layer and at least one SiGe layer. Each layer can be characterized as possessing one or more various structural features.

In some non-limiting embodiments, the layer is characterized as being an epitaxial layer. As used herein, the terms “single crystal,” “crystalline,” and “epitaxial” are used to describe a predominantly large crystal structure that may have a tolerable number of faults therein. The crystallinity of a layer generally falls along a continuum from amorphous to polycrystalline to single crystal, and therefore a crystal structure is often considered single crystal or epitaxial notwithstanding a low density of faults. The term “epitaxy” refers to a type of growth or deposition in which a newly deposited, overlying crystalline layer is formed with one or more well-defined orientations, as compared to the underlying crystalline substrate or the underlying crystalline layer. “Homoepitaxy” refers to epitaxy, in which the material of the overlying layer and the underlying layer are the same. A “homoepitaxial layer” refers to a layer formed by homoepitaxy, as described herein. “Heteroepitaxy” refers to epitaxy, in which the material of the overlying layer and the underlying layer are different. A “heteroepitaxial layer” refers to a layer formed by heteroepitaxy, as described herein.

An epitaxial layer can be further characterized as being strained. In general, differing materials will possess differing lattice constants. Typically, at an interface between materials having differing lattice parameters, misfit dislocations (or defects) can be observed. However, under certain conditions, any misfit dislocations that could exist at the interface between the underlying and overlying layers can be accommodated by elastic strain. For instance, under pseudomorphic (or atypical form) growth conditions, a newly deposited, overlying layer can adopt the lateral lattice constant of the underlying layer, rather than adopting an inherent lattice constant that is characteristic of a bulk film composed of that material.

Thus, in one non-limiting instance, the layer can be characterized as being a strained layer, in which the lattice structure within the strained layer is different than the inherent lattice constant of the material. Such lattice strain can be imposed by epitaxial deposition of a material over another structure having a different lattice structure, such that the deposited layer possesses the lattice structure of the underlying structure. The degree of lattice strain that can be accommodated within a deposited layer can be associated with various factors, including the thickness of the deposited layer, the degree of lattice mismatch between the deposited material and the underlying structure, and other factors. As used herein, a “lattice mismatch” refers to a mismatch in the crystalline lattice, as compared between two structures. In certain non-limiting embodiments, lattice strain within a heterolayer is in general a desirable attribute for active device layers, since it tends to increase the mobility of electrical carriers and thus increase device speed.

Such epitaxial layers can be optimized to reduce defects within the crystal structure. In one non-limiting instance, relaxation of a strained layer can be accompanied by defect propagation, which in turn can hinder device operation. Thus, a deposited epitaxial layer can be exposed to conditions that will minimize relaxation of the deposited layer.

In one non-limiting instance, every layer within the stack includes an epitaxial layer. In certain embodiments, a structure having such layers can be considered a strained semiconductor structure.

In another non-limiting instance, the thickness of the layer is controlled to minimize defects. For example, as the thickness of a strained layer increases beyond a “critical thickness” or h_{c}, defects within the crystal structure of the strained layer appear. As growth extends beyond this critical thickness, the increasing strain can no longer be accommodated by lattice mismatches, and thus, misfit dislocations are generated. The critical thickness depends on a variety of factors, including growth rates, growth temperatures, composition of the layer (e.g., Si concentration, Ge concentration, or both Si and Gi concentration), the number of defects within the underlying layer, and the like.

As used herein, the term “silicon germanium” and “Si₁₋ₓGeₓ” and “SiGe” may refer to an alloy of silicon and germanium, wherein the ratio of germanium to silicon may range as 1≥x>0. Non-limiting values for x include from about 0.01 to 0.6, about 0.05 to 0.6, or about 0.1 to 0.5. When deposited onto a single crystal Si substrate or layer, greater amounts of germanium generally increase the amount of strain. Generally, the higher the Ge content within a layer (even a pure Ge layer), the greater the lattice mismatch with an underlying Si layer. For example, a pure Ge layer has a 4.18% greater lattice constant, as compared to a pure Si layer. Upon increasing the thickness of a layer beyond its critical thickness h_{c}, that layer will relax to its inherent lattice constant. Generally, such relaxation will result in misfit dislocations and others defects at film interfaces or within the film. The critical thickness depends upon temperature (the higher the temperature, the lower the critical thickness) and lattice mismatch due to germanium content (the higher the concentration of Ge within the layer, the lower the critical thickness). For example, a SiGe layer containing about 10 atomic % (at. %) germanium has a critical thickness of about 300 Å when deposited at about 700° C. for an equilibrium (stable) strained film and about 2,000 Å for a metastable, strained film on Si<100>. If it is desirable to maintain the strain, the thickness is kept below the critical thickness and a cap layer is often applied to the strained heteroepitaxial layer to maintain the (metastable) strain of the SiGe layer during subsequent processing steps.

In certain instances, the stack includes Si layer and SiGe layers, and the SiGe layers are then etched away with further processing. With this processing in mind, as lower concentrations of Ge within the SiGe layer, selective etching of the SiGe layer (as compared to the Si layer) becomes more difficult. Thus, in some instances, the SiGe layer includes an effective concentration of Ge between about 2 at. % to 30 at. %. To achieve such SiGe layers having a thickness that is lower than h_{c}, two approaches can be pursued. First, a lower Ge content can be employed, at the risk of reducing etch selectivity. Second, a lower deposition temperature can be employed, as lower temperatures provide a higher h_{c}. For example, for a SiGe layer having a Ge content of less than 27 at. %, the lattice mismatch is less than 1%; and the h_{c} is about 10-100 nm for a SiGe layer having a Ge content of about 15-27 at. %. In particular embodiments, the stack includes an Si layer having a thickness of about 10 to 100 nm; or an SiGe layer having a thickness of about 5 to 50 nm.

Various strategies may be implemented for growth of low strain epitaxial layers. For instance, such conditions can facilitate growth of layers under low enough strain to prevent defects within the epitaxial layers including Si or SiGe. Low strain growth can include growth under a pseudomorphic mode, which can be characterized as having no corrugation and elastic strain that is accommodated by lattice mismatches within films. Such modes can be employed for layers having small misfit dislocations and for thin films (e.g., having a thickness that is less than h_{c}). In some embodiments, defects can be characterized as having less than about 10⁷ dislocations per cm.

Other strategies may be implemented for growth of uniform epitaxial layers. For instance, such conditions can include those to provide a layer having a uniform thickness (e.g., having a variation that is less than about 2%). One example can include rotation of wafers during deposition, in which rotation of susceptors can reduce or eliminate azimuthal non-uniformity. Another example may include optimization of the showerhead hole (or aperture) pattern to enable fluid flux uniformity on the wafer surface. For instance, the showerhead can include a plurality of apertures arranged in a non-uniform pattern (e.g., a pattern that includes an increased number of apertures as a function of radius). Yet another approach may be to use multi-zone pedestal heating to ensure thermal uniformity of the wafer. In another instance, such conditions can include those to provide a film having a uniform concentration of Ge within a layer. Further approaches, apparatuses, systems, conditions, reagents, methods, and processes are described in U.S. Pat. No. 11,127,567, filed May 4, 2020, entitled “Systems and methods for suppressing parasitic plasma and reducing within-wafer non-uniformity,” U.S. Pat. No. 11,111,581, filed May 13, 2019, entitled “Suppression of parasitic deposition in a substrate processing system by suppressing precursor flow and plasma outside of substrate region”; U.S. Pat. No. 10,984,987, filed Oct. 10, 2018, entitled “Showerhead faceplate having flow apertures configured for hollow cathode discharge suppression”; U.S. Pat. No. 10,358,722, filed Dec. 14, 2015, entitled “Showerhead assembly”; which are herein incorporated by reference in their entireties.

Other operations are described herein to facilitate growth of heterolayers. In one embodiment, a preclean operation can be used to provide a clean substrate, such as by removing oxide, carbon, metal, or other matter. Non-limiting substrates can include monocrystalline substrates, silicon substrates, silicon-on-insulator (SOI) substrates, and the like. In another embodiment, a pretreat operation can be used to passivate a surface used for growing heterolayers. Other optional operations can include coplanarization (e.g., chemical mechanical polishing (CMP)), degassing of chambers used to house a substrate, and the like.

Another operation can include a deposition operation to provide distinct heterolayers (e.g., by use of a low temperature condition). In certain embodiments, deposition can include the use of plasma (e.g., remote plasma, capacitively coupled plasma (CCP), inductively coupled plasma (ICP), transformer coupled plasma (TCP), microwave plasma (MWP), low energy plasma (LEP), low temperature plasma (LTP), etc.) in the presence of various reactants (e.g., hydrogen-containing, deuterium-containing, ammonia-containing, deuterated ammonia-containing, or argon-containing reactants). During deposition, plasma species may be transported through an ion filter prior to delivery to the substrate. Optionally, such ion filters may be employed within the showerhead.

During a deposition operation, low temperature epitaxy (with or without plasma) may be employed. In one instance, low temperature epitaxy is performed at a temperature that is less than about 700° C. or less than about 650° C. or less than about 600° C. In certain embodiments, epitaxy is performed at a temperature of about 350° C. to 550° C., about 350° C. to 600° C., about 350° C. to 650° C., about 200° C. to 600° C., about 200° C. to 650° C., about 450° C. to 600° C., or about 450° C. to 650° C. Thermal control during deposition can include the use of any useful heater sources, such as use of IR lamps for radiative heating, use of LEDs, use of frontside or backside heating, use of wafer holders to enable thermal uniformity and act as heat sink, and the like.

In other embodiments, epitaxy is performed at a lower pressure. In particular embodiments, epitaxy is performed at a pressure of about 20 Torr or less.

Yet another operation can include a reactor clean operation, which can be used to clean a chamber or to passivate an internal surface of a chamber configured to house a substrate (e.g., during preclean, pretreat, or deposition operations). Cleaning of the chamber can include the use of various reactants or plasma to remove contaminants from an inner surface of the chamber. Passivation of the chamber can include the use of various reactants or plasma to remove residual fluorine (or other halogens) from the chamber.

### Properties and Characteristics of Stacks

The vertical stack can include alternating first layers and second layers. The first layer can include a first material, and the second layer can include a second material that is different than the first. Within the vertical stack, a plurality of layers can be present. In one instance, the number of layers within the stack includes 10 layers, 20 layers, 30 layers, or more.

The stack can have any useful height, such as about 1 to 10 μm, or more. Each layer within the stack can have any useful thickness (or height), and the thickness of each layer can the same or different as other layers. For example, each layer within the stack can have a thickness within the range of about 5 nm to 30 nm, but the first layers and second layers within the stack can have repeating or non-repeating thicknesses within that range that avoids defects or minimizes strain. In some embodiments, the semiconductor layer has a thickness of about 20 nm to 40 nm. In other embodiments, the sacrificial layer has a thickness of about 8 nm to 12 nm.

In one instance, the first layer includes a semiconductor layer. The semiconductor layer can include any useful material, such as a Group IV material, e.g., silicon (Si), germanium (Ge), tin (Sn), carbon (C), as well as alloys or combinations thereof; a Group III-V material, e.g., gallium arsenide (GaAs), indium phosphide (InP), indium arsenide (InAs), indium antimonide (InSb), gallium phosphide (GaP), aluminum phosphide (AlP), gallium nitride (GaN), aluminum nitride (AlN), aluminum gallium nitride (AlGaN), indium aluminum arsenide (InAlAs), indium gallium antimonide (InGaSb), and the like; and other hole mobility or electron mobility materials.

In another instance, the second layer includes a sacrificial layer. The sacrificial layer can include any useful material, such as a Group IV material, e.g., Si, Ge, or Sn; a Group IV-IV material, e.g., silicon germanium (SiGe), a tin germanium (SnGe), and the like.

The selection of materials for the first and second layers can depend on etch selectivity between the first and second materials. For example, taking a stack including alternating Si layers and SiGe layers, the etch conditions can be selected to remove either the Si layers or the SiGe layers. In one non-limiting embodiment, hydrogen plasma under certain conditions can be used to etch Si over SiGe. In other non-limiting embodiments, hydrogen chloride vapor can be used to etch SiGe over Si. Other etchant chemistries and conditions (e.g., any described herein) can be optimized to selectively etch Si or SiGe layers.

The interface between the first and second layers can have any useful characteristic. In some embodiments, an interfacial layer is present between the first and second semiconductor layers. Such an interfacial layer can be configured to reduce or prevent diffusion of atoms between the first and second layers. The interfacial layer can include any material described herein, such as a Group IV material, a Group IV-IV material (e.g., SiGe or other materials including two different Group IV atoms), or a doped version thereof (e.g., having one or more Group III or Group IV or Group V atoms). In some embodiments, a doped interfacial layer is employed, and a concentration of a dopant atom (e.g., one or more Group III or Group IV or Group V atoms) can vary within the doped interfacial layer. In one embodiment, the concentration of the dopant atom is increased in proximity to the first layer or the second layer.

In other embodiments, a transition region exists between the first and second layers, in which the concentration of an atom can vary within this transition region. In another embodiment, the first and second layers, taken together, forms a graded film. Within the transition region, the concentration of Si₁₋ₓGeₓ can vary from x=0 to x=0.5, as well as ranges therebetween. In other embodiments, the transition region has a thickness of less than about 2 nm, less than about 1 nm, or less than about 0.5 nm.

In one embodiment, the interface between the first and second layers can be treated. In one instance, the substrate can be exposed to a plasma (e.g., any described herein), thereby providing a prepared surface between the first and second semiconductor layers. The prepared surface can provide a smoothened surface for depositing the next layer.

As described herein, the stack can include heterolayers, which in turn can include alternating first layers and second layers. The content of a specific atom within the stack can be understood as an intralayer concentration within a specific layer or as an effective concentration (or averaged concentration) within the entire stack. For an intralayer concentration, an average concentration of a specific atom can be determined within each layer or within at least one layer. For an effective stack concentration, a range of concentrations of a specific atom can be determined within all the layers within the stack, and the average concentration within that range can be determined.

The intralayer concentration and the effective stack concentration can be determined within a Si—SiGe stack, which can include alternating Si layers and SiGe layers. In one embodiment, the intralayer concentration of Ge can be from about 5 at. % to 40 at. % within each SiGe layer or at least one SiGe layer. In other embodiments, the intralayer concentration is from about 10 at. % to 30 at. %; 15 at. % to 25 at. %; or 15 at. % to 40 at. %.

An effective stack concentration of Ge within those alternating layers would account for Ge that is present in SiGe layer and present within SiGe layers. In one embodiment, the effective stack concentration of Ge can be from about 1.25 at. % to 15 at. %. In other embodiments, the effective stack concentration of Ge is from about 1.25 at. % to 10 at. %, about 2 at. % to 10 at. %, or about 4 at. % to 8 at. %. If interfacial layers are present (e.g., between the Si layer and the SiGe layer), then an effective stack concentration may be decreased if that interfacial layer does not include Ge. The interlayer concentration and the effective stack concentration may be an averaged or normalized value, which need not necessarily account for concentration gradients or concentration profiles within the layer or within the stack.

In particular non-limiting embodiments, the stack can be formed from precursors, reagents, reactants, carrier gases, and inert gases, in which halogen is avoided during deposition. The presence of halogen or halogen-containing reactants can be employed during other operation(s) that occur before or after deposition (e.g., other operations can include a preclean operation to remove oxide from the substrate, a pretreat operation to passivate the surface of the substrate, a reactor clean operation to clean a surface within the reactor chamber, or a reactor pretreat operation to remove halogen from within the reactor chamber).

The stack can include further structural features that can be provided after depositing the vertical stack. For example, the vertical stack can include a capping layer to protect the deposited stack. In another example, the vertical stack can include a hardmask to facilitate further patterning or processing of the deposited stack.

In some embodiments, a first oxygen concentration measured from the substrate is comparable to a second oxygen concentration of at least one of a first semiconductor layer or a second semiconductor layer. In other embodiments, a first oxygen concentration measured from the substrate is substantially similar to a second oxygen concentration of at least one of a first semiconductor layer or a second semiconductor layer. In one instance, a value of the first oxygen concentration is from about 80% to 120%, 90% to 110%, or 95%-105% of a value of the second oxygen concentration. If the second oxygen concentration is greater than the first oxygen concentration, then the surface (e.g., of the substrate, the first semiconductor layer, or the second semiconductor layer) can be treated with a preclean operation (e.g., any described herein).

### Selective Etch of Sacrificial Layers

After depositing the stack, further processes can be employed to release certain layers. In one instance, selective etch conditions can be employed to etch away the sacrificial layer, while maintaining the semiconductor layer. Such etch conditions can include dry process, wet processes, or a combination of wet and dry processes to selectively remove sacrificial layers after depositing the stack.

In one instance, vapor HCl is employed to selectively etch away the SiGe layer, as compared to the Si layer. In particular, etch selectively depends on the concentration of Ge within the SiGe layer and the etch temperature. Typically, etch selectivity increases as the concentration of Ge increases, and etch selectivity decreases as etch temperature increases. Thus, in some instances, the concentration of Ge within the SiGe layer can be selected to enhance selective etching of SiGe within the stack. Non-limiting concentrations of Ge within the SiGe layer can include about 2% to 60%, about 2% to 50%, about 2% to 40%, about 2% to 30%, about 2% to 20%, about 3% to 60%, about 3% to 50%, about 3% to 40%, about 3% to 30%, about 3% to 20%, about 4% to 60%, about 4% to 50%, about 4% to 40%, about 4% to 30%, about 4% to 20%, about 5% to 60%, about 5% to 50%, about 5% to 40%, about 5% to 30%, about 5% to 20%, about 6% to 60%, about 6% to 50%, about 6% to 40%, about 6% to 30%, about 6% to 20%, about 8% to 60%, about 8% to 50%, about 8% to 40%, about 8% to 30%, about 8% to 20%, about 9% to 60%, about 9% to 50%, about 9% to 40%, about 9% to 30%, about 9% to 20%, about 10% to 60%, about 10% to 50%, about 10% to 40%, about 10% to 30%, about 10% to 20%, about 15%, about 25%, about 30%, or less than about 20%, where percentage values refer to atomic percentages.

While a higher Ge concentration can enhance selective etching, it may result in increased diffusion of Ge within the stack. Thus, in one instance, to minimize diffusion of Ge during deposition, a lower deposition temperature may be employed to maintain top-to-bottom uniformity within the stack.

In some embodiments, SiGe is selectively etched, as compared to Si. In one instance, the etch rate of SiGe is higher than the etch rate of Si. In particular embodiments, the ratio of the etch rate of SiGe to the etch rate of Si is more than about 2:1, 5:1, 10:1, 25:1, 20:1, or 100:1. Such a ratio can be indicative of etch selectively of SiGe over Si.

In another to acidic vapors, other etchant chemistries can be employed. In one instance, etching can include use of a solution composed of hydrogen peroxide and acetic acid (CH₃CO₂H); a solution composed of an acid (e.g., HF), hydrogen peroxide, and acetic acid; a solution including an etch reagent (e.g., an acid, such as HF or HCl) and at least one oxidant (e.g., H₂O₂, HNO₃, or peracetic acid (CH₃CO₃H)); a plasma condition including a fluorocarbon source (e.g., CF₄ or C₄F₈), which can optionally include nitrogen gas (N₂), helium gas (He), or a combination of N₂ and He; a plasma condition including a fluorine source (e.g., F₂ or NF₃), which can optionally include nitrogen gas (N₂), helium gas (He), or a combination of N₂ and He; a dry process condition with an acid (e.g., HCl) and hydrogen gas (H₂); and the like.

Within the vertical stack, a semiconductor layer (e.g., a sacrificial layer) can be removed, and the resulting void can be filled with an insulator or a dielectric. Non-limiting insulator or dielectric materials can include silicon nitride, silicon oxide, silicon oxynitride, silicon carbide, silicon oxycarbide, silicon carbonitride, oxynitrides, oxycarbides, carbonitrides, or a doped form thereof (e.g., silicon carbide doped with oxygen, nitrogen, or both oxygen and nitrogen). As used herein, it is understood that silicon oxide materials, silicon nitride materials, etc. include both stoichiometric and non-stoichiometric versions of such materials, and that such materials may have other elements included, as described herein. Further, as the remaining semiconductor layer within the stack can serve as a channel or a channel layer, the insulator or dielectric material can serve to isolate the channel(s).

### Preclean Operations

Defects (e.g., stacking faults, microtwins, inversion boundaries, and the like) within a deposited layer can be minimized by proper precleaning and pretreating the substrate. In one instance, defect control can be facilitated by using a pristine, oxide-free surface. Providing such a surface can include one or more preclean operations to remove oxide, carbon, metal, or other contaminants from a surface of the substrate.

Preclean operations can include any suitable cleaning process, such as plasma-based oxide etch processes, dry etch processes, wet etch processes, sputter etch processes, and combinations thereof.

Preclean operations can include wet processes, dry processes, or a combination of wet and dry processes to clean the substrate prior to deposition. For example, the preclean operation can include only dry processes, a combination of wet processes followed by dry processes, or a combination of dry processes followed by wet processes. In one instance, the preclean operation includes the use of a halogen-containing reagent or other reagents in vapor form (e.g., as a halogen-containing vapor or a halogen-containing gas). In another instance, the preclean operation includes use of a halogen-containing reagent or other reagents in liquid form. Indeed, any reagent herein can be provided herein in vapor form or liquid form.

In yet another instance, the preclean operation includes the use of a reducing gas or reducing gas plasma. Examples of reducing gas plasmas can include hydrogen plasma. In a further instance, the preclean operation includes the use of hydrides (e.g., any described herein). Examples of hydrides include a silane (e.g., SiH₄, Si₂H₆, or others described herein), a germane (e.g., GeH₄ or others described herein), and the like. Such hydrides may possess the ability to remove trace oxide.

Such halogen-containing reagents can include a fluorine-containing reagent, such as hydrofluoric acid (HF), nitrogen trifluoride (NF₃), chlorine trifluoride (ClF₃), diatomic fluorine (F₂), monatomic fluorine (F*), ammonium fluoride (NH₄F), ammonium bifluoride (NH₄F:HF), and fluorine-substituted hydrocarbons, which can be in liquid or gas form. In use, fluorine reacts with silicon oxide (SiO₂) to provide a silicon- and fluorine- containing species that can be desorbed from the surface of the substrate. In one instance, wet HF (e.g., aqueous HF or buffered HF) or a dilute HF dip is employed during the preclean operation. In another instance, HF vapor is employed. In any examples, plasma may be used during the preclean process, as will be described below. Further reagents and conditions can include those described in U.S. Patent Publication No. 2010/0184301, entitled “Methods for preventing precipitation of etch byproducts during an etch process and/or subsequent rinse process,” and U.S. Pat. No. 8,058,179, entitled “Atomic layer removal process with higher etch amount,” each which is incorporated herein by reference in its entirety.

In some non-limiting instances, halogen-containing reagents may be directly introduced into the chamber, instead of being formed from ammonia and hydrogen fluoride, or other reactants, e.g., ammonia (NH₃), hydrogen fluoride (HF), hydrogen (H₂), nitrogen trifluoride (NF₃), nitrogen (N₂), and water vapor (H₂O). In certain embodiments, atomic hydrogen, atomic fluorine, atomic nitrogen, or combinations thereof may be generated ex situ and introduced into the chamber. For example, a nitrogen plasma generated remotely may be introduced into the chamber.

Yet other halogen-containing reagents can include a chlorine-containing reagent, such as hydrochloric acid (HCl), chlorine trifluoride (ClF₃), diatomic chlorine (Cl₂), monatomic chlorine, and chlorine-substituted hydrocarbons, which can be in liquid or gas form. In particular embodiments, a chlorine-containing reagent can be used in combination with a fluorine-containing reagent (e.g., HCl with HF).

The halogen-containing reagent can be used in combination with a hydrogen-containing reagent, which can be in liquid or gas form. Examples of such reagents include atomic hydrogen, molecular hydrogen, ammonia, a hydrocarbon, and an incompletely halogen-substituted hydrocarbon (e.g., having at least one hydrogen atom within the hydrocarbon that is not substituted with a halogen atom).

Herein, any hydrogen-containing reagent can be adapted or exchanged to provide a deuterium-containing reagent, which can be in liquid or gas form. Without wishing to be limited by mechanism, one benefit of deuterium is that Si—D bonds are more stable than Si—H bonds. Thus, in some instances, the presence of such Si—D bonds may provide a more stable surface if deuterium-containing reagents (including deuterium-containing gases, such as, e.g., HD or D₂) are employed during a preclean operation.

The halogen-containing reagent can used in combination with a solvent (in liquid or vapor form), as well as with an optional additive. The solvent can include a polar solvent, such as water, isopropyl alcohol (IPA), ethanol, or methanol. The additive can include a base, such as pyridine. In one non-limiting embodiment, the preclean operation includes the use of a fluorine-containing reagent (e.g., HF), a solvent (e.g., IPA), and a heterocycle (e.g., pyridine).

The halogen-containing reagent can be used in combination with a base. Examples of bases include amino-containing reagents, such as ammonia (NH₃); hydrazine (N₂H₄); aliphatic amines, such as primary amines (e.g., methylamine and ethylamine), secondary amines (e.g., dimethylamine and diethylamine), and tertiary amines (e.g., trimethylamine and triethylamine); aromatic amines, such as aniline and methylaniline; alicyclic amines, such as cyclohexylamine and dicyclohexylamine; heterocyclic amines, such as pyrrole, pyrrolidine, pyrrolidone, pyridine, morpholine, pyrazine, piperidine, N-hydroxyethylpiperidine, oxazole, and thiazole.

The halogen-containing reagent can be a fluorine-containing reagent (e.g., HF) that is employed with an amino-containing reagent (e.g., ammonia (NH₃)). In some embodiments, when the fluorine-containing reagent and the amino-containing reagent are combined, a salt of the amino-containing reagent may be formed, such as, e.g., an ammonium salt (e.g., NH₄⁺ salt) or an ammonium fluoride salt (e.g., NH₄⁺F⁻). In other embodiments, the fluorine-containing reagent (e.g., HF) is employed with two nitrogen-containing reagents (e.g., NF₃ and NH₃). In particular embodiments, the reagents are employed as a dry process employing vapor. Further reagents and conditions can include those described in U.S. Patent Publication No. 2010/0184301, entitled “Methods for preventing precipitation of etch byproducts during an etch process and/or subsequent rinse process,” and U.S. Pat. No. 8,058,179, entitled “Atomic layer removal process with higher etch amount,” each which is incorporated herein by reference in its entirety.

The halogen-containing reagent can be used with a carrier gas. Non-limiting carrier gases include hydrogen gas (H₂), helium (He), argon (Ar), nitrogen gas (N₂), and the like. In addition to the carrier gas, other gases or vapors can be present, such as water vapor or alcohol vapor. In one instance, the halogen-containing reagent can be provided with the carrier gas and other optional gases at any useful temperature (e.g., from about 30° C. to 60° C.) and any useful pressure (e.g., from about 100 Torr to 300 Torr).

The preclean operation can be performed at any useful temperature. In one embodiment, the temperature is above about 50° C.

The preclean operation can include multiple steps, in which at least one step employs a halogen-containing reagent and at least one step does not employ such a reagent. The order of the steps can be in any useful order, e.g., an initial step that lacks a halogen-containing reagent and a later step that employs such a reagent; or an initial step that includes a halogen-containing reagent and a later step that lacks such a reagent.

Multiple step processes can include any preclean conditions described herein (e.g., two, three, four, or more) and in any useful order. In one instance, one of the conditions can include using a mixture of an oxidizing reagent and an amino- or ammonium-containing reagent. For example, such a mixture can include a peroxide (e.g., hydrogen peroxide, H₂O₂) and an ammonium-containing reagent (e.g., ammonium hydroxide, NH₄OH), which can used to remove silicon, oxide, quartz, particles, and chemical impurities. The other condition can include using a mixture of a halogen-containing reagent and an oxidizing reagent. In one instance, the mixture can include a chlorine-containing reagent (e.g., HCl) and a peroxide (e.g., H₂O₂) to remove metals or ionic, or alkali contaminants. Any of these mixtures can include a solvent (e.g., a polar solvent, such as water or an alcohol). Yet another condition can include the use of a dilute dip including a halogen-containing acid (e.g., HF or HCl, which can be diluted with a solvent, such as water) or a vapor treatment including a halogen-containing acid (e.g., HF or HCl).

Furthermore, any of the preclean conditions herein can be repeated in cycles. In one instance, a cycle can include operations of etching the substrate (e.g., thereby producing Si- and halogen-containing species as by-products) and removing such by-products. The operation of etching the substrate can be the same or different between cycles. Furthermore, the cycle can be repeated any number of times. In one instance, the cycle is performed one, two, three, or more times. In another instance, each cycle removes about 10% to 40% of the total thickness of the substrate. In yet another instance, each cycles removes about 150 Å or less from the substrate.

The preclean operation can include the use of plasma (e.g., remote plasma, pulsed plasma, ICP, CCP, MWP, LEP, LTP, and the like) with a halogen-containing reagent, such as a chlorine-containing reagent or a fluorine-containing reagent. Exemplary chemistries may include, for example, a chlorine- or fluorine-based plasma etchant, such as fluorine-substituted hydrocarbons (e.g., CF₄ or CHF₃), chlorine-substituted hydrocarbons (e.g., CCl₄ or CHCl₃), HF, HCl, NF₃, sulfur hexafluoride (SF₆), silicon tetrafluoride (SiF₄), diatomic fluorine (F₂), monatomic fluorine, diatomic chlorine (Cl₂), monatomic chlorine, and the like; or, for example, a nitrogen-based plasma etchant, such as NH₃, NF₃, and the like. In some embodiments, the halogen-containing reagent is employed in combination with a hydrogen-containing reagent (e.g., to provide a hydrogen radical, H*) in the presence of plasma. In other embodiments, the halogen-containing reagent (e.g., NF₃) is employed in combination with an amino-containing reagent (e.g., NH₃) in the presence of plasma. In yet other embodiments, any of the chemistries herein can be used in the presence of plasma. Plasma can be employed with a carrier gas or an inert gas, such as any described herein (e.g., H₂, He, Ar, N₂, and the like).

In one instance, a fluorine-containing reagent (e.g., NF₃) is employed with a hydrogen radical to generate an intermediate species (e.g., NHₓF_{y}) that reacts with silicon oxide to generate a by-product (e.g., (NH₄)₂SiF₆) that can be pyrolyzed (e.g., at a temperature of about 100° C. or more) or sublimated (e.g., at a temperature of about 100° C. or more). The pyrolysis products (e.g., HF or SiF4), in turn, can be evaporated with a further bake step. In other instances, a fluorine-containing reagent (e.g., NF₃) is employed with a helium gas to produce a plasma. Further reagents and conditions can include those described in U.S. Patent Publication No. 2010/0184301, entitled “Methods for preventing precipitation of etch byproducts during an etch process and/or subsequent rinse process,” and U.S. Pat. No. 8,058,179, entitled “Atomic layer removal process with higher etch amount,” each which is incorporated herein by reference in its entirety.

Plasma may be employed, independent of halogen-containing reactants, to remove carbon, oxygen, or other contaminants from the substrate. For example, a preclean operation can include initially exposing the substrate to a halogen-containing reactant and then exposing the substrate to plasma.

Any plasma mode or configuration can be employed, such as any described herein, including electron cyclotron resonance (ECR) hydrogen plasma, RF plasma, or remote plasma. In some embodiments, plasma is employed at a temperature of about 20° C. to 500° C.; a pressure range of about 5 mTorr to 200 mTorr; or an RF power in the range of about 50 W to 1000 W, as well as combinations of any of these conditions. Other temperature and pressure ranges are described herein. Any useful plasma stripping and ashing conditions can be implemented. In one instance, an Ar-based plasma etch can be employed (e.g., at a pressure of about 5 mTorr to 20 mTorr, a source power of about 1000 W, and a bias power of 200 W).

In addition to plasma, other energy sources can used alone or in combination with a halogen-containing reagent. For instance, ultraviolet (UV) or deep ultraviolet (DUV) or extreme ultraviolet (EUV) radiation can be employed, e.g., to generate radicals, metastables, and the like. In one instance, UV and ozone can be employed to remove organic contaminants. In another instance, UV and a halogen-containing reagent (e.g., chlorine gas, Cl₂) to remove metal contaminants. In yet another instance, etching can include use of UV with NF₃ and H₂, which can be optionally followed by Ar-based etching.

Etch processes, including plasma-based etch processes, generally produce by-products (e.g., vaporized by-products), which can then be removed. The by-products can be removed via sublimation (e.g., raising the temperature of the substrate to about 300° C. or more). The by-products can optionally be pyrolyzed (e.g., raising the temperature of the substrate to about 100° C. or more), and then the pyrolyzed by-products can then be removed. The plasma etch process results in a substrate surface having silicon-hydrogen (Si—H) bonds.

After a preclean operation, further operation can be performed to provide an oxide-free substrate. For instance, a bake step or an annealing step can be performed to reduce moisture from the surface of the substrate or to sublimate reactive by-products, thereby providing a contaminant-free surface. In another instance, increasing the temperature of the cleaned substrate can suppress oxidation of the surface, especially in the presence of a non-oxidizing ambient (e.g., in an environment with N₂ or Ar).

A non-limiting bake step can include use of a temperature of more than about 800° C., such as from about 800° C. to 950° C.; or a temperature more than about 100° C. Optionally, the bake step can be performed in the presence of H₂ gas. In some examples, the preclean operation includes dipping the substrate in diluted HF followed by baking or annealing.

Another non-limiting bake step can include use of a temperature of about 350° C. at a pressure of less than 1 Torr to suppress oxide formation, and then heating to a temperature of about 350° C. to 530° C. in presence of precursor (e.g., a Si-containing precursor). Without wishing to be limited by mechanism, such a process can promote Si—Si bond formation, rather than Si—O bond formation, in which O can be provided from residual water vapor (H₂O) or oxygen (O₂) present in the ambient.

Any useful process can be employed to remove oxide, contaminants, or other undesired components from a surface of a substrate without significantly damaging the substrate. The substrate can include a monocrystalline surface or a non-monocrystalline surface (e.g., polycrystalline or amorphous surfaces). Non-limiting monocrystalline surfaces may include the bare crystalline substrate or a deposited single crystal layer usually made from a material such as silicon, germanium, silicon germanium, or silicon carbon. Polycrystalline or amorphous surfaces may include dielectric materials, such as oxides or nitrides, specifically silicon oxide or silicon nitride, as well as amorphous silicon surfaces.

### Example of Vapor-Based Preclean Operations

In various embodiments herein, a semiconductor substrate is precleaned (or etched) using a mixture of vapor phase reactants that include (1) a halogen source such as hydrogen fluoride; (2) an organic solvent, water, or a combination thereof; (3) an additive; and (4) a carrier gas. In other embodiments, the mixture of vapor phase reactants include (1) a halogen source such as hydrogen fluoride, (3) an additive, and (4) a carrier gas. In yet other embodiments, the mixture of vapor phase reactants include (1) a halogen source such as hydrogen fluoride; (2) an organic solvent, water, or a combination thereof; and (3) an additive. As used herein, the terms “vapor phase” and “gas phase” are used interchangeably in this disclosure.

The additive may have particular properties or a particular composition, as described further below. In some non-limiting embodiments, the additive serves as a catalyst, which generally serves the purposes of accelerating the reaction rate or enhancing the reaction selectivity. Examples of additives include a heterocycle compound, a heterocyclic aromatic compound, a halogen-substituted heterocyclic aromatic compound, a heterocyclic aliphatic compound, an amine, a fluoroamine, an amino acid, an organophosphorus compound, an oxidizer, a bifluoride source, ammonia, an aldehyde, a carbene, or an organic acid, as well as others described herein.

The substrate may be etched at low pressure using thermal energy, for example in a vacuum reaction chamber. In such cases, the substrate is not exposed to plasma during the etching reaction. The substrate may be etched in a selective manner, such that one or more materials are targeted for removal while other materials are etched to a lesser degree. One advantage of the disclosed techniques is that they achieve a high degree of selectivity during etching. Another advantage of the disclosed techniques is that they provide extremely precise control of the etching.

The vapor phase species delivered to the reaction chamber may be collectively referred to as a gas mixture. The non-inert species delivered to the reaction chamber (e.g., the reactants other than the carrier gas) may be collectively referred to as a reactant mixture. The gas mixture includes the reactant mixture and the carrier gas. In some cases, the reactant mixture or the gas mixture may have a particular composition. For example, hydrogen fluoride or other halogen source may be provided in the reactant mixture at a concentration between about 20-100% (by volume), or between about 20-99% (by volume). In these or other cases, hydrogen fluoride or other halogen source may be provided in the gas mixture at a concentration between about 0.5-20% (by volume). The organic solvent or water may be provided in the reactant mixture at a concentration between about 10-100% (by volume), or between about 10-99% (by volume). In these or other cases, the organic solvent or water may be provided in the gas mixture at a concentration between about 0-10% (by volume). The additive may be provided in the reactant mixture at a concentration between about 0.2-5% (by volume). In these or other cases, the additive may be provided in the gas mixture at a concentration between about 0-0.2%, or between about 0.0001-0.2% (by volume). The carrier gas may be provided in the gas mixture at a concentration between about 0-99% (by volume).

In some embodiments, the additive and organic solvent or water are mixed such that the additive is between about 0.1-5% (by weight) of the additive/organic solvent or water mixture. A reactant mixture regardless of the order of mixing may be characterized by the additive being about 0.1-5% (by weight) of the total of the amounts of additive and organic solvent or water.

In the same or alternate embodiments, the reactant mixture may be characterized by halogen source:additive ratio (by volume). As described further below, in some embodiments, the selectivity can be tuned by the halogen source:additive vol. ratio, with selectivity increasing with an increasing amount of additive (and thus a decreasing ratio). In some embodiments, the halogen source:additive ratio is less than or equal to 10. In some embodiments, the halogen source:additive ratio is greater than 10.

According to various embodiments, the reactant mixture may include a halogen source, an alcohol (a non-limiting organic solvent), and an amine (a non-limiting additive), where the amine is between 0.1-5% wt. of the total alcohol and amine amounts. In some embodiments, the halogen source:amine volumetric ratio is no more than 10. In other embodiments, the halogen source:amine volumetric ratio is 10 or higher. In some embodiments, the amine is pyridine. In some embodiments, the alcohol is isopropyl alcohol. In some embodiment the halogen source is HF. In some instances and under certain conditions, the alcohol and the amine combine together to form an adduct or a reaction product within the reactant mixture.

As described above, according to various implementations, the etch may be selective to one material on a substrate with respect to another material. In other implementations, the etch may be non-selective with respect to multiple materials on a substrate.

In some embodiments, oxides are selectively etched with respect to one or more of nitrides and epitaxial materials such as Si and SiGe. The etch selectivity of the reactant mixture to silicon oxide can be tuned by the amount of additive in the mixture. For example, very high (at least 50:1) etch selectivity of silicon oxide with respect to silicon nitride is achieved with a reactant mixture having a halogen source:additive (e.g., HF:pyridine) of no more than 10. The etch selectivity decreases with increasing ratio such that no selectivity is observed in the case where there is no additive. Similar effects may be observed for etch selectivity of silicon oxide with respect to Si and SiGe.

In some embodiments, low-k materials are selectively etched with respect to barrier materials. For example, a carbon doped silicon oxide material may be etched selectively with respect to a barrier material such as a titanium nitride layer.

The temperature may be controlled using a number of techniques that may be combined as desired, for example by controlling the temperature of a substrate support, a showerhead, reaction chamber walls, process gases, etc. In one instance, the substrate support, showerhead, reaction chamber walls, process gases, and the like can be configured to be cooled (e.g., by use of a cooling element, which can include use of a coolant, a cooling gas, a chiller, a cooling zone having a heat transfer liquid flowing through tubes disposed within the zone, and the like). In another instance, when cyclic etching techniques are used, the temperature may cycle between two or more different settings. In some embodiments, the temperature during the modification period for modifying the surface may be between about 100-500° C., while the temperature during the vapor etch period may be between about 20-200° C. In various implementations, the substrate is not exposed to plasma. In such embodiments, both the reaction that occurs during the modification period and the reaction that occurs during the vapor etch period are driven by thermal energy.

The etching operation may be carried out in a self-limiting manner. For instance, the gas mixture provided during the vapor etch period may selectively etch modified material formed during the modification period. Once the modified material is consumed, the etching rate may decrease substantially or even stop as a result of the selective nature of the etching process. As such, the etch process may be considered self-limiting in certain embodiments. Further, as mentioned above, the etch process may selectively target the material to be removed, without substantially removing other materials present on the substrate.

The methods described herein can be performed on any appropriate apparatus. The following description provides one example of an appropriate apparatus. The apparatus described herein allows for rapidly and precisely controlling a substrate's temperature during semiconductor processing, including performing etching using thermal energy, rather than or in addition to plasma energy, to drive the modification and removal operations. In certain embodiments, etching that relies upon chemical reactions in conjunction with primarily thermal energy, not a plasma, to drive the chemical reactions in the modification and removal operations may be considered “thermal etching”. This etching is not limited to ALE (atomic layer etching); it is applicable to any etching technique.

In certain embodiments, thermal etching processes, such as those employing one or more thermal cycles have relatively fast heating and cooling and relatively precise temperature control. In some cases, these features may be leveraged to provide good throughput or to reduce nonuniformity and wafer defects.

Many conventional etching apparatuses do not have the ability to adjust and control the temperature of the substrate with adequate speed. For example, while some etching apparatuses may be able to heat a substrate to multiple temperatures, they can do so only slowly, or they may not be able to reach the desired temperature ranges, or they may not be able to maintain the substrate temperature for the desired time and at the desired temperature ranges. Similarly, typical etching apparatuses are often unable to cool the substrate fast enough to enable high throughput or cool the substrate to the desired temperature ranges. For some applications, it is desirable to reduce the temperature ramp times as much as possible, such as to less than about 120 seconds in some embodiments, but many conventional etching apparatuses cannot heat, cool, or both, a substrate in less than that time; it may take some apparatuses multiple minutes to cool or heat a substrate, which slows throughput.

In various embodiments, apparatuses described herein are designed or configured to rapidly heat and cool a wafer, and precisely control a wafer's temperature. In some embodiments, the wafer is rapidly heated and its temperature is precisely controlled using, in part, visible light or infrared light emitted from light emitting diodes (LEDs) positioned in a pedestal under the wafer. The visible light may have wavelengths that include and range between 400 nanometers (nm) and 800 nm. The infrared light may have wavelengths that include and range between 700 nm and 1000 nm. In certain embodiments, the LED may be configured to provide a light having a wavelength from about 400 nm to 1000 nm or from 500 nm to 1000 nm.

The pedestal may include various features for enabling wafer temperature control, such as a transparent window that may have lensing for advantageously directing or focusing the emitted light, reflective material also for advantageously directing or focusing the emitted light, and temperature control elements that assist with temperature control of the LEDs, the pedestal, and the chamber. In another embodiment, the LED is formed from materials that are transparent to visible light and resistant to damage or etching by reactor clean or reactor treat operations described herein.

For instance, heater LEDs may be used to emit visible light or infrared light onto the backside of the substrate, which heats the substrate. Visible light having wavelengths from about 400 nm to 800 nm is able to quickly and efficiently heat silicon wafers from ambient temperature, e.g., about 20° C., to about 600° C. because silicon absorbs light within this range. In contrast, radiant, including infrared radiant, heating may ineffectively heat silicon at temperatures up to about 400° C. because silicon tends to be transparent to infrared at temperatures lower than about 400° C. Additionally, radiant heaters that directly heat the topside of a wafer, as in many conventional semiconductor processes, can cause damage or other adverse effects to the topside films. Traditional “hot plate” heaters that rely on solid-to-solid thermal transference between the substrate and a heating platen, such as a pedestal with a heating coil, have relatively slow to heating and cooling rates, and provide non-uniform heating which may be caused by substrate warping and inconsistent contact with the heating platen. For example, it may take multiple minutes to heat a traditional pedestal to a desired temperature, and from a first to a second higher temperature, as well as to cool the pedestal to a lower temperature.

The heater's plurality of LEDs may be arranged, electrically connected, and electrically controlled in various manners. Each LED may be configured to emit a visible blue light or a visible white light. In certain embodiments, white light (produced using a range of wavelengths in the visible portion of the electromagnetic (EM) spectrum) is used. In some semiconductor processing operations, white light can reduce or prevent unwanted thin film interference. For instance, some substrates have backside films that reflect different light wavelengths in various amounts, thereby creating an uneven and potentially inefficient heating. Using white light can reduce this unwanted reflection variation by averaging out the thin film interference over the broad visible spectrum provided by white light. In some instances, depending on the material on the back face of the substrate, it may be advantageous to use a visible non-white light, such as a blue light having a 450 nm wavelength, for example, in order to provide a single or narrow band of wavelength which may provide more efficient, powerful, and direct heating of some substrates that may absorb the narrow band wavelength better than white light.

Various types of LED may be employed. Examples include a chip on board (COB) LED or a surface mounted diode (SMD) LED. For SMD LEDs, the LED chip may be fused to a printed circuit board (PCB) that may have multiple electrical contacts allowing for the control of each diode on the chip. For example, a single SMD chip is typically limited to having three diodes (e.g., red, blue, or green) that can be individually controllable to create different colors, for instance. SMD LED chips may range in size, such as 2.8×2.5 mm, 3.0×3.0 mm, 3.5×2.8 mm, 5.0×5.0 mm, and 5.6×3.0 mm. For COB LEDs, each chip can have more than three diodes, such as nine, 12, tens, hundreds or more, printed on the same PCB. COB LED chips typically have one circuit and two contacts regardless of the number of diodes, thereby providing a simple design and efficient single color application. The ability and performance of LEDs to heat the substrate may be measured by the watts of heat emitted by each LED; these watts of heat may directly contribute to heating the substrate.

The apparatuses may also thermally isolate, or thermally “float,” the wafer within the processing chamber so that only the smallest thermal mass is heated, the ideal smallest thermal mass being just the substrate itself, which enables faster heating and cooling. As used herein, the term “thermally isolate” or “thermally float” means to substantially isolate an object to ensure rapid transfer of thermal energy to that object. The wafer may be rapidly cooled using a cooling gas and radiative heat transfer to a heat sink, such as a top plate (or other gas distribution element) above the wafer, or both. In some instances, the apparatus also includes temperature control elements within the processing chamber walls, pedestal, and top plate (or other gas distribution element), to enable further temperature control of the wafer and processing conditions within the chamber, such as the prevention of unwanted condensation of processing gases and vapors.

In some embodiments, precleaning includes providing a gas mixture (e.g., any described herein) in the reaction chamber and exposing the substrate to the gas mixture while a pressure in the reaction chamber is between about 0.2-10 Torr. In particular embodiments, the gas mixture is vapor phase. In certain instances, precleaning further includes: providing thermal energy to the reaction chamber to drive a reaction that partially or wholly etches the target material from the substrate, wherein the substrate is not exposed to plasma during etching. In other embodiments, precleaning further includes: exposing the substrate to plasma during etching. Further conditions and reagents are described in International Publication No. WO 2021/202411, entitled “Selective precision etching of semiconductor materials,” which is incorporated herein by reference in its entirety.

### Halogen Source

The halogen source may be any halogen-containing (e.g., X-containing, where X is fluorine (F), chlorine (Cl), bromine (Br), or iodine (I)) compound that exists in vapor phase at the processing temperature. Examples include hydrogen fluoride (HF), hydrogen chloride (HCl), hydrogen bromide (HBr), fluorine (F₂), chlorine (Cl₂), bromine (Br₂), chlorine trifluoride (ClF₃), nitrogen trifluoride (NF₃), nitrogen trichloride (NCl₃), and nitrogen tribromide (NBr₃). In some implementations, the halogen source is an organohalide, with examples including fluoroform (CHF₃), chloroform (CHCl₃), bromoform (CHBr₃), carbon tetrafluoride (CF₄), carbon tetrachloride (CCl₄), carbon tetrabromide (CBr₄), perfluorobutene (C₄F₈), and perchlorobutene (C₄Cl₈). In some implementations, the halogen source is a silicon halide, with examples including silicon tetrafluoride (SiF₄), silicon tetrachloride (SiCl₄), silicon tetrabromide (SiBr₄), and compounds that include SiX₆ such as H₂SiX₆. In some implementations, the halogen source is a metal halide with examples including molybdenum hexafluoride (MoF₆), molybdenum hexachloride (MoCl₆), molybdenum hexabromide (MoBr₆), tungsten hexafluoride (WF₆), tungsten hexachloride (WCl₆), tungsten hexabromide (WBr₆), titanium tetrafluoride (TiF₄), titanium tetrachloride (TiCl₄), titanium tetrabromide (TiBr₄), zirconium fluoride (ZrF₄), zirconium chloride (ZrCl₄), and zirconium bromide (ZrBr₄). Metal halides may be used in some embodiments to selectively etch metal oxides.

In the description below, various examples include HF as the halogen source. However, any appropriate halogen source may be used. The volume and mass percentages described for HF can be used for other halogen sources. In some embodiments, two or more halogen sources may be used.

### Organic Solvent

In certain implementations, the organic solvent may be an alcohol. The alcohol can be an alcohol having a formula of X—C(R)ₙ(OH)—Y, where:
n is 1;
each X and Y can be independently selected from hydrogen, —[C(R′)₂]ₘ—C(R²)₃, or OH, wherein each R¹ and R² is independently selected from hydrogen, hydroxyl, aliphatic, haloaliphatic, haloheteroaliphatic, heteroaliphatic, aromatic, aliphatic-aromatic, heteroaliphatic-aromatic, or any combinations thereof, and wherein m is an integer from 0 to 10; and
each R independently is selected from hydrogen, hydroxyl, aliphatic, haloaliphatic, haloheteroaliphatic, heteroaliphatic, aromatic, aliphatic-aromatic, heteroaliphatic-aromatic, or any combinations thereof.

In some embodiments, each R, R¹, and R² independently is selected from alkyl, alkenyl, alkynyl, heteroalkyl, heteroalkenyl, heteroalkynyl, haloalkyl, haloalkenyl, haloalkynyl, haloheteroalkyl, haloheteroalkenyl, haloheteroalkynyl, aryl, heterocyclyl, heteroaryl, alkyl-aryl, alkenyl-aryl, alkynyl-aryl, alkyl-heterocyclyl, alkenyl-heterocyclyl, alkynyl-heterocyclyl, alkyl-heteroaryl, alkenyl-heteroaryl, alkynyl-heteroaryl, heteroalkyl-aryl, heteroalkenyl-aryl, heteroalkynyl-aryl, heteroalkyl-heterocyclyl, heteroalkenyl-heterocyclyl, heteroalkynyl-heterocyclyl, heteroalkyl-heteroaryl, heteroalkenyl-heteroaryl, heteroalkynyl-heteroaryl, or any combinations thereof. In particular disclosed embodiments, the alcohol may further be substituted with one or more substituents, such as alkoxy, amide, amine, thioether, thiol, acyloxy, silyl, cycloaliphatic, aryl, aldehyde, ketone, ester, carboxylic acid, acyl, acyl halide, cyano, halogen, sulfonate, nitro, nitroso, quaternary amine, pyridinyl (or pyridinyl wherein the nitrogen atom is functionalized with an aliphatic or aryl group), alkyl halide, or any combinations thereof.

In other embodiments, when at least one of X or Y=—[C(R¹)₂]ₘ—C(R²)₃ or R is a hydrogen and m is 1, the alcohol can be a C₃ alcohol. For instance, if at least one R¹ and one R² is absent, then the C₃ alcohol can be a C₃ alkenol (e.g., allyl alcohol). In another instance, R and one R² together can form a ring(such as, cycloaliphatic), then the C₃ alcohol can be a cyclopropanol or 2-cyclopropenol.

In yet other embodiments, when at least one of X or Y=—[C(R′)₂]ₘ—C(R²)₃ or R is a hydrogen and m is 2, the alcohol can be a C₄ alcohol. For instance, if at least one R¹ and one R² is absent, then the C₄ alcohol can be a C₄ alkenol (e.g., 2-buten-1-ol or 3-buten-1-ol). In another instance, R and one R² together can form a ring (such as, cycloaliphatic), then the C₄ alcohol can be a C₄-cyclic alcohol (e.g., cyclobutanol or a cyclopropylmethanol). In yet another instance, if both X and Y are not OH, then the C₄ alcohol can be a C₄-branched alcohol (e.g., 2-butanol, isobutanol, or tert-butanol).

The alcohol can be diol having two OH groups. The OH group can be positioned anywhere within the compound, so long as only two OH groups are provided for the diol. In one instance, R=OH, and none of X and Y includes an OH group. In another instance, X includes an OH group, and none of R and Y includes an OH group. In some instances, when X=OH, Y=—[C(R¹)₂]ₘ—C(R²)₃, R≠OH, R¹≠OH, and R²≠OH, then the alcohol can be a diol. In some instances, when X=OH, Y=—[C(R′)₂]ₘ—C(R²)₃, R≠H, R¹≠OH, and R²≠OH, then the alcohol can be a diol. In yet other instances, when at X and R do not include OH, Y=—[C(R¹)₂]ₘ—C(R²)₃, and at least one R¹=OH or one R²=OH, then the alcohol can be a diol. In other instances, when X does not include OH, Y=—[C(R¹)₂]ₘ—C(R²)₃, R¹≠OH, R¹≠OH, and R=OH, the alcohol can be a diol. Example diols include, but are not limited to, 1,4-butane diol, propylene-1,3-diol, and the like.

The alcohol can be a triol having three OH groups. The OH group can be positioned anywhere within the compound, so long as only three OH groups are provided for the triol. In one instance, R and X includes an OH, and Y does not include an OH group. In other instances, when X=Y=OH and R≠OH, the alcohol can be a triol. In yet other instances, when X=R=OH and Y does not include OH, the alcohol can be a triol. In some instances, when X and R does not include OH, Y is —[C(R¹)₂]ₘ—C(R²)₃, and one R¹ and at least one R² is OH, the alcohol can be triol. In other instances, when R=OH, Y does not include OH, and X=—[C(R¹)₂]ₘ—C(R²)₃ and at least one R=OH or one R²=OH, the alcohol can be triol. Example triols include, but are not limited to, glycerol, glycerine, ethane-1,1,2-triol, ethane-1,1,1-triol, and the like.

In particular embodiments, when R=cycloheteroaliphatic, heterocyclyl, heteroaryl, alkyl-heterocyclyl, alkenyl-heterocyclyl, alkynyl-heterocyclyl, heteroalkyl-heterocyclyl, heteroalkenyl-heterocyclyl, or heteroalkynyl-heterocyclyl, the alcohol can be a heterocyclyl alcohol (e.g., an optionally substituted heterocyclyl substituted with or more hydroxyls, such as furfuryl alcohol). In other embodiments, when at least one of X or Y is —[C(R¹)₂]ₘ—C(R²)₃ and one R¹ and at least one R² is cycloheteroaliphatic, heterocyclyl, heteroaryl, alkyl-heterocyclyl, alkenyl-heterocyclyl, alkynyl-heterocyclyl, heteroalkyl-heterocyclyl, heteroalkenyl-heterocyclyl, or heteroalkynyl-heterocyclyl, the alcohol can be a heterocyclyl alcohol.

In various embodiments, the alcohol may have between 1-10 carbon atoms. The alcohol may be a primary alcohol, a secondary alcohol, or a tertiary alcohol. In some cases, the alcohol may be selected from the group consisting of: methanol, ethanol, 1-propanol, 2-propanol, 1-butanol, 2-butanol, t-butanol, 1-pentanol, 1-hexanol, 1-heptanol, 1-octanol, 1-nonanol, 1-decanol, and combinations thereof.

In these or other cases, the organic solvent may include a laboratory-type solvent such as acetonitrile, dichloromethane, carbon tetrachloride, or a combination thereof.

In some embodiments, the organic solvent may be a ketone. The organic solvent can also be a ketone having a formula of X—[C(O)]ₙ-Y, where:
n is an integer from 1 to 2;
each X and Y can be independently selected from —C(R¹)₃, —R², or —[C(R³)₂]ₘ—C(O)—R⁴, wherein each R¹, R², R³, and R⁴ can be independently selected from hydrogen, hydroxyl, aliphatic, haloaliphatic, haloheteroaliphatic, heteroaliphatic, aromatic, aliphatic-aromatic, heteroaliphatic-aromatic, or any combinations thereof;
in which R³ and R⁴, taken together with the atom to which each are attached, can optionally form a cycloaliphatic or cycloheteroaliphatic, and in which X and Y, taken together with the atom to which each are attached, can optionally form a cycloaliphatic or cycloheteroaliphatic; and
m is an integer from 0 to 10.

In some embodiments, each R¹, R², R³ and R⁴, independently, are alkyl, alkenyl, alkynyl, heteroalkyl, heteroalkenyl, heteroalkynyl, haloalkyl, haloalkenyl, haloalkynyl, haloheteroalkyl, haloheteroalkenyl, haloheteroalkynyl, aryl, heterocyclyl, heteroaryl, alkyl-aryl, alkenyl-aryl, alkynyl-aryl, alkyl-heterocyclyl, alkenyl-heterocyclyl, alkynyl-heterocyclyl, alkyl-heteroaryl, alkenyl-heteroaryl, alkynyl-heteroaryl, heteroalkyl-aryl, heteroalkenyl-aryl, heteroalkynyl-aryl, heteroalkyl-heterocyclyl, heteroalkenyl-heterocyclyl, heteroalkynyl-heterocyclyl, heteroalkyl-heteroaryl, heteroalkenyl-heteroaryl, heteroalkynyl-heteroaryl, or any combinations thereof. In particular disclosed embodiments, the organic solvent may further be substituted with one or more substituents, such as aldehyde (—C(O)H), oxo (=O), alkoxy, amide, amine, hydroxyl, thioether, thiol, acyloxy, silyl, cycloaliphatic, aryl, aldehyde, ketone, ester, carboxylic acid, acyl, acyl halide, cyano, halogen, sulfonate, nitro, nitroso, quaternary amine, pyridinyl (or pyridinyl wherein the nitrogen atom is functionalized with an aliphatic or aryl group), alkyl halide, or any combinations thereof. One example ketone is acetone.

In some embodiments, when X and Y, taken together with the atom to which each are attached, forms a cycloaliphatic or cycloheteroaliphatic, the organic solvent can be a cyclic ketone. Example cyclic ketones include cyclohexanone, cyclopentanone, and the like.

In other embodiments, when at least one of X or Y=—[C(R³)₂]ₘ—C(O)—R⁴, the organic solvent can be a diketone. Example diketones include diacetyl, 2,3-pentanedione, 2,3-hexanedione, 3,4-hexanedione, acetylacetone, acetonylacetone, and the like, as well as halogenated forms thereof, such as hexafluoroacetylacetone.

In further embodiments, when at least one of X or Y=—[C(R³)₂]ₘ-C(O)—R⁴ and X and Y, taken together with the atom to which each are attached, forms a cycloaliphatic or cycloheteroaliphatic, the organic solvent can be a cyclic diketone. Example cyclic diketones include dimedone, 1,3-cyclohexanedione, and the like.

In some instances, when X=—CH₃, the organic solvent can have Y=—C(R¹)₃, in which at least one R¹ is C₂₋₁₀ hydroxyl, aliphatic, haloaliphatic, haloheteroaliphatic, heteroaliphatic, aromatic, aliphatic-aromatic, heteroaliphatic-aromatic, or any combinations thereof. Example materials can include methyl propyl ketone, methyl butyl ketone, hydroxyacetone, and the like.

In other instances, when X=—CH₃, the organic solvent can have Y=—R², in which at least one R² is C₂ alkenyl, C₃₋₁₀ aliphatic, haloaliphatic, haloheteroaliphatic, heteroaliphatic, aromatic, aliphatic-aromatic, heteroaliphatic-aromatic, or any combinations thereof. Example materials can include methyl vinyl ketone, methyl propyl ketone, methyl butyl ketone, and the like.

In yet other instances, when at least one of X or Y=aromatic, or aliphatic-aromatic, or heteroaliphatic-aromatic, the organic solvent can be an aromatic ketone. Example materials include acetophenone, benzophenone, benzylacetone, 1,3-diphenylacetone, cyclopentyl phenyl ketone, and the like.

In certain embodiments where the organic solvent includes a ketone, the ketone may be selected from acetone and acetophenone. One or more additional ketones or other organic solvents described herein may be provided, as well.

In some embodiments, the organic solvent may be an alkane. In certain embodiments, the alkane may be an acyclic branched or unbranched hydrocarbon having the general formula CₙH₂ₙ₊₂. Example acyclic alkanes include, but are not limited to, pentane, hexane, octane, and combinations thereof. In certain other embodiments, the alkane may be a cyclic hydrocarbon.

Example cyclic hydrocarbons include, but are not limited to, cyclopentane, cyclohexane, and combinations thereof.

In some embodiments, the organic solvent may be an aromatic solvent. As used herein, “aromatic” means a cyclic, conjugated group or moiety of, unless specified otherwise, from 5 to 15 ring atoms having a single ring (e.g., phenyl) or multiple condensed rings in which at least one ring is aromatic (e.g., naphthyl, indolyl, or pyrazolopyridinyl); that is, at least one ring, and optionally multiple condensed rings, have a continuous, delocalized π-electron system. Typically, the number of out of plane π-electrons corresponds to the Hückel rule (4n+2). The point of attachment to the parent structure typically is through an aromatic portion of the condensed ring system. In some cases, an aromatic solvent may be selected from toluene and benzene.

In some embodiments, the organic solvent may be an ether having a formula of X—O—Y or X—O—[C(R)₂]ₙ—O—Y, where:
n is an integer from 1 to 4;
each X and Y can be independently selected from —[C(R¹)₂]ₘ₁—C(R²)₃ or —R³ or —[C(R⁴)—O—[C(R⁵)₂]ₘ₂—C(R⁶)₃, wherein each of R¹, R², R³, R⁴, R⁵, R⁶, and R is independently selected from hydrogen, hydroxyl, aliphatic, haloaliphatic, haloheteroaliphatic, heteroaliphatic, aromatic, aliphatic-aromatic, heteroaliphatic-aromatic, or any combinations thereof, and
wherein m1 is an integer from 0 to 10, m2 is an integer from 0 to 10, and p is an integer from 1 to 10;
in which X and Y, taken together with the atom to which each are attached, can optionally form a cycloheteroaliphatic group.

In some embodiments, each R, R¹, R², R³, R⁴, R⁵, and R⁶ independently are selected from alkyl, alkenyl, alkynyl, heteroalkyl, heteroalkenyl, heteroalkynyl, haloalkyl, haloalkenyl, haloalkynyl, haloheteroalkyl, haloheteroalkenyl, haloheteroalkynyl, aryl, heterocyclyl, heteroaryl, alkyl-aryl, alkenyl-aryl, alkynyl-aryl, alkyl-heterocyclyl, alkenyl-heterocyclyl, alkynyl-heterocyclyl, alkyl-heteroaryl, alkenyl-heteroaryl, alkynyl-heteroaryl, heteroalkyl-aryl, heteroalkenyl-aryl, heteroalkynyl-aryl, heteroalkyl-heterocyclyl, heteroalkenyl-heterocyclyl, heteroalkynyl-heterocyclyl, heteroalkyl-heteroaryl, heteroalkenyl-heteroaryl, heteroalkynyl-heteroaryl, or any combinations thereof. In particular disclosed embodiments, the ether may further be substituted with one or more substituents, such as alkoxy, amide, amine, thioether, thiol, acyloxy, silyl, cycloaliphatic, aryl, aldehyde, ketone, ester, carboxylic acid, acyl, acyl halide, cyano, halogen, sulfonate, nitro, nitroso, quaternary amine, pyridinyl (or pyridinyl wherein the nitrogen atom is functionalized with an aliphatic or aryl group), alkyl halide, or any combinations thereof.

In some embodiments, when X and Y are taken together with the atom to which each are attached in order form a cycloheteroaliphatic group, the organic solvent is a cyclic ether, such as, acetal, dioxane, dioxolane, etc. For instance, when forming a ring, each of X and Y can be, independently, a covalent bond or a multivalent (e.g., bivalent) form of aliphatic, alkyl, alkenyl, alkynyl, heteroaliphatic, heteroalkyl, heteroalkenyl, or heteroalkynyl. In some embodiments, when n=1 and each R=H, X and Y taken together form a five, six, seven, eight, nine, or ten-membered ring. Example ethers include, but are not limited to, 1,3-dioxolane, or derivatives thereof. In other embodiments, when n=2 and R=H, X and Y form a six, seven, eight, nine, or ten-membered ring. Example ethers include, but are not limited to, 1,4-dioxane, or derivatives thereof. In yet other embodiments, when n=1 or n=2, then R is aliphatic, haloaliphatic, haloheteroaliphatic, heteroaliphatic, aromatic, aliphatic-aromatic, heteroaliphatic-aromatic, or any combinations thereof. Example cyclic ethers include tetrahydrofuran, 2-methyltetrahydrofuran, 2-methyl-1,3-dioxolane, and the like.

In other embodiments, when at least one of X or Y=aromatic, the organic solvent can be an aromatic ether. Example aromatic ethers include anisole, diphenyl ether, and the like.

In some embodiments, when at least one of X or Y=cycloaliphatic, the organic solvent can be a cycloalkyl ether. Example cycloalkyl ethers include cyclopentyl methyl ether, cyclohexyl methyl ether, and the like.

In other embodiments, when at least one of X or Y=—[C(R⁴)₂-O]ₚ—C(R⁶)₃, the organic solvent can be a glycol based ether. Example glycol based ethers include diethylene glycol diethyl ether, dipropylene glycol dimethyl ether, poly(ethylene glycol) dimethyl ether, etc., including methyl, ethyl, propyl, and butyl mono- and di-ethers of ethylene glycol, and the like.

In some cases, the organic solvent is a nitrile having a formula R—C≡N, where
R is aliphatic, haloaliphatic, haloheteroaliphatic, heteroaliphatic, aromatic, aliphatic-aromatic, or heteroaliphatic-aromatic.

In certain embodiments, R can be optionally substituted with a hydroxyl group (e.g., in one example R can be CH₃—CH(OH)—CH₂—, and the organic solvent will be CH₃—CH(OH)—CH₂—CN).

One example nitrile is acetonitrile, mentioned above.

In some embodiments, the organic solvent may include two or more of the organic solvents or types of organic solvents described herein. In some embodiments, water may be provided instead of, or in addition to, the organic solvent.

### Additive

In some embodiments, the additive serves the purposes of accelerating the reaction rate and enhancing the reaction selectivity. The additive may be selected from a number of different types of additives. For instance, in some cases the additive may be a heterocycle compound, a heterocyclic aromatic compound, a halogen-substituted heterocyclic aromatic compound, a heterocyclic aliphatic compound, an amine, a fluoroamine, an amino acid, an organophosphorus compound, an oxidizer, a bifluoride source, ammonia, an aldehyde, a carbene, or an organic acid.

In some cases, more than one additive may be used. In some embodiments, the additive may be a boron-containing Lewis acid or Lewis adduct. Boron trifluoride (BF₃) is an example of a Lewis acid that forms the acid-base adduct BF₄⁻. In some cases, the additive may fall into two or more of the categories listed above.

In certain embodiments, the additive is a heterocyclic aromatic compound. The term “aromatic” is defined above. A heterocyclic aromatic compound is an aromatic compound that includes a 5-, 6- or 7-membered ring, unless otherwise specified, containing one, two, three, or four non-carbon heteroatoms (e.g., independently selected from the group consisting of nitrogen, oxygen, phosphorous, sulfur, or halo). Example heterocyclic aromatic compounds that may be used include, but are not limited to, picoline, pyridine, pyrrole, imidazole, thiophene, N-methylimidazole, N-methylpyrrolidone, benzimidazole, 2,2-bipyridine, dipicolonic acid, 2,6-lutidine, 4-N,N-dimethylaminopyridine, and azulene. In some cases, a heterocyclic aromatic compound may be methylated. In some cases, a heterocyclic aromatic compound may follow the Hückel 4n+2 rule. In some cases, the additive is a halogen-substituted aromatic compound. A halogen-substituted aromatic compound is an aromatic compound that includes at least one halogen bonded to the aromatic ring. As used herein, halogen or halo refers to F, Cl, Br, or I.

Example halogen-substituted aromatic compounds include, but are not limited to, 4-bromopyridine, chlorobenzene, 4-chlorotoluene, fluorobenzene, etc.

In some embodiments, the additive is a heterocyclic aliphatic compound. As used herein, “aliphatic” means a hydrocarbon group having at least one carbon atom to 50 carbon atoms (C₁₋₅₀), such as one to 25 carbon atoms (C₁₋₂₅), or one to ten carbon atoms (C₁₋₁₀), and which includes alkanes (or alkyl), alkenes (or alkenyl), alkynes (or alkynyl), including cyclic versions thereof, and further including straight- and branched-chain arrangements, and all stereo and position isomers as well. A heterocyclic aliphatic compound is an aliphatic compound that includes a 5-, 6- or 7-membered ring, unless otherwise specified, containing one, two, three, or four non-carbon heteroatoms (e.g., independently selected from the group consisting of nitrogen, oxygen, phosphorous, sulfur, or halo). Example heterocyclic aliphatic compounds include pyrrolidine, piperidine, etc.

In some embodiments, the additive is an amine having a formula of NR¹R²R³, where:
each of R¹, R², and R³ is independently selected from hydrogen, hydroxyl, aliphatic, haloaliphatic, haloheteroaliphatic, heteroaliphatic, aromatic, aliphatic-aromatic, heteroaliphatic-aromatic, or any combinations thereof;
in which R¹ and R², taken together with the atom to which each are attached, can optionally form a cycloheteroaliphatic; and
in which R¹, R², and R³, taken together with the atom to which each are attached, can optionally form a cycloheteroaliphatic.

In some embodiments, each of R¹, R², and R³ is independently selected from alkyl, alkenyl, alkynyl, heteroalkyl, heteroalkenyl, heteroalkynyl, haloalkyl, haloalkenyl, haloalkynyl, haloheteroalkyl, haloheteroalkenyl, haloheteroalkynyl, aryl, heterocyclyl, heteroaryl, alkyl-aryl, alkenyl-aryl, alkynyl-aryl, alkyl-heterocyclyl, alkenyl-heterocyclyl, alkynyl-heterocyclyl, alkyl-heteroaryl, alkenyl-heteroaryl, alkynyl-heteroaryl, heteroalkyl-aryl, heteroalkenyl-aryl, heteroalkynyl-aryl, heteroalkyl-heterocyclyl, heteroalkenyl-heterocyclyl, heteroalkynyl-heterocyclyl, heteroalkyl-heteroaryl, heteroalkenyl-heteroaryl, heteroalkynyl-heteroaryl, or any combinations thereof. In particular disclosed embodiments, the amine may further be substituted with one or more substituents, such as alkoxy, amide, amine, hydroxyl, thioether, thiol, acyloxy, silyl, cycloaliphatic, aryl, aldehyde, ketone, ester, carboxylic acid, acyl, acyl halide, cyano, halogen, sulfonate, nitro, nitroso, quaternary amine, pyridinyl (or pyridinyl wherein the nitrogen atom is functionalized with an aliphatic or aryl group), alkyl halide, or any combinations thereof.

In some embodiments, when at least one of R¹, R², and R³ is aliphatic, haloaliphatic, haloheteroaliphatic, or heteroaliphatic, the additive is an alkyl amine. The alkyl amine can include dialkylamines, trialkyl amines, and derivatives thereof. Example alkyl amines include methylamine, dimethylamine, trimethylamine, ethylamine, diethylamine, triethylamine, isopropylamine, 1,2-ethylenediamine, dimethylisopropylamine, N-ethyldiisopropylamine, trimethylamine, dimethylamine, methylamine, triethylamine, t-butyl amine, and the like.

In other embodiments, when at least one of R¹, R², and R³ includes a hydroxyl, the additive is an alcohol amine. In one instance, at least one of R¹, R², and R³ is an aliphatic group substituted with one or more hydroxyls. Example alcohol amines include 2-(dimethylamino)ethanol, 2-(diethylamino)ethanol, 2-(dipropylamino)ethanol, 2-(dibutylamino)ethanol, N-ethyldiethanolamine, N-tertbutyldiethanolamine, and the like.

In some embodiments, when R¹ and R², taken together with the atom to which each are attached, form a cycloheteroaliphatic, the additive can be a cyclic amine. Example cyclic amines include piperidine, N-alkyl piperidine (e.g., N-methyl piperidine, N-propyl piperidine, etc.), pyrrolidine, N-alkyl pyrrolidine (e.g., N-methyl pyrrolidine, N-propyl pyrrolidine, etc.), morpholine, N-alkyl morpholine (e.g., N-methyl morpholine, N-propyl morpholine, etc.), piperazine, N-alkyl piperazine, N,N-dialkyl piperazine (e.g., 1,4-dimethylpiperazine), and the like.

In other embodiments, when at least one of R¹, R², and R³ includes an aromatic, the additive is an aromatic amine. In some embodiments, at least one of R¹, R², and R³ is aromatic, aliphatic-aromatic, or heteroaliphatic-aromatic. In other embodiments, both R¹ and R² includes an aromatic. In yet other embodiments, R¹ and R² and optionally R³, taken together with the atom to which each are attached, from a cycloheteroaliphatic that is an aromatic. Example aromatic amines include aniline, aniline derivatives, histamine, pyrrole, pyridine, imidazole, pyrimidine, and the derivatives thereof.

In some embodiments, the additive may include an amine selected from the group consisting of: methylamine, dimethylamine, trimethylamine, ethylamine, diethylamine, triethylamine, isopropylamine, 1,2-ethylenediamine, aniline (and aniline derivatives such as N,N-dimethylaniline), N-ethyldiisopropylamine, tert-butylamine, and combinations thereof.

In some embodiments, the additive may include a fluoramine. A fluoramine is an amine having one or more fluorinated substituents. Example fluoroamines that may be used include, but are not limited to, 4-trifluoromethylaniline.

In some embodiments, the additive can be a nitrogenous analogue of a carbonic acid, having a formula R¹N—C(NR²)—NR³. Example additives can include, but are not limited to, guanidine or derivatives thereof.

In some embodiments, the additive may be a relatively low molecular weight amine, e.g., having a molecular weight of less than 200 g/mol or 100 g/mol in certain embodiments. Higher molecular weight amines, including those having long chains or heterocyclic compounds with aromatic rings, may be used in some embodiments.

In some embodiments, the additive may include an amino acid. The amino acid may have a formula of R—CH(NR′₂)—COOH, where:
each R and R¹ independently are hydroxyl, aliphatic, haloaliphatic, haloheteroaliphatic, heteroaliphatic, aromatic, aliphatic-aromatic, heteroaliphatic-aromatic, or any combination thereof.

Example amino acids that may be used include, but are not limited to, histidine, alanine, and derivatives thereof.

In some embodiments, the additive may include an organophosphorus compound. The organophosphorus compound may be a phosphate ester, a phosphate amide, a phosphonic acid, a phosphinic acid, a phosphonate, a phosphinate, a phosphine oxide, a phosphine imide, or a phosphonium salt. Example organophosphorus compounds include phosphoric acid and trialkylphosphate. In some cases, the organophosphorous compound is a phosphazene. A phosphazene is an organophosphorus compound that includes phosphorus (V) with a double bond between P and N. The phosphazene may have a formula of RN═P(NR₂)₃(where each of R and R₂ are independently selected from hydroxyl, aliphatic, haloaliphatic, haloheteroaliphatic, heteroaliphatic, aromatic, aliphatic-aromatic, heteroaliphatic-aromatic, or any combination thereof). In some cases, the phosphazene may have a formula of [X₂PN]ₙ (where X is a halide, alkoxide, or amide). Other types of phosphazenes may be used as desired.

In some embodiments, the additive includes an oxidizer. As used herein, an oxidizer is a material that has the ability to oxidize (e.g., accept electrons from) another substance. Example oxidizers that may be used include, but are not limited to, hydrogen peroxide, sodium hypochlorate, tetramethyl ammonium hydroxide, and combinations thereof.

In some embodiments, the additive includes a bifluoride source. A bifluoride source is a material that includes or produces bifluoride (HF₂⁻). Example bifluoride sources that may be used include, but are not limited to, ammonium fluoride, aqueous HF, gaseous HF, buffered oxide etch mixture (e.g., a mixture of HF and a buffering reagent such as ammonium fluoride), and hydrogen fluoride pyridine. In some embodiments, the bifluoride source (or one or more of the other additives listed herein) may react to form HF₂ before or after delivery to the reaction chamber.

In certain embodiments, the additive may act as a proton acceptor and promote formation of HF₂⁻. In some such cases, the HF₂ may actively etch one or more materials on the substrate such as an oxide material or another material.

In some embodiments, the additive includes an aldehyde having a formula of X—[C(O)]—H, where:
X can be selected from hydrogen, —R¹, —C(R²)₃, or —[C(R³)₂]ₘ—C(O)H, wherein each R¹, R² and R³ independently are selected from hydrogen, aliphatic, haloaliphatic, haloheteroaliphatic, heteroaliphatic, aromatic, aliphatic-aromatic, heteroaliphatic-aromatic, or any combinations thereof, and m is an integer from 0 to 10.

In some embodiments, each of R¹, R², and R³ is, independently, alkyl, alkenyl, alkynyl, heteroalkyl, heteroalkenyl, heteroalkynyl, haloalkyl, haloalkenyl, haloalkynyl, haloheteroalkyl, haloheteroalkenyl, haloheteroalkynyl, aryl, heterocyclyl, heteroaryl, alkyl-aryl, alkenyl-aryl, alkynyl-aryl, alkyl-heterocyclyl, alkenyl-heterocyclyl, alkynyl-heterocyclyl, alkyl-heteroaryl, alkenyl-heteroaryl, alkynyl-heteroaryl, heteroalkyl-aryl, heteroalkenyl-aryl, heteroalkynyl-aryl, heteroalkyl-heterocyclyl, heteroalkenyl-heterocyclyl, heteroalkynyl-heterocyclyl, heteroalkyl-heteroaryl, heteroalkenyl-heteroaryl, heteroalkynyl-heteroaryl, or any combinations thereof. In particular disclosed embodiments, the aldehyde or ketone may further be substituted with one or more substituents, such as aldehyde (—C(O)H), oxo (=O), alkoxy, amide, amine, hydroxyl, thioether, thiol, acyloxy, silyl, cycloaliphatic, aryl, aldehyde, ketone, ester, carboxylic acid, acyl, acyl halide, cyano, halogen, sulfonate, nitro, nitroso, quaternary amine, pyridinyl (or pyridinyl wherein the nitrogen atom is functionalized with an aliphatic or aryl group), alkyl halide, or any combinations thereof.

In some embodiments, when X=aromatic, the additive can be an aromatic aldehyde. Example aromatic aldehydes include benzaldehyde, 1-naphthaldehyde, phthalaldehyde, and the like.

In other embodiments, when X=aliphatic, the additive can be an aliphatic aldehyde. Example aliphatic aldehydes include acetaldehyde, propionaldehyde, butyraldehyde, isovalerylaldehyde, and the like.

In yet other embodiments, when X=—[C(R³)₂]ₘ—C(O)H and m is 0 to 10 or when X=aliphatic or heteroaliphatic substituted with —C(O)H, the additive can be a dialdehyde. Example dialdehydes include glyoxal, phthalaldehyde, glutaraldehyde, malondialdehyde, succinaldehyde, and the like.

In some examples, an aldehyde used as an additive may be selected from the group consisting of: acrolein, acetaldehyde, formaldehyde, benzaldehyde, propionaldehyde, butyraldehyde, cinnamaldehyde, vanillin, and tolualdehyde. In these or other cases, an aldehyde used as an additive may be selected from the aldehydes discussed in this section and the aldehydes discussed in the organic solvent section.

In some embodiments, the additive includes a carbene. The carbene may have a formula of X—(C:)-Y, where:
each of X and Y can be independently selected from H, halo, —[C(R¹)₂]ₘ—C(R²)₃, —C(O)—R¹, or —C(═NR¹)—R², —NR¹R², —OR², —SR², or —C(R²)₃, wherein each of R¹ and R² is independently selected from hydrogen, hydroxyl, aliphatic, haloaliphatic, haloheteroaliphatic, heteroaliphatic, aromatic, aliphatic-aromatic, heteroaliphatic-aromatic, or any combinations thereof, and wherein m is an integer from 0 to 10;
in which R¹ and R², taken together with the atom to which each are attached, can optionally form a cycloheteroaliphatic group; and
in which X and Y, taken together with the atom to which each are attached, can optionally form a cycloaliphatic or cycloheteroaliphatic group.

Furthermore, the additive can be a carbenium cation having a formula R¹—C⁺(R)—R², wherein each of R, R¹, and R² is independently selected from hydrogen, aliphatic, haloaliphatic, haloheteroaliphatic, heteroaliphatic, aromatic, aliphatic-aromatic, heteroaliphatic-aromatic, or any combinations thereof.

In some embodiments, each R, R¹, and R² independently is selected from alkyl, alkenyl, alkynyl, heteroalkyl, heteroalkenyl, heteroalkynyl, haloalkyl, haloalkenyl, haloalkynyl, haloheteroalkyl, haloheteroalkenyl, haloheteroalkynyl, aryl, heterocyclyl, heteroaryl, alkyl-aryl, alkenyl-aryl, alkynyl-aryl, alkyl-heterocyclyl, alkenyl-heterocyclyl, alkynyl-heterocyclyl, alkyl-heteroaryl, alkenyl-heteroaryl, alkynyl-heteroaryl, heteroalkyl-aryl, heteroalkenyl-aryl, heteroalkynyl-aryl, heteroalkyl-heterocyclyl, heteroalkenyl-heterocyclyl, heteroalkynyl-heterocyclyl, heteroalkyl-heteroaryl, heteroalkenyl-heteroaryl, heteroalkynyl-heteroaryl, or any combinations thereof. In particular disclosed embodiments, the carbene may further be substituted with one or more substituents, such as alkoxy, amide, amine, hydroxyl, thioether, thiol, acyloxy, silyl, cycloaliphatic, aryl, aldehyde, ketone, ester, carboxylic acid, acyl, acyl halide, cyano, halogen, sulfonate, nitro, nitroso, quaternary amine, pyridinyl (or pyridinyl wherein the nitrogen atom is functionalized with an aliphatic or aryl group), alkyl halide, or any combinations thereof. In any embodiment of a carbene, each of R¹ and R² can be independently selected.

In some embodiments, when at least one of X or Y is halo, the additive can be a halocarbene. Example, non-limiting halocarbenes include dihalocarbene, such as dichlorocarbene, difluorocarbene, and the like.

In some embodiments, when both X=Y=—NR¹R², the additive can be a diaminocarbene. In one instance, each of R¹ and R² is independently aliphatic. Example diaminocarbenes include bis(diisopropylamino) carbene, and the like.

In other embodiments, when both at least one of X or Y=—NR¹R² and both R¹ and R² within X or within Y are taken together, with the nitrogen atom to which each are attached, to form a cycloheteroaliphatic group, the additive can be a cyclic diaminocarbene. Example cyclic diamino carbenes include bis(N-piperidyl) carbene, bis(N-pyrrolidinyl) carbene, and the like.

In one instance, when both X=Y=—NR¹R² and an R group from X and an R² group from Y are taken together, with the nitrogen atom to which each are attached, to form a cycloheteroaliphatic group, the additive is an N-heterocyclic carbene. Example N-heterocyclic carbenes include imidazol-2-ylidenes (e.g., 1,3-dimesitylimidazol-2-ylidene, 1,3-dimesityl-4,5-dichloroimidazol-2-ylidene, 1,3-bis(2,6-diisopropylphenyl)imidazol-2-ylidene, 1,3-di-tert-butylimidazol-2-ylidene, etc.), imidazolidin-2-ylidenes (e.g., 1,3-bis(2,6-diisopropylphenyl)imidazolidin-2-ylidene), triazol-5-ylidenes (e.g., 1,3,4-triphenyl-4,5-dihydro-1H-1,2,4-triazol-5-ylidene), and the like.

In some embodiments, when X=—NR¹R² and Y=—SR² and an R¹ group from X and an R² group from Y are taken together, with the nitrogen atom to which each are attached, to form a cycloheteroaliphatic group, the additive is a cyclic thioalkyl amino carbene. Example cyclic thioalkyl amino carbenes include thiazol-2-ylidenes (e.g., 3-(2,6-diisopropylphenyl)thiazol-2-ylidene and the like).

In some embodiments, when X=—NR¹R² and Y=—C(R²)₃ and an R group from X and an R² group from Y are taken together, with the atom to which each are attached, to form a cycloheteroaliphatic group, the additive is a cyclic alkyl amino carbene. Example cyclic alkyl amino carbenes include pyrrolidine-2-ylidenes (e.g., 1,3,3,5,5-pentamethyl-pyrrolidin-2-ylidene and the like) and piperidin-2-ylidenes (e.g., 1,3,3,6,6-pentamethyl-piperidin-2-ylidene and the like).

Further example carbenes and derivatives thereof include compounds having a thiazol-2-ylidene moiety, a dihydroimidazol-2-ylidene moiety, an imidazol-2-ylidene moiety, a triazol-5-ylidene moiety, or a cyclopropenylidene moiety. Yet other carbenes and carbene analogs include an aminothiocarbene compound, an aminooxycarbene compound, a diaminocarbene compound, a heteroamino carbene compound, a 1,3-dithiolium carbene compound, a mesoionic carbene compound (e.g., an imidazolin-4-ylidene compound, a 1,2,3-triazolylidene compound, a pyrazolinylidene compound, a tetrazol-5-ylidene compound, an isoxazol-4-ylidene compound, a thiazol-5-ylidene compound, etc.), a cyclic alkyl amino carbene compound, a boranylidene compound, a silylene compound, a stannylene compound, a nitrene compound, a phosphinidene compound, a foiled carbene compound, etc. Further example carbenes include dimethyl imidazol-2-ylidene, 1,3-bis(2,4,6-trimethylphenyl)-4,5-dihydroimidazol-2-ylidene, (phosphanyl)(trifluoromethyl)carbene, bis(diisopropylamino) carbene, bis(diisopropylamino) cyclopropenylidene, 1,3-dimesityl-4,5-dichloroimidazol-2-ylidene, 1,3-diadamantylimidazol-2-ylidene, 1,3,4,5-tetramethylimidazol-2-ylidene, 1,3-dimesitylimidazol-2-ylidene, 1,3-dimesitylimidazol-2-ylidene, 1,3,5-triphenyltriazol-5-ylidene, bis(diisopropylamino) cyclopropenylidene, bis(9-anthryl)carbene, norbornen-7-ylidene, dihydroimidazol-2-ylidene, methylidenecarbene, etc.

In some embodiments, the additive includes an organic acid. The organic acid may have a formula of R—CO₂H, wherein R is selected from hydrogen, aliphatic, haloaliphatic, haloheteroaliphatic, heteroaliphatic, aromatic, aliphatic-aromatic, heteroaliphatic-aromatic or any combinations thereof. In certain embodiments, R is alkyl, alkenyl, alkynyl, heteroalkyl, heteroalkenyl, heteroalkynyl, haloalkyl, haloalkenyl, haloalkynyl, haloheteroalkyl, haloheteroalkenyl, haloheteroalkynyl, aryl, heteroaryl, alkyl-aryl, alkenyl-aryl, alkynyl-aryl, alkyl-heteroaryl, alkenyl-heteroaryl, alkynyl-heteroaryl, heteroalkyl-aryl, heteroalkenyl-aryl, heteroalkynyl-aryl, heteroalkyl-heteroaryl, heteroalkenyl-heteroaryl, heteroalkynyl-heteroaryl or any combinations thereof. In particular disclosed embodiments, R may further be substituted with one or more substituents such as, alkoxy, amide, amine, thioether, hydroxyl, thiol, acyloxy, silyl, cycloaliphatic, aryl, aldehyde, ketone, ester, carboxylic acid, acyl, acyl halide, cyano, halogen, sulfonate, nitro, nitroso, quaternary amine, pyridinyl (or pyridinyl wherein the nitrogen atom is functionalized with an aliphatic or aryl group), alkyl halide or any combinations thereof. In certain implementations, the organic acid may be selected from formic acid and acetic acid.

### Carrier Gas

The carrier gas may be an inert gas, a noble gas, or other gases, as described herein. In some cases, the carrier gas is a noble gas. In certain embodiments, the carrier gas may be selected from the group consisting of N₂, He, Ne, Ar, Kr, and Xe. In some such embodiments, the carrier gas may be selected from the group consisting of N₂, He, and Ar.

### Pretreat Operations

One or more pretreatment operations can be performed to provide at least one of a passivated surface or apristine surface. In one instance, pretreatment provides apassivated surface on the substrate prior to deposition. In another instance, pretreatment can remove contaminants (e.g., oxygen, carbon, fluorine, and the like) disposed on a surface of the substrate, in which such contaminants can be present on the surface after precleaning but before deposition. In other non-limiting embodiments, pretreatment can be employed between deposition cycles for providing the stack. During pretreatment, optional etch steps can be performed (e.g., any etch conditions described herein).

Typically, pretreatment is performed in the presence of a hydrogen-containing reagent to provide a hydrogen-passivated surface. In one instance, pretreatment of a silicon substrate typically includes a baking step with a hydrogen soak (e.g., 10% H₂ in an inert gas, such as argon). Temperature ranges for pretreatment can be from about 300° C. to more than about 700° C. A hydrogen ambient below about 10 Torr is generally applied over the substrate surface during the cleaning and passivation of the substrate. In other embodiments, higher pressure (e.g., more than 10 Torr) may be employed for a thermal soak (e.g., more than about 700° C., as described herein).

Herein, any hydrogen-containing reagent can be adapted or exchanged to provide a deuterium-containing reagent. Without wishing to be limited by mechanism, one benefit of deuterium is that Si—D bonds (as presented on a deuterated surface) can be more stable than Si—H bonds (as presented on a hydrogenated surface). Thus, in some instances, the presence of such Si-D bonds may provide a more stable surface if deuterium-containing reagents (including deuterium-containing gases) are employed during a pretreat operation. Thus, in any embodiment herein, a hydrogen soak gas may be supplemented with a deuterium soak gas (e.g., 10% of a combination of H₂ and D₂ in an inert gas, such as argon), or the hydrogen soak gas may be replaced with a deuterium soak gas (e.g., 10% D₂ in an inert gas, such as argon), or the hydrogen soak gas may be replaced with a hydrogen deuteride soak gas (e.g., 10% HD in an inert gas, such as argon).

In one instance, a hydrogen-containing or deuterium-containing soak gas (e.g., H₂, D₂, HD, or others) can be employed in the presence of high temperature to radiatively heat the substrate for temporary heating or to resistively heat the substrate by way of the pedestal. Such temperatures can include more than about 700° C., more than about 750° C., or more than about 775° C. Radiative heating can include use of thermal lamp heating, an array of LEDs, or any described herein.

Alternatively, a hydrogen-containing or deuterium-containing soak gas (e.g., H₂, D₂, HD, or others) can be employed with plasma (e.g., in situ plasma developed within the chamber or remote plasma that is delivered to the chamber). Plasma conditions can be any described herein. In one instance, the temperature for pretreatment can include from about 250° C. to 650° C. in the presence of plasma. Temperature can be increased, e.g., by use of thermal lamp heating, resistive heating (by way of the pedestal), LED based heating to provide temporary heating, and radiative heating to quickly heat the wafer.

Pretreatment can include the use of any type of activated hydrogen or activated deuterium. In one instance, plasma is employed with a hydrogen-containing reagent (e.g., H₂, a hydrogen-containing silane, such as SiH₄) to provide activated hydrogen. In another instance, plasma is employed with a deuterium-containing reagent (e.g., D₂, HD, a deuterium-containing silane, such as SiD₄) to provide activated deuterium. When plasma is employed, inert gases (e.g., He, Ar, N₂, etc.) may or may not be used. Plasma can include any described herein, including remote plasma. After pretreatment, the pretreated surface can be preserved by controlling the environment or storing the substrate under vacuum.

The hydrogen-containing reagent or deuterium-containing reagent can be provided by use of catalysts. Non-limiting catalysts useful for regenerating or generating hydrogen or deuterium can include platinum (Pt), iridium (Ir), palladium (Pd), rhodium (Rh), nickel (Ni), and combinations thereof.

Activated hydrogen or deuterium can be provided by use of plasma, and any hydrogen-containing or deuterium-containing reactant. Any activated hydrogen processes can be used, such as by employing catalytic hydrogen processes to generate hydrogen species within the chamber. In one instance, atomic hydrogen can be formed in the plasma, and then atomic hydrogen can be reacted with a catalyst to provide a lower-energy hydrogen species. As used herein, a “lower-energy hydrogen species” can include any species including a hydrogen atom that is lower in energy than unreacted atomic hydrogen. A non-limiting source for atomic hydrogen can include molecular hydrogen. Activated hydrogen can be formed in the presence of reducing reagents, such as hydrides, silanes (e.g., SiH₄), boranes, hydrazines, diborane, germane, phosphate, trimethyl aluminum (TMA or AlMe₃), which can be used to scavenge fluorine), and the like. Similarly, by replacing hydrogen with deuterium, activated deuterium can be formed.

In one embodiment, pretreatment include use of hydrogen (H₂), deuterium (D₂), hydrogen deuteride (HD), or a combination thereof in the presence of plasma, including remote plasma or in situ plasma. In some embodiments, remote plasma is employed. Optionally, H₂, D₂, HD, or a combination thereof is used in the presence of inert gas, helium, argon, and the like. In use, the plasma-generated radicals, plasma-generated metastables, or a combination thereof clean up the surface of the substrate.

In another embodiment, minimal amounts of a reducing reagent (e.g., any herein, such as silanes, SiH₄, and the like) can be introduced downstream of the plasma source (e.g., downstream of the remote plasma source). The reducing reagent, such as SiH₄, can be used alone or in conjunction with H₂, D₂, HD, or a combination thereof. Whereas high amounts of SiH₄ may result in deposition, minimal amounts of SiH₄ can result in etching of surfaces. Furthermore, SiH₄-based radicals generated in this way can be used in conjunction with hydrogen-containing or deuterium-containing radicals to clean surfaces. Non-limiting flow rates for reducing reagents include, for example, less than 1 sccm, less than 2 sccm, or from about 0.01-2 sccm (e.g., for SiH₄ per 300 mm wafer).

### Deposition Operations

Deposition operations can be conducted to provide heterolayers (e.g., heteroepitaxial layers) within a stack. In particular embodiments, to facilitate low temperature deposition conditions, plasma can be used to provide epitaxial growth of semiconductor layers or sacrificial layers. In some embodiments, low temperature processing conditions are desired to minimize diffusion of atoms between heterolayers. To enhance growth even at low temperature conditions, plasma can be used to provide ground state or excited radicals, metastables (e.g., higher energy long living states), charged species (ions), or other energetic species, which in turn can provide activated precursor species for deposition.

In some embodiments, plasma-based epitaxy includes the use of a remote plasma source that is separated from the epitaxy chamber or the use of an in situ plasma to generate a plasma within the epitaxy chamber. Plasma can be employed with or without an ion filter.

As further described herein, plasma can be used to provide various types of activated species. It should be noted that, in some embodiments, a reactive plasma may contain substantially no components that react with silicon, with germanium, or with both silicon and germanium. In one example, a reactive plasma may contain only hydrogen (e.g., H* or H₂), deuterium (e.g., D* or D₂), hydrogen deuteride (HD), an inert gas (e.g., He, Ar, He*, Ar*, etc.), or any combination thereof. In another example, a reactive plasma does not contain a nitrogen-containing species, a halogen-containing species, or an oxygen-containing species. In one embodiment, plasma can be used to activate the precursors, in which the activated precursor species can be delivered to the epitaxy chamber or formed within the epitaxy chamber. Such a process can be considered direct activation of the precursor.

Indirect activation can also be employed (e.g., without an ion filter). In one embodiment, plasma can be used to activate an inert gas (e.g., He or Ar) upstream of the precursor, and then the activated inert species can be combined with the precursor in the epitaxy chamber. In another embodiment, plasma can be used to activate hydrogen (H₂) upstream of the precursor, and then the activated hydrogen species can be combined with the precursor in the epitaxy chamber. In yet another embodiment, plasma can be used to activate deuterium (D₂) or hydrogen deuteride (HD) upstream of the precursor, and then the activated deuterium species can be combined with the precursor in the epitaxy chamber. Activation by way of plasma can occur within an excitation chamber (upstream of the deposition chamber) or within the deposition chamber (e.g., the epitaxy chamber).

Herein, any hydrogen-containing reagent can be adapted or exchanged to provide a deuterium-containing reagent. Without wishing to be limited by mechanism, in some non-limiting instances, D* radicals may recombine less than H* radicals or similar to H* radicals. Also without wishing to be limited by mechanism, in some non-limiting instances, D* radicals may provide an increased amount of certain desired energetic species within the plasma, as compared to H* radicals. In part, such an effect may be due to the larger collisional cross-section of D atoms, as compared to H atoms. Yet other benefits may be observed by providing deuterium-containing reagents during deposition. Thus, in any embodiment herein, a hydrogen-containing reagent, including a hydrogen-containing gas, may be supplemented with a deuterium-containing reagent or may be replaced with a deuterium-containing reagent during deposition.

Deposition of a semiconductor layer or a sacrificial layer can include any useful methodology, which can be plasma-enhanced. Such methodologies can include atomic layer deposition (ALD), plasma-enhanced ALD (PEALD), chemical vapor deposition (CVD), plasma-enhanced CVD (PECVD), or remote plasma CVD (RPCVD).

The plasma can be generated in any useful manner. A plasma source may be in situ or remote (e.g., upstream from a process chamber in which the substrate resides). Examples of in situ plasma sources include a capacitively coupled plasma (CCP) source, an inductively coupled plasma (ICP) source, a transformer coupled plasma (TCP) source, an electron cyclotron resonance (ECR) plasma source (e.g., in which magnetic fields are used to provide an alternating electric field, which increases the kinetic energy of electrons within the gas and provides ionizing plasma), surface wave plasma (SWP) source (e.g., in which circularly polarized high-gain antenna or linearly polarized arrays are used to provide surface wave plasma at microwave and millimeter wave bands, such as by using a radial line slot antenna), microwave plasma (MWP) source, ultraviolet (UV)-assisted plasma source, low energy plasma (LEP) source, low temperature plasma (LTP) source, or the like. Examples of remote plasma sources include a capacitively coupled plasma (CCP) source, a parallel plate CCP source (e.g., in which plasma species from parallel plate is transported through ion filter, and then the filtered species are delivered to the substrate), an ICP source, a TCP source, a surface wave plasma (SWP) source, a hollow cathode plasma source, microwave plasma (MWP) source, low energy plasma (LEP) source, low temperature plasma (LTP) source, or the like. Any of these may be employed with or without ion filtering.

Plasma may be ignited at a power per substrate area between about 0.2122 W/cm² and about 2.122 W/cm². For example, the power may range from about 150 W to 6000 W, or from about 600 W to 6000 W. Various frequencies may be used to generate plasma, e.g., depending on type of plasma source. For example, the frequency may be within a range of about 60 kHz to 100 MHz. In some implementations, a frequency may be in a microwave range, e.g., 700 MHz to 1000 GHz. Yet other non-limiting frequencies can include from about 60 kHz to 60 MHz or from about 100 MHz to microwave (e.g., 1 GHz to 1000 GHz). In some embodiments, frequencies include about 60 kHz, 100 kHz, 200 kHz, 400 kHz, 1200 kHz, 2 MHz, 13.5 MHz, 27 MHz, 40 MHz, or 60 MHz. In other embodiments, the plasma source can be a low energy plasma (LEP) source (e.g., a low energy in situ plasma source). In particular non-limiting embodiments, the LEP source provides a plasma having an energy from about 0.1 eV to 20 eV. In other embodiments, the plasma has a high density, e.g., a density of at least about 10¹⁰ cm⁻³ at the wafer surface.

In any implementation herein, the energetic species can be configured to have any useful density. In particular embodiments, the energetic species is characterized by a density of at least about 10⁸ cm⁻³, 10⁹ cm⁻³, 10¹⁰ cm³, 10¹¹ cm³, or 10¹² cm³, or more at the surface of the substrate. In some embodiments, the energetic species (e.g., radicals, metastables, and the like) is characterized by a density from about 108 cm⁻³ to 10¹³ cm³ at the surface of the substrate.

Deposition can include any useful process parameter ranges. Such parameters can include a pedestal temperature range (e.g., 250° C.-650° C.), chamber pressure range (e.g., within a range of about 0.1 Torr-10 Torr, optionally within a range of about 0.5 Torr-3 Torr), precursor flow rate (e.g., 1-100 sccm for SiH₄, 1-25 sccm for GeH₄ which may be about 10% H₂, or the like, per 300 mm wafer), inert gas/carrier gas flow rate (e.g., 100-2000 sccm per 300 mm wafer), plasma power (e.g., 500 W-6 kW per 300 mm wafer), plasma frequency (e.g., about 13.56 MHz, within a range of about 400-1000 kHz, or any other suitable plasma frequency), process gas composition (e.g., 2-100% H₂ in helium or argon, with a gas flow of about 2-25 slm), deposition rate (e.g., within a range of about 10 Angstroms per minute-500 Angstroms per minute), and the like.

As described above, deposition may occur by flowing a precursor into the chamber in which a substrate resides. For example, the precursors can be provided at any useful flow rates. In one embodiment, the flow rate of the precursor may be greater than 1 sccm, or greater than 10 sccm, or greater than 50 sccm, or greater than 100 sccm, or ever greater than 200 sccm; or from about 20 sccm to 300 sccm. In one example, SiH₄ may have a flow rate within a range of about 1-100 sccm. In another example, GeH₄ may have a flow rate within a range of about 1-25 sccm. As described above, carrier gases may be employed with precursors. The carrier gas can have any useful flow rates, such as from about 100 sccm to 2000 sccm. The precursor to carrier gas in the deposition chamber can have a volume ratio between 2000:1 to 1:1.

As described herein, alternating layers of a semiconductor layer (e.g., an Si layer) and a sacrificial layer (e.g., an SiGe layer) may be deposited. Deposition may occur at a rate of at least about 10 nanometers per minute (nm/min) or at least about 30 nm/min, such as 10 nm/min, 30 nm/min, 60 nm/min, or the like; or at a rate of about 10 nm/min to 60 nm/min; or at a rate of about 3 nm/min to 15 nm/min. In some implementations, chamber pressure may be maintained within a range of about 0.5 Torr-3 Torr.

In some instances, deposition can include the introduction of dopants. Non-limiting dopants include Group IV atoms, such as carbon (C), germanium (Ge), tin (Sn) and the like; Group III atoms, such as boron (B), aluminum (Al), gallium (Ga), indium (In), and the like; Group V atoms, such as nitrogen (N), phosphorus (P), arsenic (As), antimony (Sb), and the like. In some instances, dopants, such as carbon or boron may be useful in a SiGe layer or an interface between two layers to prevent diffusion of Ge from an SiGe layer to a Si layer. Dopants can be introduced by use of one or more dopant precursors, such as any described herein.

Deposition can also include the deposition of interfacial layer(s). Such an interfacial layer between the semiconductor layer and the sacrificial layer can prevent the diffusion of particular atoms (e.g., dopant atoms, such as the diffusion of Ge from an SiGe layer into a Si layer). In other embodiments, such an interfacial layer can be used to confine a concentration profile of a dopant, thereby enhancing etch selectivity for etch chemistries that are highly dependent on dopant concentration. In some embodiments, the interfacial layer can be epitaxially deposited (e.g., by using epitaxy).

Prior to deposition, the substrate may be optionally heated or treated with plasma.

During deposition, any exposed surface may be optionally heated or treated with plasma. In one embodiment, the interface between the first and second layers can be treated. In one instance, the substrate can be exposed to a plasma (e.g., any described herein), thereby providing a prepared surface between the first and second semiconductor layers. In another instance, deposition can include forming a first semiconductor layer by flowing a first precursor into the reaction chamber and toward the substrate in the presence of energetic species (e.g., radicals, metastables, and the like); exposing the first semiconductor layer to a plasma; and then forming a second semiconductor layer by flowing a second precursor and an optional third precursor into the reaction chamber and toward the substrate in the presence of energetic species (e.g., radicals, metastables, and the like).

In one instance, deposition can include a single cycle of delivering a silicon-containing precursor; optionally purging the chamber; delivering a germanium-containing precursor; optionally purging the chamber. Furthermore, deposition can include repeating the cycles for any number of times to obtain a stack of desired height. During deposition, temperature can be maintained from about 250° C. to 750° C., or from about 250° C. to 600° C. In some implementations, deposition at relatively lower temperatures (e.g., below about 650° C.) may allow a higher germanium concentration in deposited SiGe layers. A higher germanium concentration may allow for better etch selectivity when etching a sacrificial SiGe layer. Plasma can be provided during any portion of this cycle, such as during the delivering operation. Non-limiting RF power for plasma can be from about 300 W to 600 W, from about 600 W to 800 W, or from about 2 kW to 3 kW (e.g., in the case of remote plasma).

In addition to precursors, the environment adjacent the work piece (e.g., substrate) can include one or more energetic species, radical species, metastables, ions, or neutrals. An in situ plasma or remote plasma may include the one or more energetic species, radical species, metastables, ions, or neutrals, where the one or more energetic species, radical species, metastables, ions, or neutrals may interact with the precursors to activate the precursors. In some embodiments, the one or more radical species are preferably in a substantially low energy state. An example of such radical species includes hydrogen atom radicals. In some embodiments, as used herein, a substantially low energy state can include all, or substantially all, or a substantial fraction of the hydrogen atom radicals to be in the ground state, e.g., at least about 90% or 95% of the hydrogen atom radicals adjacent the work piece are in the ground state. In certain embodiments, source gas is provided in a carrier gas such as helium or argon. Hydrogen gas may be a source gas in various embodiments. As an example, hydrogen gas may be provided in a helium carrier at a concentration of about 4-25% hydrogen. Pressure, fraction of carrier gas such as helium, and other process conditions are chosen so that the hydrogen atoms encounter the substrate as radicals in a low energy state without recombining.

For any use herein, the energetic species can be generated with any useful source gas. In some implementations, plasma may be ignited using a source gas. The source gas may include a hydrogen-containing gas, a deuterium-containing gas, an oxygen-containing gas, a nitrogen-containing gas, or an inert gas, such as a helium-containing gas, an argon-containing gas, or other inert gas, as well as combinations thereof. In some embodiments, the source gas may be mixed with one or more additional gases to form a gas mixture. In some cases, the additional gases may include any of the aforementioned gases to form a gas mixture such as hydrogen (H₂) and oxygen (O₂), H₂ and nitrogen (N₂), and H₂ and ammonia (NH₃), among other possible gas mixtures. In some cases, the additional gases may include a carrier gas. Non-limiting examples of additional gases can include helium (He), neon (Ne), argon (Ar), krypton (Kr), xenon (Xe), hydrogen (H₂), and ammonia (NH₃). In some cases, the additional gases may include a co-reactant. Non-limiting examples of co-reactants include carbon dioxide (CO₂), carbon monoxide (CO), water (H₂O), methanol (CH₃OH), oxygen (O₂), ozone (O₃), nitrogen (N₂), nitrous oxide (N₂O), NH₃, methane (CH₄), ethane (C₂H₆), acetylene (C₂H₂), ethylene (C₂H₄), and diborane (B₂H₆). In some embodiments, co-reactants are supplied with the source gas at a flow rate that is less than a flow rate of the source gas.

Hydrogen gas may be supplied into a plasma source (e.g., remote plasma source) to generate hydrogen atom radicals or hydrogen radicals. Once generated, the hydrogen atom radicals may be in an excited energy state (e.g., an energy of at least 10.2 eV as a first excited state), a substantially low energy state hydrogen atom radical, or a ground state hydrogen atom radical. Similarly, different energy states for different atoms may be generated and employed. By controlling the energy state of the radical or metastables species, selective or unselective decomposition of the precursor can be controlled. In some implementations, process conditions may be provided so that excited hydrogen atom radicals lose energy or relax to form substantially low energy state or ground state hydrogen atom radicals. For example, a remote plasma source or associated components may be designed so that a residence time of hydrogen atom radicals diffusing from the remote plasma source to the substrate is greater than the energetic relaxation time of an excited hydrogen atom radical. In other implementations, process conditions may be provided so that the energy of the excited radicals can be retained. For example, a remote plasma source or associated components may be designed so that a residence time of hydrogen atom radicals diffusing from the remote plasma source to the substrate is shorter than the energetic relaxation time of an excited hydrogen atom radical. The energetic relaxation time for an excited hydrogen atom radical can be about equal to or less than about 1×10⁻³ seconds.

Apparatus features and process control features can be tested and tuned to produce a state in which a substantial fraction of the hydrogen atom radicals are in aa desired energy state (e.g., excited energy state, substantially low energy state, or ground state). For example, an apparatus may be operated and tested for charged particles downstream of the plasma source; i.e., near the substrate. The process and apparatus may be tuned until substantially no charged species exist near the substrate.

The precursors are typically delivered with other species, notably carrier gas, in the environment adjacent to the substrate. In some implementations, the silicon-containing precursors (Si precursors), the germanium-containing precursors (Ge precursors), the silicon- and germanium-containing precursors (SiGe precursors), or combinations of any of these precursors are present with the energetic species, e.g., radical species, metastable species, other reactive species, and even neutral species or carrier gases. Upstream from the deposition reaction surface, the precursors can be mixed with an inert carrier gas. Example inert carrier gases include, but are not limited to, nitrogen (N₂), argon (Ar), and helium (He), deuterium (D₂), and hydrogen (H₂), as well as combinations thereof.

An example process for depositing the silicon-containing layer (Si layer) or the silicon-and germanium-containing layer (SiGe layer), as described herein, may include CVD operations. In some embodiments, the Si layer or the SiGe layer, as described herein may be deposited by thermal CVD. In some other embodiments, the Si layer or the SiGe layer may be deposited by a plasma-based CVD process, such as an in situ plasma-enhanced CVD (PECVD) process or remote plasma CVD (RPCVD) process. In a plasma-based CVD process, the substrate may be exposed to plasma. As used herein, a plasma may include plasma-activated species such as ions, radicals, metastables, neutrals, and the like generated from a source gas. One or more ions, radicals, metastables, or neutrals of the plasma may interact with the Si precursors, Ge precursors, or SiGe precursors in the environment adjacent to the substrate to deposit the Si layer or the SiGe layer. In some embodiments, the plasma includes radicals, such as hydrogen radicals, hydrogen-containing radicals, deuterium-containing radicals, as well as combinations thereof. For example, the hydrogen-containing radicals or deuterium-containing radicals may activate the silicon-containing precursors, the germanium-containing precursors, or the silicon- and germanium-containing precursors in the environment adjacent to the substrate to deposit the Si layer or the SiGe layer. In this way, plasma-generated, hydrogen-containing radicals or deuterium-containing radicals are employed to activate the precursor.

In other embodiments, the plasma itself can be employed to activate the precursor. In some instances, the plasma is a remote plasma source, and the activated precursor is then delivered to the substrate for deposition. In other instances, the plasma is generated in situ, thereby generating an activated precursor that can then be deposited on the surface of the substrate. The precursor may be activated in any useful manner, such as by hydrogen abstraction, selective breaking of bonds, or breaking down of precursors into smaller molecules, radicals, or other energetic species. Further conditions, reagents, methods, and processes are described in U.S. patent application Ser. No. 16/044,371 (published as U.S. Patent Publication No. 2018/0330945), filed Jul. 24, 2018, and International Publication No. WO 2020/023378, each of which is titled “Remote plasma based deposition of silicon carbide films using silicon-containing and carbon-containing precursors,” which are herein incorporated by reference in their entireties.

In yet other embodiments, the plasma includes metastables, such as helium-containing metastables or argon-containing metastables. For example, the metastables may activate the Si precursors, Ge precursors, SiGe precursors, or a combination thereof in the environment adjacent to the substrate to deposit the Si layers, SiGe layers, or both types of layers. Such metastables can be generated remotely and then transported downstream to the chamber housing the substrate.

One example of a process for depositing the Si layer or SiGe layer, as described herein, may include the following operations. Any deposition processes may be implemented to provide semiconductor layers. In one instance and without limitation, the Si layer or SiGe layer may be deposited by ALD. ALD is a technique that deposits thin layers of material using sequential self-limiting reactions. Typically, an ALD cycle includes operations to deliver and adsorb at least one reactant to the substrate surface, and then react the adsorbed reactant with one or more reactants to form the partial layer of film. As an example, a silicon germanium deposition cycle may include the following operations: (i) delivery/adsorption of a silicon-containing precursor (Si precursor) with an optional plasma, (ii) purging of the Si precursor from the chamber, (iii) delivery of a Si precursor and a germanium-containing precursor (Ge precursor) with an optional plasma, and (iv) purging of the Si precursor, Ge precursor, other gas, plasma, or combinations thereof from the chamber.

Each ALD cycle can be used to form a partial layer (e.g., a partial first semiconductor layer or a partial second semiconductor layer), and then each ALD cycle can be repeated an m number of times to form an entire layer (e.g., a first semiconductor layer or a second semiconductor layer). At least about two ALD cycles or more may be included in disclosed embodiments to deposit a desired layer thickness. For example, between about 2 and about 50 cycles may be performed, or between about 2 and about 30 cycles, or between about 2 and about 20 cycles, or between about 2 and about 10 cycles. In other embodiments, m is from 1 to 100 (e.g., from 2 to 100, 3 to 100, 4 to 100, 5 to 100, 6 to 100, 7 to 100, 8 to 100, 9 to 100, 10 to 100, 2 to 50, 3 to 50, 4 to 50, 5 to 50, 6 to 50, 7 to 50, 8 to 50, 9 to 50, 10 to 50, 2 to 30, 3 to 30, 4 to 30, 5 to 30, 2 to 20, 3 to 20, 4 to 20, 5 to 20, and the like). To deposit an n number of layers, each ALD cycle is repeated an m number of time to form a single layer, and then each n^{th} layer includes an m number of ALD cycles, thus resulting in an m×n number of cycles being performed to deposit such layers.

Unlike a chemical vapor deposition (CVD) technique, ALD processes use surface-mediated deposition reactions to deposit films on a layer-by-layer basis. In one example of an ALD process, a substrate surface that includes a population of surface active sites is exposed to a gas phase distribution of a first precursor, such as a silicon-containing precursor, in a dose provided to a chamber housing a substrate. Molecules of this first precursor are adsorbed onto the substrate surface, including chemisorbed species or physisorbed molecules of the first precursor. It should be understood that when the compound is adsorbed onto the substrate surface as described herein, the adsorbed layer may include the compound as well as derivatives of the compound. For example, an adsorbed layer of a silicon-containing precursor may include the silicon-containing precursor as well as derivatives of the silicon-containing precursor. After a first precursor dose, the chamber is then evacuated to remove most or all of first precursor remaining in gas phase so that mostly or only the adsorbed species remain. In some implementations, the chamber may not be fully evacuated. For example, the chamber may be evacuated such that the partial pressure of the first precursor in gas phase is sufficiently low to mitigate a reaction. A second set of reactants, such as a silicon-containing precursor and a germanium-containing precursor, is introduced to the chamber so that some of these molecules react with the first precursor adsorbed on the surface. In some processes, the second set reacts immediately with the adsorbed first precursor. In other embodiments, the second set reacts only after a source of activation is applied temporally. In some embodiments, a plasma is ignited during the dose of the second set of reactants. In some cases, the plasma may be a remote plasma that includes radicals in a low energy state or excited energy state. Such radicals may include hydrogen radicals. Additionally or alternatively, such radicals may include hydrogen-containing radicals, deuterium-containing radicals, nitrogen-containing radicals, argon-containing metastables, helium-containing metastables, or the like. It should be noted that, in some embodiments, the radicals may not include those that react with Si, with Ge, or with Si and Ge. For example, in some implementations, the radicals may not include nitrogen-containing radicals, halogen-containing radicals, oxygen-containing radicals, or the like. These radicals, metastables, and the like may interact with the second set of reactants to form activated silicon-containing precursors (Si precursors), activated germanium-containing precursors (Ge precursors), or activated forms of both Si precursors and Ge precursors that react with the adsorbed first precursor. These radicals, metastables, and the like may alternatively or additionally interact with the adsorbed first precursor to activate the adsorbed first precursor. The chamber may then be evacuated again to remove unbound molecules from the second set. As described above, in some embodiments the chamber may not be completely evacuated. Additional ALD cycles may be used to build film thickness.

In certain embodiments, an ALD first precursor dose partially saturates the substrate surface. In some embodiments, the dose phase of an ALD cycle concludes before the precursor contacts the substrate to evenly saturate the surface. Typically, the precursor flow is turned off or diverted at this point, and only purge gas flows. By operating in this sub-saturation regime, the ALD process reduces the cycle time and increases throughput. However, because precursor adsorption is not saturation limited, the adsorbed precursor concentration may vary slightly across the substrate surface. Examples of ALD processes operating in the sub-saturation regime are provided in U.S. patent application Ser. No. 14/061,587 (now U.S. Pat. No. 9,355,839), filed Oct. 23, 2013, titled “Sub-saturated atomic layer deposition and conformal film deposition,” which is incorporated herein by reference in its entirety.

As described, in some implementations, the ALD methods include plasma activation. As described herein, the ALD methods and apparatuses described herein may be conformal film deposition (CFD) methods, which are described generally in U.S. patent application Ser. No. 13/084,399 (now U.S. Pat. No. 8,728,956), filed Apr. 11, 2011, and titled “Plasma activated conformal film deposition,” and in U.S. patent application Ser. No. 13/084,305 (published as U.S. Patent Publication No. 2011/0256734), filed Apr. 11, 2011, and titled “Silicon nitride films and methods,” which are herein incorporated by reference in their entireties.

In some embodiments, plasma may be used during deposition, such as during exposure of the Si precursor, Ge precursor, or SiGe precursor. Plasma energy may be provided to activate a reactant into energetic species, ions, radicals, metastables, and other activated species, which react with the adsorbed layer of a first precursor. In various embodiments, the plasma is an in situ plasma, such that the plasma is formed directly above the substrate surface in the chamber.

The in situ plasma may be ignited at a power per substrate area between about 0.2122 W/cm² and about 2.122 W/cm². For example, the power may range from about 150 W to about 6000 W, or from about 600 W to about 6000 W, or from about 800 W to about 4000 W, for a chamber processing four 300 mm wafers. For example, plasmas may be generated by applying a radio frequency (RF) field to a gas using two capacitively coupled plates. Ionization of the gas between plates by the RF field ignites the plasma, creating free electrons in the plasma discharge region. These electrons are accelerated by the RF field and may collide with gas phase reactant molecules. Collision of these electrons with reactant molecules may form radical species that participate in the deposition process. It will be appreciated that the RF field may be coupled via any suitable electrodes. In various embodiments, a high frequency plasma is used having a frequency of at least about 13.56 MHz, or at least about 27 MHz, or at least about 40 MHz, or at least about 60 MHz. In some embodiments, a microwave-based plasma may be used. Non-limiting examples of electrodes include process gas distribution showerheads and substrate support pedestals. It will be appreciated that plasmas may be formed by one or more suitable methods other than capacitive coupling of an RF field to a gas. In some embodiments, the plasma is a remote plasma, such that a reactant is ignited in a remote plasma generator upstream of the chamber, then delivered to the chamber where the substrate is housed. Further apparatuses and operations are described in U.S. Patent Application No. 63/261,533, filed Sep. 23, 2021, entitled “Remote plasma deposition with electrostatic clamping,” which is incorporated herein by reference in its entirety.

### Energetic Species

As described herein, an energetic species can be employed during any operation, including one or more preclean, pretreat, deposition, reactor clean, or reactor treat operations. An energetic species can include any species that is reactive with one or more components provided during a preclean, pretreat, deposition, reactor clean, or reactor treat operation. Such components can include a precursor, a reagent, a gas, a deposited layer, a substrate, a surface of the substrate, a chamber, a surface of the chamber, and the like.

Non-limiting examples of energetic species include radicals, metastables, ions, neutral species, plasma, photons, radiation (e.g., ultraviolet radiation), excited molecules, excited atoms, a reactive species (e.g., a reactive precursor, a reactive reagent, or a reactive gas), an activated species (e.g., an activated precursor, an activated reagent, or an activated gas), a catalytically activated species (e.g., a catalytically activated precursor, a catalytically activated reagent, or a catalytically activated gas), or others described herein. In one non-limiting embodiment, the metastable has an energy of about 0.01-1 eV. In another non-limiting embodiment, the ion has an energy of about 100-1000 eV. In yet another non-limiting embodiment, the energetic species has an energy of about 0.01-1000 eV. Any description herein related to radicals and metastables may, in some non-limiting instances, encompass any energetic species described herein.

The energetic species can be generated in any useful manner. Methodologies for generating an energetic species can occur in situ (within the chamber) or ex situ (outside of the chamber) with delivery of the energetic species into the chamber. In one embodiment, the energetic species can be generated by use of plasma, such as by use of a remote plasma source or an in situ plasma source. In another embodiment, the energetic species can be generated by not using plasma. In yet another embodiment, the energetic species can be generated by use of a plasma source (e.g., a remote plasma source or an in situ plasma source) and a non-plasma source (e.g., a catalyst source, a radiation source, and the like).

In another embodiment, the energetic species can be generated by use a catalyst. For example, a catalyst can be useful for regenerating or generating hydrogen or deuterium, as well as energetic species including hydrogen or deuterium. Non-limiting catalysts can include platinum (Pt), iridium (Ir), palladium (Pd), rhodium (Rh), nickel (Ni), and combinations thereof.

In yet another embodiment, energetic species can be generated by use of radiation, such as ultraviolet radiation. Radiation can be provided by any useful radiation source, including lamps, lasers, light emitting diodes (LEDs), and the like, including pulsed and continuous wave forms thereof.

In one embodiments, the energetic species includes an activated form of any reagent described herein. For instance, the energetic species can include an activated form of a precursor (e.g., the first precursor, the second precursor, or the optional third precursor). In one instance, precracking of the precursor can include use of any energy source or any energetic species to provide a more reactive form of the precursor. A precursor may be activated in any useful manner, such as by hydrogen abstraction, selective breaking of bonds, non-selective breaking of bonds, or breaking down of precursors into smaller molecules, radicals, or other energetic species. Any useful energy source can be used for precracking, such as providing a catalyst, a radiation source (e.g., a UV source), a plasma source (e.g., a remote plasma), and the like in the presence of the precursor. Precracking can occur within the chamber (e.g., in proximity to the substrate or away from the substrate) or outside of the chamber (and then delivered into the chamber).

### Precursors

Precursors can include those including a silicon atom (e.g., a silicon-containing precursor), a germanium atom (e.g., a germanium-containing precursor), or both (e.g., a silicon-and germanium-containing precursor). Combination of precursors can be employed during deposition. Any precursors herein having a hydrogen atom can include a deuterium atom or have its hydrogen atom be replaced with a deuterium atom.

Si-containing precursors can be employed to provide a Si-containing layer. In one embodiment, the Si-containing precursor is a silicon hydride (SiₐH_{b}), silicon hydrohalide (SiₐH_{b}X_{c}), and silicon halide (SiₐX_{b}), in which X is a halo, and each of a, b, and c is, independently, an integer from 1 to 20.

Non-limiting silicon hydride compounds (e.g., silanes or polysilanes) include SiₐH₂ₐ₊₂, wherein a is 1-8; or SiₐH₂ₐ, wherein a is 3-8. Examples of silicon hydride compounds include silane (SiH₄), disilane (Si₂H₆), trisilane (Si₃H₈), cyclotrisilane (Si₃H₆), tetrasilane (Si₄H₁₀), cyclotetrasilane (Si₄H₈), pentasilane (S₁₅H₁₂), cyclopentasilane (Si₅H₁₀), hexasilane (Si₆H₁₄), cyclohexasilane (Si₆H₁₂), heptasilane (Si₇H₁₆), cycloheptasilane (Si₇H₁₄), octasilane (S₁₅H₁₈), and the like.

Non-limiting silicon hydrohalide compounds include SiₐH_{b}X_{c}, wherein a is 1-8, b is 1-18, and c is 1-18. In some embodiments, b+c=2a+2. Examples of silicon hydrohalide compounds include monochlorosilane (MCS, SiH₃Cl), dichlorosilane (DCS, SiH₂Cl₂), trichlorosilane (TCS, SiHCl₃), 1,2-dichloro-disilane (Si₂H₄Cl₂), 1,2,3-trichlorosilane (Si₃H₅Cl₃), and the like.

Non-limiting silicon halide compounds (or halosilanes) include SiₐX₂ₐ₊₂, wherein a is 1-8; or SiₐX₂ₐ, wherein a is 3-8. Examples of silicon halide compounds include silicon tetrachloride (STC, SiCl₄), hexachlorodisilane (HCDS, Si₂Cl₆), octachlorotrisilane (OCTS, Si₃Cl₈), or a combination thereof.

Ge-containing precursors can be employed to provide a Ge-containing layer. Ge-containing precursors include a germanium hydride (GeₐH_{b}), germanium hydrohalide (GeₐH_{b}X_{c}), and germanium halide (GeₐX_{b}), in which X is a halo, and each of a, b, and c is, independently, an integer from 1 to 20.

Non-limiting germanium hydride compounds (e.g., germanes or polygermanes) include GeₐH₂ₐ₊₂, wherein a is 1-8; or GeₐH₂ₐ, wherein a is 3-8. Examples of germanium hydride compounds include germane (GeH₄), digermane (Ge₂H₆), trigermane (Ge₃H₈), tetragermane (Ge₄H₁₀), pentagermane (Ge₅H₁₂), and the like.

Non-limiting germanium hydrohalide compounds include GeₐH_{b}X_{c}, wherein a is 1-8, b is 1-18, and c is 1-18. In some embodiments, b+c=2a+2. Examples of germanium hydrohalide compounds include dichlorogermane (GeH₂Cl₂), trichlorogermane (GeHCl₃), and the like.

Non-limiting germanium halide compounds (or halogermanes) include GeₐX₂ₐ₊₂, wherein a is 1-8; or GeₐX₂ₐ, wherein a is 3-8. Examples of germanium halide compounds include germanium tetrachloride (GeCl₄), hexachlorodigermane (Ge₂Cl₆), or a combination thereof.

Precursors can include both Si and Ge atoms. In one instance, the precursor is a Si- and Ge-containing precursor, such as germylsilane (H₃Ge—SiH₃). In some embodiments, the Si- and Ge-containing precursor may comprise a Si—Ge-hydride precursor, such as GeₐH_{b}Si_{c}, wherein a is 1-8, b is 1-18, and c is 1-8. In particular embodiments, the precursor includes (H₃Ge)ₐSiH₄₋ₐ, wherein a=1-4, or (H₃Si)_{c}GeH_{4-c}, wherein c=1-4.

The precursors can be provided at any useful flow rates. In one embodiment, the flow rate of the precursor may be greater than 10 sccm, or greater than 50 sccm, or greater than 100 sccm, or ever greater than 200 sccm; or from about 20 sccm to 300 sccm. Carrier gases may be employed with precursors, in which carrier gases can include a hydrogen-containing reagent (e.g., H₂), a deuterium-containing reagent (e.g., D₂), an inert gas (e.g., Ar, N₂, or He), or combinations thereof. The carrier gas can have any useful flow rates, such as from about 0.01 sccm to 200 sccm. The precursor to carrier gas in the deposition chamber can have a volume ratio between 2000:1 to 1:1. Pressure during deposition for use with such precursors can be about 0.2 Torr to 0.6 Torr at a temperature of about 350° C. to 530° C.; or a pressure of about 300 Torr or less at a temperature of about 700° C. or less.

Precursors can be used in combination with a reducing reagent. Non-limiting reducing reagents can include H₂, BH₃, or B₂H₆.

In other embodiments, one or more precursors can be used in combination with dopant precursors to introduce one or more dopants into the layer. The dopants can include any atom, including a Group IV atom (e.g., carbon (C), silicon (Si), germanium (Ge), tin (Sn), and the like); Group III atom (e.g., boron (B), aluminum (Al), gallium (Ga), indium (In), thallium (Tl), or a combination thereof) or a Group V atom (e.g., nitrogen (N), phosphorous (P), arsenic (As), antimony (Sb), bismuth (Bi), or a combination thereof).

The dopant precursor can include a Group IV atom, a Group III atom, a Group V atom, or a combination thereof, with any useful ligand. In one embodiment, the dopant precursor includes ZₐR_{b}, in which Z is a Group IV atom, a Group III atom, a Group V atom, or a combination thereof; each R is, independently, a ligand; a is 1-8; and b is 2-18. Non-limiting examples of ligands (e.g., R) include, independently, H, halo, hydroxyl, optionally substituted aliphatic, optionally substituted alkyl, optionally substituted alkenyl, optionally substituted alkynyl, optionally substituted cycloalkyl, optionally substituted heteroaliphatic, optionally substituted alkoxy, optionally substituted acyl, optionally substituted aromatic, optionally substituted aryl, cyclopentadienyl, optionally substituted bis(trialkylsilyl)amino (e.g., —N(SiR¹R²R³)₂), optionally substituted alkanoyloxy (e.g., acetate), a diketonate (e.g., —OC(R¹)-Ak-(R²)CO—), a bidentate chelating dinitrogen (e.g., —N(R¹)-Ak-N(R¹)-), optionally substituted silyl, optionally substituted silyloxy, and the like. Yet other non-limiting examples of ligands (e.g., R) include H, methyl (-Me), ethyl (-Et), n-propyl (-nPr), iso-propyl (-iPr), n-butyl (-nBu), iso-butyl (-iBu), sec-butyl (-sBu), tert-butyl (-tBu), methoxy (-OMe), ethoxy (-OEt), n-propoxy (—O-nPr), iso-propoxy (—O-iPr), n-butoxy (—O-nBu), iso-butoxy (—O-iBu), sec-butoxy (—O-sBu), tert-butoxy (—O-tBu), dimethyl amino (—NMe₂), diethylamino (-NEt₂), methylethylamino (—NMeEt), and the like.

For any use herein, the C-containing precursor can include a hydrocarbon precursor or any precursor described herein having one or more organic ligands (e.g., ligands selected from the group of optionally substituted aliphatic, optionally substituted alkyl, optionally substituted alkenyl, optionally substituted alkynyl, optionally substituted heteroaliphatic, optionally substituted heteroalkyl, optionally substituted alkoxy, optionally substituted amino, and the like). A non-limiting hydrocarbon precursor includes those having formula CₓH_{y}, wherein x is an integer between 2 and 10, and y is an integer between 2 and 24, may be used. Examples include methane (CH₄), acetylene (C₂H₂), ethylene (C₂H₄), propylene (C₃H₆), butane (C₄H₁₀), cyclohexane (C₆H₁₂), benzene (C₆H₆), and toluene (C₇H₈).

For any use herein, the Ge-containing precursor can include a germanium hydride, a germanium hydrohalide, a germanium halide, an alkyl germane, or an alkoxy germane. Further examples include GeₐR₂ₐ₊₂, wherein a is 1-8; GeₐR₂ₐ, wherein a is 3-8; or GeR₄, in which each R is, independently, any ligand described herein. In some embodiments, the Ge-containing precursor is germane (GeH₄), tetramethylgermane (GeMe₄), tetraethylgermane (GeEt₄), tetra-n-butylgermane (Ge[nBu]₄), tetraethoxygermane (Ge[OEt]₄), tris(2,2,6,6-tetramethyl-3,5-heptanedionato)gallium (Ga[thd]₃, in which thd is 2,2,6,6-tetramethyl-3,5-heptanedionate), and the like.

For any use herein, the Sn-containing precursor can include a tin hydride, a tin hydrohalide, a tin halide, an alkyl tin, an alkoxy tin, or an amino tin. Further examples include SnₐR₂ₐ₊₂, wherein a is 1-8; SnₐR₂ₐ, wherein a is 3-8; or SnR₄, in which each R is, independently, any ligand described herein. In some embodiments, the Sn-containing precursor includes SnR or SnR₂ or SnR₄ or R₃SnSnR₃, wherein each R is, independently, H, halo, optionally substituted C₁₋₁₂ alkyl, optionally substituted C₁₋₁₂ alkoxy, optionally substituted amino (e.g., —NR¹R²), optionally substituted C₂₋₁₂ alkenyl, optionally substituted C₂₋₁₂ alkynyl, optionally substituted C₃₋₈ cycloalkyl, optionally substituted aryl, cyclopentadienyl, optionally substituted bis(trialkylsilyl)amino (e.g., —N(SiR¹R²R³)₂), optionally substituted alkanoyloxy (e.g., acetate), a diketonate (e.g., —OC(R¹)-Ak-(R²)CO—), or a bidentate chelating dinitrogen (e.g., —N(R¹)-Ak-N(R¹)-). In particular embodiments, each R¹, R², and R³ is, independently, H or C₁₋₁₂ alkyl (e.g., methyl, ethyl, isopropyl, t-butyl, or neopentyl); and Ak is optionally substituted C₁₋₆ alkylene. In particular embodiments, each R is, independently, halo, optionally substituted C₁₋₁₂ alkoxy, optionally substituted amino, optionally substituted aryl, cyclopentadienyl, or a diketonate. Non-limiting tin precursors include SnF₂, SnH₄, SnBr₄, SnCl₄, SnI₄, tetramethyl tin (SnMe₄), tetraethyl tin (SnEt₄), trimethyl tin chloride (SnMe₃Cl), dimethyl tin dichloride (SnMe₂Cl₂), methyl tin trichloride (SnMeCl₃), tetraallyltin, tetravinyl tin, hexaphenyl ditin (IV) (Ph₃Sn—SnPh₃, in which Ph is phenyl), dibutyldiphenyltin (SnBu₂Ph₂), trimethyl(phenyl) tin (SnMe₃Ph), trimethyl(phenylethynyl) tin, tricyclohexyl tin hydride, tributyl tin hydride (SnBu₃H), dibutyltin diacetate (SnBu₂(CH₃COO)₂), tin(II) acetylacetonate (Sn(acac)₂), SnBu₃(OEt), SnBu₂(OMe)₂, SnBu₃(OMe), Sn(t-BuO)₄, Sn(n-Bu)(t-BuO)₃, tetrakis(dimethylamino)tin (Sn(NMe₂)₄), tetrakis(ethylmethylamino)tin (Sn(NMeEt)₄), tetrakis(diethylamino)tin(IV) (Sn(NEt₂)₄), (dimethylamino)trimethyl tin(IV) (Sn(Me)₃(NMe₂), Sn(i-Pr)(NMe₂)₃, Sn(n-Bu)(NMe₂)₃, Sn(s-Bu)(NMe₂)₃, Sn(i-Bu)(NMe₂)₃, Sn(t-Bu)(NMe₂)₃, Sn(t-Bu)₂(NMe₂)₂, Sn(t-Bu)(NEt2)₃, Sn(tbba), Sn(II) (1,3-bis(1,1-dimethylethyl)-4,5-dimethyl-(4R,5R)-1,3,2-diazastannolidin-2-ylidene), or bis[bis(trimethylsilyl)amino]tin (Sn[N(SiMe₃)₂]₂).

For any use herein, the B-containing precursor can include a boron hydride, a boron hydrohalide, a boron halide, an alkyl borane, or an alkyl borate. Further examples include BₐRₐ₊₂, wherein a is 1-8; B₂R₄; B₂R₆; or BR₃, in which each R is, independently, any ligand described herein. In some embodiments, the B-containing precursor is borane (BH₃), diborane (B₂H₆), triborane (B₃H₇), boron tribromide (BBr₃), boron trichloride (BCl₃), boron trifluoride (BF₃), trimethylborane (BMe₃), triethylborane (BEt₃), triphenylborane (BPh₃), borate (B(OH)₃), trimethyl borate (B[OMe]₃), triethylborate (B[OEt]₃), triisopropyl borate (B[O-iPr]₃), tri-n-butyl borate (B[O-nBu]₃), tetrakis(dimethylamino)diboron (B₂[NMe₂]₄), and the like.

For any use herein, the Al-containing precursor can include an alkyl aluminum or an aluminum alkoxide. Further examples include AlₐRₐ₊₂, wherein a is 1-8; or AlR₃, in which each R is, independently, any ligand described herein. In some embodiments, the Al-containing precursor is trimethylaluminum (Al[Me]₃), triethylaluminum (AI[Et]₃), tri-i-butylaluminum (Al[iBu]3), dimethylaluminum i-propoxide (Me₂AlI[O-iPr]), triethyl(tri-sec-butoxy)dialuminum (Et₃Al₂[O-sBu]3), diethyl(tetra-sec-butoxy) dialuminum (Et₂Al₂[O-sBu]₄), tetraethyl(di-sec-butoxy)dialuminum (Et₄Al₂[O-sBu]₂). aluminum ethoxide (Al[OEt]₃), aluminum i-propoxide (Al[O-iPr]₃), aluminum s-butoxide (Al[O-sBu]₃), aluminum acetylacetonate (Al[CH₃COCHCOCH₃]₃ or Al[acac]3), tris(2,2,6,6-tetramethyl-3,5-heptanedionato)aluminum (Al[thd]₃, in which thd is 2,2,6,6-tetramethyl-3,5-heptanedionate), and the like.

For any use herein, the Ga-containing precursor can include an alkyl gallium or an amino gallium. Further examples include GaₐRₐ₊₂, wherein a is 1-8; or GaR₃, in which each R is, independently, any ligand described herein. In some embodiments, the Ga-containing precursor is trimethylgallium (Ga[Me]₃), triethylgallium (Ga[Et]₃), gallium acetylacetonate (Ga[CH₃COCHCOCH₃]₃ or Ga[acac]₃), bis(p-dimethylamino)tetrakis (dimethylamino)digallium (Ga₂[NMe₂]₆), and the like.

For any use herein, the In-containing precursor can include InR₃, wherein each R is, independently, any ligand described herein, such as halo, optionally substituted C₁₋₁₂ alkyl (e.g., methyl, ethyl, isopropyl, t-butyl, and neopentyl), or a diketonate (e.g., —OC(R⁴)-Ak-(R⁵)CO—, in which each R⁴ and R⁵ is, independently, H or C₁₋₁₂ alkyl). Non-limiting In-containing precursors include indium trichloride (InCl₃), trimethylindium (InMe₃), cyclopentadienylindium (InCp, in which Cp is cyclopentadienyl), indium acetylacetonate (In[acac]₃, in which acac is acetylacetonate), and the like.

For any use herein, the T1-containing precursor can include TlR, wherein each R is, independently, any ligand described herein. Non-limiting T1-containing precursors include thallium ethoxide (Tl[OEt]), cyclopentadienylthallium (Tl[Cp], in which Cp is cyclopentadienyl), thallium acetylacetonate (Tl[acac]), and the like.

For any use herein, N-containing precursors include any that has at least one N atom, for example, nitrogen gas (N₂), ammonia (NH₃), hydrazine (N₂H₄), nitric oxide (NO), nitrous oxide (N₂O), amines (e.g., amines bearing carbon) such as methylamine, dimethylamine, ethylmethylamine, ethylamine, isopropylamine, t-butylamine, di-t-butylamine, cyclopropylamine, sec-butylamine, cyclobutylamine, isoamylamine, 2-methylbutan-2-amine, trimethylamine, diisopropylamine, diethylisopropylamine, di-t-butylhydrazine, as well as aromatic containing amines such as anilines, pyridines, and benzylamines. Yet other N-containing precursors can include nitrile (e.g., acetonitrile), amides, N-containing heterocyclic compound, or amino alcohols (e.g., ethanolamine). Amines may be primary, secondary, tertiary, or quaternary (for example, tetraalkylammonium compounds). An N-containing precursor can contain heteroatoms other than N, for example, hydroxylamine, t-butyloxycarbonyl amine, and N-t-butyl hydroxylamine are N-containing precursors. In other embodiment, the N-containing precursor can include any precursor herein having one or more optionally substituted amino groups.

For any use herein, P-containing precursors include any that has at least one P atom, for example, phosphates, phosphines, phosphorous halides, organophosphorus compounds, and others. Non-limiting P-containing precursor include phosphine (PH₃), alkyl phosphates such as trimethyl phosphate (PO[OMe]₃) or triethyl phosphate (PO[OEt]₃), trimethyl phosphite (P[OMe]₃), tris(dimethylamino)phosphine (P[NMe₂]₃), phosphorous halides such as phosphorous trichloride (PCl₃), trismethylsilyl phosphine (P[SiMe₃]₃), and phosphorus oxychloride (POCl₃), and the like.

For any use herein, As-containing precursors include AsₐRₐ₊₂, wherein a is 1-8; or AsR₃, in which each R is, independently, any ligand described herein. Non-limiting As-containing precursors include arsenide, alkylarsine, alkoxyarsine, and aminoarsine chemical families, and include, but are not limited to, the following specific compounds: arsine (AsH₃), triethyl aresenate (ArO[OEt]₃), trimethylarsine (As[Me]₃), triethylarsine (As[Et]₃), triphenylarsine (As[Ph]₃, in which Ph is phenyl), triphenylarsine oxide (AsO[Ph]₃), tris(dimethylamino)arsine (As[NMe₂]₃), and As(OR)₃ where R is -Me, -Et, or other optionally substituted alkyl groups (including saturated and unsaturated alkyl groups), and other similar arsenic containing compounds.

For any use herein, the Sb-containing precursor can include SbR₃, wherein each R is, independently, any ligand described herein, including halo, optionally substituted C₁₋₁₂ alkyl (e.g., methyl, ethyl, isopropyl, t-butyl, and neopentyl), optionally substituted C₁₋₁₂ alkoxy, or optionally substituted amino (e.g., —NR¹R², in which each R¹ and R² is, independently, H or optionally substituted C₁₋₁₂ alkyl). Non-limiting antimony precursors include antimony chloride (SbCl₃), antimony ethoxide (Sb[OEt]₃), antimony n-butoxide (Sb[O-nBu]₃, and tris(dimethylamino)antimony (Sb[NMe₂]₃).

For any use herein, the Bi-containing precursor can include BiR₃, wherein each R is, independently, any ligand described herein, including halo, optionally substituted C₁₋₁₂ alkyl, mono-C₁₋₁₂ alkylamino (e.g., —NR¹H), di-C₁₋₁₂ alkylamino (e.g., —NR¹R²), optionally substituted aryl, optionally substituted bis(trialkylsilyl)amino (e.g., —N(SiR¹R²R³)₂), or a diketonate (e.g., —OC(R⁴)-Ak-(R⁵)CO—). In particular embodiments, each R¹, R², and R³ is, independently, C₁₋₁₂ alkyl (e.g., methyl, ethyl, isopropyl, t-butyl, or neopentyl); and each R⁴ and R⁵ is, independently, H or optionally substituted C₁₋₁₂ alkyl (e.g., methyl, ethyl, isopropyl, t-butyl, or neopentyl). Non-limiting bismuth precursors include bismuth chloride (BiCl₃), trimethylbismuth (BiMe₃), triphenyl bismuth (BiPh₃), tris(dimethylamino)bismuth (Bi[NMe₂]₃), Bi[N(SiMe₃)₂]₃, and tris(2,2,6,6-tetramethyl-3,5-heptanedionato)bismuth (Bi[thd]₃, in which thd is 2,2,6,6-tetramethyl-3,5-heptanedionate).

In yet other embodiments, one or more insulator or dielectric materials may be deposited. Non-limiting insulator precursors can include a silicon-containing precursor, a nitrogen-containing precursor (e.g., any described herein), an oxygen-containing precursor (e.g., oxygen, ozone, carbon monoxide, carbon dioxide, nitrous oxide, water, alkyl alcohols such as isopropanol, and the like), a carbon-containing precursor (e.g., any described herein), an organic silicon-containing precursor, an organic nitrogen-containing precursor, an organic oxygen-containing precursor, as well as any combination thereof.

Yet other non-limiting precursors include silanes, organosilanes, halosilanes, aminosilanes, alkoxysilanes, silanols, hydrocarbons, and the like, as well as any described herein. Other examples of silicon-containing precursors include SiR₄, wherein each R is, independently, any ligand described herein, including H, halo, hydroxyl, optionally substituted aliphatic, optionally substituted alkyl, optionally substituted alkenyl, optionally substituted alkynyl, optionally substituted amino, optionally substituted heteroaliphatic, optionally substituted aromatic, optionally substituted aryl, optionally substituted silyl, optionally substituted silyloxy, and the like.

For any use herein, silicon-containing precursors can include silanes (e.g., SiH₄), polysilanes (H₃Si—(SiH₂)ₙ—SiH₃) where n>1, organosilanes, halogenated silanes, aminosilanes, alkoxysilanes, and the like. Organosilanes such as methylsilane, ethylsilane, isopropylsilane, t-butylsilane, dimethylsilane, diethyl silane, di-t-butylsilane, trimethylsilane (SiHMe₃), tetramethylsilane (SiMe₄), allylsilane, sec-butyl silane, thexylsilane, isoamylsilane, t-butyldisilane, di-t-butyldisilane, and the like, may be used. Yet other types of organosilanes include monoalkylsilanes, dialkylsilanes, trialkylsilanes, and tetraalkylsilanes.

A halogenated silane contains at least one halogen group and may or may not contain hydrogens, carbon groups, or both hydrogens and carbon groups. Examples of halogenated silanes are iodosilanes, bromosilanes, chlorosilanes and fluorosilanes (e.g., SiF₄). Specific chlorosilanes are tetrachlorosilane (SiCl₄), trichlorosilane (HSiCl₃), dichlorosilane (H₂SiCl₂), monochlorosilane (ClSiH₃), chloroallylsilane, chloromethylsilane, dichloromethylsilane, chlorodimethylsilane, chloroethylsilane, t-butylchlorosilane, di-t-butylchlorosilane, chloroisopropylsilane, chloro-sec-butyl silane, t-butyldimethylchlorosilane, thexyldimethylchlorosilane, and the like.

An aminosilane includes at least one N atom bonded to a Si atom, but may also contain H, O, halogen, C atoms, or a combination thereof. Examples of aminosilanes are mono-, di-, tri-and tetra-aminosilane (H₃Si(NH₂), H₂Si(NH₂)₂, HSi(NH₂)₃ and Si(NH₂)₄, respectively), as well as substituted mono-, di-, tri- and tetra-aminosilanes, for example, t-butylaminosilane (SiH₃[NHtBu]), methylaminosilane, t-butylsilanamine, bis(t-butylamino)silane (SiH₂[NHtBu]₂ or BTBAS), t-butyl silylcarbamate, bis(dimethylamino)silane (SiH₂[NMe₂]₂), bis(dimethylamino)methylsilane (SiH[Me][NMe₂]₂), bis(dimethylamino)dimethylsilane (Si[Me]₂[NMe₂]₂), bis(dimethylamino)chlorosilane (SiHCl[NMe₂]₂), tris(dimethylamino) silane (SiH[NMe₂]₃), hexakis(ethylamino)disilane (Si₂[NHEt]₆), 2,2,4,4,6,6-hexamethylcyclotrisilazane ([Si(Me)₂N(H)]₃), tetrakis(ethylmethylamino)silane (Si[NEtMe]₄), and the like. A further example of an aminosilane is trisilylamine (N[SiH₃]₃) or tris(trimethylsilyl)amine (N[SiMe₃]₃).

An alkoxysilane includes at least one O atom bonded to a Si atom, but may also contain H, N, halogen, C atoms, or a combination thereof. Examples of alkoxysilanes are mono-, di-, tri-and tetra-alkoxysilanes (H₃Si(OR), H₂Si(OR)₂, HSi(OR)₃ and Si(OR)₄, respectively, in which each R can be, independently, optionally substituted alkyl or aryl), as well as substituted mono-, di-, tri-and tetra-alkoxysilanes, for example, trimethoxymethylsilane (MeSi[OMe]₃), (3-aminopropyl) trimethoxysilane (NH₂(CH₂)₃Si[OMe]₃), (3-aminopropyl)triethoxysilane (NH₂(CH₂)₃Si[OEt]₃), triethoxyvinylsilane (CH₂═CHSi[OEt]₃), triethoxyethylsilane (EtSi[OEt]₃), trimethoxyphenylsilane (PhSi[OMe]₃), isobutyltriethoxysilane (i-BuSi[OEt]₃), diacetoxydimethylsilane (Me₂Si(OCOCH₃)₂), and the like. Yet other examples include tetrabutoxysilane (Si[OtBu]₄), tetraethoxysilane (Si[OEt]₄), triethoxysilane (HSi[OEt]₃), tetramethoxysilane (Si[OMe]₄), and trimethoxysilane (HSi[OMe]₃).

A silanol includes at least one OH group bonded to a Si atom by way of the oxygen atom within the OH group, but may also contain H, N, halogen, C atoms, or a combination thereof. Examples of silanols include [HO]SiR₃, in which each R can be, independently, H, hydroxyl, optionally substituted aliphatic, optionally substituted heteroaliphatic, optionally substituted aromatic, optionally substituted amino, optionally substituted silyl, or optionally substituted silyloxy. Examples include tri-t-butoxysilanol ([HO]Si[OtBu]₃), and the like.

### Reactor Clean and Reactor Treat Operations

Further operations may be performed to provide a clean reactor prior to precleaning the surface of the substrate, pretreating the surface of the substrate, or depositing on the surface of the substrate. For instance, a reactor clean operation can be performed to remove contaminants from the walls of the reactor chamber. In another instance, a reactor clean operation can be performed to remove a film that is deposited on reactor surfaces. In another instance, a reactor treat operation can be performed to passivate a surface of the reactor or to scavenge or remove contaminants (e.g., halogens, such as fluorine) within the volume of the reactor chamber.

A reactor chamber may be cleaned during a chamber clean process to enhance deposition performance. For example, a reactor clean process may be used to remove contaminants contained on windows or walls of the chamber.

The reactor chamber may be cleaned using a photoexcited or plasma-activated cleaning reagent. Alternatively, the cleaning reagent may be provided from the remote plasma source. In one instance, a remote plasma source may be coupled to the reactor chamber. Alternatively, a TCP source itself may be used to activate the cleaning reagent. In particular embodiments, the cleaning reagent includes fluorine. Non-limiting cleaning reagents can be a halogen-containing reagent, such as any described herein, e.g., HCl, Cl₂, or fluorine-containing reagents (e.g., NF₃ or ClF₃). Yet other cleaning reagents can include any described herein for preclean operations for the substrate.

The reactor chamber may be treated using any useful reagent to scavenge, capture, or remove contaminants (e.g., halogens, such as fluorine). Non-limiting reagents can be a hydrogen-containing reagent, a deuterium-containing reagent, or a reducing reagent, such as any described herein, e.g., H₂, D₂, HD, SiH₄, GeH₄, and the like. Such reagents may optional be employed in the presence of plasma.

Herein, any hydrogen-containing reagent can be adapted or exchanged to provide a deuterium-containing reagent. In any embodiment herein, a hydrogen-containing reagent, including a hydrogen-containing gas, may be supplemented with a deuterium-containing reagent or may be replaced with a deuterium-containing reagent during a reactor clean operation or a reactor treat operation.

Reactor clean and reactor treat operations can be performed at any useful temperature. For instance, the pedestal can be maintained at a temperature from about 100° C. to 300° C. or even up to 650° C.; or the showerhead can be maintained at a temperature from about 18° C. to 200° C.; or the chamber wall can be maintained at a temperature from about 18° C. to 200° C. Cleaning can be optionally be performed at elevated temperatures (relative to deposition). In some embodiments, if desired, higher temperatures may be employed. For instance, the temperature during reactor clean or reactor treat operations can be a temperature of about 400° C. to 900° C.

Conditions for reactor treat operations can include use of hydrogen-containing plasma (e.g., H₂ plasma), deuterium-containing plasma (e.g., D₂ plasma), a silane soak (e.g., SiH₄ soak), a germane soak (e.g., GeH₄), a nitrogen-containing plasma (e.g., N₂ plasma; N₂ and H₂ plasma; NH₃ plasma; or ND₃ plasma), a borane soak (e.g., B₂H₆ soak), an oxygen-containing plasma (e.g., O₂ plasma or H₂O plasma), and combinations of any these. Such operations can include a CVD process or an ALD process. Optionally, a silicon-containing precursor (e.g., any described herein, such as a halosilane, aminosilane, and the like) can be employed.

In one embodiment, the reactor treat operation includes generating hydrogen-containing radicals and then using such radicals to activate a reducing reagent, such as SiH₄, within an environment of the reactor chamber. In one instance, the hydrogen-containing radicals are generated using a hydrogen source (e.g., H₂) in a remote plasma source positioned upstream of the reactor chamber, and the reducing reagent is introduced downstream of the remote plasma source. Such an operation can include, e.g., a CVD process that provides deposited silicon. The environment of the reactor chamber can include any surface, volume, region, or area through which a precursor can flow and be provided to a surface of the substrate.

In another embodiment, the reactor treat operation includes generating hydrogen-containing and nitrogen-containing radicals and then using such radicals to activate a reducing reagent, such as SiH₄, within an environment of the reactor chamber. In one instance, the hydrogen-containing and nitrogen-containing radicals are generated using a hydrogen source (e.g., H₂) and a nitrogen source (e.g., N₂) in a remote plasma source positioned upstream of the reaction chamber, and the reducing reagent is introduced downstream of the remote plasma source. In another instance, the hydrogen-containing and nitrogen-containing radicals are generated using a hydrogen- and nitrogen-containing source (e.g., NH₃). Such an operation can include, e.g., a CVD process that provides deposited silicon nitride.

In one embodiment, the reactor treat operation includes providing a silicon-containing precursor, such as a halosilane or an aminosilane, as described herein, within an environment of the reactor chamber; and then generating a plasma of a hydrogen-containing reactant and a nitrogen-containing reactant, which can react with the precursor. In one instance, the plasma is generated using a hydrogen source (e.g., H₂) and a nitrogen source (e.g., N₂ or NH₃). In another instance, the plasma is generated using a hydrogen- and nitrogen-containing source (e.g., NH₃). Such an operation can include, e.g., an ALD process that provides deposited silicon nitride, which can optionally employ remote plasma.

In one embodiment, the reactor treat operation includes providing a silicon-containing precursor, such as a halosilane or an aminosilane, as described herein, within an environment of the reactor chamber; and then generating a plasma of a nitrogen-containing reactant, which can react with the precursor. In one instance, the plasma is generated using a nitrogen source (e.g., N₂ or NH₃). Such an operation can include, e.g., an ALD process that provides deposited silicon nitride, which can optionally employ remote plasma.

In one embodiment, the reactor treat operation includes providing a silicon-containing precursor, such as a halosilane or an aminosilane, as described herein, within an environment of the reactor chamber; and then introducing an oxidant to react with the precursor. Examples of suitable oxidants include, but are not limited to, includes ozone, hydrogen peroxide, oxygen, water (steam), and alcohols, such as methanol, ethanol, and isopropanol. In certain embodiments, a remote plasma source may supply an activated oxidant species. Such an operation can include, e.g., an ALD process that provides deposited silicon oxide, which can optionally employ remote plasma.

In one embodiment, the reactor treat operation includes generating a plasma of an oxygen-containing reactant or an oxidant, within an environment of the reactor chamber. Examples of suitable oxygen-containing reactants and oxidants include, but are not limited to, includes ozone, hydrogen peroxide, oxygen, water (steam or water vapor), and alcohols, such as methanol, ethanol, and isopropanol. In one embodiment, the oxygen-containing reactant is 02, which can optionally be employed with H₂.

In one embodiment, the reactor treat operation includes providing a purge with a gas to react with halogens (e.g., fluorine) within an environment of the reactor chamber. Examples of suitable gas include, e.g., ambient air, air with moisture, and the like. Such a purge can result in converting reactive halogens, such as fluorine, into its acidic vapor form, which can then be pumped out of the reactor chamber.

Any of these operations can be conducted with an inert gas (e.g., Ar or He). Any of these operations can be conducted with plasma (e.g., remote plasma).

### Embodiments for Plasma-Based Epitaxy

The present disclosure encompasses non-limiting methods for plasma-based epitaxy, as well as apparatuses and systems to implement such methods. In particular embodiments, the method includes epitaxially depositing one or more Si layers, SiGe layers, or both types of layers in the presence of plasma. In some embodiments, the plasma is remote plasma. Without wishing to be limited by mechanism, use of plasma can allow for lower temperature deposition (e.g., a temperature of less than about 900° C., 800° C., 750° C., 700° C., 650° C., 600° C., 550° C., or 500° C.; or within a range of about 250° C. to 900° C., 250° C. to 650° C., 400° C. to 900° C., or 400° C. to 700° C.), thereby minimizing interdiffusion between the Si and SiGe epitaxial layers. In other non-limiting embodiments, lower temperature deposition (e.g., a temperature of less than about 900° C., 800° C., 750° C., 700° C., 650° C., 600° C., 550° C., or 500° C.; or within a range of about 250° C. to 900° C., 250° C. to 650° C., 400° C. to 900° C., or 400° C. to 700° C.) can provide a higher limit for the critical thickness (he), which in turn can allow for thicker stacks and thicker epitaxial layers.

### Embodiments for Defect-Free, Plasma-Based Epitaxy

The present disclosure encompasses non-limiting methods for defect-free, plasma-based epitaxy, as well as apparatuses and systems to implement such methods. In particular embodiments, the method includes epitaxially depositing one or more Si layers, SiGe layers, or both types of layers on a precleaned and pretreated surface (e.g., an oxide-free, hydrophobic surface). In other embodiments, the method includes a preclean operation to provide a precleaned surface (e.g., an oxide-free surface), a pretreat operation to provide a pretreated surface (e.g., a hydrophobic surface), and then a deposition operation to provide Si layers, SiGe layers, or both types of layers on the precleaned and pretreated surface.

Precleaning can include any processes described herein. In particular embodiments, the preclean operation provides a pristine surface by removing native oxide from the substrate. Other contaminants can be removed from the surface, such as particles, metals, ions, organics, and the like. The substrate acts as a template upon which Si layers and SiGe layers can be deposited. In turn, the crystallographic characteristics of the deposited Si and SiGe layers can be influenced by the underlying substrate. By providing a pristine surface as the template, a more uniform and defect-free layer can be deposited.

Pretreating can include any processes described herein. In particular embodiments, the pretreat operation provides a pretreated surface that is beneficial for epitaxial deposition. In particular embodiments, the pretreated surface (e.g., a hydrophobic surface) includes a hydrogenated surface, as characterized by H—Si— bonds with exposed H atoms or D-Si— bonds with exposed D atoms, in which exposed atoms can be available for surface reactions during epitaxial deposition. In other embodiments, the hydrophobic surface is characterized by the presence of at least one of Si—H, Si—D, and Si—F bonds. In yet other embodiments, the hydrophobic surface is characterized as having substantially all or at least 90% of the surface as presenting at least one of Si—H, Si—D, and Si—F bonds. In some embodiments, the hydrophobic surface is characterized as having at least 95% of the surface as presenting at least one of Si—H, Si—D, or Si—F bonds.

Deposition can include any processes described herein. In particular embodiments, the deposition operation can provide a vertical stack including a plurality of alternating Si layer and SiGe layers. In one embodiment, deposition including epitaxial deposition in the presence of plasma.

Embodiments for Low Temperature Processes within an Epitaxy Chamber

The present disclosure encompasses non-limiting methods for low temperature epitaxy, as well as apparatuses and systems to implement such methods. In particular embodiments, the method includes epitaxially depositing one or more Si layers, SiGe layers, or both types of layers on a pretreated surface (e.g., a hydrophobic surface) within an epitaxy chamber and then performing a reactor clean of the epitaxy chamber. In other embodiments, the method includes a pretreat operation to provide a pretreated surface (e.g., a hydrophobic surface), a deposition operation to provide Si layers, SiGe layers, or both types of layers on the pretreated surface, and a reactor clean operation to provide a clean chamber during pretreatment and deposition.

In particular, each of the pretreat, deposition, and reactor clean operations is performed within the epitaxy chamber. Each of the operations can be performed at a low temperature condition, such as from about 250° C. to about 900° C. or any ranges described herein. Without wishing to be limited by mechanism, by maintaining operations within this temperature range, the thermal budget can be minimized, while providing a vertical stack having minimal interdiffusion atoms between the Si and SiGe epitaxial layers. In other non-limiting embodiments, lower temperature deposition (e.g., a temperature of less than about 900° C., 800° C., 750° C., 700° C., 650° C., 600° C., 550° C., or 500° C.; or within a range of about 250° C. to 900° C., 250° C. to 650° C., 400° C. to 900° C., or 400° C. to 700° C.) can provide a higher limit for the critical thickness (he), which in turn can allow for thicker stacks having epitaxial layers.

Pretreating can include any processes described herein. In particular embodiments, the pretreat operation provides a hydrophobic surface that is beneficial for epitaxial deposition. In particular embodiments, the hydrophobic surface includes a hydrogenated surface, as characterized by H—Si— bonds with exposed H atoms or D-Si— bonds with exposed D atoms, in which exposed atoms can be available for surface reactions during epitaxial deposition. In other embodiments, the hydrophobic surface is characterized by the presence of at least one of Si—H, Si-D, and Si—F bonds.

Deposition can include any processes described herein. In particular embodiments, the deposition operation can provide a vertical stack including a plurality of alternating Si layer and SiGe layers. In one embodiment, deposition including epitaxial deposition in the presence of plasma.

Reactor clean can include any processes described herein. In particular embodiments, the reactor clean operation provides a clean epitaxy chamber for providing a controlled environment that is free of contaminants. For instance, during pretreatment, any contaminants within the chamber can foul the surface of the substrate, which in turn can influence the crystallographic characteristics of the deposited layer. In another instance, during deposition, contaminants may introduce defects within the epitaxial layer, as well as reduce deposition rate of the precursors. Thus, a reactor clean operation can be performed within the epitaxy chamber prior to introducing a substrate, thereby providing a clean epitaxy chamber for deposition. Alternatively, a reactor clean operation can be performed within the epitaxy chamber after removing the substrate, thereby providing a clean epitaxy chamber for use with a new batch.

### Embodiments for Providing Si/SiGe Vertical Stacks

The present disclosure encompasses non-limiting methods for providing vertical stacks, as well as apparatuses and systems to implement such methods. In particular embodiments, the method includes epitaxially depositing one or more Si layers, SiGe layers, or both types of layers on a precleaned and pretreated surface (e.g., an oxide-free, hydrophobic surface) within an epitaxy chamber and then performing a reactor clean of the epitaxy chamber.

In some embodiments, the method includes a preclean operation to provide a precleaned surface (e.g., an oxide-free surface), a pretreat operation to provide a pretreated surface (e.g., a hydrophobic surface), a deposition operation to provide Si layers, SiGe layers, or both types of layers on the precleaned and pretreated surface and within an epitaxy chamber, and a reactor clean operation to provide a clean epitaxy chamber during deposition. In other non-limiting embodiments, the pretreat operation is also performed within the epitaxy chamber. In yet other embodiments, the preclean operation is a wet process; and each of the pretreat, deposition, and reactor clean operations is a dry process.

Precleaning can include any processes described herein. In particular embodiments, the preclean operation provides a pristine surface by removing native oxide from the substrate. Other contaminants can be removed from the surface, such as particles, metals, ions, organics, and the like.

Pretreating can include any processes described herein. In particular embodiments, the pretreat operation provides a hydrophobic surface that is beneficial for epitaxial deposition. In particular embodiments, the hydrophobic surface includes a hydrogenated surface, as characterized by H—Si— bonds with exposed H atoms or D—Si— bonds with exposed D atoms, in which exposed atoms can be available for surface reactions during epitaxial deposition. In other embodiments, the hydrophobic surface is characterized by the presence of at least one of Si—H, Si— D, and Si—F bonds.

Deposition can include any processes described herein. In particular embodiments, the deposition operation can provide a vertical stack including a plurality of alternating Si layer and SiGe layers. In one embodiment, deposition including epitaxial deposition in the presence of plasma.

Reactor clean can include any processes described herein. In particular embodiments, the reactor clean operation provides a clean epitaxy chamber for providing a controlled environment that is free of contaminants for pretreatment, deposition, or both.

In particular embodiments, the combination of such operations can provide optimized conditions to provide a vertical stack. For instance and without limitation, an oxide-free substrate provides a crystalline template, and a hydrophobic surface thereon can promote epitaxial deposition of precursors. To provide an optimal environment for conducting plasma-based deposition reactions, the epitaxy chamber can be cleaned with a halogen-containing reactant and then purged prior to introducing a substrate within the epitaxy chamber. Finally, to achieve effective deposition rates without increasing the temperature, plasma-enhanced processes are employed during deposition.

### Embodiments for Plasma-Based Epitaxy on an Oxide-Free Surface

The present disclosure encompasses non-limiting methods for plasma-based epitaxy on an oxide-free surface, as well as apparatuses and systems to implement such methods. In particular embodiments, the method includes epitaxially depositing one or more Si layers, SiGe layers, or both types of layers on an oxide-free surface. In other embodiments, the method includes a preclean operation to provide an oxide-free surface, followed by a deposition operation to provide Si layers, SiGe layers, or both types of layers on the precleaned surface. In yet other embodiments, the method includes a preclean operation and a pretreat operation to provide the oxide-free surface.

In particular embodiments, use of an oxide-free surface can result in defect control during epitaxial deposition. Such defects to be minimized can include, for instance, stacking faults, microtwins, inversion boundaries, proper precleaning of the substrate.

Precleaning can include any processes described herein. In particular embodiments, the preclean operation provides a pristine surface by removing native oxide from the substrate. Other contaminants can be removed from the surface, such as particles, metals, ions, organics, and the like. In some instances, a pretreatment operation can be used to further remove contaminants from the substrate. Examples of pretreating processes and contaminants can be any described herein.

Deposition can include any processes described herein. In particular embodiments, the deposition operation can provide a vertical stack including a plurality of alternating Si layer and SiGe layers. In one embodiment, deposition including epitaxial deposition in the presence of plasma.

### Embodiments for Plasma-Based Epitaxy on a Pretreated Surface

The present disclosure encompasses non-limiting methods for plasma-based epitaxy on a pretreated surface (e.g., a hydrophobic surface), as well as apparatuses and systems to implement such methods. In particular embodiments, the method includes epitaxially depositing one or more Si layers, SiGe layers, or both types of layers on a pretreated surface (e.g., a hydrophobic surface).

In other embodiments, the method includes a preclean operation to provide a hydrophobic surface, followed by a deposition operation to provide Si layers, SiGe layers, or both types of layers on the pretreated surface.

Pretreating can include any processes described herein. In particular embodiments, the pretreat operation provides a pretreated surface or a hydrophobic surface that is beneficial for epitaxial deposition. In particular embodiments, the pretreated surface or the hydrophobic surface includes a hydrogenated surface, as characterized by H—Si— bonds with exposed H atoms or D—Si— bonds with exposed D atoms, in which exposed atoms can be available for surface reactions during epitaxial deposition. In other embodiments, the pretreated surface or the hydrophobic surface is characterized by the presence of at least one of Si—H, Si—D, and Si—F bonds. In particular embodiments, use of a pretreated surface or a hydrophobic surface can result in uniform, epitaxial deposition.

In some embodiments, pretreating can include use of hydrogen-containing vapor or hydrogen-containing plasma. Such pretreating can, in some instances, be performed after each layer is epitaxially deposited.

Deposition can include any processes described herein. In particular embodiments, the deposition operation can provide a vertical stack including a plurality of alternating Si layer and SiGe layers. In one embodiment, deposition including epitaxial deposition in the presence of plasma.

### Apparatuses and Systems

The methods herein can be implemented in any apparatus or system described herein. The apparatus or system can include any combination of chambers (e.g., one or more preclean chambers, pretreat chambers, epitaxy chambers, and transfer chambers to allow for transfer between chambers under vacuum or other controlled conditions), energy sources (e.g., a plasma source, an ultraviolet source, a microwave source, an infrared source, and the like), process gas inlets (e.g., fluidically connected to one or more chambers to allow for delivery of one or more reactants, precursors, carrier gases, and the like into the chamber), or outlets (e.g., fluidically connected to one or more chambers and optionally coupled to a vacuum to allow for evacuating or purging chambers).

In one instance, the apparatus includes an integrated tool having the following wafer sequence: load lock, degas, preclean, pretreat, deposition, optional post-treatment, and load lock. Deposition could occur within a single chamber or between multiple chambers to produce the desired film stack.

Any component of the apparatus or system can be formed of any useful material. Such components can include chambers, energy sources, inlets, outlets, flow lines, showerheads, chucks, pedestals, or others described herein. In one embodiment, the reaction chamber or the energy source includes quartz. For instance, the energy source can include a window or a dome formed from quartz or a dielectric material. In another instance, the chamber, inlets, or outlets include stainless steel. In yet another instance, the reaction chamber, the energy source, or any component within the reaction chamber (e.g., a showerhead), as well as portions of any of these components, can include a coating. Without wishing to be limited by mechanism, such a coating can be configured to withstand the preclean, pretreat, reactor clean, or reactor treat operations described herein. Non-limiting examples of such coatings (e.g., an in situ coating) can include an inert coating, a fluorinated coating, a ceramic, a metal, an oxide (e.g., a metal oxide or a rare earth oxide, including aluminum oxide, calcium oxide, cerium oxide, erbium aluminum oxide, erbium oxide, gadolinium oxide, hafnium oxide, indium oxide, indium tin oxide, lanthanum oxide, magnesium oxide, samarium oxide, scandium oxide, tantalum oxide, tin oxide, yttrium aluminum oxide, yttrium fluoride oxide, yttrium oxide, zirconium oxide, and the like), a halide (e.g., aluminum fluoride, yttrium fluoride, yttrium fluoride oxide, and the like), a nitride (e.g., aluminum nitride, titanium nitride, and the like), a silicate (e.g., erbium silicate, gadolinium silicate, iridium silicate, lanthanum silicate, rhodium silicate, samarium silicate, scandium silicate, tantalum silicate, yttrium silicate, and the like, including monosilicate and disilicate forms of any of these), a carbide (e.g., silicon carbide, titanium carbide, tantalum carbide, and the like), and the like, as well as combinations thereof.

Each chamber can include a pedestal or a chuck for holding a substrate. In some implementations, a substrate may be heated using the pedestal. In some implementations, a chuck may hold the substrate, and heat may be provided externally, e.g., using an infrared (IR) or light emitting diode (LED) lamp. Further description of chucks, including electrostatic chucks, and apparatuses are described in U.S. Patent Publication No. 2018/0350649, entitled “Electrostatic chuck for use in semiconductor processing,” which is incorporated herein by reference in its entirety and for all purposes.

The chamber can be configured for performing a particular operation. For instance, a preclean chamber can be configured to deliver reactants, process conditions, and the like for precleaning the substrate to provide a precleaned surface (e.g., an oxide-free surface). For instance, to implement a preclean operation that employs fluorine-containing plasma, the preclean chamber can include one or more process gas inlets coupled to one or more fluorine-containing reactant sources and a plasma source, either within the chamber or fluidically coupled to the chamber. In another instance, to implement a pretreat operation that employs hydrogen-containing plasma, the pretreat chamber can include one or more process gas inlets coupled to one or more hydrogen-containing reactant sources and a plasma source, either within the chamber or fluidically coupled to the chamber. In yet another instance, to implement a deposition operation that employs plasma-based epitaxy, the epitaxy chamber can include one or more process gas inlets coupled to one or more silicon-containing precursor sources, one or more process gas inlets coupled to one or more germanium-containing precursor sources, and a plasma source, either within the chamber or fluidically coupled to the chamber.

The present disclosure encompasses modification to any chambers, apparatuses, systems, or other components that are described herein. For instance, if plasma is not required, then the plasma source may be omitted. If a further carrier gas or inert gas is useful to deliver with a reactant or a precursor into a chamber, then one or more process gas inlets can be connected to the chamber for delivery of such carrier or inert gases. To implement purge steps, a vacuum can be connected to the chamber by way of an outlet.

Any useful combination and arrangement of ports, inlets, and outlets can be employed to deliver reactants, precursors, and gases. For instance, injector ports may be arrayed above or around the pedestal holding the substrate. In order to avoid the center-to-edge uniformity issues, asymmetric biasing of the individual injector ports can be used. One example of asymmetric biasing may include using different flow rates for the individual injector ports or using different precursors or gases within the individual injector ports. Furthermore, controller(s) can be used to control such components and to implement any methods, processes, or process conditions herein.

Rapid switching may be employed. For instance, rapid switching can include any useful time period for delivering one or more reactants, process gases, carrier gases, precursors, and the like to a chamber or a module. In one non-limiting instance, rapid switching includes a transition period (between two different operations or substeps within a method or process; between switching from one gas to another gas; or between exchanging one reactant for another reactant) of from about sub-second (e.g., about 10 milliseconds (ms)) to 20 seconds (s) (e.g., less than 1 s, less than about 200 ms, less than 100 ms, less than 50 ms, or less; or from about 10 ms to 20 s, 10 ms to 10 s, 10 ms to 5 s, 10 ms to 1 s, 20 ms to 20 s, 20 ms to 10 s, 20 ms to 5 s, 20 ms to 1 s, 50 ms to 20 s, 50 ms to 10 s, 50 ms to 5 s, 50 ms to 1 s, and ranges therebetween). Such rapid switching can include the use of gas distribution systems with fast gas switching capabilities, multiple flow zones with independent flow control sections, fast switching valves (e.g., ALD valves), low volume plenums, low volume chambers or reactors, use of a chamber filler, minimized plasma confinement zones, shower plates having high aspect ratio gas holes, diversion by way of by-pass lines (e.g., in which a by-pass line is fluidly coupled to a vacuum), early line charges or accounting for line charge delay, short plasma strikes, and the like, as well as combinations thereof.

Additional processing, operations, apparatuses, and systems to facilitate rapid switching are generally described in U.S. Pat. No. 10,094,018, entitled “Dynamic precursor dosing for atomic layer deposition”; U.S. Pat. No. 9,934,979, entitled “Gas distribution showerhead for inductively coupled plasma etch reactor”; U.S. Pat. No. 9,679,751, entitled “Chamber filler kit for plasma etch chamber useful for fast gas switching”; U.S. Pat. No. 9,011,631, entitled “Rapid and uniform gas switching for aplasma etch process”; U.S. Pat. No. 8,728,956, entitled “Plasma activated conformal film deposition”; U.S. Pat. No. 8,728,955, “Method of plasma activated deposition of a conformal film on a substrate surface”; U.S. Pat. No. 8,673,785, entitled “Gas distribution system having fast gas switching capabilities”; U.S. Pat. No. 8,343,876, entitled “Fast gas switching plasma processing apparatus”; U.S. Pat. No. 8,088,248, entitled “Gas switching section including valves having different flow coefficients for gas distribution system”; U.S. Pat. No. 7,708,859, entitled “Gas distribution system having fast gas switching capabilities”; U.S. Pat. No. 7,459,100, entitled “Methods and apparatus for sequentially alternating among plasma processes in order to optimize a substrate”; and U.S. Patent Publication No. 2007/0066038, entitled “Fast gas switching plasma processing apparatus”, each of which is herein incorporated by reference in its entirety.

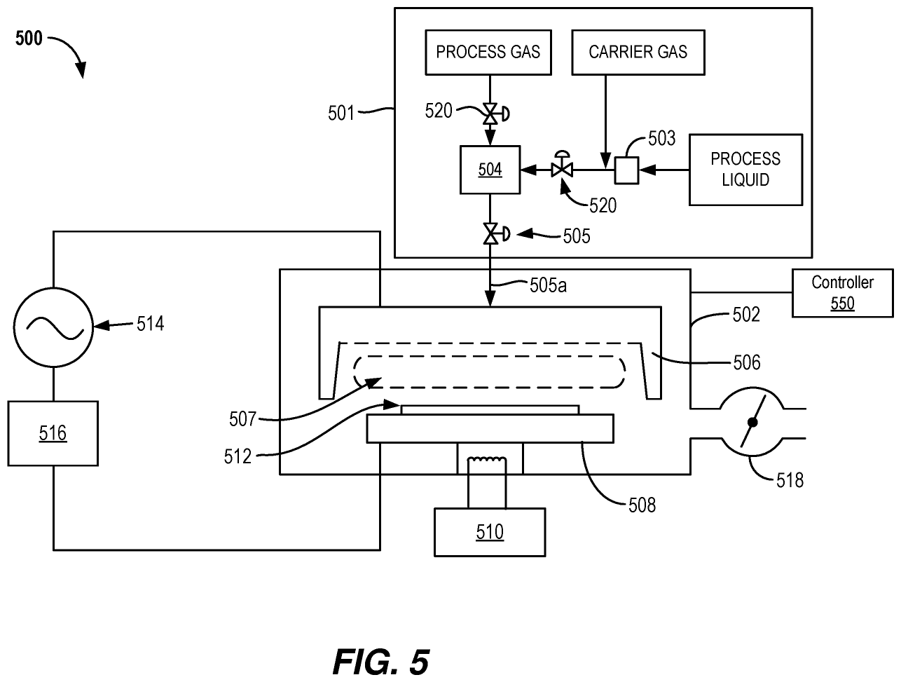

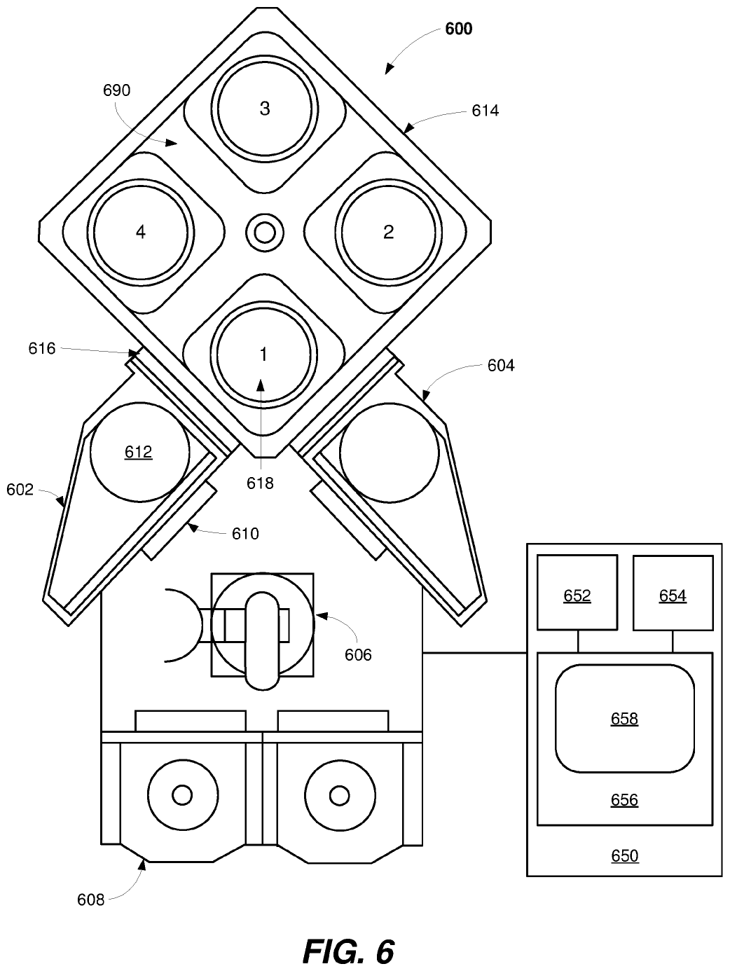

FIG. 5 depicts a schematic illustration of an embodiment of an atomic layer deposition (ALD) or chemical vapor deposition (CVD) process station 500 having a process chamber body 502 for maintaining a low-pressure environment. A plurality of process stations 500 may be included in a common low pressure process tool environment. For example, FIG. 6 depicts an embodiment of a multi-station processing tool 600. In some embodiments, one or more hardware parameters of process station 500 including those discussed in detail below may be adjusted programmatically by one or more computer controllers 550. Details for controllers are described herein. For instance, controller 550 may include any one or more characteristic described below with respect to system controller 650.

FIG. 5 schematically shows an embodiment of a process station 500 that may be used to deposit material using atomic layer deposition (ALD) or chemical vapor deposition (CVD), either of which may be plasma enhanced. For simplicity, the process station 500 is depicted as a standalone process station having a process chamber body 502 for maintaining a low-pressure environment. However, it will be appreciated that a plurality of process stations 500 may be included in a common process tool environment. Further, it will be appreciated that, in some embodiments, one or more hardware parameters of process station 500, including those discussed in detail below, may be adjusted programmatically by one or more computer controllers.

Process station 500 fluidly communicates with reactant delivery system 501 for delivering process gases to a distribution showerhead 506. Reactant delivery system 501 includes a mixing vessel 504 (which is optional) for blending, conditioning, or blending and conditioning process gases for delivery to showerhead 506. One or more mixing vessel inlet valves 520 may control introduction of process gases to mixing vessel 504. Similarly, a showerhead inlet valve 505 may control introduction of process gasses to the showerhead 506 by way of a gas inlet 505a.

Some reactants (e.g., any precursor herein) may be stored in liquid form prior to vaporization at and subsequent delivery to the process station. For example, the embodiment of FIG. 5 includes a vaporization point 503 for vaporizing liquid reactant to be supplied to mixing vessel 504. In some embodiments, vaporization point 503 may be a heated vaporizer. The reactant vapor produced from such vaporizers may condense in downstream delivery piping. Exposure of incompatible gases to the condensed reactant may create small particles. These small particles may clog piping, impede valve operation, contaminate substrates, etc. Some approaches to addressing these issues involve sweeping or evacuating the delivery piping to remove residual reactant. However, sweeping the delivery piping may increase process station cycle time, degrading process station throughput. Thus, in some embodiments, delivery piping downstream of vaporization point 503 may be heat traced. In some examples, mixing vessel 504 may also be heat traced. In one non-limiting example, piping downstream of vaporization point 503 has an increasing temperature profile extending from approximately 100° C. to approximately 150° C. or higher (e.g., any temperature or ranges described herein) at mixing vessel 504.

In some embodiments, reactant liquid may be vaporized at a liquid injector. For example, a liquid injector may inject pulses of a liquid reactant into a carrier gas stream upstream of the mixing vessel. In one scenario, a liquid injector may vaporize reactant by flashing the liquid from a higher pressure to a lower pressure. In another scenario, a liquid injector may atomize the liquid into dispersed microdroplets that are subsequently vaporized in a heated delivery pipe. It will be appreciated that smaller droplets may vaporize faster than larger droplets, reducing a delay between liquid injection and complete vaporization. Faster vaporization may reduce a length of piping downstream from vaporization point 503. In one scenario, a liquid injector may be mounted directly to mixing vessel 504. In another scenario, a liquid injector may be mounted directly to showerhead 506.

In some embodiments, a liquid flow controller upstream of vaporization point 503 may be provided for controlling a mass flow of liquid for vaporization and delivery to process station 500. For example, the liquid flow controller (LFC) may include a thermal mass flow meter (MFM) located downstream of the LFC or a vaporizer downstream of the LFC. A plunger valve of the LFC may then be adjusted responsive to feedback control signals provided by a proportional-integral-derivative (PID) controller in electrical communication with the MFM. However, it may take one second or more to stabilize liquid flow using feedback control. This may extend a time for dosing a liquid reactant. Thus, in some embodiments, the LFC may be dynamically switched between a feedback control mode and a direct control mode. In some embodiments, the LFC may be dynamically switched from a feedback control mode to a direct control mode by disabling a sense tube of the LFC and the PID controller. In one embodiment, feedback control mode includes using a system measurement obtained from the flow process to determine the action of the PID controller. For instance, a system measurement can include a flow measurement or a pressure measurement from a sensor of the LFC, and such a system measurement can be used to determine an action of the PID controller. In another embodiment, direct control mode does not use such a system measurement. For instance, rather than a system measurement, direct control mode can include the use of a discrete setpoint to determine an action of the PID controller.

Showerhead 506 distributes process gases toward substrate 512. In the embodiment shown in FIG. 5, substrate 512 is located beneath showerhead 506, and is shown resting on a pedestal 508. It will be appreciated that showerhead 506 may have any suitable shape, and may have any suitable number and arrangement of ports for distributing processes gases to substrate 512.

In some embodiments, a microvolume 507 is located beneath showerhead 506. Performing an ALD or CVD process in a microvolume rather than in the entire volume of a process station may reduce reactant exposure and sweep times, may reduce times for altering process conditions (e.g., pressure, temperature, etc.), may limit an exposure of process station robotics to process gases, etc. Example microvolume sizes include, but are not limited to, volumes between 0.1 liter and 2 liters. This microvolume also impacts productivity throughput. While deposition rate per cycle drops, the cycle time also simultaneously reduces. In certain cases, the effect of the latter is dramatic enough to improve overall throughput of the module for a given target thickness of film.

In some embodiments, pedestal 508 may be raised or lowered to expose substrate 512 to microvolume 507 or to vary a volume of microvolume 507. For example, in a substrate transfer phase, pedestal 508 may be lowered to allow substrate 512 to be loaded onto pedestal 508. During a deposition process phase, pedestal 508 may be raised to position substrate 512 within microvolume 507. In some embodiments, microvolume 507 may completely enclose substrate 512 as well as a portion of pedestal 508 to create a region of high flow impedance during a deposition process. Alternatively, a susceptor or a chuck can be used to hold a substrate, and heat can be externally provided (e.g., by use of a heat source, such as IR-based lamps, LED-based lamps, and the like).

Optionally, pedestal 508 may be lowered or raised during portions the deposition process to modulate process pressure, reactant concentration, etc., within microvolume 507. In one scenario where process chamber body 502 remains at a base pressure during the deposition process, lowering pedestal 508 may allow microvolume 507 to be evacuated. Example ratios of microvolume to process chamber volume include, but are not limited to, volume ratios between 1:500 and 1:10. It will be appreciated that, in some embodiments, pedestal height may be adjusted programmatically by a suitable computer controller.

In another scenario, adjusting a height of pedestal 508 may allow a plasma density to be varied during plasma activation or treatment cycles included in the deposition process. At the conclusion of the deposition process phase, pedestal 508 may be lowered during another substrate transfer phase to allow removal of substrate 512 from pedestal 508.

While the example microvolume variations described herein refer to a height-adjustable pedestal, it will be appreciated that, in some embodiments, a position of showerhead 506 may be adjusted relative to pedestal 508 to vary a volume of microvolume 507. Further, it will be appreciated that a vertical position of pedestal 508 or showerhead 506 may be varied by any suitable mechanism within the scope of the present disclosure. In some embodiments, pedestal 508 may include a rotational axis for rotating an orientation of substrate 512. It will be appreciated that, in some embodiments, one or more of these example adjustments may be performed programmatically by one or more suitable computer controllers.

Returning to the embodiment shown in FIG. 5, showerhead 506 and pedestal 508 electrically communicate with RF power supply 514 and matching network 516 for powering a plasma. In some embodiments, the plasma energy may be controlled by controlling one or more of a process station pressure, a gas concentration, an RF source power, an RF source frequency, and a plasma power pulse timing. For example, RF power supply 514 and matching network 516 may be operated at any suitable power to form a plasma having a desired composition of energetic species, radical species, metastable species, or other activated species. Examples of suitable powers are included above. Likewise, RF power supply 514 may provide RF power of any suitable frequency. In some embodiments, RF power supply 514 may be configured to control high- and low-frequency RF power sources independently of one another. Example low-frequency RF frequencies may include, but are not limited to, frequencies between 0 kHz and 1000 kHz. Example high-frequency RF frequencies may include, but are not limited to, frequencies between 1.8 MHz and 2.45 GHz, or greater than about 13.56 MHz, or greater than 27 MHz, or greater than 180 MHz, or greater than 60 MHz. It will be appreciated that any suitable parameters may be modulated discretely or continuously to provide plasma energy for the surface reactions. In one non-limiting example, the plasma power may be intermittently pulsed to reduce ion bombardment with the substrate surface relative to continuously powered plasmas.

In some embodiments, the plasma may be monitored in-situ by one or more plasma monitors. In one scenario, plasma power may be monitored by one or more voltage, current sensors (e.g., voltage-current (VI) probes). In another scenario, plasma density or process gas concentration may be measured by one or more optical emission spectroscopy sensors (OES). In some embodiments, one or more plasma parameters may be programmatically adjusted based on measurements from such in-situ plasma monitors. For example, an OES sensor may be used in a feedback loop for providing programmatic control of plasma power. It will be appreciated that, in some embodiments, other monitors may be used to monitor the plasma and other process characteristics. Such monitors may include, but are not limited to, infrared (IR) monitors, acoustic monitors, and pressure transducers.

In some embodiments, the plasma may be controlled via input/output control (IOC) sequencing instructions. In one example, the instructions for setting plasma conditions for a plasma process phase may be included in a corresponding plasma activation recipe phase of a deposition process recipe. In some cases, process recipe phases may be sequentially arranged, so that all instructions for a deposition process phase are executed concurrently with that process phase. In some embodiments, instructions for setting one or more plasma parameters may be included in a recipe phase preceding a plasma process phase. For example, a first recipe phase may include instructions for setting a flow rate of an inert gas, a reactant gas, or both; instructions for setting a plasma generator to a power set point; and time delay instructions for the first recipe phase. A second, subsequent recipe phase may include instructions for enabling the plasma generator and time delay instructions for the second recipe phase. A third recipe phase may include instructions for disabling the plasma generator and time delay instructions for the third recipe phase. It will be appreciated that these recipe phases may be further subdivided or iterated in any suitable way within the scope of the present disclosure.

In some deposition processes, plasma may be more or less continuous for the entire recipe. In some such implementations, plasma may remain on during purge steps (e.g., between deposited layers). In some deposition processes, plasma strikes last on the order of a few seconds or more in duration. For example, plasma strikes may be on the order of at least 1 second, at least 2 seconds, at least 3 seconds, at least 4 seconds, or at least 5 seconds. In certain implementations, much shorter plasma strikes may be used. These may be on the order of 10 ms to 1 second, typically, about 20 to 80 ms, with 50 ms being a specific example. Such very short RF plasma strikes require extremely quick stabilization of the plasma. To accomplish this, the plasma generator may be configured such that the impedance match is preset to a particular voltage, while the frequency is allowed to float. Conventionally, high-frequency plasmas are generated at an RF frequency at about 13.56 MHz. In various embodiments disclosed herein, the frequency is allowed to float to a value that is different from this standard value. By permitting the frequency to float while fixing the impedance match to a predetermined voltage, the plasma can stabilize much more quickly, a result which may be important when using the very short plasma strikes associated with some types of deposition cycles.

In some embodiments, pedestal 508 may be temperature controlled via heater 510. In some embodiments, the pedestal is set at a temperature between about 250° C. and about 900° C., such as at a temperature between about 400° C. and 700° C. or other ranges described herein. In some embodiments, the pedestal is set at a temperature between about 250° C. and 650° C. In yet other embodiments, the pedestal is configured to provide the substrate at a temperature between about 250° C. and about 900° C., such as at a temperature between about 400° C. and 700° C. or other ranges described herein. In particular non-limiting instances, the pedestal may be set a temperature that is lower than, higher than, or at the desired temperature for the substrate. In some implementations, heat may be provided externally, e.g., using an infrared or LED lamp. In yet other implementations, heat may be provided by the pedestal and by an external source (e.g., an infrared or LED lamp).

Further, in some embodiments, pressure control for deposition process station 500 may be provided by butterfly valve 518. As shown in the embodiment of FIG. 5, butterfly valve 518 throttles a vacuum provided by a downstream vacuum pump (not shown). In some implementations, a pendulum valve (not shown) may be utilized rather than butterfly valve 518. However, in some embodiments, pressure control of process station 500 may also be adjusted by varying a flow rate of one or more gases introduced to process station 500.

As described above, one or more process stations may be included in a multi-station processing tool. FIG. 6 shows a schematic view of an embodiment of a multi-station processing tool 600 with an inbound load lock 602 and an outbound load lock 604, either or both of which may comprise a remote plasma source. A robot 606, at atmospheric pressure, is configured to move wafers from a cassette loaded through a pod 608 into inbound load lock 602 via an atmospheric port 610. A wafer is placed by the robot 606 on a pedestal 612 in the inbound load lock 602, the atmospheric port 610 is closed, and the load lock is pumped down. Where the inbound load lock 602 comprises a remote plasma source, the wafer may be exposed to a remote plasma treatment in the load lock prior to being introduced into a processing chamber 614. Further, the wafer also may be heated in the inbound load lock 602 as well, for example, to remove moisture and adsorbed gases. Next, a chamber transport port 616 to processing chamber 614 is opened, and another robot (not shown) places the wafer into the reactor on a pedestal of a first station shown in the reactor for processing. While the embodiment depicted in FIG. 6 includes load locks, it will be appreciated that, in some embodiments, direct entry of a wafer into a process station may be provided.

The depicted processing chamber 614 comprises four process stations, numbered from 1 to 4 in the embodiment shown in FIG. 6. Each station has a heated pedestal (shown at 618 for station 1) and gas inlets. It will be appreciated that in some embodiments, each process station may have different or multiple purposes. While the depicted processing chamber 614 comprises four stations, it will be understood that a processing chamber according to the present disclosure may have any suitable number of stations. For example, in some embodiments, a processing chamber may have five or more stations, while in other embodiments a processing chamber may have three or fewer stations.

FIG. 6 also depicts an embodiment of a wafer handling system 690 for transferring wafers within processing chamber 614. In some embodiments, wafer handling system 690 may transfer wafers between various process stations or between a process station and a load lock. It will be appreciated that any suitable wafer handling system may be employed. Non-limiting examples include wafer carousels and wafer handling robots. FIG. 6 also depicts an embodiment of a system controller 650 employed to control process conditions and hardware states of process tool 600. System controller 650 may include one or more memory devices 656, one or more mass storage devices 654, and one or more processors 652. Processor 652 may include a CPU or computer, analog or digital input/output connections, stepper motor controller boards, etc.

In some embodiments, system controller 650 controls all of the activities of process tool 600. System controller 650 executes system control software 658 stored in mass storage device 654, loaded into memory device 656, and executed on processor 652. System control software 658 may include instructions for controlling the timing, mixture of gases, chamber or station pressure, chamber or station temperature, purge conditions and timing, wafer temperature, RF power levels, RF frequencies, substrate, pedestal, chuck or susceptor position, and other parameters of a particular process performed by process tool 600. System control software 658 may be configured in any suitable way. For example, various process tool component subroutines or control objects may be written to control operation of the process tool components necessary to carry out various process tool processes in accordance with the disclosed methods. System control software 658 may be coded in any suitable computer readable programming language.

In some embodiments, system control software 658 may include input/output control (IOC) sequencing instructions for controlling the various parameters described above. For example, each phase of a deposition process may include one or more instructions for execution by system controller 650. The instructions for setting process conditions for a deposition process phase may be included in a corresponding deposition recipe phase. In some embodiments, the deposition recipe phases may be sequentially arranged, so that all instructions for a deposition process phase are executed concurrently with that process phase.

Other computer software or programs stored on mass storage device 654 or memory device 656 associated with system controller 650 may be employed in some embodiments. Examples of programs or sections of programs for this purpose include a substrate positioning program, a process gas control program, a pressure control program, a heater control program, and a plasma control program.

A substrate positioning program may include program code for process tool components that are used to load the substrate onto pedestal 618 and to control the spacing between the substrate and other parts of process tool 600.

A process gas control program may include code for controlling gas composition and flow rates and optionally for flowing gas into one or more process stations prior to deposition in order to stabilize the pressure in the process station. The process gas control program may include code for controlling gas composition and flow rates within any of the disclosed ranges. A pressure control program may include code for controlling the pressure in the process station by regulating, for example, a throttle valve or pendulum valve in the exhaust system of the process station, a gas flow into the process station, etc. The pressure control program may include code for maintaining the pressure in the process station within any of the disclosed pressure ranges.

A heater control program may include code for controlling the current to a heating unit that is used to heat the substrate. Alternatively, the heater control program may control delivery of a heat transfer gas (such as helium) to the substrate. The heater control program may include instructions to maintain the temperature of the substrate within any of the disclosed ranges.

A plasma control program may include code for setting RF power levels and frequencies applied to the process electrodes in one or more process stations, for example using any of the RF power levels disclosed herein. The plasma control program may also include code for controlling the duration of each plasma exposure or for maintaining the pressure in the reaction chamber in accordance with the embodiments herein.

In some embodiments, there may be a user interface associated with system controller 650. The user interface may include a display screen, graphical software displays of the apparatus or process conditions, and user input devices such as pointing devices, keyboards, touch screens, microphones, etc.

In some embodiments, parameters adjusted by system controller 650 may relate to process conditions. Non-limiting examples include process gas composition and flow rates, temperature, pressure, plasma conditions (such as RF power levels, frequency, and exposure time), etc. These parameters may be provided to the user in the form of a recipe, which may be entered utilizing the user interface.

Signals for monitoring the process may be provided by analog or digital input connections of system controller 650 from various process tool sensors. The signals for controlling the process may be output on the analog and digital output connections of process tool 600. Non-limiting examples of process tool sensors that may be monitored include mass flow controllers, pressure sensors (such as manometers), thermocouples, etc. Appropriately programmed feedback and control algorithms may be used with data from these sensors to maintain process conditions.

System controller 650 may provide program instructions for implementing the above-described deposition processes. The program instructions may control a variety of process parameters, such as DC power level, RF bias power level, pressure, temperature, etc. The instructions may control the parameters to operate precleaning or pretreating of substrates, as well as deposition of film stacks according to various embodiments described herein.

The system controller 650 will typically include one or more memory devices and one or more processors configured to execute the instructions so that the apparatus will perform a method in accordance with disclosed embodiments. Machine-readable media containing instructions for controlling process operations in accordance with disclosed embodiments may be coupled to the system controller 650.

It should be noted that FIG. 6 depicts a load lock interfacing directly with a module. In some implementations, there may be a transfer module that interfaces with the load lock, where the transfer module can then interface with multiple modules.

Any suitable chamber may be used to implement the disclosed embodiments. Non-limiting examples of deposition apparatuses include any of a variety of other commercially available processing systems and components thereof, as well as prototypes or research tools including such processing systems and components thereof. In particular non-limiting embodiments, the deposition apparatuses can include, but are not limited to, apparatus from the ALTUS® product family, the VECTOR® product family, the SPEED® product family, or the STRIKER® product family, each available from Lam Research Corp., of Fremont, California, or any of a variety of other commercially available processing systems. Two or more of the stations may perform the same functions. Similarly, two or more stations may perform different functions. Each station can be designed/configured to perform a particular function/method as desired.

In some implementations, a controller is part of a system, which may be part of the above-described examples. Such systems can include semiconductor processing equipment, including a processing tool or tools, chamber or chambers, a platform or platforms for processing, or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements or the type of system, may be programmed to control any of the processes disclosed herein, including the delivery of processing gases, temperature settings (e.g., heating or cooling), pressure settings, vacuum settings, power settings, radio frequency (RF) generator settings in some systems, RF matching circuit settings, frequency settings, flow rate settings, fluid delivery settings, positional and operation settings, wafer transfers into and out of a tool and other transfer tools or load locks connected to or interfaced with a specific system.

Broadly speaking, the controller may be defined as electronics having various integrated circuits, logic, memory, or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, or dies of a wafer.

The controller, in some implementations, may be a part of or coupled to a computer that is integrated with, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations or load ports in a semiconductor manufacturing factory.

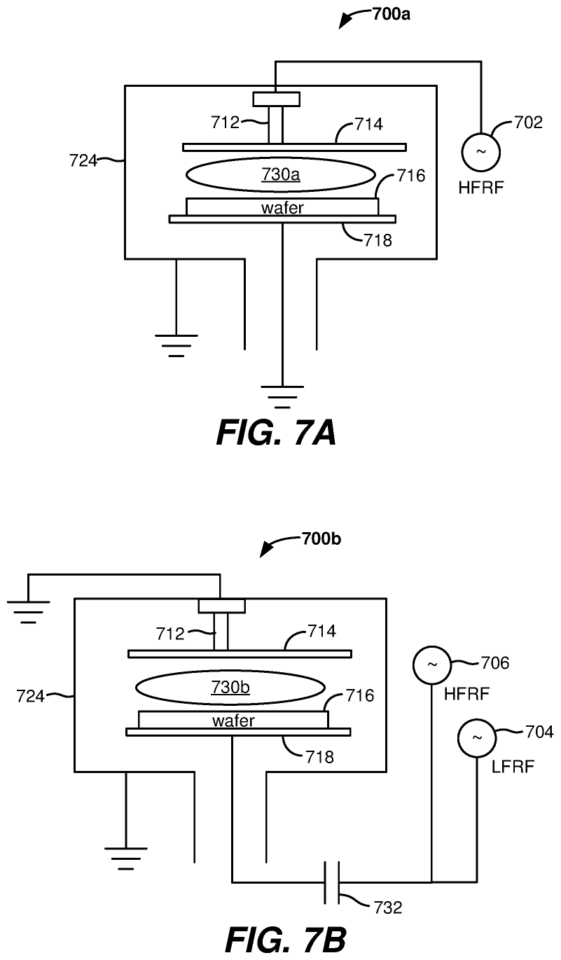

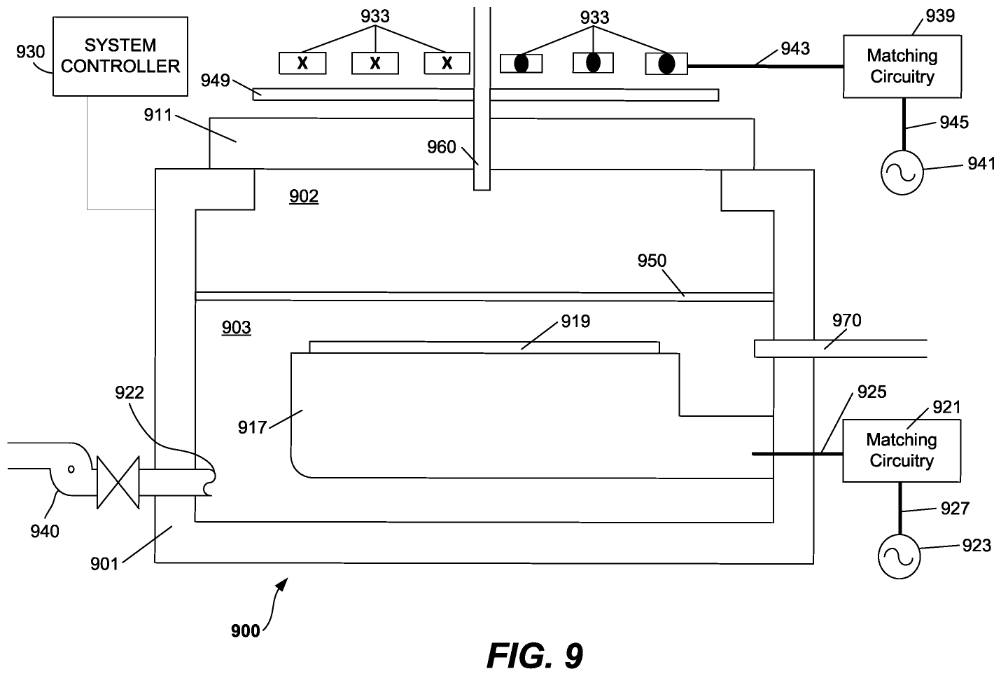

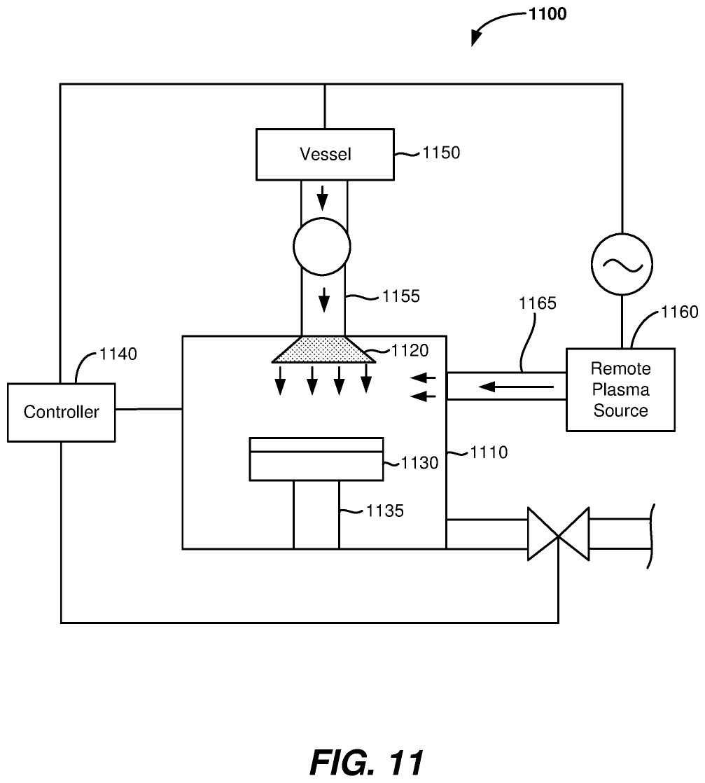

Plasma-based deposition operations for forming epitaxial Si or SiGe layers may be performed in any suitable process chamber. In some implementations, a plasma source may be in situ. When plasma is formed in situ, precursor gases are activated in the plasma and the substrate is exposed to the plasma within the process chamber. Examples of in situ plasma sources are shown in and described below in connection with FIG. 7A-7B and FIG. 9. In some implementations, a plasma source may be a remote plasma source. As used herein, a “remote plasma source” refers to plasma generation which occurs remote from the substrate. For example, in some implementations, a remote plasma source may be upstream of the process chamber where the substrate resides. Examples of plasma apparatuses that utilize a remote plasma source are shown in and described below in connection with FIGS. 11-14. In various implementations, a plasma source may or may not be positioned behind a showerhead that distributes gases toward a substrate undergoing processing.

It should be noted that, in some implementations, energetic species, radicals, metastables, or other activated species that interact with a precursor to deposit a film on the substrate may be formed in a manner other than by using plasma. For example, in some implementations, radicals or other activated species may be formed using a hot wire filament, for example, using a hot-wire deposition technique (e.g., hot wire chemical vapor deposition, or the like). As a more particular example, a chamber that utilizes hot wire chemical vapor deposition may flow a source gas (e.g., SiH₄, GeH₄, or other hydrogen-containing gas) over a heated filament. The filament may be made of tungsten, and may be heated to a sufficiently high temperature (e.g., greater than 1800° C., or the like), which may cause hydrogen to dissociate from the source gas. The hydrogen radicals may then interact with precursors to which the substrate is exposed to deposit a film on the substrate.

Plasma, whether in connection with an in situ plasma source or a remote plasma source, may be generated using any suitable technique or apparatus. For example, plasma may be generated using a radio-frequency (RF) plasma source, a microwave (MW) plasma source, a surface wave (SW) plasma source (e.g., using a radial line slot antenna), or the like.

In some implementations, plasma may be a capacitively coupled plasma (CCP). A CCP may be generated using a parallel plate CCP that comprises two parallel capacitors. Each capacitor may be operatively coupled to a plasma source. FIG. 7A-7B shows examples of CCP plasma apparatuses with an in situ plasma source, where the substrate resides between the two parallel plates. In some implementations, CCP may be generated at a remote plasma source. In some such implementations, parallel plates may be disposed upstream from the processing chamber where the substrate resides, and plasma species generated may be transported through one or more gas outlets and delivered to the process chamber. In some implementations, whether in situ or remote.

The CCP may be excited with frequencies from about 100 kHz to 100 MHz. The CCP source may have a power within a range of about 100 W to 20 kW. CCP may be provided in situ or remote. For in situ applications, CCP can be generated utilizing a flat plate as the top electrode and a showerhead as the bottom electrode. In another implementation, CCP may be generated by utilizing the wafer and the wafer pedestal as the bottom electrode. The pressure range may be from about sub-Torr (e.g., 0.001 Torr) to 20 Torr. The gap between two electrodes may be from about 0.2″ (inches) to 2″.

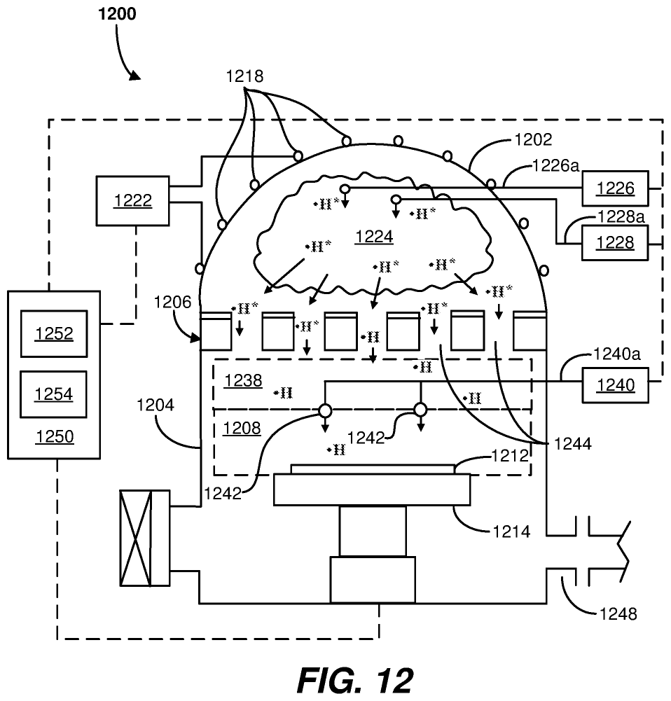

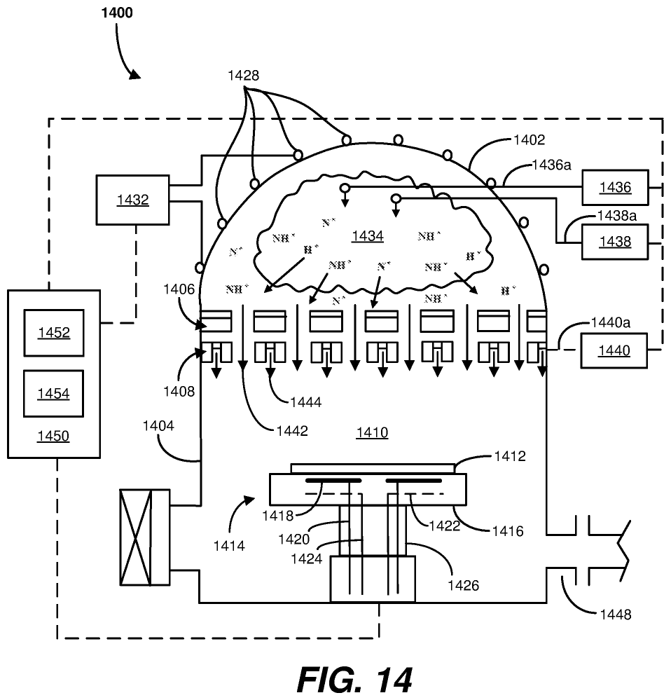

As another example, in some implementations, a plasma source may be an inductively coupled plasma (ICP) source to increase plasma density and the rate of dissociation. The ICP may be excited with frequencies from about 100 kHz to 100 MHz. The ICP source may have a power within a range of about 100 W to 20 kW. The ICP may operate in low-power capacitive mode or high-power inductive mode. ICP may be generated in a dome-shaped dielectric material with single or multiple coils covering the dome. ICP may be generated under a flat dielectric window with single or multiple coils covering the flat window. The number of turns of coils may range from 2 to 30. An ICP source may be provided in situ or remote. For remote applications, ICP is generated between showerhead and a dome or between showerhead and a flat window. In another implementation, ICP may be generated between a wafer and a dome or between a wafer and a flat window. The pressure range may be from about sub-Torr (e.g., 0.001 Torr) to 20 Torr. In some implementations, a plasma source may consist of an array of small ICP sources to control on-wafer uniformity.. FIG. 9 shows a schematic diagram of a plasma apparatus that utilizes an in situ ICP plasma. FIG. 12 and FIG. 14 show examples of a plasma apparatus that utilizes a remote ICP plasma.

As yet another example, in some implementations, plasma may be an electron cyclotron resonance (ECR) generated plasma. As a more particular example, in some implementations, plasma may be generated by using magnetic fields to provide an alternating electric field, thereby increasing the kinetic energy of electrons within a gas (e.g., a source gas, which may be a hydrogen-containing gas, an argon-containing gas, a nitrogen-containing gas, or the like). In some implementations, the magnetic fields may be generated using one or more coils positioned in or on the chamber. In some implementations the magnetic field may have a strength within a range of about 0.07 Tesla (T)-1 T. In one implementation, the magnetic field is about 0.0875 T. In some implementations, the gas may be ignited using a microwave source. The microwave source may have a frequency within a range of about 2.3 GHz-2.5 GHz. In one example, the frequency is about 2.45 GHz. In some implementations, the microwaves may be supplied to the chamber through a window, such as a quartz window. In some implementations, the magnetic field(s) may be generated by a magnetron. Plasma generated using ECR may be in situ, e.g., within the process chamber in which the substrate resides.

As still another example, in some implementations, a surface wave plasma (SWP) may be excited with frequencies from about 1 MHz to 10 GHz. A surface wave source may have a power within a range of about 1 kW to 60 kW. The SWP may be generated utilizing a microwave within a frequency range of about 700 MHz to 2.5 GHz. In one example, the frequency is about 900 MHz. In one example, the microwave source has a frequency of about 915 MHz and a power of about 60 kW. In another example, the microwave source has a frequency of about 2.45 GHz and a power of about 6 kW. The surface wave source may include polarized antennas or an array of polarized antennas, such as a radial line slot antenna (RLSA) apparatus. Polarized antennas may be circularly polarized or linearly polarized. In some implementations, an antenna may be a high-gain antenna. An SWP may be provided in situ or remote. Additionally, radicals generated by SWP may be provided with or without a showerhead. The pressure range may be from about sub-Torr (e.g., 0.001 Torr) to 20 TorrIn some implementations, uniformity of the SWP may be achieved using various techniques. For example, in some implementations, a plasma source may include an array of sources that spreads out or spears out the generated plasma. In some such implementations, each source is conical in shape. In some implementations, plasma may be speared out to about 3 mm in a uniform matter. As another example, in some implementations, the slots of the antenna may be configured to generate uniform plasma, for example, based on the number of slots, dimensions of the slots, distribution of the slots, etc.

It should be noted that surface wave plasmas may be provided in situ or remote. Additionally, it should be noted that radicals or other activated species generated by surface wave plasma may be provided with or without a showerhead. For example, in a process chamber that does not include a showerhead, the surface wave plasma may have a high density in a relatively small area, thereby alleviating a need for a showerhead.

As another example, a plasma source may be a microwave plasma (MWP) source. Some details regarding microwave plasma and microwave sources are described herein. In some embodiments, the MWP may be generated using a microwave within a frequency range of about 700 MHz to 2.5 GHz or about 900 MHz to 2.4 GHz. In one example, the frequency is about 900 MHz. In one example, the MWP source has a frequency of about 915 MHz and a power of about 60 kW. In another example, the MWP source has a frequency of about 2.45 GHz and a power of about 6 kW. MWP can include ECR generated plasma and SWP, which are non-limiting examples.

As still another example, a plasma source may be a hollow cathode plasma source. In some implementations, a hollow cathode discharge plasma source may be used as a remote plasma source. A hollow cathode discharge plasma source may comprise an array of cylinders with one end open. Each cylinder may have a gas inlet to receive plasma source gas. The diameter of the cylinder is determined based on pressure to maximize the pendulum effect. In other implementations, a cylindrical hole in the cathode, with a ring-shaped anode separated by an insulator may be utilized. In other implementations, a cylindrical opening in a thin solid cathode layer may be utilized. An array of the hollow cathode discharge cells may be used to control radical uniformity. A wafer or wafer pedestal maybe used as a third electrode at the anode side to achieve a stable glow discharge. A power source may be an AC power source or a pulse DC power source. The power source may provide a voltage within a range of about 100 V and 1 kV. In one example, the frequency is within a range of about 10 kHz to 1 MHz, within a range of about 10 kHz and 100 kHz, or the like. The pressure range may be from about sub-Torr (e.g., 0.001 Torr) to 20 Torr.

As still another example, in some implementations, plasma may be generated using ultraviolet (UV) radiation, which can include deep UV (DUV) or extreme UV (EUV) radiation. In some examples, ultraviolet radiation may additionally or alternatively be used to pre-treat a substrate, e.g., prior to a deposition operation, between deposition of various layers during a series of operations, or the like. In some implementations, a UV source that it utilized to generate plasma may additionally be used to pre-treat a substrate. In some implementations, one or more catalysts may be added to a precursor gas that are UV active, which may help in activating the precursor. For example, in such catalysts may be used to remove organics from a layer. In one example, O₂ may be used to generate ozone with UV, where the ozone is utilized to remove carbon (e.g., organics) or other contaminants. In another example, NH₃ may be activated with UV, which in turn can be used to remove carbon (e.g., organics) or other contaminants.

As another example, a plasma source can include other low temperature plasma (LTP) sources. For instance, the LTP source can provide a plasma at a temperature of less than about 900° C., 800° C., 750° C., 700° C., 650° C., 600° C., 550° C., or 500° C.; or at a temperature of about 400° C. to 900° C. or at a temperature of about 400° C. to 700° C. Non-limiting examples of LTP sources include MWP sources, SWP sources, electron beam generated plasma, pulsed plasma sources (e.g., nanosecond pulsed discharge plasma sources), laser beam generated plasma, nonthermal sources, as well as any described herein. The plasma source can any useful type of source, such as a beam source, a line source, or a pixelated source. In one instance, the plasma source is a line source, which can be configured to mechanically scan the wafer or the substrate with respect to the plasma source. In another instance, the plasma source is a pixelated source, in which a plurality of plasma sources are arranged in an array.

In some implementations, an ion filter is utilized, for example, to filter ions of a plasma species. Such filtering may be performed in connection with plasma apparatuses that utilize a remote plasma source, for example, to filter ions prior to the ions being introduced into the process chamber. Filtering may reduce substrate damage, undesirable re-excitation of molecules, or selective breakdown or decomposition of precursors. In some implementations, an ion filter may be implemented as part of a showerhead. An example of a showerhead that includes an ion filter is shown in and described below in connection with FIG. 12.

In some implementations, gases may be delivered (e.g., from a gas source to a chamber) via gas flow lines. In some implementations, such gas flow lines may comprise stainless steel. In some implementations, gas lines may be provisioned with one or more heaters to enable bakeout. In some implementations, a gas line may be operatively coupled to one or more purifiers that are configured to reduce moisture levels or oxygen levels. Reduction in moisture or oxygen may enable epitaxial Si or SiGe layers to be formed on a substrate with relatively few or no defects. In some implementations, moisture levels or oxygen levels may be reduced or maintained at relatively low levels via one or more pumps, such as water pumps, cryopumps, turbopumps, drag pumps, getter pumps, roughing pumps, or local boosters or the like. In particular implementations, the water pump can include a cryogenically cooled plate. A water pump can be configured to provide a high throughput pump. In one non-limiting embodiments, the reactor can include a local compressor configured to support a remote pump (e.g., a remote, high throughput roughing pump).

In some embodiments, various seals may be used to control leak rates of oxygen or water, thereby reducing oxygen or moisture levels in the process chamber. The seals may be metal seals, O-ring seals, or differentially pumped seals to reduce moisture diffusion or permeation, as well as to reduce the probability of leaks. In some implementations, ceramic to metal, metal to metal, or ceramic to ceramic bonding or brazing methods may be utilized to eliminate seals and thus reduce moisture.

In some embodiments, use of one or more pumps may be utilized to maintain low partial pressures on a substrate surface. In one example, low partial pressures may be achieved through relatively high flow rates of H₂ in a process chamber. In some implementations, a transfer module may be provided with a higher pumping speed at the transfer module to enable lower pressure during bakeouts, as well as during processing and wafer transfer. In some implementations, a module may be outfitter with larger forelines to enable better pumping. In another example, low partial pressures may be achieved through relatively high flow rates of N₂ in a transfer chamber. In some implementations, there may be local valves upstream of the chamber and other hardware on the module which are capable of being heated to a degree suitable for enabling bakeouts (e.g., heater to greater than about 150° C.). In some implementations, purge curtains may be utilized to reduce the entrainment of moisture during wafer transfer.

In some implementations, thermal control may be utilized to generate relatively defect free epitaxial Si and SiGe layers. For example, in some implementations, radiative heating may be used to heat a substrate undergoing processing. In some implementations, radiative heating is provided to a backside of a substrate undergoing processing. In one example, heating may be provided via a chuck or pedestal on which the substrate resides during processing. In another example, radiative heating is provided by an infrared lamp or a light emitting diode (LED). In yet another embodiment, the radiative heat source is configured to provide radiation having a wavelength from about 500 nm to 1000 nm. In another embodiment, the infrared lamp or LED is formed from materials that are transparent to desired radiation (e.g., infrared radiation or radiation having a wavelength from about 500 nm to 1000 nm) and resistant to damage or etching by reactor clean or reactor treat operations described herein.

In some implementations, a radiative heat source may be positioned such that a front surface of a substrate undergoes radiative heating rather than the backside of the surface. In some implementations, a wafer holder (e.g., a pedestal on which a substrate is positioned during processing) may function as a heat sink. This may allow the substrate to experience thermal uniformity. In some implementations, a wafer holder that functions as a heat sink may be a sintered anisotropic graphite-coated wafer holder.

FIG. 7A-B shows schematic diagrams of example hardware for generating CCP plasma. It should be noted that, in some implementations, certain hardware configurations and techniques described below for generating in situ CCP may be utilized to generate remote CCP plasma. Typically, deposition in a CCP reactor may occur in certain hardware configurations, and etch in a CCP reactor may occur in different hardware configurations. Specifically, deposition in a CCP reactor may be optimized according to certain RF hardware configurations, and etch in a CCP reactor may be optimized according to different RF hardware configurations. FIG. 7A-B shows different RF hardware configurations for performing deposition and etch in a CCP reactor. In FIG. 7A, the wafer is supported on a grounded electrode for deposition and the top electrode is powered. In FIG. 7B, the wafer is supported on a powered electrode for etch and the top electrode is grounded.

FIG. 7A shows a schematic illustration of an example apparatus including a CCP reactor for carrying out deposition processes. An apparatus 700a includes a CCP reactor 724 capable of performing PECVD or ALD. The CCP reactor 724 includes a showerhead 714 that serves as a top electrode and a pedestal 718 that serves as a bottom electrode. The pedestal 718 is below and opposite the showerhead 714 and may support a wafer 716 to be processed. In some implementations, the wafer 716 may have one or more features so that the wafer 716 is not planar. For example, the wafer 716 may have one or more gaps or a plurality of gaps. In some embodiments, the pedestal 718 may be raised or lowered. Process gases are introduced to the showerhead 714 via gas inlet 712, and the showerhead 714 distributes the process gases into the CCP reactor 724 and towards the wafer 716. An RF power supply 702 may be electrically connected to the showerhead 714 for generating a plasma 730a in a volume between the showerhead 714 and the wafer 716. The plasma 730a in the hardware configuration of FIG. 7A can be optimized for deposition. In some embodiments, the plasma energy can be controlled by controlling one or more of chamber pressure, gas concentration, gas mixture, RF source power, RF source frequency, duty cycle, pulse frequency, etc.

FIG. 7A illustrates an example RF hardware configuration for deposition, where the RF power supply 702 can be an HFRF generator electrically connected to the showerhead 714 and where the pedestal 718 is grounded. The RF hardware configuration of FIG. 7A is generally not capable of providing sufficient etch rates because an insufficient voltage drop across the wafer 716 would be produced. However, the RF hardware configuration of FIG. 7A is capable of fast frequency tuning, which can be useful in some applications.

Fast frequency tuning is what allows for impedance matching to occur quickly in the RF hardware configuration of FIG. 7A. Impedance matching is the practice of designing the input impedance of an electrical load or the output impedance of its corresponding signal source in order to maximize the power transfer and minimize reflection from the load. In a plasma processing context, impedance matching is used to minimize the reflected power back from a plasma discharge into the transmission line (e.g., RF cables), and maximize the power transferred from an RF power supply 702 into the plasma discharge. In addition, if the RF power supply 702 is not matched, there is reflected power that builds standing waves on a transmission line between the source (RF power supply 702) and the load (plasma 730a), which can lead to further power waste and cause frequency-dependent loss. In some implementations, an impedance matching network (not shown) can be coupled to the RF power supply 702. The impedance matching network can transform the load impedance presented from the plasma 730a to match the source impedance of the RF power supply 702. Typically, the impedance matching network can be equipped with one or more capacitors or inductors to tune the impedance of the RF power supply 702 to match the plasma impedance. However, tuning the impedance using capacitors or inductors can be a long process, which can be undesirable in applications that require short plasma on-times. For example, to operate in a certain window, processes can take on the order of 0.5 seconds or less. So rather than matching impedance using capacitors or inductors, impedance matching can occur by simply switching the frequency of the RF power supply 702. To illustrate, if the impedance of the RF power supply 702 needs to match the plasma impedance at 50 ohms, then the RF power supply 702 can quickly switch from operating at 13.56 MHz to 13.8 MHz. This kind of fast frequency tuning may not be possible in other RF hardware configurations, such as what is illustrated in FIG. 7B.

FIG. 7B shows a schematic illustration of an example apparatus including a CCP reactor for carrying out etch processes. The apparatus 700b includes a CCP reactor 724 capable of performing plasma etching. Like the apparatus 700a in FIG. 7A, the apparatus 700b in FIG. 7B includes a showerhead 714, a pedestal 718, a wafer 716, and a gas inlet 712. An RF power supply 704, 706 may be electrically connected to the pedestal 718 for applying a voltage drop across the wafer 716. The RF power supply 704, 706 may include both an LFRF generator 704 and an HFRF generator 706. A plasma 730b may be generated in a volume between the showerhead 714 and the wafer 716. The plasma 730b in the hardware configuration of FIG. 7B may be optimized for etching.

FIG. 7B illustrates an example RF hardware configuration for etching, where the LFRF generator 704 and the HFRF generator 706 can be electrically connected to the pedestal 718 and where the showerhead 714 is grounded. In some implementations, the LFRF generator 704 can provide a low-frequency RF signal between about 2 Hz and about 1000 kHz, such as 400 kHz. In some implementations, the HFRF generator 706 can provide a high-frequency RF signal between about 1 MHz and about 100 MHz, such as 13.56 MHz. A blocking capacitor 732 can be positioned between the pedestal 718 and both the LFRF generator 704 and the HFRF generator 706. With both high-frequency and low-frequency signals being mixed, the blocking capacitor 732 can serve as a filter leading to the pedestal 718. The RF configuration of FIG. 7B is not capable of fast frequency tuning. This is due in part to the number of components in the RF path that would prevent the fast response necessary for frequency tuning. Unlike the RF configuration of FIG. 7A, the RF configuration of FIG. 7B is able to provide a high voltage drop across the wafer 716.

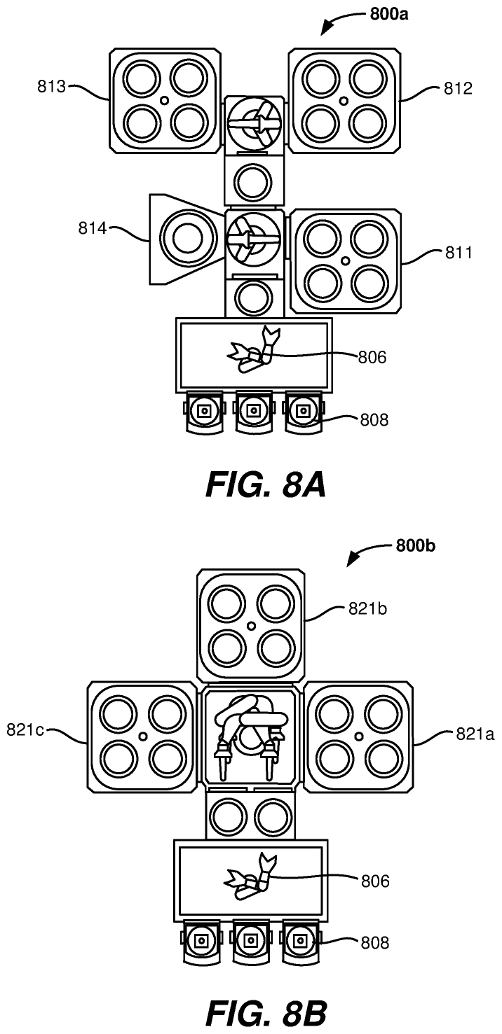

CCP reactors can be provided within a multi-station tool. FIG. 8A shows a schematic illustration of an example multi-station processing tool. The multi-station processing tool 800a includes a robot 806 configured to move wafers from a cassette loaded through a pod 808 into a load lock and ultimately into one of four process chambers 811, 812, 813, 814, though it is understood that there may be fewer or more process chambers. The multi-station processing tool 800a can include similar features as a multi-station processing tool 600 in FIG. 6. In the multi-station processing tool 800a, three of the process chambers 811, 812, 813 may be configured to perform deposition processes, such as CVD or ALD, and one of the process chambers 814 may be configured to perform an etch process.

FIG. 8B shows a schematic illustration of another example multi-station processing tool. A multi-station processing tool 800b includes a robot 806 configured to move wafers from a cassette loaded through a pod 808 into a load lock and ultimately into one of three process chambers 821a, 821b, 821c, though it is understood that there may be fewer or more process chambers. In one example, a first subset of modules may be utilized for processing, and a second subset may be utilized for precleaning substrates. In some implementations, such a multi-station processing tool may additionally include a location to store wafers between preclean and processing steps. In some such implementations, such a storage location may be maintained as relatively moisture free, e.g., through the usage of one or more getters, pumps (e.g., turbo pumps), etc. The multi-station processing tool 800b can include similar features as the multi-station processing tool 600 in FIG. 6. In the multi-station processing tool 800b, each of the process chambers 821a, 821b, 821c may be configured to perform both deposition and etch processes. For example, each of the process chambers 821a, 821b, 821c may incorporate an integrated apparatus with a certain RF hardware configuration, as described herein. The multi-station processing tool 800b may provide for fast frequency tuning for deposition processes and improved flexibility by performing multiple deposition sequences in the same chamber.

The multi-station processing tool 800b may include a system controller (not shown), such as the system controller 650 in FIG. 6. The system controller may be configured to provide instructions for performing operations, including the operations of switching between deposition and other processing modes. The system controller may be part of a system, which may be part of an integrated apparatus. The system controller may provide program instructions for operating in deposition and other processing modes using any of the above-described RF hardware configurations described herein. The system controller may include instructions for controlling RF power levels, RF frequencies, duty cycle, wafer temperature, chamber or station temperature, chamber or station pressure, wafer or pedestal position, timing, mixture of gases, gas flow rates, purge conditions and timing, deposition and etch mode switching, etc.

FIG. 9 shows an example of a plasma apparatus that utilizes in situ inductively coupled plasma. Inductively coupled plasma (ICP) reactors which, in certain embodiments, may be suitable for precleaning, pretreating, deposition, etching, or other operations are now described. Such ICP reactors have also been described in U.S. Patent Application Publication No. 2014/0170853, filed Dec. 10, 2013, and titled “IMAGE REVERSAL WITH AHM GAP FILL FOR MULTIPLE PATTERNING,” hereby incorporated by reference in its entirety and for all purposes.

FIG. 9 schematically shows a cross-sectional view of an inductively coupled plasma etching apparatus 900 in accordance with certain embodiments herein. The inductively coupled plasma etching apparatus 900 includes an overall etching chamber structurally defined by chamber walls 901 and a window 911. The chamber walls 901 may be fabricated from stainless steel or aluminum. The window 911 may be fabricated from quartz or other dielectric material. An optional internal plasma grid 950 divides the overall etching chamber into an upper sub-chamber 902 and a lower sub-chamber 903. The plasma grid 950 may include a single grid or multiple individual grids. In many embodiments, plasma grid 950 may be removed, thereby utilizing a chamber space made of sub-chambers 902 and 903. In some embodiments, the inductively coupled plasma etching apparatus 900 is a TCP plasma etching apparatus.

A chuck 917 is positioned within the lower sub-chamber 903 near the bottom inner surface. The chuck 917 is configured to receive and hold a semiconductor wafer 919 upon which the etching process is performed. The chuck 917 can be an electrostatic chuck for supporting the wafer 919 when present. In some embodiments, an edge ring (not shown) surrounds chuck 917, and has an upper surface that is approximately planar with a top surface of a wafer 919, when present over chuck 917. The chuck 917 also includes electrostatic electrodes for chucking and dechucking the wafer. A filter and DC clamp power supply (not shown) may be provided for this purpose. Other control systems for lifting the wafer 919 off the chuck 917 can also be provided. The chuck 917 can be electrically charged using an RF power supply 923. The RF power supply 923 is connected to matching circuitry 921 through a connection 927. The matching circuitry 921 is connected to the chuck 917 through a connection 925. In this manner, the RF power supply 923 is connected to the chuck 917.

A coil 933 is positioned above window 911. The coil 933 is fabricated from an electrically conductive material and includes at least one complete turn. The exemplary coil 933 shown in FIG. 9 includes three turns. The cross-sections of coil 933 are shown with symbols, and coils having an “X” extend rotationally into the page, while coils having a “e” extend rotationally out of the page. An RF power supply 941 is configured to supply RF power to the coil 933. In general, the RF power supply 941 is connected to matching circuitry 939 through a connection 945. The matching circuitry 939 is connected to the coil 933 through a connection 943. In this manner, the RF power supply 941 is connected to the coil 933. An optional Faraday shield 949 is positioned between the coil 933 and the window 911. The Faraday shield 949 is maintained in a spaced apart relationship relative to the coil 933. The Faraday shield 949 is disposed immediately above the window 911. The coil 933, the Faraday shield 949, and the window 911 are each configured to be substantially parallel to one another. The Faraday shield may prevent metal or other species from depositing on the dielectric window of the plasma chamber.

Process gases may be supplied through a main injection port 960 positioned in the upper chamber or through a side injection port 970, sometimes referred to as a side tuning gas (STG) injection port. A vacuum pump, e.g., a one or two stage mechanical dry pump or turbomolecular pump 940, may be used to draw process gases out of the process chamber and to maintain a pressure within the process chamber 900 by using a closed-loop-controlled flow restriction device, such as a throttle valve (not shown) or a pendulum valve (not shown), during operational plasma processing.

During operation of the apparatus, one or more reactant gases may be supplied through injection ports 960 or 970. In certain embodiments, gas may be supplied only through the main injection port 960, or only through the side injection port 970. In some cases, the injection ports may be replaced by showerheads. The Faraday shield 949 or optional grid 950 may include internal channels and holes that allow delivery of process gases to the chamber. Either or both of Faraday shield 949 and optional grid 950 may serve as a showerhead for delivery of process gases.

Radio frequency power is supplied from the RF power supply 941 to the coil 933 to cause an RF current to flow through the coil 933. The RF current flowing through the coil 933 generates an electromagnetic field about the coil 933. The electromagnetic field generates an inductive current within the upper sub-chamber 902. The physical and chemical interactions of various generated ions, radicals, metastables, or other activated species with the wafer 919 selectively etch features of the wafer.

If the plasma grid 950 is used such that there is both an upper sub-chamber 902 and a lower sub-chamber 903, the inductive current acts on the gas present in the upper sub-chamber 902 to generate an electron-ion plasma in the upper sub-chamber 902. The optional internal plasma grid 950, if present, may act to limit the number of hot electrons in the lower sub-chamber 903. In some embodiments, the apparatus is designed and operated such that the plasma present in the lower sub-chamber 903 is an ion-ion plasma. In other embodiments, the apparatus may be designed and operated such that the plasma present in the lower sub-chamber 903 is an electron-ion plasma. Internal plasma grids and ion-ion plasma are further discussed in U.S. patent application Ser. No. 14/082,009, filed Nov. 15, 2013, and titled “INTERNAL PLASMA GRID FOR SEMICONDUCTOR FABRICATION,” and in U.S. Pat. No. 9,245,761, each of which is herein incorporated by reference in its entirety.

Volatile etching byproducts may be removed from the lower-sub chamber 903 through port 922. The chuck 917 disclosed herein may operate at elevated temperatures ranging between about 30° C. and about 250° C. In some cases, the chuck 917 may also operate at lower temperatures, for example when the chuck 917 is actively chilled. In such cases the chuck 917 may operate at substantially lower temperatures, as desired. The temperature will depend on the etching process operation and specific recipe. In some embodiments, the chamber 901 may operate at pressures in the range of between about 1 mTorr and about 95 mTorr. In certain embodiments, the pressure may be higher.

Chamber 901 may be coupled to facilities (not shown) when installed in a clean room or a fabrication facility. Facilities include plumbing that provide processing gases, vacuum, temperature control, and environmental particle control. These facilities are coupled to chamber 901, when installed in the target fabrication facility. Additionally, chamber 901 may be coupled to a transfer chamber that allows robotics to transfer semiconductor wafers into and out of chamber 901 using typical automation.

In some embodiments, a system controller 930 (which may include one or more physical or logical controllers) controls some or all of the operations of an etching chamber. The system controller 930 may include one or more memory devices and one or more processors. The processor may include a central processing unit (CPU) or computer, analog or digital input/output connections, stepper motor controller boards, and other like components. Instructions for implementing appropriate control operations are executed on the processor. These instructions may be stored on the memory devices associated with the system controller 930 or they may be provided over a network. In certain embodiments, the system controller 930 executes system control software.

In some cases, the system controller 930 controls gas concentration, wafer movement, or the power supplied to the coils 933 or electrostatic chuck 917. The system controller 930 may control the gas concentration by, for example, opening and closing relevant valves to produce one or more inlet gas stream that provide the necessary reactant(s) at the proper concentration(s). The wafer movement may be controlled by, for example, directing a wafer positioning system to move as desired. The power supplied to the coils 933 or chuck 917 may be controlled to provide particular RF power levels. Similarly, if the internal grid 950 is used, any RF power applied to the grid may be adjusted by the system controller 930.

The system controller 930 may control these and other aspects based on sensor output (e.g., when power, potential, pressure, etc. reach a certain threshold), the timing of an operation (e.g., opening valves at certain times in a process), or based on received instructions from the user. An example controller is further discussed elsewhere herein.

Both the upper electron-ion plasma and the lower ion-ion plasma may contain positive and negative ions, through the ion-ion plasma will have a greater ratio of negative ions to positive ions. Volatile etching or deposition byproducts may be removed from the lower-sub-chamber 903 through port 922. The chuck 917 disclosed herein may operate at elevated temperatures ranging between about 10° C. and about 850° C. The temperature will depend on the process operation and specific recipe.

Chamber 901 may be coupled to facilities (not shown) when installed in a clean room or a fabrication facility. Facilities include plumbing that provide processing gases, vacuum, temperature control, and environmental particle control. These facilities are coupled to chamber 901, when installed in the target fabrication facility. Additionally, chamber 901 may be coupled to a transfer chamber that allows robotics to transfer semiconductor wafers into and out of chamber 901 using typical automation.

In some embodiments, a system controller 930 (which may include one or more physical or logical controllers) controls some or all of the operations of a processing chamber. The system controller 930 may include any one or more characteristic described above with respect to system controller 650.

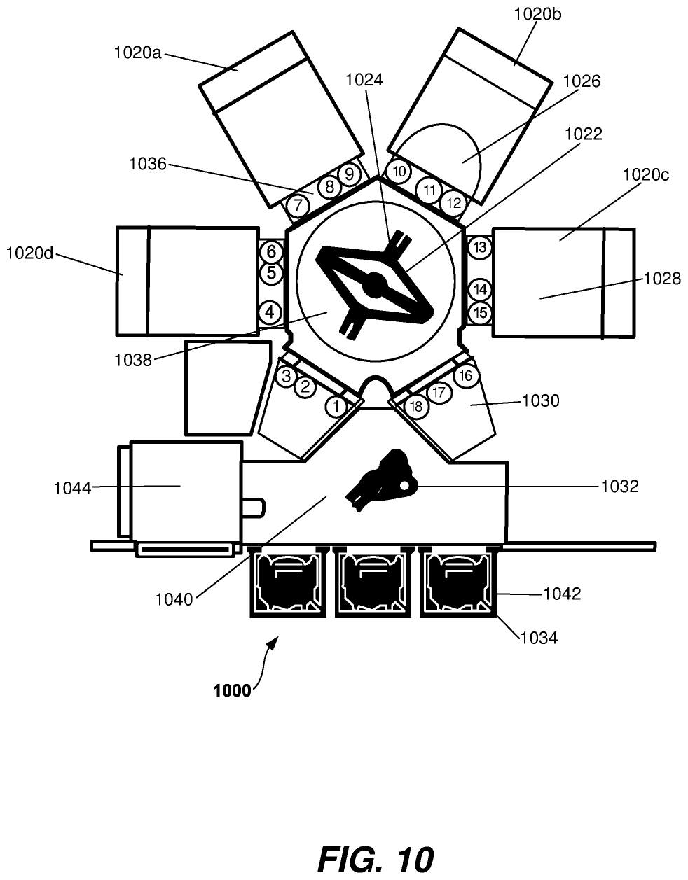

In some implementations, the techniques disclosed herein may be implemented in a tool that utilizes multiple process chambers arranged in a cluster. FIG. 10 depicts a semiconductor process cluster architecture with various modules that interface with a vacuum transfer module 1038 (VTM). The arrangement of transfer modules to “transfer” wafers among multiple storage facilities and processing modules may be referred to as a “cluster tool architecture” system. Airlock 1030, also known as a loadlock or transfer module, is shown in VTM 1038 with four processing modules 1020a-1020d, which may be individually optimized to perform various fabrication processes. By way of example, processing modules 1020a-1020d may be implemented to perform substrate etching, deposition, ion implantation, wafer cleaning, sputtering, or other semiconductor processes. One or more of the substrate etching processing modules (any of 1020a-1020d) may be implemented as disclosed herein. Airlock 1030 and process module 1020 may be referred to as “stations.” Each station has a facet 1036 that interfaces the station to VTM 1038. Inside each facet, sensors 1-18 are used to detect the passing of wafer 1026 when moved between respective stations.

Robot 1022 transfers wafer 1026 between stations. In one embodiment, robot 1022 has one arm, and in another embodiment, robot 1022 has two arms, where each arm has an end effector 1024 to pick wafers such as wafer 1026 for transport. Front-end robot 1032, in atmospheric transfer module (ATM) 1040, is used to transfer wafers 1026 from cassette or Front Opening Unified Pod (FOUP) 1034 in Load Port Module (LPM) 1042 to airlock 1030. Module center 1028 inside process module 1020 is one location for placing wafer 1026. Aligner 1044 in ATM 1040 is used to align wafers.

In an exemplary processing method, a wafer is placed in one of the FOUPs 1034 in the LPM 1042. Front-end robot 1032 transfers the wafer from the FOUP 1034 to an aligner 1044, which allows the wafer 1026 to be properly centered before it is etched or processed. After being aligned, the wafer 1026 is moved by the front-end robot 1032 into an airlock 1030. Because airlock modules have the ability to match the environment between an ATM and a VTM, the wafer 1026 is able to move between the two pressure environments without being damaged. From the airlock module 1030, the wafer 1026 is moved by robot 1022 through VTM 1038 and into one of the process modules 1020a-1020d. In order to achieve this wafer movement, the robot 1022 uses end effectors 1024 on each of its arms. Once the wafer 1026 has been processed, it is moved by robot 1022 from the process modules 1020a-1020d to an airlock module 1030. From here, the wafer 1026 may be moved by the front-end robot 1032 to one of the FOUPs 1034 or to the aligner 1044.

It should be noted that the computer controlling the wafer movement can be local to the cluster architecture, or can be located external to the cluster architecture in the manufacturing floor, or in a remote location and connected to the cluster architecture via a network. A controller as described above with respect to FIG. 6 may be implemented with the tool in FIG. 10.

As described above, in some implementations, plasma may be generated using a remote plasma source, where the remote plasma source is remote from a process chamber (e.g., in which a substrate undergoes processing). For example, in some implementations, the remote plasma source is upstream from the process chamber. A remote plasma source provides mild reaction conditions in comparison to a direct plasma. An example of a suitable remote plasma apparatus is described in U.S. patent application Ser. No. 14/062,648 (now U.S. Pat. No. 9,371,579), filed Oct. 24, 2013, entitled “Ground state hydrogen radical sources for chemical vapor deposition of silicon-carbon-containing films,” which is incorporated herein by reference in its entirety and for all purposes.

FIG. 11 presents a schematic diagram of a remote plasma apparatus according to certain embodiments. The device 1100 includes a reaction chamber 1110 with a showerhead assembly 1120. Inside the reaction chamber 1110, a substrate 1130 rests on a stage or pedestal 1135. In some embodiments, the pedestal 1135 can be fitted with a heating/cooling element. A controller 1140 may be connected to the components of the device 1100 to control the operation of the device 1100. For example, the controller 1140 may contain instructions for controlling process conditions for the operations of the device 1100, such as the temperature process conditions or the pressure process conditions. In some embodiments, the controller 1140 may contain instructions for controlling the flow rates of precursor gas, co-reactant gas, source gas, and carrier gas. The controller 1140 may contain instructions for changing the flow rate of the co-reactant gas over time. In addition or in the alternative, the controller 1140 may contain instructions for changing the flow rate of the precursor gas over time.

During operation, gases or gas mixtures are introduced into the reaction chamber 1110 via one or more gas inlets coupled to the reaction chamber 1110. In some embodiments, two or more gas inlets are coupled to the reaction chamber 1110. A first gas inlet 1155 can be coupled to the reaction chamber 1110 and connected to a vessel 1150, and a second gas inlet 1165 can be coupled to the reaction chamber 1110 and connected to a remote plasma source 1160. In embodiments including remote plasma configurations, the delivery lines for the precursors and the radical species generated in the remote plasma source are separated. Hence, the precursors and the radical species do not substantially interact before reaching the substrate 1130. As described herein, any description related to a radical species can apply to other activated species, such as metastable species or others described herein.

One or more radical species may be generated in the remote plasma source 1160 and configured to enter the reaction chamber 1110 via the gas inlet 1165. Any type of plasma source may be used in remote plasma source 1160 to create the radical species. This includes, but is not limited to, capacitively coupled plasmas, inductively coupled plasmas, transformer coupled plasmas, microwave plasmas, DC plasmas, surface wave plasmas, electron cyclotron resonance (ECR) plasma, and laser-created plasmas. An example of a capacitively coupled plasma can be a radio frequency (RF) plasma. In some implementations, a capacitively coupled plasma can be generated at a frequency within a range of about 60 KHz to 60 MHz. A high-frequency plasma can be configured to operate at 13.56 MHz or higher. An example of such a remote plasma source 1160 can be the GAMMA®, manufactured by Lam Research Corporation of Fremont, California. Another example of such a RF remote plasma source 1160 can be the Astron®, manufactured by MKS Instruments of Wilmington, Massachusetts, which can be operated at 440 kHz and can be provided as a subunit bolted onto a larger apparatus for processing one or more substrates in parallel. In some embodiments, a microwave plasma can be used as the remote plasma source 1160, such as the Astex®, also manufactured by MKS Instruments. A microwave plasma can be configured to operate at a frequency of about 2.45 GHz. A surface wave plasma may be generated using a radial line slot antenna, which may include an array of polarized (e.g., circularly polarized or linearly polarized) antennas. Utilizing a radial line slot array, the plasma may be generated using a microwave generated that operates within a range of about 700 MHz to 1 GHz. Gas provided to the remote plasma source may include hydrogen, nitrogen, ammonia, helium, argon, and other gases as mentioned elsewhere herein. In certain embodiments, hydrogen is provided in a carrier such helium. As an example, hydrogen gas may be provided in a helium carrier at a concentration of about 1-10% hydrogen. In some implementations, gas may be provided to a remote plasma source such that the generated reactive plasma contains substantially no components that react with silicon, with germanium, or with both silicon and germanium. As one example, a reactive plasma may contain only hydrogen (e.g., H* or H₂), deuterium (e.g., D* or D₂), hydrogen deuteride (HD), an inert gas (e.g., He, Ar, He*, Ar*, etc.), or any combination thereof. In some cases, a reactive plasma may not contain a nitrogen-containing species, a halogen-containing species, or an oxygen-containing species.

The precursors can be provided in vessel 1150 and can be supplied to the showerhead 1120 via the first gas inlet 1155. The showerhead 1120 distributes the precursors into the reaction chamber 1110 toward the substrate 1130. The substrate 1130 can be located beneath the showerhead 1120. It will be appreciated that the showerhead 1120 can have any suitable shape, and may have any number and arrangement of ports for distributing gases to the substrate 1130. The precursors can be supplied to the showerhead 1120 and ultimately to the substrate 1130 at a controlled flow rate.

The one or more radical species formed in the remote plasma source 1160 can be carried in the gas phase toward the substrate 1130. The one or more radical species can flow through a second gas inlet 1165 into the reaction chamber 1110. It will be understood that the second gas inlet 1165 need not be transverse to the surface of the substrate 1130 as illustrated in FIG. 11. In certain embodiments, the second gas inlet 1165 can be directly above the substrate 1130 or in other locations. The distance between the remote plasma source 1160 and the reaction chamber 1110 can be configured to provide mild reactive conditions such that the ionized species generated in the remote plasma source 1160 are substantially neutralized, but at least some radical species in low energy states (e.g., ground states) remain in the environment adjacent to the substrate 1130. Such low energy state radical species are not recombined to form stable compounds. The distance between the remote plasma source 1160 and the reaction chamber 1110 can be a function of the aggressiveness of the plasma (e.g., determined in part by the source RF power level), the density of gas in the plasma (e.g., if there's a high concentration of hydrogen atoms, a significant fraction of them may recombine to form H₂ before reaching the reaction chamber 1110), and other factors. In some embodiments, the distance between the remote plasma source 1160 and the reaction chamber 1110 can be between about 1 cm and 30 cm, such as about 5 cm or about 15 cm.

In some embodiments, a co-reactant, which is not the primary silicon-containing precursor or a hydrogen radical, is introduced during the deposition reaction. In some implementations, the apparatus is configured to introduce the co-reactant through the second gas inlet 1165, in which case the co-reactant is at least partially converted to plasma. In some implementations, the apparatus is configured to introduce the co-reactant through the showerhead 1120 via the first gas inlet 1155. Examples of the co-reactant include oxygen, nitrogen, ammonia, carbon dioxide, carbon monoxide, and the like. In some embodiments, co-reactants may be limited to those that do not react with silicon, with germanium, or with both silicon and germanium. The flow rate of the co-reactant can vary over time to produce a composition gradient in a graded film.

The controller 1140 may contain instructions for controlling process conditions for the operation of the device 1100. The controller 1140 will typically include one or more memory devices and one or more processors. The processor may include a CPU or computer, analog or digital input/output connections, stepper motor controller boards, etc. Instructions for implementing appropriate control operations are executed on the processor. These instructions may be stored on the memory devices associated with the controller 1140 or they may be provided over a network.

In certain embodiments, the controller 1140 controls all or most activities of the semiconductor processing device 1100 described herein. For example, the controller 1140 may control all or most activities of the semiconductor processing device 1100 associated with depositing a silicon film or silicon-germanium film as described herein. The controller 1140 may execute system control software including sets of instructions for controlling the timing, gas composition, gas flow rates, chamber pressure, chamber temperature, RF power levels, substrate position, or other parameters. Other computer programs, scripts, or routines stored on memory devices associated with the controller 1140 may be employed in some embodiments. To provide relatively mild reactive conditions at the environment adjacent to the substrate 1130, parameters such as the RF power levels, gas flow rate to the remote plasma region, and timing of the plasma ignition can be adjusted and maintained by controller 1140. Additionally, adjusting the substrate position may further reduce the presence of high-energy radical species at the environment adjacent to the substrate 1130. In a multi-station reactor, the controller 1140 may comprise different or identical instructions for different apparatus stations, thus allowing the apparatus stations to operate either independently or synchronously.

In some embodiments, the controller 1140 may include instructions for performing operations such as flowing a precursor (e.g., an Si precursor, a Ge precursor, an SiGe precursor, or a combination thereof) through the first gas inlet 1155 into the reaction chamber 1110, providing one or more radical species of a source gas from the remote plasma source 1160, flowing a co-reactant gas through the second gas inlet 1165 into the reaction chamber 1110, and flowing the one or more radical species through the second gas inlet 1165 into the reaction chamber 1110 to react with the precursor to form a deposited layer on the substrate 1130. In some implementations, the controller 1140 may include instructions for changing a flow rate of the precursor over time. A controller as described above with respect to FIG. 6 may be implemented with the apparatus in FIG. 11.

FIG. 12 illustrates a schematic diagram of an example plasma processing apparatus with a remote plasma source that is an inductively coupled plasma according to some implementations. The plasma processing apparatus 1200 includes the remote plasma source 1202 separated from a reaction chamber 1204. The remote plasma source 1202 is fluidly coupled with the reaction chamber 1204 via a showerhead 1206, which may also be referred to as a multiport gas distributor. As used herein, in some embodiments, the term “fluidly coupled” is meant directly or indirectly connected, such as by any duct, channel, tube, pipe, chamber, or pathway through which a substance, such as a liquid, gas, or solid may pass substantially unrestricted when the pathway is open. When the pathway is closed, the substance is substantially restricted from passing through.

Radical species are generated in the remote plasma source 1202 and supplied to the reaction chamber 1204. One or more precursors (e.g., an Si precursor, a Ge precursor, an SiGe precursor, or a combination thereof) are supplied to the reaction chamber 1204 downstream from the remote plasma source 1202 and downstream from the showerhead 1206. The one or more precursors react with the radical species in a chemical vapor deposition zone 1208 of the reaction chamber 1204 to deposit a layer on a front surface of a substrate 1212. In one example, a silicon containing precursor reacts with the radical species such that an epitaxial Si layer is deposited on the front surface of the substrate. In another example, a germanium containing precursor reacts with the radical species such that an epitaxial SiGe layer is deposited on the front surface of the substrate. The chemical vapor deposition zone 1208 includes an environment adjacent to the front surface of the substrate 1212, where the front surface of the substrate 1212 faces the remote plasma source 1202.

The substrate 1212 is supported on a substrate support or pedestal 1214. The pedestal 1214 may move within the reaction chamber 1204 to position the substrate 1212 within the chemical vapor deposition zone 1208. In the embodiment shown in FIG. 12, pedestal 1214 is shown having elevated the substrate 1210 within the chemical vapor deposition zone 1208. The pedestal 1214 may also adjust the temperature of the substrate 1212 in some embodiments, which can provide some selective control over thermally activated surface reactions on the substrate 1212.

FIG. 12 shows a coil 1218 arranged around the remote plasma source 1202, where the remote plasma source 1202 includes an outer wall (e.g., quartz dome). The coil 1218 is electrically coupled to a plasma generator controller 1222, which may be used to form and sustain plasma within a plasma region 1224 via inductively coupled plasma generation. In some implementations, the plasma generator controller 1222 may include a power supply for supplying power to the coil 1218, where the power can be in a range between about 1 and 6 kilowatts (kW) during plasma generation. In some implementations, electrodes or antenna for parallel plate or capacitively coupled plasma generation may be used to generate a continuous supply of radicals via plasma excitation rather than inductively coupled plasma generation. Regardless of the mechanism used to ignite and sustain the plasma in the plasma region 1224, radical species may continuously be generated using plasma excitation during film deposition. In some implementations, hydrogen radicals are generated under approximately steady-state conditions during steady-state film deposition, though transients may occur at the beginning and end of film deposition.

A supply of hydrogen radicals may be continuously generated within the plasma region 1224 while hydrogen gas or other source gas is being supplied to the remote plasma source 1202. Excited hydrogen radicals may be generated in the remote plasma source 1202. If not re-excited or re-supplied with energy, or re-combined with other radicals, the excited hydrogen radicals lose their energy, or relax. Thus, excited hydrogen radicals may relax to form hydrogen radicals in a substantially low energy state or ground state.

The hydrogen gas (H₂) or other source gas may be diluted with one or more additional gases. These one or more additional gases may be supplied to the remote plasma source 1202. In some implementations, the hydrogen gas or other source gas is mixed with one or more additional gases to form a gas mixture, where the one or more additional gases can include a carrier gas. Non-limiting examples of additional gases can include helium (He), neon (Ne), argon (Ar), krypton (Kr), xenon (Xe), and nitrogen (N₂). In some embodiments, the additional gases may include only those that do not react with silicon, with germanium, or with both silicon and germanium, such as inert gases. The one or more additional gases may support or stabilize steady-state plasma conditions within the remote plasma source 1202 or aid in transient plasma ignition or extinction processes. In some implementations, diluting hydrogen gas or other source gas with helium, for example, may permit higher total pressures without concomitant plasma breakdown. Put another way, a dilute gas mixture of hydrogen gas and helium may permit higher total gas pressure without increasing plasma power to the remote plasma source 1202. In certain embodiments, hydrogen gas is provided in a carrier such helium. As an example, hydrogen gas may be provided in a helium carrier at a concentration of about 1-25% hydrogen or about 1-10% hydrogen.

As shown in FIG. 12, a source gas supply 1226 is fluidly coupled with the remote plasma source 1202 for supplying the hydrogen gas or source gas (e.g., by way of gas inlet 1226a). In addition, an additional gas supply 1228 is fluidly coupled with the remote plasma source 1202 for supplying the one or more additional gases (e.g., by way of gas inlet 1228a). The one or more additional gases may also include a co-reactant gas. While the embodiment in FIG. 12 depicts the gas mixture of the source gas and the one or more additional gases being introduced through separate gas outlets, it will be understood that the gas mixture may be introduced directly into the remote plasma source 1202. That is, a pre-mixed dilute gas mixture may be supplied to the remote plasma source 1202 through a single gas outlet.

Gases, such as excited hydrogen and helium radicals and relaxed gases/radicals, flow out of the remote plasma source 1202 and into the reaction chamber 1204 via the showerhead 1206. Gases within the showerhead 1206 and within the reaction chamber 1204 are generally not subject to continued plasma excitation therein. In some implementations, the showerhead 1206 includes an ion filter, a photon filter, or both. Filtering ions, photons, or both may reduce substrate damage, undesirable re-excitation of molecules, or selective breakdown or decomposition of precursors within the reaction chamber 1204. Showerhead 1206 may have a plurality of gas ports 1244 to diffuse the flow of gases into the reaction chamber 1204. In some implementations, the plurality of gas ports 1244 may be mutually spaced apart. In some implementations, the plurality of gas ports 1244 may be arranged as an array of regularly spaced apart channels or through-holes extending through a plate separating the remote plasma source 1202 and the reaction chamber 1204. The plurality of gas ports 1244 may smoothly disperse and diffuse exiting radicals from the remote plasma source 1202 into the reaction chamber 1204.

Typical remote plasma sources are far removed from reaction vessels. Consequently, radical extinction and recombination, e.g., via wall collision events, may reduce active species substantially. In contrast, in some implementations, dimensions for the plurality of gas ports 1244 may be configured in view of the mean free path or gas flow residence time under typical processing conditions to aid the free passage of radicals into the reaction chamber 1204. In some implementations, openings for the plurality of gas ports 1244 may occupy between about 5% and about 20% of an exposed surface area of the showerhead 1206. In some implementations, the plurality of gas ports 1244 may each have an axial length to diameter ratio of between about 3:1 and 10:1 or between about 6:1 and about 8:1. Such aspect ratios may reduce wall-collision frequency for radical species passing through the plurality of gas ports 1244 while providing sufficient time for a majority of excited state radical species to relax to ground state radical species. In some implementations, dimensions of the plurality of gas ports 1244 may be configured so that the residence time of gases passing through the showerhead 1206 is greater than the typical energetic relaxation time of an excited state radical species. Excited state radical species for hydrogen source gas may be denoted by ⋅H* in FIG. 12 and ground state radical species for hydrogen source gas may be denoted by ⋅H in FIG. 12.

In some implementations, excited state radical species exiting the plurality of gas ports 1244 may flow into a relaxation zone 1238 contained within an interior of the reaction chamber 1204. The relaxation zone 1238 is positioned upstream of the chemical vapor deposition zone 1208 but downstream of the showerhead 1206. Substantially all or at least 90% of the excited state radical species exiting the showerhead 1206 will transition into relaxed state radical species in the relaxation zone 1238. Put another way, almost all of the excited state radical species (e.g., excited hydrogen radicals) entering the relaxation zone 1238 become de-excited or transition into a relaxed state radical species (e.g., ground state hydrogen radicals) before exiting the relaxation zone 1238. In some implementations, process conditions or a geometry of the relaxation zone 1238 may be configured so that the residence time of radical species flowing through the relaxation zone 1238, e.g., a time determined by mean free path and mean molecular velocity, results in relaxed state radical species flowing out of the relaxation zone 1238.

With the delivery of radical species to the relaxation zone 1238 from the showerhead 1206, one or more precursors may be introduced into the chemical vapor deposition zone 1208. The one or more precursors may be introduced via a gas distributor or gas outlet 1242, where the gas outlet 1242 may be fluidly coupled with a precursor supply source 1240 (e.g., by way of gas inlet 1240a). The relaxation zone 1238 may be contained within a space between the showerhead 1206 and the gas outlet 1242. The gas outlet 1242 may include mutually spaced apart openings so that the flow of the one or more precursors may be introduced in a direction parallel with gas mixture flowing from the relaxation zone 1238. The gas outlet 1242 may be located downstream from the showerhead 1206 and the relaxation zone 1238. The gas outlet 1242 may be located upstream from the chemical vapor deposition zone 1208 and the substrate 1212. The chemical vapor deposition zone 1208 is located within the interior of the reaction chamber 1204 and between the gas outlet 1242 and the substrate 1212.

Substantially all of the flow of the one or more precursors may be prevented from mixing with excited state radical species adjacent to the showerhead 1206. Relaxed or ground state radical species mix in a region adjacent to the substrate 1212 with the one or more precursors. The chemical vapor deposition zone 1208 includes the region adjacent to the substrate 1212 where the relaxed or ground state radical species mix with the one or more precursors. The relaxed or ground state radical species mix with the one or more precursors in the gas phase during deposition of the Si layer, the SiGe layers, or both types of layers.

In some implementations, a co-reactant may be introduced from the showerhead 1206 and flowed along with the radical species generated in the remote plasma source 1202 and into the reaction chamber 1204. This may include radicals, ions, or both of a co-reactant gas provided in the remote plasma source 1202. The co-reactant may be supplied from the additional gas supply 1228. In some implementations, the co-reactant may include a nitrogen-containing reagent such as nitrogen gas (N₂). For example, radicals, ions, or both of nitrogen may be generated and flowed with the radical species of hydrogen during pretreatment of the substrate 1212. In some embodiments, a co-reactant may be one that does not substantially react with silicon, with germanium, or with both silicon and germanium. For example, in some embodiments, nitrogen-containing reagents, oxygen-containing reagents, or a combination of nitrogen-containing reagents and oxygen-containing reagents may not be used as co-reactants.

The gas outlet 1242 may be separated from the showerhead 1206 by a sufficient distance to prevent back diffusion or back streaming of the one or more precursors. This can afford sufficient time for radical species of hydrogen to transition from an excited state to a relaxed state (e.g., ground state). In some implementations, the gas outlet 1242 may be separated from the plurality of gas ports 1244 by a distance between about 0.5 inches and about 5 inches, or between about 1.5 inches and about 4.5 inches, or between about 1.5 inches and about 3 inches.

Process gases may be removed from the reaction chamber 1204 via an outlet 1248 that is fluidly coupled to a pump (not shown). Thus, excess precursors, co-reactants, radical species, and diluent and displacement or purge gases may be removed from the reaction chamber 1204. In some implementations, a system controller 1250 is in operative communication with the plasma processing apparatus 1200. In some implementations, the system controller 1250 includes a processor system 1252 (e.g., microprocessor) configured to execute instructions held in a data system 1254 (e.g., memory). In some implementations, the system controller 1250 may be in communication with the plasma generator controller 1222 to control plasma parameters or conditions. In some implementations, the system controller 1250 may be in communication with the pedestal 1214 to control pedestal elevation and temperature. In some implementations, the system controller 1250 may control other processing conditions, such as RF power settings, frequency settings, duty cycles, pulse times, pressure within the reaction chamber 1204, pressure within the remote plasma source 1202, gas flow rates from the source gas supply 1226 and the additional gas supply 1228, gas flow rates from the precursor supply source 1240 and other sources, temperature of the pedestal 1214, and temperature of the reaction chamber 1204, among others.

The controller 1250 may contain instructions for controlling process conditions for the operation of the plasma processing apparatus 1200. The controller 1250 will typically include one or more memory devices and one or more processors. The processor may include a CPU or computer, analog or digital input/output connections, stepper motor controller boards, etc. Instructions for implementing appropriate control operations are executed on the processor. These instructions may be stored on the memory devices associated with the controller 1250 or they may be provided over a network.

In certain embodiments, the controller 1250 controls all or most activities of the plasma processing apparatus 1200 described herein. For example, the controller 1250 may control all or most activities of the plasma processing apparatus 1200 associated with depositing Si layers, SiGe layers, or both types of layer and, optionally, other operations in a fabrication flow. The controller 1250 may execute system control software including sets of instructions for controlling the timing, gas composition, gas flow rates, chamber pressure, chamber temperature, RF power levels, substrate position, or other parameters. Other computer programs, scripts, or routines stored on memory devices associated with the controller 1250 may be employed in some embodiments. To provide relatively mild reactive conditions at the environment adjacent to the substrate 1212, parameters such as the RF power levels, gas flow rates to the plasma region 1224, gas flow rates to the chemical vapor deposition zone 1208, and timing of the plasma ignition can be adjusted and maintained by controller 1250. Additionally, adjusting the substrate position may further reduce the presence of high-energy radical species at the environment adjacent to the substrate 1212. In a multi-station reactor, the controller 1250 may comprise different or identical instructions for different apparatus stations, thus allowing the apparatus stations to operate either independently or synchronously.

In some embodiments, the controller 1250 may include instructions for performing operations such as flowing one or more precursors through the gas outlet 1242 into the reaction chamber 1204, providing a source gas into the remote plasma source 1202, generating one or more radical species of the source gas in the remote plasma source 1202 upstream of the one or more precursors, introducing the one or more radical species from the remote plasma source 1202 into the reaction chamber 1204 to react with the one or more precursors to deposit Si layers, SiGe layers, or both types of layers on a surface of the substrate 1212. The one or more radical species in the reaction chamber 1204 in an environment adjacent to the substrate 1212 may be hydrogen radicals in a ground state. In some implementations, the controller 1250 may include instructions for treating the surface of the substrate 1212 prior to depositing Si layers, SiGe layers, or both types of layers. In some implementations, the controller 1250 may include instructions for maintaining a temperature of the substrate 1212 equal to or less than about 400° C., or between about 200° C. and about 400° C.

In some embodiments, the apparatus 1200 may include a user interface associated with controller 1250. The user interface may include a display screen, graphical software displays of the apparatus 1200 or process conditions, and user input devices such as pointing devices, keyboards, touch screens, microphones, etc.

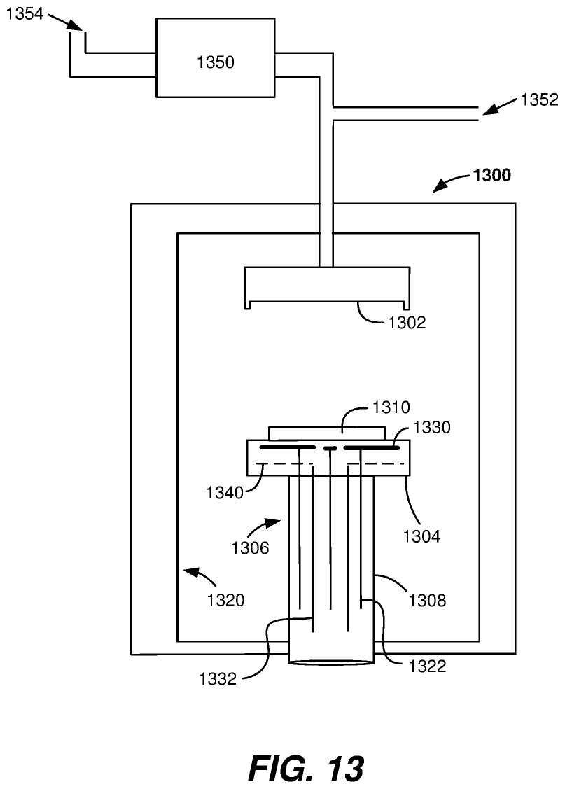

In some implementations, a plasma processing apparatus may utilize an electrostatic chuck for clamping or chucking a semiconductor substrate during processing. In some implementations, such electrostatic chucking may cause the substrate to be more securely clamped during, for example, a deposition process, which may ameliorate or prevent wafer bowing. It should be noted that, in some implementations, striking of capacitively coupled plasma (e.g., for in situ plasma) may occur using the electrostatic chuck, for example, using an RF generator operatively coupled to the electrostatic chuck. FIG. 13 and FIG. 14 show example schematic diagrams of plasma processing apparatuses that utilize electrostatic chucks. In the example of FIG. 13, the plasma processing apparatus utilizes a remote plasma source, which may be a CCP plasma source, an ICP plasma source, an ECR plasma source, a surface wave plasma (SWP) source (e.g., an RLSA plasma source), a microwave plasma source, or the like. In the example of FIG. 14, the plasma processing apparatus utilizes an ICP plasma source.

FIG. 13 shows a schematic illustration of an example plasma processing apparatus utilizing an electrostatic chuck for retaining a semiconductor substrate according to some implementations. As shown in FIG. 13, the plasma processing apparatus 1300 includes a remote plasma source 1350 for generating plasma and a reaction chamber 1320 for processing a substrate 1310. Plasma is generated upstream of the reaction chamber 1320 to provide indirect (remote) plasma exposure to the substrate 1310. Plasma-activated species may be supplied from the remote plasma source 1350 to the reaction chamber 1320 via a showerhead 1302. In some implementations, process gas(es), carrier gas(es), or combinations thereof may be delivered to the reaction chamber 1320 from gas line 1352 through the showerhead 1302. The substrate 1310 is supported by a substrate pedestal 1306 including a platen 1304 and a stem 1308 connected to an underside of the platen 1304. The platen 1304 may be a pedestal base and the stem 1308 may be a support column, where the pedestal base is positioned on top of the support column. The substrate pedestal 1306 may be an electrostatic chuck for retaining the substrate 1310 by electrostatic attractive forces. In some implementations, the plasma processing apparatus 1300 can perform remote plasma CVD or remote plasma ALD. In some implementations, the plasma processing apparatus 1300 may expose the substrate 1310 to elevated temperatures such as temperatures greater than about 300° C., greater than about 400° C., greater than about 500° C., between about 300° C. and about 750° C., or between about 500° C. and about 700° C. The substrate pedestal 1306 can support high temperature conditions and withstand harsh environments produced by the remote plasma CVD or remote plasma ALD.

The substrate pedestal 1306 is positioned within an interior of the reaction chamber 1320. The platen 1304 includes a surface for supporting the substrate 1310. The platen 1304 includes electrodes 1330 that may be embedded within a ceramic body of the platen 1304. The electrodes 1330 may include one or more clamping electrodes and optionally one or more RF electrodes, where the one or more clamping electrodes may receive power to clamp the substrate 1310 by electrostatic attractive forces. Power may be supplied to the electrodes 1330 via one or more electrical lines 1322 embedded in the substrate pedestal 1306. The platen 1304 further includes heating elements 1340, such as resistive heaters, configured to generate heat and control a temperature of the substrate 1310. For instance, the heating elements 1340 may heat the substrate 1310 to temperatures greater than about 450° C., greater than about 500° C., greater than about 550° C., greater than about 600° C., or greater than about 650° C. Power may be supplied to the heating elements 1340 via one or more power lines 1332 embedded in the substrate pedestal 1306.

In some embodiments, the electrodes 1330 may be coplanar or substantially coplanar. The electrodes 1330 may include one or more pairs of clamping electrodes having opposite polarities. In some embodiments, an outer ring-shaped RF electrode may surround the one or more pairs of clamping electrodes. The outer ring-shaped RF electrode may further include a radially extending lead or power feed strip that extends diagonally across the outer ring-shaped RF electrode. This allows a terminal to be connected at or near a center of the platen 1304 to power the outer ring-shaped RF electrode. The outer ring-shaped RF electrode serves to minimize undesirable inductance effects that would otherwise be created by embedded power distribution circuits, and also serves to minimize adverse effects of disturbances to an RF field above the substrate 1310 being processed. In some embodiments, the electrodes 1330 include one or more clamping electrodes powered by a DC power source to provide DC chucking voltage (e.g., between about 200 V to about 2000 V), and the electrodes 1330 further includes at least one outer ring-shaped RF electrode powered by an RF power source to provide RF bias voltage (e.g., one or more frequencies of about 400 kHz to about 60 MHz at power levels of about 50 W to about 3000 W), and the electrodes 1330 may optionally include at least one electrode powered by DC and RF power sources via suitable circuitry. In some implementations, electrodes 1330 may be used to ground RF instead of supplying RF. In other implementations, electrodes 1330 may be configured to act as a guard ring for the DC.

In some embodiments, an inside of the stem 1308 may include electrical lines 1322, 1332. First electrical lines 1322 may power the electrodes 1330 and second electrical lines 1332 may power the heating elements 1340. Some portions of the stem 1308 may be hollow to house the electrical lines 1322, 1332. In some cases, channels or tubes (not shown) may extend through the stem 1308 to provide a gas passage to an upper surface of the platen 1304. The gas passage may facilitate delivery of an inert gas, heat transfer gas, or other gas to an underside of the substrate 1310 being supported on the platen 1304.

In some embodiments, the substrate pedestal 1306 includes ceramic material(s) such as aluminum oxide (alumina), aluminum nitride, aluminum oxynitride, yttria, boron nitride, silicon oxide, silicon carbide, silicon nitride, titanium oxide, zirconium oxide, or other suitable ceramic material. For example, the substrate pedestal 1306 can be made of an aluminum-containing material, where the aluminum-containing material comprises alumina, aluminum nitride, aluminum oxynitride, or combinations thereof. The platen 1304 and the stem 1308 may be made of any of the foregoing ceramic materials, where a bottom surface of the platen 1304 may be joined to an upper surface of the stem 1308 by brazing, friction welding, diffusion bonding, or other suitable technique.

Plasma generated in the remote plasma source 1350 may include energetic species (e.g., radicals, ions, or both) of a process gas. An RF power supply (not shown) may be coupled to the remote plasma source 1350 to ignite and sustain plasma in the remote plasma source 1350. In some embodiments, the RF power supply may be configured to control high- and low-frequency RF power sources independently of one another. Example low-frequency RF frequencies may include but are not limited to frequencies between about 0 kHz and about 500 kHz. Example high-frequency RF frequencies may include but are not limited to frequencies between about 1.8 MHz and about 2.45 GHz, or equal to or greater than about 13.56 MHz, equal to or greater than about 27 MHz, equal to or greater than about 30 MHz, or equal to or greater than about 60 MHz. It will be appreciated that any suitable parameters may be modulated discretely or continuously to provide plasma energy for surface reactions. In some embodiments, the RF power supply is configured to supply plasma power in a range between about 500 W and about 15 kW per station, between about 2 kW and about 10 kW per station, or between about 3 kW and about 8 kW per station, such as about 6.5 kW per station. High plasma power may be supplied and controlled to generate amine-containing radicals, nitrogen-containing radicals, helium-containing metastables, argon-containing metastables, hydrogen-containing radicals, or a combination thereof in a remote plasma. It should be noted that, in some embodiments, a reactive plasma may contain substantially no components that react with silicon, with germanium, or with both silicon and germanium. As an example, a reactive plasma may contain only hydrogen (e.g., H* or H₂), deuterium (e.g., D* or D₂), hydrogen deuteride (HD), an inert gas (e.g., He, Ar, He*, Ar*, etc.), or any combination thereof. In some embodiments, a reactive plasma does not contain a nitrogen-containing species, an oxygen-containing species, a halogen-containing species, or a combination thereof. In some embodiments, a coil (not shown) may be positioned around an outer wall (e.g., quartz dome) of the remote plasma source 1350 to provide inductively coupled plasma (ICP) generation. In some instances, the RF power supply is electrically coupled to the coil via an impedance matching network. However, it will be understood that the remote plasma source 1350 may alternatively be equipped to provide capacitively-coupled plasma (CCP) generation.

Gas lines 1352, 1354 may supply precursor gas(es), reactant gas(es), inert gas(es), or other gas(es) to the plasma processing apparatus 1300. Process gases delivered through the gas lines 1352, 1354 participate in gas phase reactions for depositing films in CVD processes. These films may include, for example, silicon-containing films such as silicon or silicon-germanium. Gas line 1354 may be fluidly coupled to the remote plasma source 1350 for supplying reactant gases for remote plasma generation, and gas line 1352 may be fluidly coupled to the reaction chamber 1320 for supplying precursor gases. The gas line 1352 may be positioned downstream of the remote plasma source 1350. This separates delivery of the reactant gases from the precursor gases. In some embodiments, precursor gases may include Si precursor gases, Ge precursor gases, or SiGe precursor gases, as well as combinations thereof.

FIG. 14 shows a schematic illustration of an example plasma processing apparatus with a remote plasma source that is an inductively coupled plasma source according to some implementations. The plasma processing apparatus 1400 includes a remote plasma source 1402 separated from a reaction chamber 1404. The remote plasma source 1402 is fluidly coupled with the reaction chamber 1404 via a gas distributor or showerhead 1406. In some embodiments, the showerhead 1406 includes an ion filter for filtering ions to limit ion bombardment damage to a substrate 1412. Energetic species (e.g., radical species, ions, and the like) can be generated in the remote plasma source 1402, where the radical species may be supplied to the reaction chamber 1404. Precursors such as Si precursors, Ge precursors, SiGe precursors, or combinations thereof are supplied to the reaction chamber 1404 through gas outlets 1408 positioned downstream from the remote plasma source 1402 and from the showerhead 1406. It will be understood, however, that other precursors may be supplied to the reaction chamber 1404 through gas outlets 1408 for depositing films. The precursors react with the radical species in a deposition zone 1410 of the reaction chamber 1404 to deposit film on a surface of the substrate 1412. The deposition zone 1410 includes an environment adjacent to the surface of the substrate 1412.

The substrate 1412 is supported on a substrate support structure or wafer pedestal 1414. The wafer pedestal 1414 may be configured with lift pins or other movable support members to position the substrate 1412 within the deposition zone 1410. The substrate 1412 may be moved to a position closer or farther from the showerhead 1406. The wafer pedestal 1414 is shown in FIG. 14 as having elevated the substrate 1412 within the deposition zone 1410.

In some embodiments, the wafer pedestal 1414 includes an electrostatic chuck 1416. The electrostatic chuck 1416 includes one or more electrostatic clamping electrodes 1418 embedded within a body of the electrostatic chuck 1416. In some implementations, the one or more electrostatic clamping electrodes 1418 may be coplanar or substantially coplanar. The electrostatic clamping electrodes 1418 may be powered by a DC power source or DC chucking voltage (e.g., between about 200 V to about 2000 V) so that the substrate 1412 may be retained on the electrostatic chuck 1416 by electrostatic attractive forces. Power to the electrostatic clamping electrodes 1418 may be provided via first electrical lines 1420. The electrostatic chuck 1416 may further include one or more heating elements 1422 embedded within the body of the electrostatic chuck 1416. The one or more heating elements 1422 may include resistive heaters. In some embodiments, the one or more heating elements 1422 are positioned below the one or more electrostatic clamping electrodes 1418. The one or more heating elements 1422 may be configured to heat the substrate 1412 to a temperature greater than about 450° C., greater than about 500° C., greater than about 550° C., greater than about 600° C., or greater than about 650° C. The one or more heating elements 1422 provide selective temperature control to the substrate 1412. Power to the one or more heating elements 1422 may be provided via second electrical lines 1424.

The wafer pedestal 1414 includes the electrostatic chuck 1416 and a stem 1426 connected to an underside of the electrostatic chuck 1416. The electrostatic chuck 1416 may serve as a pedestal base or platen, and the stem 1426 may serve as a support column. At least some portions of the stem 1426 may be hollow so that the first electrical lines 1420 and the second electrical lines 1424 may be housed in the stem 1426. In some cases, the stem 1426 may facilitate passage of gases to a backside of the substrate 1412. In some implementations, backside gases may be provided via an annulus outside stem 1426.

A coil 1428 is arranged around the remote plasma source 1402, where the remote plasma source 1402 includes an outer wall (e.g., quartz dome). The coil 1428 is electrically coupled to a plasma generator controller 1432, which may be used to form and sustain plasma within a plasma region 1434 via inductively coupled plasma generation. In some implementations, the plasma generator controller 1432 may include a power supply for supplying power to the coil 1428, where the power can be in a range between about 500 W and about 15 kW per station, or between about 2 kW and about 10 kW per station during plasma generation. In some implementations, electrodes or antenna for parallel plate or capacitively coupled plasma generation may be used to generate a continuous supply of radicals via plasma excitation rather than inductively coupled plasma generation. Regardless of the mechanism used to ignite and sustain the plasma in the plasma region 1434, radical species may continuously be generated using plasma excitation during film deposition. In some implementations, hydrogen radicals (H*), nitrogen radicals (N*), amine radicals (NH*, NH₂*), helium metastables (He*), argon metastables (Ar*), or combinations thereof, are generated in the plasma region 1434 under approximately steady-state conditions during steady-state film deposition, though transients may occur at the beginning and end of film deposition. For example, nitrogen-containing radicals may be generated in the plasma region 1434, where the nitrogen-containing radicals comprise at least one of nitrogen radicals (N*) and amine radicals (NH*, NH₂*). It should be noted that, in some embodiments, the radical species may contain substantially no components that react with silicon, with germanium, or with both silicon and germanium. As an example, in some embodiments, reactive plasma may contain only hydrogen (e.g., H* or H₂), deuterium (e.g., D* or D₂), hydrogen deuteride (HD), an inert gas (e.g., He, Ar, He*, Ar*, etc.), or any combination thereof. In some embodiments, the radicals may not include a nitrogen-containing species, a halogen-containing species, an oxygen-containing species, or a combination thereof.

A supply of ions and radicals may be continuously generated within the plasma region 1434 while source gas is being supplied to the remote plasma source 1402. Ions generated in the plasma region 1434 may be filtered out by the ion filter of the showerhead 1406. That way, radicals generated in the plasma region 1434 may be supplied to the substrate 1412 in the reaction chamber 1404 while limiting ion bombardment. Conditions in the remote plasma source 1402, including a composition of the source gas provided to the remote plasma source 1402 and RF power supplied to the coil 1428, may be controlled to optimize generation of desired radical species in the plasma region 1434. In some embodiments, the source gas may include an oxygen-containing reactant such as oxygen or nitrogen-containing reactant such as nitrogen. In some other embodiments, the source gas may include hydrogen gas. In some other embodiments, the source gas may include helium gas, argon gas, or other inert gas.

In some embodiments, the source gas may be mixed with one or more additional gases. These one or more additional gases may be supplied to the remote plasma source 1402. In some implementations, the source gas is mixed with one or more additional gases to form a gas mixture, where the one or more additional gases can include a carrier gas. Non-limiting examples of additional gases can include helium (He), neon (Ne), argon (Ar), krypton (Kr), and xenon (Xe). Other examples of additional gases can include hydrogen (H₂) and ammonia (NH₃). In some embodiments, the additional gases may be limited to those that contain substantially no components that react with silicon, with germanium, or with both silicon and germanium. For example, in some embodiments, the additional gases may not include nitrogen-containing gases, oxygen-containing gases, or a combination thereof. The one or more additional gases may support or stabilize steady-state plasma conditions within the remote plasma source 1402 or aid in transient plasma ignition or extinction processes. In FIG. 14, a source gas supply 1436 is fluidly coupled with the remote plasma source 1402 for supplying the source gas (e.g., by way of gas inlet 1436a). In addition, an additional gas supply 1438 is fluidly coupled with the remote plasma source 1402 for supplying the one or more additional gases (e.g., by way of gas inlet 1438a). While the embodiment in FIG. 14 depicts the gas mixture of the source gas and the one or more additional gases being introduced through separate gas outlets, it will be understood that the gas mixture may be introduced directly into the remote plasma source 1402. That is, a pre-mixed dilute gas mixture may be supplied to the remote plasma source 1402 through a single gas outlet.

Plasma-activated gases 1442, such as excited nitrogen, hydrogen, helium, argon, amine radicals, or combinations of such radicals, flow out of the remote plasma source 1402 and into the reaction chamber 1404 via showerhead 1406. Plasma-activated gases 1442 within the showerhead 1406 and within the reaction chamber 1404 are generally not subject to continued plasma excitation therein. The showerhead 1406 may have a plurality of gas ports to diffuse the flow of plasma-activated gases 1442 into the reaction chamber 1404. In some implementations, the plurality of gas ports may be mutually spaced apart. In some implementations, the plurality of gas ports may be arranged as an array of regularly spaced apart channels or through-holes extending through a plate separating the remote plasma source 1402 and the reaction chamber 1404. The plurality of gas ports may smoothly disperse and diffuse exiting radicals (including plasma-activated gases 1442) from the remote plasma source 1402 into the deposition zone 1410 of the reaction chamber 1404 while filtering out ions.

With the delivery of the plasma-activated gases 1442 to the reaction chamber 1404 from the showerhead 1406, precursors 1444 (or other process gases) may be introduced into the reaction chamber 1404. The precursors 1444 may include Si precursors, Ge precursors, SiGe precursors, and combinations thereof. The precursors 1444 may be introduced via gas outlets 1408, where the gas outlets 1408 may be fluidly coupled with a precursor supply source 1440 (e.g., by way of gas inlet 1440a). The gas outlets 1408 may include mutually spaced apart openings so that the flow of the precursors 1444 may be introduced in a direction parallel with the plasma-activated gases 1442 flowing from the showerhead 1406. In some embodiments, the gas outlets 1408 may be located downstream from the showerhead 1406. In some embodiments, the gas outlets 1408 are part of the showerhead 1406 such as in a dual-plenum showerhead. The dual-plenum showerhead may provide separate outlets/passages for the plasma-activated species 1442 and the precursors 1444 to avoid mixing in the showerhead 1406. That way, the precursors 1444 may flow into the reaction chamber 1404 via the showerhead 1406 without exposure to plasma in the remote plasma source 1402. The gas outlets 1408 may be located upstream from the deposition zone 1410 and the substrate 1412. The chemical vapor deposition zone 1410 is located within the interior of the reaction chamber 1404 between the gas outlets 1408 and the substrate 1412.

A substantial fraction of the precursors 1444 may be prevented from mixing with plasma-activated species 1442 in the showerhead 1406 or adjacent to the showerhead 1406. In some implementations, precursors 1444 may be delivered to the substrate 1412 in dose phases of ALD cycles separate from plasma-activated species 1442 delivered to the substrate 1412 during plasma exposure phases of the ALD cycles. Adsorbed precursors 1444 may react with radicals of the plasma-activated species 1442 during plasma exposure phases of the ALD cycles to deposit film. In some implementations, precursors 1444 may be delivered to the substrate 1412 in a continuous manner to interact with plasma-activated species 1442 in a deposition zone 1410 to deposit film by CVD. The radicals of the plasma-activated species 1442 mix with the precursors 1444 in the gas phase during CVD formation of the film.

Gases may be removed from the reaction chamber 1404 via an outlet 1448 that is fluidly coupled to a pump (not shown). Thus, excess silicon-containing precursors, germanium-containing precursors, reactant gases, radical species, and diluent and displacement or purge gases may be removed from the reaction chamber 1404.

In some embodiments, a thermal shield (not shown) may be positioned underneath the wafer pedestal 1414. The thermal shield serves as a thermal insulator under the wafer pedestal 1414 to mitigate heat loss via thermal radiation, thereby reducing the amount of power needed to maintain the wafer pedestal 1414 at a particular elevated temperature and also preventing other components within the reaction chamber 1404 from overheating due to excess heat radiated from the wafer pedestal 1414. For example, the thermal shield may be radially offset from the stem 1426 and may have a thin annular-shaped body with a high view factor relative to the underside of the electrostatic chuck 1416. Thus, the annular-shaped thermal shield may reduce radiative heat loss from the wafer pedestal 1414.

The electrostatic chuck 1416 of the wafer pedestal 1414 may chuck/dechuck the substrate 1412 in the plasma processing apparatus 1400 that is configured to operate at high temperatures, configured to deposit film such as silicon-containing film by remote plasma ALD, remote plasma CVD, or by thermal ALD, and configured to operate in corrosive environments. Such high temperatures may be greater than about 450° C., greater than about 500° C., greater than about 550° C., greater than about 600° C., or greater than about 650° C.

In some implementations, a system controller 1450 is in operative communication with the plasma processing apparatus 1400. In some implementations, the system controller 1450 includes a processor system 1452 (e.g., microprocessor) configured to execute instructions held in a data system 1454 (e.g., memory). In some implementations, the system controller 1450 may be in communication with the plasma generator controller 1432 to control plasma parameters or conditions in the remote plasma source 1402. In some implementations, the system controller 1450 may be in communication with the wafer pedestal 1414 to control pedestal elevation, electrostatic chucking and dechucking, and temperature. In some implementations, the system controller 1450 may control other processing conditions, such as RF power settings, frequency settings, duty cycles, pulse times, pressure within the reaction chamber 1404, pressure within the remote plasma source 1402, gas flow rates from the source gas supply 1436, gas flow rates from the additional gas supply 1438, gas flow rates from the precursor supply source 1440 and other sources, temperature of the wafer pedestal 1414, and temperature of the reaction chamber 1404, among other processing conditions.

The controller 1450 may contain instructions for controlling process conditions for the operation of the plasma processing apparatus 1400. The controller 1450 will typically include one or more memory devices and one or more processors. The processor may include a CPU or computer, analog or digital input/output connections, stepper motor controller boards, etc. Instructions for implementing appropriate control operations are executed on the processor. These instructions may be stored on the memory devices associated with the controller 1450 or they may be provided over a network.

In certain embodiments, the controller 1450 controls all or most activities of the plasma processing apparatus 1400 described herein. For example, the controller 1450 may control all or most activities of the plasma processing apparatus 1400 associated with depositing a silicon-containing film and, optionally, other operations in a fabrication flow that includes the silicon-containing film. The controller 1450 may execute system control software including sets of instructions for controlling the timing, gas composition, gas flow rates, chamber pressure, chamber temperature, RF power levels, substrate position, substrate temperature, DC chucking voltage, dechucking routines, or other parameters. Other computer programs, scripts, or routines stored on memory devices associated with the controller 1450 may be employed in some embodiments. In a multi-station reactor, the controller 1450 may comprise different or identical instructions for different apparatus stations, thus allowing the apparatus stations to operate either independently or synchronously.

In some embodiments, the controller 1450 may include instructions configured to perform operations such as introducing a first dose of a precursor 1444 in a vapor phase to adsorb on the substrate 1412, and exposing the substrate 1412 to plasma-activated species 1442 of a source gas generated in the remote plasma source 1402, where the adsorbed precursor 1444 reacts with the plasma-activated species 1442 to deposit a film. In some embodiments, the controller 1450 may include instructions configured to perform operations such as setting the chamber pressure in the reaction chamber 1404 to between about 1 Torr and about 10 Torr, and setting a substrate temperature to an elevated temperature between about 500° C. and about 700° C. In some embodiments, the controller 1450 may include instructions configured to perform operations such as applying a first voltage to the electrostatic chuck 1416 of the wafer pedestal 1414 for electrostatically clamping the substrate 1412 in the reaction chamber 1404, reversing a polarity of the first voltage applied to the electrostatic chuck 1416, applying a second voltage to the electrostatic chuck 1416 that is less than the first voltage, reversing a polarity of the second voltage applied to the electrostatic chuck 1416, and removing the substrate 1412 from the electrostatic chuck 1416.

In some embodiments, the apparatus 1400 may include a user interface associated with controller 1450. The user interface may include a display screen, graphical software displays of the apparatus 1400 or process conditions, and user input devices such as pointing devices, keyboards, touch screens, microphones, etc.

The computer program code for controlling the above operations can be written in any conventional computer readable programming language: for example, assembly language, C, C++, Pascal, Fortran, or others. Compiled object code or script is executed by the processor to perform the tasks identified in the program.

Signals for monitoring the process may be provided by analog or digital input connections of the system controller. The signals for controlling the process are output on the analog and digital output connections of the processing system.

In general, the methods described herein can be performed on systems including semiconductor processing equipment such as a processing tool or tools, chamber or chambers, a platform or platforms for processing, or specific processing components (a wafer pedestal, a gas flow system, etc.). These systems may be integrated with electronics for controlling their operation before, during, and after processing of a semiconductor wafer or substrate. In general, the electronics are referred to as the controller, which may control various components or subparts of the system or systems. The controller, depending on the processing requirements or the type of system, may be programmed to control any of the processes disclosed herein, including the delivery of processing gases, temperature settings (e.g., heating or cooling), pressure settings, vacuum settings, power settings, RF generator settings, RF matching circuit settings, frequency settings, flow rate settings, fluid delivery settings, positional and operation settings, wafer transfers into and out of a tool and other transfer tools or load locks connected to or interfaced with a specific system.

### Definitions and Substitutions

This section presents additional definitions that may be used herein. Some of the materials described in this section may overlap with those presented elsewhere in the application.

The term “acyl,” or “alkanoyl,” as used interchangeably herein, represents groups of 1, 2, 3, 4, 5, 6, 7, 8 or more carbon atoms of a straight, branched, cyclic configuration, saturated, unsaturated and aromatic, and combinations thereof, or hydrogen, attached to the parent molecular group through a carbonyl group, as defined herein. This group is exemplified by formyl, acetyl, propionyl, isobutyryl, butanoyl, and the like. In some embodiments, the acyl or alkanoyl group is —C(O)—R, in which R is hydrogen, an aliphatic group, or an aromatic group, as defined herein.

By “acyl halide” is meant —C(O)X, where X is a halogen, such as Br, F, I, or C₁.

By “aldehyde” is meant a —C(O)H group.

By “aliphatic” is meant a hydrocarbon group having at least one carbon atom to 50 carbon atoms (C₁₋₅₀), such as one to 25 carbon atoms (C₁₋₂₅), or one to ten carbon atoms (C₁₋₁₀), and which includes alkanes (or alkyl), alkenes (or alkenyl), alkynes (or alkynyl), including cyclic versions thereof, and further including straight- and branched-chain arrangements, and all stereo and position isomers as well. An aliphatic group is unsubstituted or substituted, e.g., by a functional group described herein. For example, the aliphatic group can be substituted with one or more substitution groups, as described herein for alkyl.

By “alkyl-aryl,” “alkenyl-aryl,” and “alkynyl-aryl” is meant an aryl group, as defined herein, that is or can be coupled (or attached) to the parent molecular group through an alkyl, alkenyl, or alkynyl group, respectively, as defined herein. The alkyl-aryl, alkenyl-aryl, or alkynyl-aryl group can be substituted or unsubstituted. For example, the alkyl-aryl, alkenyl-aryl, or alkynyl-aryl group can be substituted with one or more substitution groups, as described herein for alkyl, alkenyl, alkynyl, or aryl. Example unsubstituted alkyl-aryl groups are of from 7 to 16 carbons (C₇₋₁₆ alkyl-aryl), as well as those having an alkyl group with 1 to 6 carbons and an aryl group with 4 to 18 carbons (i.e., C₁₋₆ alkyl-C₄₋₁₈ aryl). Example unsubstituted alkenyl-aryl groups are of from 7 to 16 carbons (C₇₋₁₆ alkenyl-aryl), as well as those having an alkenyl group with 2 to 6 carbons and an aryl group with 4 to 18 carbons (i.e., C₂₋₆ alkenyl-C₄₋₁₈ aryl). Example unsubstituted alkynyl-aryl groups are of from 7 to 16 carbons (C₇₋₁₆ alkynyl-aryl), as well as those having an alkynyl group with 2 to 6 carbons and an aryl group with 4 to 18 carbons (i.e., C₂₋₆ alkynyl-C₄₋₁₈ aryl). In some embodiments, the alkyl-aryl group is -L-R, in which L is an alkyl group, as defined herein, and R is an aryl group, as defined herein. In some embodiments, the alkenyl-aryl group is -L-R, in which L is an alkenyl group, as defined herein, and R is an aryl group, as defined herein. In some embodiments, the alkynyl-aryl group is -L-R, in which L is an alkynyl group, as defined herein, and R is an aryl group, as defined herein.

By “alkenyl” is meant an unsaturated monovalent hydrocarbon having at least two carbon atom to 50 carbon atoms (C₂₋₅₀), such as two to 25 carbon atoms (C₂₋₂₅), or two to ten carbon atoms (C₂₋₁₀), and at least one carbon-carbon double bond, wherein the unsaturated monovalent hydrocarbon can be derived from removing one hydrogen atom from one carbon atom of a parent alkene. An alkenyl group can be branched, straight-chain, cyclic (e.g., cycloalkenyl), cis, or trans (e.g., E or Z). An example alkenyl includes an optionally substituted C₂₋₂₄ alkyl group having one or more double bonds. The alkenyl group can be monovalent or multivalent (e.g., bivalent) by removing one or more hydrogens to form appropriate attachment to the parent molecular group or appropriate attachment between the parent molecular group and another substitution. The alkenyl group can also be substituted or unsubstituted. For example, the alkenyl group can be substituted with one or more substitution groups, as described herein for alkyl.

By “alkyl-heteroaryl” is meant a heteroaryl group, as defined herein, attached to the parent molecular group through an alkyl group, as defined herein. In some embodiments, the alkyl-heteroaryl group is -L-R, in which L is an alkyl group, as defined herein, and R is a heteroaryl group, as defined herein.

By “alkyl-heterocyclyl,” “alkenyl-heterocyclyl,” and “alkynyl-heterocyclyl” is meant a heterocyclyl group, as defined herein, that is or can be coupled (or attached) to the parent molecular group through an alkyl, alkenyl, or alkynyl group, respectively, as defined herein. The alkyl-heterocyclyl, alkenyl-heterocyclyl, or alkynyl-heterocyclyl group can be substituted or unsubstituted. For example, the alkyl-heterocyclyl, alkenyl-heterocyclyl, or alkynyl-heterocyclyl group can be substituted with one or more substitution groups, as described herein for alkyl, alkenyl, alkynyl, or heterocyclyl. Example unsubstituted alkyl-heterocyclyl groups are of from 2 to 16 carbons (C₂₋₁₆ alkyl-heterocyclyl), as well as those having an alkyl group with 1 to 6 carbons and a heterocyclyl group with 1 to 18 carbons (i.e., C₁₋₆ alkyl-C₁₋₁₈ heterocyclyl). Example unsubstituted alkenyl-heterocyclyl groups are of from 3 to 16 carbons (C₃₋₁₆ alkenyl-heterocyclyl), as well as those having an alkenyl group with 2 to 6 carbons and a heterocyclyl group with 1 to 18 carbons (i.e., C₂₋₆ alkenyl-C₁₋₁₈ heterocyclyl). Example unsubstituted alkynyl-heterocyclyl groups are of from 3 to 16 carbons (C₃₋₁₆ alkynyl-heterocyclyl), as well as those having an alkynyl group with 2 to 6 carbons and a heterocyclyl group with 1 to 18 carbons (i.e., C₂₋₆ alkynyl-C₁₋₁₈ heterocyclyl). In some embodiments, the alkyl-heterocyclyl group is -L-R, in which L is an alkyl group, as defined herein, and R is a heterocyclyl group, as defined herein. In some embodiments, the alkenyl-heterocyclyl group is -L-R, in which L is an alkenyl group, as defined herein, and R is a heterocyclyl group, as defined herein. In some embodiments, the alkynyl-heterocyclyl group is -L-R, in which L is an alkynyl group, as defined herein, and R is a heterocyclyl group, as defined herein.

By “alkoxy” is meant —OR, where R is an optionally substituted aliphatic group, as described herein. Example alkoxy groups include, but are not limited to, methoxy, ethoxy, n-propoxy, isopropoxy, n-butoxy, t-butoxy, sec-butoxy, n-pentoxy, trihaloalkoxy, such as trifluoromethoxy, etc. The alkoxy group can be substituted or unsubstituted. For example, the alkoxy group can be substituted with one or more substitution groups, as described herein for alkyl.

Example unsubstituted alkoxy groups include C₁₋₃, C₁₋₆, C₁₋₁₂, C₁₋₁₆, C₁₋₁₈, C₁₋₂₀, or C₁₋₂₄ alkoxy groups.

By “alkyl” is meant a saturated monovalent hydrocarbon having at least one carbon atom to 50 carbon atoms (C₁₋₅₀), such as one to 25 carbon atoms (C₁₋₂₅), or one to ten carbon atoms (C₁₋₁₀), wherein the saturated monovalent hydrocarbon can be derived from removing one hydrogen atom from one carbon atom of a parent compound (e.g., alkane). An alkyl group can be branched, straight-chain, or cyclic (e.g., cycloalkyl). An exemplary alkyl includes a branched or unbranched saturated hydrocarbon group of 1 to 24 carbon atoms, such as methyl (Me), ethyl (Et), n-propyl (nPr), iso-propyl (iPr), n-butyl (nBu), iso-butyl (iBu), sec-butyl (sBu), tert-butyl (tBu), pentyl (Pe), n-pentyl (nPe), isopentyl (iPe), s-pentyl (sPe), neopentyl (neoPe), tert-pentyl (tPe), hexyl, heptyl, octyl, nonyl, decyl, dodecyl, tetradecyl, hexadecyl, eicosyl, tetracosyl, and the like. The alkyl group can also be substituted or unsubstituted. The alkyl group can be monovalent or multivalent (e.g., bivalent) by removing one or more hydrogens to form appropriate attachment to the parent molecular group or appropriate attachment between the parent molecular group and another substitution. For example, the alkyl group can be substituted with one, two, three or, in the case of alkyl groups of two carbons or more, four substituents independently selected from the group consisting of: (1) C₁₋₆ alkoxy (e.g., —O—R, in which R is C₁₋₆ alkyl); (2) C₁₋₆ alkylsulfinyl (e.g., —S(O)—R, in which R is C₁₋₆ alkyl); (3) C₁₋₆ alkylsulfonyl (e.g., —SO₂—R, in which R is C₁₋₆ alkyl); (4) amine (e.g., —NR¹R², where each of R¹ and R² is, independently, selected from hydrogen, aliphatic, heteroaliphatic, haloaliphatic, haloheteroaliphatic, aromatic, as defined herein, or any combination thereof, or R¹ and R², taken together with the nitrogen atom to which each are attached, can form a heterocyclyl group, as defined herein); (5) aryl; (6) arylalkoxy (e.g., —O-L-R, in which L is alkyl and R is aryl); (7) aryloyl (e.g., —C(O)—R, in which R is aryl); (8) azido (e.g., -N₃); (9) cyano (e.g., —CN); (10) aldehyde (e.g., —C(O)H); (11) C₃₋₈ cycloalkyl; (12) halo; (13) heterocyclyl (e.g., as defined herein, such as a 5-, 6- or 7-membered ring containing one, two, three, or four non-carbon heteroatoms); (14) heterocyclyloxy (e.g., —O—R, in which R is heterocyclyl, as defined herein); (15) heterocyclyloyl (e.g., —C(O)—R, in which R is heterocyclyl, as defined herein); (16) hydroxyl (e.g., —OH); (17)N-protected amino; (18) nitro (e.g., —NO₂); (19) oxo (e.g., ═O); (20) C₁₋₆ thioalkyl (e.g., —S—R, in which R is alkyl); (21) thiol (e.g., —SH); (22) —CO₂R¹, where R¹ is selected from the group consisting of (a) hydrogen, (b) C₁₋₆ alkyl, (c) C₄₋₁₈ aryl, and (d) C₁₋₆ alkyl-C₄₋₁₈ aryl (e.g., -L-R, in which L is C₁₋₆ alkyl and R is C₄₋₁₈ aryl); (23) —C(O)NR¹R², where each of R¹ and R² is, independently, selected from the group consisting of (a) hydrogen, (b) C₁₋₆ alkyl, (c) C₄₋₁₈ aryl, and (d) C₁₋₆ alkyl-C₄₋₁₈ aryl (e.g., -L-R, in which L is C₁₋₆ alkyl and R is C₄₋₁₈ aryl); (24) —SO₂R¹, where R¹ is selected from the group consisting of (a) C₁₋₆ alkyl, (b) C₄₋₁₈ aryl, and (c) C₁₋₆ alkyl-C₄₋₁₈ aryl (e.g., -L-R, in which L is C₁₋₆ alkyl and R is C₄₋₁₈ aryl); (25) —SO₂NR¹R², where each of R¹ and R² is, independently, selected from the group consisting of (a) hydrogen, (b) C₁₋₆ alkyl, (c) C₄₋₁₈ aryl, and (d) C₁₋₆ alkyl-C₄₋₁₈ aryl (e.g., -L-R, in which L is C₁₋₆ alkyl and R is C₄₋₁₈ aryl); and (26) —NR¹R², where each of R¹ and R² is, independently, selected from the group consisting of (a) hydrogen, (b) an N-protecting group, (c) C₁₋₆ alkyl, (d) C₂₋₆ alkenyl, (e) C₂₋₆ alkynyl, (f) C₄₋₁₈ aryl, (g) C₁₋₆ alkyl-C₄₋₁₈ aryl (e.g., -L-R, in which L is C₁₋₆ alkyl and R is C₄₋₁₈ aryl), (h) C₃₋₈ cycloalkyl, and (i) C₁₋₆ alkyl-C₃₋₈ cycloalkyl (e.g., -L-R, in which L is C₁₋₆ alkyl and R is C₃₋₈ cycloalkyl), wherein in one embodiment no two groups are bound to the nitrogen atom through a carbonyl group or a sulfonyl group. The alkyl group can be a primary, secondary, or tertiary alkyl group substituted with one or more substituents (e.g., one or more halo or alkoxy). In some embodiments, the unsubstituted alkyl group is a C₁₋₃, C₁₋₆, C₁₋₁₂, C₁₋₁₆, C₁₋₁₈, C₁₋₂₀, or C₁₋₂₄ alkyl group.

By “alkylsulfinyl” is meant an alkyl group, as defined herein, attached to the parent molecular group through an —S(O)— group. In some embodiments, the unsubstituted alkylsulfinyl group is a C₁₋₆ or C₁₋₁₂ alkylsulfinyl group. In other embodiments, the alkylsulfinyl group is —S(O)—R, in which R is an alkyl group, as defined herein.

By “alkylsulfonyl” is meant an alkyl group, as defined herein, attached to the parent molecular group through an —SO₂— group. In some embodiments, the unsubstituted alkylsulfonyl group is a C₁₋₆ or C₁₋₁₂ alkylsulfonyl group. In other embodiments, the alkylsulfonyl group is —SO₂—R, where R is an optionally substituted alkyl (e.g., as described herein, including optionally substituted C₁₋₁₂ alkyl, haloalkyl, or perfluoroalkyl).

By “alkynyl” is meant an unsaturated monovalent hydrocarbon having at least two carbon atom to 50 carbon atoms (C₂-5o), such as two to 25 carbon atoms (C₂₋₂₅), or two to ten carbon atoms (C₂₋₁₀), and at least one carbon-carbon triple bond, wherein the unsaturated monovalent hydrocarbon can be derived from removing one hydrogen atom from one carbon atom of a parent alkyne. An alkynyl group can be branched, straight-chain, or cyclic (e.g., cycloalkynyl). An example alkynyl includes an optionally substituted C₂₋₂₄ alkyl group having one or more triple bonds. The alkynyl group can be cyclic or acyclic and is exemplified by ethynyl, 1-propynyl, and the like. The alkynyl group can be monovalent or multivalent (e.g., bivalent) by removing one or more hydrogens to form appropriate attachment to the parent molecular group or appropriate attachment between the parent molecular group and another substitution. The alkynyl group can also be substituted or unsubstituted. For example, the alkynyl group can be substituted with one or more substitution groups, as described herein for alkyl.

By “amide” is mean —C(O)NR¹R² or —NHCOR¹, where each of R¹ and R² is, independently, selected from hydrogen, aliphatic, heteroaliphatic, haloaliphatic, haloheteroaliphatic, aromatic, as defined herein, or any combination thereof, or R¹ and R², taken together with the nitrogen atom to which each are attached, form a heterocyclyl group, as defined herein.

By “amine” or “amino” is meant —NR¹R², where each of R¹ and R² is, independently, selected from hydrogen, optionally substituted aliphatic, optionally substituted heteroaliphatic, optionally substituted haloaliphatic, optionally substituted haloheteroaliphatic, optionally substituted aromatic, optionally substituted silyl, or optionally substituted silyloxy, as defined herein, or any combination thereof, or R¹ and R², taken together with the nitrogen atom to which each are attached, form a heterocyclyl group, as defined herein. In particular embodiments, each of R¹ and R² is, independently, H, optionally substituted alkyl, optionally substituted alkoxy, optionally substituted aryl, optionally substituted aryloxy, optionally substituted alkyl-aryl, optionally substituted aryl-alkyl, optionally substituted silyl, or optionally substituted silyloxy. In particular embodiments, R¹ and R² can be taken together, with the nitrogen atom to which each is attached, to form an optionally substituted heterocyclyl.

By “aminoalkyl” is meant an alkyl group, as defined herein, substituted by an amine group, as defined herein. In some embodiments, the aminoalkyl group is -L-NR¹R², in which L is an alkyl group, as defined herein, and each of R¹ and R² is, independently, selected from hydrogen, aliphatic, heteroaliphatic, haloaliphatic, haloheteroaliphatic, aromatic, as defined herein, or any combination thereof, or R¹ and R², taken together with the nitrogen atom to which each are attached, form a heterocyclyl group, as defined herein. In other embodiments, the aminoalkyl group is -L-C(NR¹R²)(R³)—R⁴, in which L is a covalent bond or an alkyl group, as defined herein; each of R¹ and R² is, independently, selected from hydrogen, aliphatic, heteroaliphatic, haloaliphatic, haloheteroaliphatic, aromatic, as defined herein, or any combination thereof, or R¹and R², taken together with the nitrogen atom to which each are attached, form a heterocyclyl group, as defined herein; and each of R³ and R⁴ is, independently, H or alkyl, as defined herein.

By “aromatic” is meant a cyclic, conjugated group or moiety of, unless specified otherwise, from 5 to 15 ring atoms having a single ring (e.g., phenyl) or multiple condensed rings in which at least one ring is aromatic (e.g., naphthyl, indolyl, or pyrazolopyridinyl); that is, at least one ring, and optionally multiple condensed rings, have a continuous, delocalized π-electron system. Typically, the number of out of plane π-electrons corresponds to the Huckel rule (4n+2). The point of attachment to the parent structure typically is through an aromatic portion of the condensed ring system.

By “aryl” is meant an aromatic carbocyclic group comprising at least five carbon atoms to 15 carbon atoms (C₅₋₁₅), such as five to ten carbon atoms (C₅₋₁₀), having a single ring or multiple condensed rings, which condensed rings can or may not be aromatic provided that the point of attachment to a remaining position of the compounds disclosed herein is through an atom of the aromatic carbocyclic group. Aryl groups may be substituted with one or more groups other than hydrogen, such as aliphatic, heteroaliphatic, aromatic, other functional groups, or any combination thereof. Example aryl groups include, but are not limited to, benzyl, naphthalene, phenyl, biphenyl, phenoxybenzene, and the like. The term aryl also includes heteroaryl, which is defined as a group that contains an aromatic group that has at least one heteroatom incorporated within the ring of the aromatic group. Examples of heteroatoms include, but are not limited to, nitrogen, oxygen, sulfur, and phosphorus. Likewise, the term non-heteroaryl, which is also included in the term aryl, defines a group that contains an aromatic group that does not contain a heteroatom. The aryl group can be substituted or unsubstituted. The aryl group can be substituted with one, two, three, four, or five substituents independently selected from the group consisting of: (1) C₁₋₆ alkanoyl (e.g., —C(O)—R, in which R is C₁₋₆ alkyl); (2) C₁₋₆ alkyl; (3) C₁₋₆ alkoxy (e.g., —O—R, in which R is C₁₋₆ alkyl); (4) C₁₋₆ alkoxy-C₁₋₆ alkyl (e.g., -L-O—R, in which each of L and R is, independently, C₁₋₆ alkyl); (5) C₁₋₆ alkylsulfinyl (e.g., —S(O)—R, in which R is C₁₋₆ alkyl); (6) C₁₋₆ alkylsulfinyl-C₁₋₆ alkyl (e.g., -L-S(O)—R, in which each of L and R is, independently, C₁₋₆ alkyl); (7) C₁₋₆ alkylsulfonyl (e.g., —SO₂—R, in which R is C₁₋₆ alkyl); (8) C₁₋₆ alkylsulfonyl-C₁₋₆ alkyl (e.g., -L-SO₂—R, in which each of L and R is, independently, C₁₋₆ alkyl); (9) aryl; (10) amine (e.g., —NR¹R², where each of R¹ and R² is, independently, selected from hydrogen, aliphatic, heteroaliphatic, haloaliphatic, haloheteroaliphatic, aromatic, as defined herein, or any combination thereof, or R¹ and R², taken together with the nitrogen atom to which each are attached, form a heterocyclyl group, as defined herein); (11) C₁₋₆ aminoalkyl (e.g., -L¹—NR¹R² or -L²-C(NR¹R²)(R³)—R⁴, in which L¹ is C₁₋₆ alkyl; L² is a covalent bond or C₁₋₆ alkyl; each of R¹ and R² is, independently, selected from hydrogen, aliphatic, heteroaliphatic, haloaliphatic, haloheteroaliphatic, aromatic, as defined herein, or any combination thereof, or R¹ and R², taken together with the nitrogen atom to which each are attached, form a heterocyclyl group, as defined herein; and each of R³ and R⁴ is, independently, H or C₁₋₆ alkyl); (12) heteroaryl; (13) C₁₋₆ alkyl-C₄₋₁₈ aryl (e.g., -L-R, in which L is C₁₋₆ alkyl and R is C₄₋₁₈ aryl); (14) aryloyl (e.g., —C(O)—R, in which R is aryl); (15) azido (e.g., —N₃); (16) cyano (e.g., —CN); (17) C₁₋₆ azidoalkyl (e.g., -L-N₃, in which L is C₁₋₆ alkyl); (18) aldehyde (e.g., —C(O)H); (19) aldehyde-C₁₋₆ alkyl (e.g., -L-C(O)H, in which L is C₁₋₆ alkyl); (20) C₃₋₈ cycloalkyl; (21) C₁₋₆ alkyl-C₃₋₈ cycloalkyl (e.g., -L-R, in which L is C₁₋₆ alkyl and R is C₃₋₈ cycloalkyl); (22) halo; (23) C₁₋₆ haloalkyl (e.g., -L¹-X or -L²-C(X)(R¹)—R², in which L¹ is C₁₋₆ alkyl; L² is a covalent bond or C₁₋₆ alkyl; X is fluoro, bromo, chloro, or iodo; and each of R¹ and R² is, independently, H or C₁₋₆ alkyl); (24) heterocyclyl (e.g., as defined herein, such as a 5-, 6- or 7-membered ring containing one, two, three, or four non-carbon heteroatoms); (25) heterocyclyloxy (e.g., —O—R, in which R is heterocyclyl, as defined herein); (26) heterocyclyloyl (e.g., —C(O)—R, in which R is heterocyclyl, as defined herein); (27) hydroxyl (—OH); (28) C₁₋₆ hydroxyalkyl (e.g., -L¹—OH or -L²—C(OH)(R¹)—R², in which L¹ is C₁₋₆ alkyl; L² is a covalent bond or alkyl; and each of R¹ and R² is, independently, H or C₁₋₆ alkyl, as defined herein); (29) nitro; (30) C₁₋₆ nitroalkyl (e.g., -L¹—NO or -L²-C(NO)(R¹)—R², in which L¹ is C₁₋₆ alkyl; L² is a covalent bond or alkyl; and each of R¹ and R² is, independently, H or C₁₋₆ alkyl, as defined herein); (31)N-protected amino; (32)N-protected amino-C₁₋₆ alkyl; (33) oxo (e.g., ═O); (34) C₁₋₆ thioalkoxy (e.g., —S—R, in which R is C₁₋₆ alkyl); (35) thio-C₁₋₆ alkoxy-C₁₋₆ alkyl (e.g., -L-S—R, in which each of L and R is, independently, C₁₋₆ alkyl); (36) —(CH₂)ᵣCO₂R¹, where r is an integer of from zero to four, and R¹ is selected from the group consisting of (a) hydrogen, (b) C₁₋₆ alkyl, (c) C₄₋₁₈ aryl, and (d) C₁₋₆ alkyl-C₄₋₁₈ aryl (e.g., -L-R, in which L is C₁₋₆ alkyl and R is C₄₋₁₈ aryl); (37) —(CH₂)ᵣCONR¹R², where r is an integer of from zero to four and where each R¹ and R² is independently selected from the group consisting of (a) hydrogen, (b) C₁₋₆ alkyl, (c) C₄₋₁₈ aryl, and (d) C₁₋₆ alkyl-C₄₋₁₈ aryl (e.g., -L-R, in which L is C₁₋₆ alkyl and R is C₄₋₁₈ aryl); (38) —(CH₂)ᵣSO₂R¹, where r is an integer of from zero to four and where R¹ is selected from the group consisting of (a) C₁₋₆ alkyl, (b) C₄₋₁₈ aryl, and (c) C₁₋₆ alkyl-C₄₋₁₈ aryl (e.g., -L-R, in which L is C₁₋₆ alkyl and R is C₄₋₁₈ aryl); (39) —(CH₂)ᵣSO₂NR¹R², where r is an integer of from zero to four and where each of R¹ and R² is, independently, selected from the group consisting of (a) hydrogen, (b) C₁₋₆ alkyl, (c) C₄₋₁₈ aryl, and (d) C₁₋₆ alkyl-C₄₋₁₈ aryl (e.g., -L-R, in which L is C₁₋₆ alkyl and R is C₄₋₁₈ aryl); (40) —(CH₂)ᵣNR¹R², where r is an integer of from zero to four and where each of R¹ and R² is, independently, selected from the group consisting of (a) hydrogen, (b) an N-protecting group, (c) C₁₋₆ alkyl, (d) C₂₋₆ alkenyl, (e) C₂₋₆ alkynyl, (f) C₄₋₁₈ aryl, (g) C₁₋₆ alkyl-C₄₋₁₈ aryl (e.g., -L-R, in which L is C₁₋₆ alkyl and R is C₄₋₁₈ aryl), (h) C₃₋₈ cycloalkyl, and (i) C₁₋₆ alkyl-C₃₋₈ cycloalkyl (e.g., -L-R, in which L is C₁₋₆ alkyl and R is C₃₋₈ cycloalkyl), wherein in one embodiment no two groups are bound to the nitrogen atom through a carbonyl group or a sulfonyl group; (41) thiol (e.g., —SH); (42) perfluoroalkyl (e.g., —(CF₂)ₙCF₃, in which n is an integer from 0 to 10); (43) perfluoroalkoxy (e.g., —O—(CF₂)ₙCF₃, in which n is an integer from 0 to 10); (44) aryloxy (e.g., —O—R, in which R is aryl); (45) cycloalkoxy (e.g., —O—R, in which R is cycloalkyl); (46) cycloalkylalkoxy (e.g., —O-L-R, in which L is alkyl and R is cycloalkyl); and (47) arylalkoxy (e.g., —O-L-R, in which L is alkyl and R is aryl). In particular embodiments, an unsubstituted aryl group is a C₄₋₁₈, C₄₋₁₄, C₄₋₁₂, C₄₋₁₀, C₆₋₁₈, C₆₋₁₄, C₆₋₁₂, or C₆₋₁₀ aryl group.

By “arylalkoxy” is meant an alkyl-aryl group, as defined herein, attached to the parent molecular group through an oxygen atom. In some embodiments, the arylalkoxy group is —O-L-R, in which L is an alkyl group, as defined herein, and R is an aryl group, as defined herein.

By “aryloxy” is meant —OR, where R is an optionally substituted aryl group, as described herein. In some embodiments, an unsubstituted aryloxy group is a C₄₋₁₈ or C₆₋₁₈ aryloxy group.

By “aryloyl” is meant an aryl group that is attached to the parent molecular group through a carbonyl group. In some embodiments, an unsubstituted aryloyl group is a C₇₋₁₁ aryloyl or C₅₋₁₉ aryloyl group. In other embodiments, the aryloyl group is —C(O)—R, in which R is an aryl group, as defined herein.

By “azido” is meant an —N₃ group.

By “azidoalkyl” is meant an azido group attached to the parent molecular group through an alkyl group, as defined herein. In some embodiments, the azidoalkyl group is -L-N₃, in which L is an alkyl group, as defined herein. By “azo” is meant an —N═N— group.

By “carbene” is meant H₂C: and derivatives thereof having carbon bearing two nonbonding electrons or (C:). In some embodiments, the carbene is R¹R²(C:), where each of R¹ and R² is, independently, selected from hydrogen, aliphatic, heteroaliphatic, haloaliphatic, haloheteroaliphatic, aromatic, as defined herein, or any combination thereof, or R¹ and R², taken together with the atom to which each are attached, form a cycloaliphatic group, as defined herein.

By “carbenium cation” is meant H₃C⁺ and derivatives thereof having carbon bearing a+1 formal charge or C⁺. In some embodiments, the carbenium cation is R¹—C⁺(R)—R², where each of R, R¹, and R² is, independently, selected from hydrogen, aliphatic, heteroaliphatic, haloaliphatic, haloheteroaliphatic, aromatic, as defined herein, or any combination thereof, or R¹ and R² and optionally R, taken together with the atom to which each are attached, form a cycloaliphatic group, as defined herein.

By “carbonyl” is meant a —C(O)— group, which can also be represented as >C═O.

By “carboxyl” is meant a —CO₂H group or an anion thereof.

By “cyano” is meant a —CN group.

By “cycloaliphatic” is meant an aliphatic group, as defined herein, that is cyclic.

By “cycloalkoxy” is meant a cycloalkyl group, as defined herein, attached to the parent molecular group through an oxygen atom. In some embodiments, the cycloalkoxy group is —O—R, in which R is a cycloalkyl group, as defined herein.

By “cycloalkylalkoxy” is meant an alkyl-cycloalkyl group, as defined herein, attached to the parent molecular group through an oxygen atom. In some embodiments, the cycloalkylalkoxy group is —O-L-R, in which L is an alkyl group, as defined herein, and R is a cycloalkyl group, as defined herein.

By “cycloalkyl” is meant a monovalent saturated or unsaturated non-aromatic cyclic hydrocarbon group of from three to eight carbons, unless otherwise specified, and is exemplified by cyclopropyl, cyclobutyl, cyclopentyl, cyclohexyl, cycloheptyl, bicyclo[2.2.1.heptyl, and the like. The cycloalkyl group can also be substituted or unsubstituted. For example, the cycloalkyl group can be substituted with one or more groups including those described herein for alkyl.

By “cycloheteroaliphatic” is meant a heteroaliphatic group, as defined herein, that is cyclic.

By “ester” is meant —C(O)OR or —OC(O)R, where R is selected from aliphatic, heteroaliphatic, haloaliphatic, haloheteroaliphatic, aromatic, as defined herein, or any combination thereof.

By “halo” is meant F, Cl, Br, or I.

By “haloaliphatic” is meant an aliphatic group, as defined herein, in which one or more hydrogen atoms, such as one to 10 hydrogen atoms, independently is replaced with a halogen atom, such as fluoro, bromo, chloro, or iodo.

By “haloalkyl” is meant an alkyl group, as defined herein, where one or more hydrogen atoms, such as one to 10 hydrogen atoms, independently is replaced with a halogen atom, such as fluoro, bromo, chloro, or iodo. In an independent embodiment, haloalkyl can be a —CX₃ group, wherein each X independently can be selected from fluoro, bromo, chloro, or iodo. In some embodiments, the haloalkyl group is -L-X, in which L is an alkyl group, as defined herein, and X is fluoro, bromo, chloro, or iodo. In other embodiments, the haloalkyl group is -L-C(X)(R¹)—R², in which L is a covalent bond or an alkyl group, as defined herein; X is fluoro, bromo, chloro, or iodo; and each of R¹ and R² is, independently, H or alkyl, as defined herein.

By “haloheteroaliphatic” is meant a heteroaliphatic, as defined herein, in which one or more hydrogen atoms, such as one to 10 hydrogen atoms, independently is replaced with a halogen atom, such as fluoro, bromo, chloro, or iodo.

By “heteroaliphatic” is meant an aliphatic group, as defined herein, including at least one heteroatom to 20 heteroatoms, such as one to 15 heteroatoms, or one to 5 heteroatoms, which can be selected from, but not limited to oxygen, nitrogen, sulfur, silicon, boron, selenium, phosphorous, and oxidized forms thereof within the group.

By “heteroalkyl,” “heteroalkenyl,” and “heteroalkynyl” is meant an alkyl, alkenyl, or alkynyl group (which can be branched, straight-chain, or cyclic), respectively, as defined herein, including at least one heteroatom to 20 heteroatoms, such as one to 15 heteroatoms, or one to 5 heteroatoms, which can be selected from, but not limited to, oxygen, nitrogen, sulfur, silicon, boron, selenium, phosphorous, and oxidized forms thereof within the group.

By “heteroalkyl-aryl,” “heteroalkenyl-aryl,” and “heteroalkynyl-aryl” is meant an aryl group, as defined herein, that is or can be coupled to a compound disclosed herein, where the aryl group is or becomes coupled through a heteroalkyl, heteroalkenyl, or heteroalkynyl group, respectively, as defined herein. In some embodiments, the heteroalkyl-aryl group is -L-R, in which L is a heteroalkyl group, as defined herein, and R is an aryl group, as defined herein. In some embodiments, the heteroalkenyl-aryl group is -L-R, in which L is a heteroalkenyl group, as defined herein, and R is an aryl group, as defined herein. In some embodiments, the heteroalkynyl-aryl group is -L-R, in which L is a heteroalkynyl group, as defined herein, and R is an aryl group, as defined herein.

By “heteroalkyl-heteroaryl,” “heteroalkenyl-heteroaryl,” and “heteroalkynyl-heteroaryl” is meant a heteroaryl group, as defined herein, that is or can be coupled to a compound disclosed herein, where the heteroaryl group is or becomes coupled through a heteroalkyl, heteroalkenyl, or heteroalkynyl group, respectively, as defined herein. In some embodiments, the heteroalkyl-heteroaryl group is -L-R, in which L is a heteroalkyl group, as defined herein, and R is a heteroaryl group, as defined herein. In some embodiments, the heteroalkenyl-heteroaryl group is -L-R, in which L is a heteroalkenyl group, as defined herein, and R is a heteroaryl group, as defined herein. In some embodiments, the heteroalkynyl-heteroaryl group is -L-R, in which L is a heteroalkynyl group, as defined herein, and R is a heteroaryl group, as defined herein.

By “heteroaryl” is meant an aryl group including at least one heteroatom to six heteroatoms, such as one to four heteroatoms, which can be selected from, but not limited to, oxygen, nitrogen, sulfur, silicon, boron, selenium, phosphorous, and oxidized forms thereof within the ring. Such heteroaryl groups can have a single ring or multiple condensed rings, where the condensed rings may or may not be aromatic or contain a heteroatom, provided that the point of attachment is through an atom of the aromatic heteroaryl group. Heteroaryl groups may be substituted with one or more groups other than hydrogen, such as aliphatic, heteroaliphatic, aromatic, other functional groups, or any combination thereof. An example heteroaryl includes a subset of heterocyclyl groups, as defined herein, which are aromatic, i.e., they contain 4n+2 pi electrons within the mono- or multicyclic ring system.

By “heteroatom” is meant an atom other than carbon, such as oxygen, nitrogen, sulfur, silicon, boron, selenium, or phosphorous. In particular disclosed embodiments, such as when valency constraints do not permit, a heteroatom does not include a halogen atom.

By “heterocycle” is meant a compound having one or more heterocyclyl moieties. Non-limiting heterocycles include optionally substituted imidazole, optionally substituted triazole, optionally substituted tetrazole, optionally substituted pyrazole, optionally substituted imidazoline, optionally substituted pyrazoline, optionally substituted imidazolidine, optionally substituted pyrazolidine, optionally substituted pyrrole, optionally substituted pyrroline, optionally substituted pyrrolidine, optionally substituted tetrahydrofuran, optionally substituted furan, optionally substituted thiophene, optionally substituted oxazole, optionally substituted isoxazole, optionally substituted isothiazole, optionally substituted thiazole, optionally substituted oxathiolane, optionally substituted oxadiazole, optionally substituted thiadiazole, optionally substituted sulfolane, optionally substituted succinimide, optionally substituted thiazolidinedione, optionally substituted oxazolidone, optionally substituted hydantoin, optionally substituted pyridine, optionally substituted piperidine, optionally substituted pyridazine, optionally substituted piperazine, optionally substituted pyrimidine, optionally substituted pyrazine, optionally substituted triazine, optionally substituted pyran, optionally substituted pyrylium, optionally substituted tetrahydropyran, optionally substituted dioxine, optionally substituted dioxane, optionally substituted dithiane, optionally substituted trithiane, optionally substituted thiopyran, optionally substituted thiane, optionally substituted oxazine, optionally substituted morpholine, optionally substituted thiazine, optionally substituted thiomorpholine, optionally substituted cytosine, optionally substituted thymine, optionally substituted uracil, optionally substituted thiomorpholine dioxide, optionally substituted indene, optionally substituted indoline, optionally substituted indole, optionally substituted isoindole, optionally substituted indolizine, optionally substituted indazole, optionally substituted benzimidazole, optionally substituted azaindole, optionally substituted azaindazole, optionally substituted pyrazolopyrimidine, optionally substituted purine, optionally substituted benzofuran, optionally substituted isobenzofuran, optionally substituted benzothiophene, optionally substituted benzisoxazole, optionally substituted anthranil, optionally substituted benzisothiazole, optionally substituted benzoxazole, optionally substituted benzthiazole, optionally substituted benzthiadiazole, optionally substituted adenine, optionally substituted guanine, optionally substituted tetrahydroquinoline, optionally substituted dihydroquinoline, optionally substituted dihydroisoquinoline, optionally substituted quinoline, optionally substituted isoquinoline, optionally substituted quinolizine, optionally substituted quinoxaline, optionally substituted phthalazine, optionally substituted quinazoline, optionally substituted cinnoline, optionally substituted naphthyridine, optionally substituted pyridopyrimidine, optionally substituted pyridopyrazine, optionally substituted pteridine, optionally substituted chromene, optionally substituted isochromene, optionally substituted chromenone, optionally substituted benzoxazine, optionally substituted quinolinone, optionally substituted isoquinolinone, optionally substituted carbazole, optionally substituted dibenzofuran, optionally substituted acridine, optionally substituted phenazine, optionally substituted phenoxazine, optionally substituted phenothiazine, optionally substituted phenoxathiine, optionally substituted quinuclidine, optionally substituted azaadamantane, optionally substituted dihydroazepine, optionally substituted azepine, optionally substituted diazepine, optionally substituted oxepane, optionally substituted thiepine, optionally substituted thiazepine, optionally substituted azocane, optionally substituted azocine, optionally substituted thiocane, optionally substituted azonane, optionally substituted azecine, etc. Optional substitutions include any described herein for aryl. Heterocycles can also include cations or salts of any of these.

By “heterocyclyl” is meant a 5-, 6- or 7-membered ring, unless otherwise specified, containing one, two, three, or four non-carbon heteroatoms (e.g., independently selected from the group consisting of nitrogen, oxygen, phosphorous, sulfur, or halo). The 5-membered ring has zero to two double bonds and the 6- and 7-membered rings have zero to three double bonds. The term “heterocyclyl” also includes bicyclic, tricyclic and tetracyclic groups in which any of the above heterocyclic rings is fused to one, two, or three rings independently selected from the group consisting of an aryl ring, a cyclohexane ring, a cyclohexene ring, a cyclopentane ring, a cyclopentene ring, and another monocyclic heterocyclic ring, such as indolyl, quinolyl, isoquinolyl, tetrahydroquinolyl, benzofuryl, benzothienyl and the like. Heterocyclics include thiiranyl, thietanyl, tetrahydrothienyl, thianyl, thiepanyl, aziridinyl, azetidinyl, pyrrolidinyl, piperidinyl, azepanyl, pyrrolyl, pyrrolinyl, pyrazolyl, pyrazolinyl, pyrazolidinyl, imidazolyl, imidazolinyl, imidazolidinyl, pyridyl, homopiperidinyl, pyrazinyl, piperazinyl, pyrimidinyl, pyridazinyl, oxazolyl, oxazolidinyl, oxazolidonyl, isoxazolyl, isoxazolidiniyl, morpholinyl, thiomorpholinyl, thiazolyl, thiazolidinyl, isothiazolyl, isothiazolidinyl, indolyl, quinolinyl, isoquinolinyl, benzimidazolyl, benzothiazolyl, benzoxazolyl, furyl, thienyl, thiazolidinyl, isothiazolyl, isoindazoyl, triazolyl, tetrazolyl, oxadiazolyl, uricyl, thiadiazolyl, pyrimidyl, tetrahydrofuranyl, dihydrofuranyl, dihydrothienyl, dihydroindolyl, tetrahydroquinolyl, tetrahydroisoquinolyl, pyranyl, dihydropyranyl, tetrahydropyranyl, dithiazolyl, dioxanyl, dioxinyl, dithianyl, trithianyl, oxazinyl, thiazinyl, oxothiolanyl, triazinyl, benzofuranyl, benzothienyl, and the like.

By “heterocyclyloxy” is meant a heterocyclyl group, as defined herein, attached to the parent molecular group through an oxygen atom. In some embodiments, the heterocyclyloxy group is —O—R, in which R is a heterocyclyl group, as defined herein.

By “heterocyclyloyl” is meant a heterocyclyl group, as defined herein, attached to the parent molecular group through a carbonyl group. In some embodiments, the heterocyclyloyl group is —C(O)—R, in which R is a heterocyclyl group, as defined herein.

By “hydroxyl” is meant —OH.

By “hydroxyalkyl” is meant an alkyl group, as defined herein, substituted by one to three hydroxyl groups, with the proviso that no more than one hydroxyl group may be attached to a single carbon atom of the alkyl group and is exemplified by hydroxymethyl, dihydroxypropyl, and the like. In some embodiments, the hydroxyalkyl group is -L-OH, in which L is an alkyl group, as defined herein. In other embodiments, the hydroxyalkyl group is -L-C(OH)(R¹)—R², in which L is a covalent bond or an alkyl group, as defined herein, and each of R¹ and R² is, independently, H or alkyl, as defined herein.

By “ketone” is meant —C(O)R, where R is selected from aliphatic, heteroaliphatic, aromatic, as defined herein, or any combination thereof.

By “nitro” is meant an —NO₂ group.

By “nitroalkyl” is meant an alkyl group, as defined herein, substituted by one to three nitro groups. In some embodiments, the nitroalkyl group is -L-NO, in which L is an alkyl group, as defined herein. In other embodiments, the nitroalkyl group is -L-C(NO)(R¹)—R², in which L is a covalent bond or an alkyl group, as defined herein, and each of R¹ and R² is, independently, H or alkyl, as defined herein.

By “oxo” is meant an ═O group.

By “oxy” is meant —O—.

By “perfluoroalkyl” is meant an alkyl group, as defined herein, having each hydrogen atom substituted with a fluorine atom. Example perfluoroalkyl groups include trifluoromethyl, pentafluoroethyl, etc. In some embodiments, the perfluoroalkyl group is —(CF₂)ₙCF₃, in which n is an integer from 0 to 10.

By “perfluoroalkoxy” is meant an alkoxy group, as defined herein, having each hydrogen atom substituted with a fluorine atom. In some embodiments, the perfluoroalkoxy group is —O—R, in which R is a perfluoroalkyl group, as defined herein.

By “salt” is meant an ionic form of a compound or structure (e.g., any formulas, compounds, or compositions described herein), which includes a cation or anion compound to form an electrically neutral compound or structure. Salts are well known in the art. For example, non-toxic salts are described in Berge S M et al., “Pharmaceutical salts,” J. Pharm. Sci. 1977 January; 66(1):1-19; and in “Handbook of Pharmaceutical Salts: Properties, Selection, and Use,” Wiley-VCH, April 2011 (2nd rev. ed., eds. P. H. Stahl and C. G. Wermuth. The salts can be prepared in situ during the final isolation and purification of the compounds of the invention or separately by reacting the free base group with a suitable organic acid (thereby producing an anionic salt) or by reacting the acid group with a suitable metal or organic salt (thereby producing a cationic salt). Representative anionic salts include acetate, adipate, alginate, ascorbate, aspartate, benzenesulfonate, benzoate, bicarbonate, bisulfate, bitartrate, borate, bromide, butyrate, camphorate, camphorsulfonate, chloride, citrate, cyclopentanepropionate, digluconate, dihydrochloride, diphosphate, dodecylsulfate, edetate, ethanesulfonate, fumarate, glucoheptonate, gluconate, glutamate, glycerophosphate, hemisulfate, heptonate, hexanoate, hydrobromide, hydrochloride, hydroiodide, hydroxyethanesulfonate, hydroxynaphthoate, iodide, lactate, lactobionate, laurate, lauryl sulfate, malate, maleate, malonate, mandelate, mesylate, methanesulfonate, methylbromide, methylnitrate, methylsulfate, mucate, 2-naphthalenesulfonate, nicotinate, nitrate, oleate, oxalate, palmitate, pamoate, pectinate, persulfate, 3-phenylpropionate, phosphate, picrate, pivalate, polygalacturonate, propionate, salicylate, stearate, subacetate, succinate, sulfate, tannate, tartrate, theophyllinate, thiocyanate, triethiodide, toluenesulfonate, undecanoate, valerate salts, and the like. Representative cationic salts include metal salts, such as alkali or alkaline earth salts, e.g., barium, calcium (e.g., calcium edetate), lithium, magnesium, potassium, sodium, and the like; other metal salts, such as aluminum, bismuth, iron, and zinc; as well as nontoxic ammonium, quaternary ammonium, and amine cations, including, but not limited to ammonium, tetramethylammonium, tetraethylammonium, methylamine, dimethylamine, trimethylamine, triethylamine, ethylamine, pyridinium, and the like. Other cationic salts include organic salts, such as chloroprocaine, choline, dibenzylethylenediamine, diethanolamine, ethylenediamine, methylglucamine, and procaine. Yet other salts include ammonium, sulfonium, sulfoxonium, phosphonium, iminium, imidazolium, benzimidazolium, amidinium, guanidinium, phosphazinium, phosphazenium, pyridinium, etc., as well as other cationic groups described herein (e.g., optionally substituted isoxazolium, optionally substituted oxazolium, optionally substituted thiazolium, optionally substituted pyrrolium, optionally substituted furanium, optionally substituted thiophenium, optionally substituted imidazolium, optionally substituted pyrazolium, optionally substituted isothiazolium, optionally substituted triazolium, optionally substituted tetrazolium, optionally substituted furazanium, optionally substituted pyridinium, optionally substituted pyrimidinium, optionally substituted pyrazinium, optionally substituted triazinium, optionally substituted tetrazinium, optionally substituted pyridazinium, optionally substituted oxazinium, optionally substituted pyrrolidinium, optionally substituted pyrazolidinium, optionally substituted imidazolinium, optionally substituted isoxazolidinium, optionally substituted oxazolidinium, optionally substituted piperazinium, optionally substituted piperidinium, optionally substituted morpholinium, optionally substituted azepanium, optionally substituted azepinium, optionally substituted indolium, optionally substituted isoindolium, optionally substituted indolizinium, optionally substituted indazolium, optionally substituted benzimidazolium, optionally substituted isoquinolinum, optionally substituted quinolizinium, optionally substituted dehydroquinolizinium, optionally substituted quinolinium, optionally substituted isoindolinium, optionally substituted benzimidazolinium, and optionally substituted purinium).

By “silyl” is meant a —SiR¹R²R³ or —SiR¹R²—group. In some embodiments, each of R¹, R², and R³ is, independently, H, optionally substituted aliphatic, optionally substituted heteroaliphatic, optionally substituted aromatic, optionally substituted heteroaromatic, or optionally substituted amino. In particular embodiments, each of R¹, R², and R³ is, independently, H, optionally substituted alkyl, optionally substituted alkoxy, optionally substituted aryl, optionally substituted aryloxy, optionally substituted alkyl-aryl, optionally substituted aryl-alkyl, or optionally substituted amino. In other embodiments, the silyl group is —Si(R)ₐ(OR)_{b}(NR₂)_{c}, in which each R is, independently, H, optionally substituted aliphatic, optionally substituted heteroaliphatic, optionally substituted aromatic, or optionally substituted heteroaromatic; each of a, b, and c≥0; and a+b+c=3. In particular embodiments, each R is, independently, H, optionally substituted alkyl, optionally substituted aryl, optionally substituted alkyl-aryl, or optionally substituted aryl-alkyl.

By “silyloxy” is meant —OR, where R is an optionally substituted silyl group, as described herein. In some embodiments, the silyloxy group is —O—SiR¹R²R³, in which each of R¹, R², and R³ is, independently, H, optionally substituted aliphatic, optionally substituted heteroaliphatic, optionally substituted aromatic, optionally substituted heteroaromatic, or optionally substituted amino. In particular embodiments, each of R¹, R², and R³ is, independently, H, optionally substituted alkyl, optionally substituted alkoxy, optionally substituted aryl, optionally substituted aryloxy, optionally substituted alkyl-aryl, optionally substituted aryl-alkyl, or optionally substituted amino. In other embodiments, the silyloxy group is —O—Si(R)ₐ(OR)_{b}(NR₂)_{c}, in which each R is, independently, H, optionally substituted aliphatic, optionally substituted heteroaliphatic, optionally substituted aromatic, or optionally substituted heteroaromatic; each of a, b, and c>0; and a+b+c=3. In particular embodiments, each R is, independently, H, optionally substituted alkyl, optionally substituted aryl, optionally substituted alkyl-aryl, or optionally substituted aryl-alkyl

By “sulfo” is meant an —S(O)₂OH group.

By “sulfonyl” or “sulfonate” is meant an —S(O)₂— group or a —SO₂R, where R is selected from hydrogen, aliphatic, heteroaliphatic, haloaliphatic, haloheteroaliphatic, aromatic, as defined herein, or any combination thereof.

By “thioalkoxy” is meant an alkyl group, as defined herein, attached to the parent molecular group through a sulfur atom. Example unsubstituted thioalkoxy groups include C₁₋₆ thioalkoxy. In some embodiments, the thioalkoxy group is —S—R, in which R is an alkyl group, as defined herein.

By “thiol” is meant an —SH group.

As used herein, the term “about” means+/−10% of any recited value. As used herein, this term modifies any recited value, range of values, or endpoints of one or more ranges.

As used herein, the term “or” is used to link alternatives provided within a list. The use of this term does not exclude the use of such alternatives together, such as in a combination; and the use of this term does not indicate or require that an alternative must be used alone. The use of this term can indicate that the alternative can be used alone or can be used together with any other alternative within the list.

As used herein, the terms “top,” “bottom,” “upper,” “lower,” “above,” and “below” are used to provide a relative relationship between structures. The use of these terms does not indicate or require that a particular structure must be located at a particular location in the apparatus.

Any of the example materials described herein include unsubstituted or substituted forms of the compound (e.g., halogen source, additive, carrier gas, precursors, and the like). Non-limiting example substituents include, e.g., one, two, three, four, or more substituents independently selected from the group consisting of: (1) C₁₋₆ alkoxy (e.g., —O—R, in which R is C₁₋₆ alkyl); (2) C₁₋₆ alkylsulfinyl (e.g., —S(O)—R, in which R is C₁₋₆ alkyl); (3) C₁₋₆ alkylsulfonyl (e.g., —SO₂—R, in which R is C₁₋₆ alkyl); (4) amine (e.g., —C(O)NR¹R² or —NHCOR¹, where each of R¹ and R² is, independently, selected from hydrogen, aliphatic, heteroaliphatic, haloaliphatic, haloheteroaliphatic, aromatic, as defined herein, or any combination thereof, or R¹ and R², taken together with the nitrogen atom to which each are attached, form a heterocyclyl group, as defined herein); (5) aryl; (6) arylalkoxy (e.g., —O-L-R, in which L is alkyl and R is aryl); (7) aryloyl (e.g., —C(O)—R, in which R is aryl); (8) azido (e.g., —N₃); (9) cyano (e.g., —CN); (10) aldehyde (e.g., —C(O)H); (11) C₃₋₈ cycloalkyl; (12) halo; (13) heterocyclyl (e.g., as defined herein, such as a 5-, 6- or 7-membered ring containing one, two, three, or four non-carbon heteroatoms); (14) heterocyclyloxy (e.g., —O—R, in which R is heterocyclyl, as defined herein); (15) heterocyclyloyl (e.g., —C(O)—R, in which R is heterocyclyl, as defined herein); (16) hydroxyl (e.g., —OH); (17)N-protected amino; (18) nitro (e.g., —NO₂); (19) oxo (e.g., ═O); (20) C₁₋₆ thioalkoxy (e.g., —S—R, in which R is C₁₋₆ alkyl); (21) thiol (e.g., —SH); (22) —CO₂R¹, where R¹ is selected from the group consisting of (a) hydrogen, (b) C₁₋₆ alkyl, (c) C₄₋₁₈ aryl, and (d) C₁₋₆ alkyl-C₄₋₁₈ aryl (e.g., -L-R, in which L is C₁₋₆ alkyl and R is C₄₋₁₈ aryl); (23) —C(O)NR¹R², where each of R¹ and R² is, independently, selected from the group consisting of (a) hydrogen, (b) C₁₋₆ alkyl, (c) C₄₋₁₈ aryl, and (d) C₁₋₆ alkyl-C₄₋₁₈ aryl (e.g., -L-R, in which L is C₁₋₆ alkyl and R is C₄₋₁₈ aryl); (24) —SO₂R¹, where R¹ is selected from the group consisting of (a) C₁₋₆ alkyl, (b) C₄₋₁₈ aryl, and (c) C₁₋₆ alkyl-C₄₋₁₈ aryl (e.g., -L-R, in which L is C₁₋₆ alkyl and R is C₄₋₁₈ aryl); (25) —SO₂NR¹R², where each of R¹ and R² is, independently, selected from the group consisting of (a) hydrogen, (b) C₁₋₆ alkyl, (c) C₄₋₁₈ aryl, and (d) C₁₋₆ alkyl-C₄₋₁₈ aryl (e.g., -L-R, in which L is C₁₋₆ alkyl and R is C₄₋₁₈ aryl); and (26) —NR¹R², where each of R¹ and R² is, independently, selected from the group consisting of (a) hydrogen, (b) an N-protecting group, (c) C₁₋₆ alkyl, (d) C₂₋₆ alkenyl, (e) C₂₋₆ alkynyl, (f) C₄₋₁₈ aryl, (g) C₁₋₆ alkyl-C₄₋₁₈ aryl (e.g., -L-R, in which L is C₁₋₆ alkyl and R is C₄₋₁₈ aryl), (h) C₃₋₈ cycloalkyl, and (i) C₁₋₆ alkyl-C₃₋₈ cycloalkyl (e.g., -L-R, in which L is C₁₋₆ alkyl and R is C₃₋₈ cycloalkyl), wherein in one embodiment no two groups are bound to the nitrogen atom through a carbonyl group or a sulfonyl group.

Other features and advantages of the invention will be apparent from the description and the claims herein.

### CONCLUSION

Although the foregoing embodiments have been described in some detail for purposes of clarity of understanding, it will be apparent that certain changes and modifications may be practiced within the scope of the appended claims. Embodiments disclosed herein may be practiced without some or all of these specific details. In other instances, well-known process operations have not been described in detail to not unnecessarily obscure the disclosed embodiments. Further, while the disclosed embodiments will be described in conjunction with specific embodiments, it will be understood that the specific embodiments are not intended to limit the disclosed embodiments. It should be noted that there are many alternative ways of implementing the processes, systems, and apparatus of the present embodiments. Accordingly, the present embodiments are to be considered as illustrative and not restrictive, and the embodiments are not to be limited to the details given herein.

1. A method for forming heterolayers on a substrate, the method comprising:
(a) forming a first layer by flowing a first precursor into a reaction chamber and toward a substrate in the presence of an energetic species, wherein the energetic species reacts with the first precursor to deposit the first layer on the substrate, and wherein the substrate is disposed within the reaction chamber;
(b) forming a second layer by flowing a second precursor and an optional third precursor into the reaction chamber and toward the substrate in the presence of an energetic species, wherein the energetic species reacts with the second precursor or the optional third precursor to deposit the second layer on the substrate; and
(c) repeating (a) and (b) until a predetermined number of layers have been deposited on the substrate,
optionally wherein the first layer has a differing etch behavior than the second layer.

2. The method of claim 1, wherein the energetic species comprises one or more of radicals, plasma-generated radicals, metastables, plasma-generated metastables, ions, or plasma-generated ions.

3. The method of claim 1, wherein the energetic species comprises at least one of hydrogen-containing radicals, deuterium-containing radicals, helium-containing metastables, or argon-containing metastables.

4. The method of claim 1, wherein the energetic species is characterized by a density of at least about 10⁸ cm⁻³ at a surface of the substrate.

5. The method of claim 1, wherein the second layer comprises a sacrificial layer.

6. The method of claim 1, further comprising, before operation (a) or (b):
(a″′) depositing a buffer layer between the substrate and the first layer or between the substrate and the second layer.

7. The method of claim 1, wherein operations (a) and (b) occur subsequent to an initial layer being deposited on the substrate.

8. The method of claim 1, wherein (1) the energetic species is generated in a remote plasma source positioned upstream of the reaction chamber, or (2) the energetic species is generated in situ in a portion of the reaction chamber, or (3) wherein the energetic species is generated by way of plasma.

9. The method of claim 1, further comprising (1) heating the substrate using a radiative heat source, or (2) providing an interfacial layer between the first layer and the second layer.

10. The method of claim 1, further comprising either:
(1) exposing the substrate to a plasma after operation (a), between operations (a) and (b), or after operation (b); or
(2) before operation (a) or after operation (c), performing at least one of operation (a′) or (a″):
(a′) precleaning the substrate to provide a precleaned surface of the substrate; or
(a″) pretreating the surface of the substrate to provide a pretreated surface of the substrate; or
(3) before operation (a) or after operation (c), performing at least one of operation (c′) or (c″):
(c′) performing a reactor clean of the reaction chamber either after removing the substrate from the reaction chamber or before providing the substrate to the reaction chamber by removing contaminants from an environment or a surface within the reaction chamber; or
(c″) performing a reactor treat of the reaction chamber after operation (c′) by passivating the environment or the surface within the reaction chamber.

11. An apparatus to form heterolayers on a substrate, the apparatus comprising:
a reaction chamber;
a substrate support positioned in the reaction chamber and configured to support a substrate;
a plasma source; and
one or more controllers configured with instructions for performing the following operations:
(a) causing formation of a first layer by flowing a first precursor into the reaction chamber and toward the substrate in the presence of a plasma-generated energetic species, wherein the plasma-generated energetic species reacts with the first precursor to deposit the first layer on the substrate;
(b) causing formation of a second layer by flowing a second precursor and an optional third precursor into the reaction chamber and toward the substrate in the presence of a plasma-generated energetic species, wherein the plasma-generated energetic species reacts with the second precursor and the optional third precursor to deposit the second layer on the substrate; and
(c) causing repetition of (a) and (b) until a predetermined number of layers have been deposited on the substrate,
optionally wherein the first layer has a differing etch behavior than the second layer.

12. A method for epitaxially depositing a film, the method comprising:
precleaning a surface of a substrate to remove an oxide;
pretreating the surface of the substrate to provide a hydrophobic surface or a passivated surface;
epitaxially depositing at least one of a first layer or a second layer in the presence of plasma on a precleaned and pretreated surface and within an epitaxy chamber;
removing the substrate from the epitaxy chamber; and
performing a reactor clean, wherein the performing the reactor clean is performed at least one of before providing the substrate within the epitaxy chamber or after the removing the substrate from the epitaxy chamber.

13. The method of claim 12, wherein the precleaning comprises delivering a halogen-containing reagent, a halogen-containing vapor, or a halogen-containing plasma.

14. The method of claim 12, further comprising, before the epitaxially depositing:
depositing a buffer layer between the substrate and the first layer or between the substrate and the second layer.

15-20. (canceled)
